(19) United States
(12) Patent Application Publication
(10) Pub. No.: US 2023/0240131 A1
(43) Pub. Date: Jul. 27, 2023

(54) LIGHT EMITTING ELEMENT AND ORGANOMETALLIC COMPOUND FOR THE SAME

(71) Applicant: Samsung Display Co., Ltd., Yongin-si (KR)

(72) Inventors: Eunyoung LEE, Yongin-si (KR); Soo-Byung KO, Yongin-si (KR); Sungbum KIM, Yongin-si (KR); Eunsoo AHN, Yongin-si (KR); Mina JEON, Yongin-si (KR); Jinhee JU, Yongin-si (KR)

(21) Appl. No.: 18/160,269

(22) Filed: Jan. 26, 2023

(30) Foreign Application Priority Data
Jan. 26, 2022 (KR) 10-2022-0011819
Jan. 19, 2023 (KR) 10-2023-0007891

(51) Int. Cl. H10K 85/30; C09K 11/06; C07F 15/00

(52) U.S. Cl. CPC H10K 85/346; C09K 11/06; C07F 15/0086; H10K 50/12

(57) ABSTRACT

A light emitting element that includes a first electrode, a second electrode on the first electrode, and an emission layer between the first electrode and the second electrode is provided. The emission layer includes an organometallic compound represented by a specific chemical structure. Accordingly, the light emitting element exhibits a high color purity, a low driving voltage, a long service life, and a high efficiency.

### CROSS-REFERENCE TO RELATED APPLICATION

This application claims priority to and the benefit of Korean Patent Applications No. 10-2022-0011819, filed on Jan. 26, 2022, and Korean Patent Applications No. 10-2023-0007891, filed on Jan. 19, 2023, the entire content of both of which is hereby incorporated by reference.

### BACKGROUND

### 1. Field

Aspects of one or more embodiments of the present disclosure herein relate to a light emitting element and an organometallic compound utilized therein.

### 2. Description of the Related Art

Recently, the development of an organic electroluminescence display device as an image display device is being actively conducted. The organic electroluminescence display device includes a self-luminescent light emitting element in which holes and electrons injected from a first electrode and a second electrode recombine in an emission layer, and thus a luminescent material of the emission layer emits light to implement a display (e.g., to display an image).

In the application of a light emitting element to a display device, there is a demand for a light emitting element having a high luminous efficiency and a long service life, and development of materials for a light emitting element capable of stably attaining such a characteristic is being continuously required (sought).

### SUMMARY

An aspect of one or more embodiments of the present disclosure is directed toward a light emitting element exhibiting a low driving voltage, a long service life, and/or a high luminous efficiency.

An aspect of one or more embodiments of the present disclosure is directed toward an organometallic compound which is a material for a light emitting element having low driving voltage, long service life, and/or high luminous efficiency characteristics.

Additional aspects will be set forth in part in the description which follows and, in part, will be apparent from the description, or may be learned by practice of the presented embodiments of the disclosure.

An embodiment of the present disclosure provides a light emitting element including: a first electrode; a second electrode on the first electrode; and an emission layer which is between the first electrode and the second electrode and includes an organometallic compound represented by Formula 1:

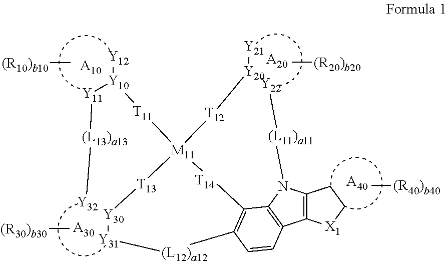

In Formula 1, M₁₁ is Pt, Pd, Cu, Ag, Au, Rh, Ir, Ru, Os, Ti, Zr, Hf, Eu, Tb, or Tm, and X₁ is O or S. Y₁₀, Y₁₁, Y₁₂, Y₂₀, Y₂₁, Y₂₂, Y₃₀, Y₃₁, and Y₃₂ may each independently be N, C, NRₐ, or CR_{b}. T₁₁ to T₁₄ may each independently be a direct linkage, *—O—*′, or *—S—*′, and L₁₁ to L₁₃ may each independently be a direct linkage, *—O—*′, *—S—*′, *—C(R₁)(R₂)—*′, *—C(R₁)═*′, *═C(R₁)—*′, *—C(R₁)═C(R₂)—*′, *—C(═O)—*′, *—C(═S)—*′, *—C≡C—*′, *—B(R₁)—*′, *—N(R₁)—*′, *—P(R₁)—*′, *—Si(R₁)(R₂)—*′, or *—Ge(R₁)(R₂)—*′. a11 to a13 may each independently be an integer from 0 to 3, rigs A₁₀, A₂₀, A₃₀, and A₄₀ may each independently be a substituted or unsubstituted hydrocarbon ring having 5 to 60 ring-forming carbon atoms, or a substituted or unsubstituted heterocycle having 2 to 60 ring-forming carbon atoms, and Rₐ, R_{b}, R₁, R₂, R₁₀, R₂₀, R₃₀, and R₄₀ may each independently be a hydrogen atom, a deuterium atom, —F, —Cl, —Br, —I, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂), and/or bonded to an adjacent group to form a ring. b10, b20, b30, and b40 may each independently be an integer from 0 to 8, Q₁ to Q₃ may each independently be a hydrogen atom, a deuterium atom, a halogen atom, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms, and * and are linkage positions.

In an embodiment, the emission layer may emit green phosphorescence.

In an embodiment, the emission layer may include a host and a dopant, and the dopant may include the organometallic compound represented by Formula 1.

In an embodiment, the organometallic compound represented by Formula 1 may be represented by Formula 2:

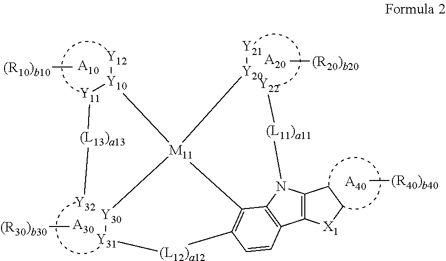

In Formula 2, M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, L₁₁ to L₁₃, a11 to a13, R₁₀, R₂₀, R₃₀, R₄₀, b10, b20, b30, and b40 may each independently be the same as defined in Formula 1.

In an embodiment, the organometallic compound represented by Formula 1 may be represented by Formula 3:

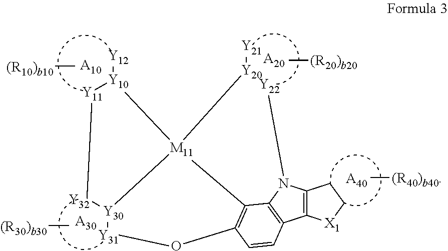

In Formula 3, M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, R₁₀, R₂₀, R₃₀, R₄₀, b10, b20, b30, and b40 may each independently be the same as defined in Formula 1.

In an embodiment, the organometallic compound represented by Formula 3 may be represented by any one selected from among Formula 3-1 to Formula 3-3:

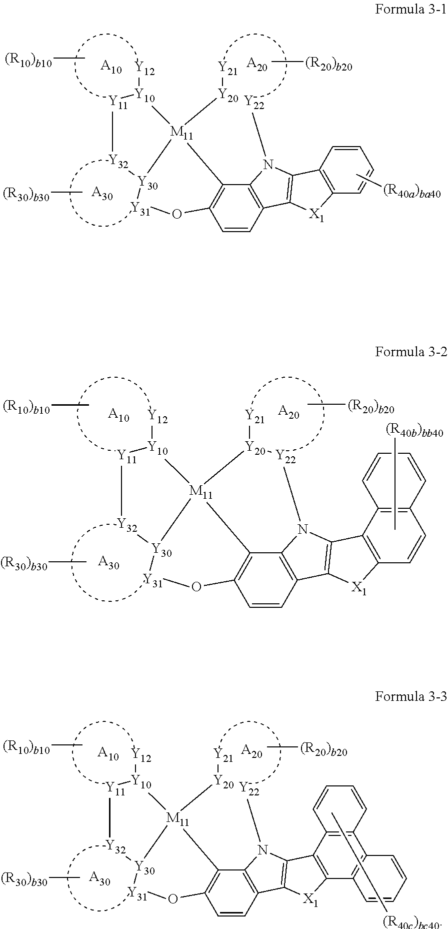

In Formula 3-1 to Formula 3-3, R₄₀ₐ to R_{40c} may each independently be a hydrogen atom or a deuterium atom, ba40 may be an integer from 0 to 4, bb40 may be an integer from 0 to 6, bc40 may be an integer from 0 to 8, and M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, R₁₀, R₂₀, R₃₀, b10, b20, and b30 may each independently be the same as defined in Formula 1.

In an embodiment, the organometallic compound represented by Formula 1 may be represented by Formula 4:

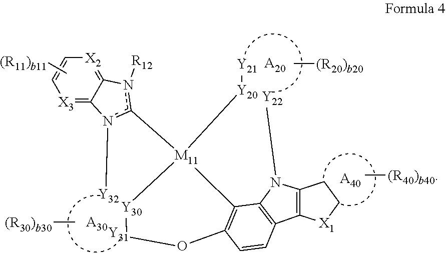

In Formula 4, X₂ and X₃ may each independently be CRₓ or N, Rₓ and R₁₁ may each independently be a hydrogen atom, a deuterium atom, a substituted or unsubstituted alkyl group having 1 to 60 carbon atoms, or a substituted or unsubstituted aryl group having 6 to 60 ring-forming carbon atoms, b11 may be an integer from 0 to 2, R₁₂ may be a substituted or unsubstituted aryl group having 6 to 60 ring-forming carbon atoms, or a substituted or unsubstituted heteroaryl group having 2 to 60 ring-forming carbon atoms, and M₁₁, X₁, Y₂₀, Y₂₁, Y₂₂, Y₃₀, Y₃₁, Y₃₂, A₂₀, A₃₀, A₄₀, R₂₀, R₃₀, R₄₀, b20, b30, and b40 may each independently be the same as defined in Formula 1.

In an embodiment, the organometallic compound represented by Formula 4 may be represented by Formula 5:

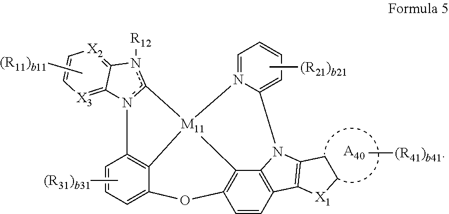

In Formula 5, R₂₁, R₃₁, and R₄₁ may each independently be a hydrogen atom, a deuterium atom, a cyano group, a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), or —N(Q₁)(Q₂), b21 may be an integer from 0 to 4, b31 may be an integer from 0 to 3, b41 may be an integer from 0 to 8, A₄₀, X₁, M₁₁, and Q₁ to Q₃ may each independently be the same as defined in Formula 1 and X₂, X₃, R₁₁, R₁₂, and b11 may each independently be the same as defined in Formula 4.

In an embodiment, the organometallic compound represented by Formula 5 may be represented by any one selected from among Formula 5-1 to Formula 5-3:

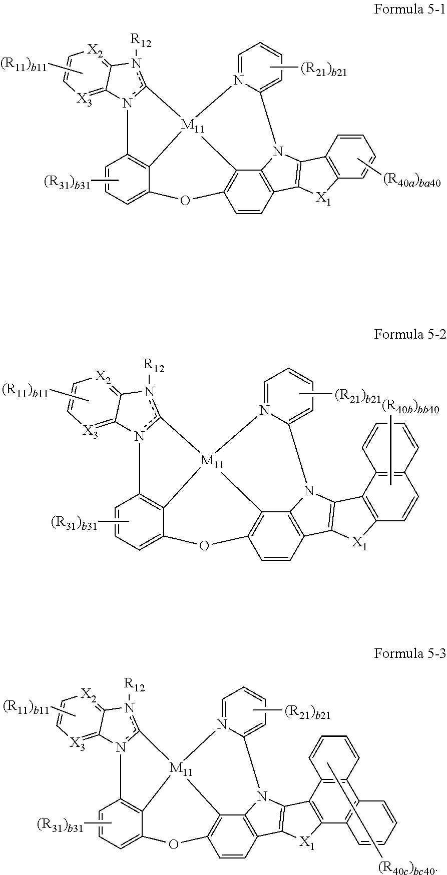

In Formula 5-1 to Formula 5-3, R₄₀ₐ to R_{40c} may each independently be a hydrogen atom, or a deuterium atom, ba40 may be an integer from 0 to 4, bb40 may be an integer from 0 to 6, bc40 may be an integer from 0 to 8, and M₁₁, X₁, X₂, X₃, R₁₁, R₁₂, R₂₁, R₃₁, b11, b21, and b31 may each independently be the same as defined in Formula 5.

In an embodiment, R₁₂ may be represented by any one selected from among R12-1 to R12-32 which will be described in more detail.

In an embodiment, R₁₁, R₂₁, R₃₁, and R₄₁ may each independently be a hydrogen atom, a deuterium atom, a substituted or unsubstituted methyl group, a substituted or unsubstituted i-propyl group, a substituted or unsubstituted t-butyl group, a substituted or unsubstituted phenyl group, a substituted or unsubstituted pyridine group, —Si(Ph)₃, —Si(CH₃)(CH₃)(CH₃), or —N(CH₃)(CH₃).

In an embodiment, R₁₀, R₂₀, R₃₀, and R₄₀ may each independently be a hydrogen atom, a deuterium atom, a cyano group, a substituted or unsubstituted alkyl group having 1 to 30 carbon atoms, a substituted or unsubstituted aryl group having 6 to 30 ring-forming carbon atoms, a substituted or unsubstituted heteroaryl group having 2 to 30 ring-forming carbon atoms, —Si(Q₁)(Q₂)(Q₃), or —N(Q₁)(Q₂), and Q₁ to Q₃ may each independently be a hydrogen atom, a deuterium atom, a substituted or unsubstituted alkyl group having 1 to 30 carbon atoms, or a substituted or unsubstituted aryl group having 6 to 30 ring-forming carbon atoms.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view illustrating a display device according to an embodiment,

FIG. 2 is a cross-sectional view illustrating a part taken along line I-I′ of FIG. 1;

FIG. 3 is a cross-sectional view schematically illustrating a light emitting element of an embodiment;

FIG. 4 is a cross-sectional view schematically illustrating a light emitting element of an embodiment;

FIG. 5 is a cross-sectional view schematically illustrating a light emitting element of an embodiment;

FIG. 6 is a cross-sectional view schematically illustrating a light emitting element of an embodiment;

FIG. 7 is a cross-sectional view illustrating a display device according to an embodiment;

FIG. 8 is a cross-sectional view illustrating a display device according to an embodiment;

FIG. 9 is a cross-sectional view illustrating a display device according to an embodiment; and

FIG. 10 is a cross-sectional view illustrating a display device according to an embodiment.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present disclosure, when a component (or a region, a layer, a portion, etc.) is referred to as being “on,” “connected to,” or “coupled to” another component, it refers to that the component may be directly disposed on/connected to/coupled to the other component, or that one or more third components may be disposed therebetween.

Like reference numerals refer to like elements throughout, and duplicative descriptions thereof may not be provided. Also, in the drawings, the thicknesses, ratios, and dimensions of the components may be exaggerated for effective description of technical contents. The term “and/or” includes all combinations of one or more of which associated configurations may define.

It will be understood that, although the terms “first,” “second,” etc., may be utilized herein to describe one or more suitable components, these components should not be limited by these terms. These terms are only utilized to distinguish one element from another. For example, a first component could be termed a second component, and, similarly, a second component could be termed a first component, without departing from the scope of the present disclosure. As utilized herein, the singular forms, “a,” “an,” and “the” are intended to include the plural forms as well, unless the context clearly indicates otherwise.

In some embodiments, terms such as “below,” “under,” “on,” and “above” may be utilized to describe the relationship between components illustrated in the drawings. The terms are utilized as a relative concept and are described with reference to the direction indicated in the drawings.

It should be understood that the terms “comprise,” include,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

In the present disclosure, when a layer, a film, a region, or a plate is referred to as being “above” or “in an upper portion” another layer, film, region, or plate, it can be not only directly on the layer, film, region, or plate, but intervening layers, films, regions, or plates may also be present. In contrast, when a part such as a layer, a film, a region, or a plate is referred to as being “under” or “below” another part, it can be directly under the other part, or an intervening part may also be present. In some embodiments, it will be understood that when a part is referred to as being “on” another part, it can be disposed above the other part, or disposed under the other part as well.

Unless otherwise defined, all terms (including technical and scientific terms) utilized herein have the same meaning as commonly understood by one of ordinary skill in the art to which the present disclosure belongs. In some embodiments, it will be understood that terms, such as those defined in commonly utilized dictionaries, should be interpreted as having a meaning that is consistent with their meaning in the context of the relevant art and will not be interpreted in an idealized or overly formal sense unless expressly so defined herein.

In the disclosure, the term “substituted or unsubstituted” may refer to substituted or unsubstituted with at least one substituent selected from the group including (e.g., consisting of) a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the disclosure, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may be monocyclic or polycyclic. In some embodiments, the rings formed by being bonded to each other may be connected to another ring to form a spiro structure.

In the disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the disclosure, examples of the halogen atom may include a fluorine atom, a chlorine atom, a bromine atom, or an iodine atom.

In the disclosure, the alkyl group may be a linear, branched, or cyclic type or kind. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

The hydrocarbon ring group herein refers to any suitable functional group or substituent derived from an aliphatic hydrocarbon ring. The hydrocarbon ring group may be a saturated hydrocarbon ring group having 5 to 20 ring-forming carbon atoms.

In the disclosure, an aryl group refers to any suitable functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the disclosure, the fluorenyl group may be substituted, and two substituents may be bonded to each other to form a spiro structure. Examples of embodiments in which the fluorenyl group is substituted are as follows. However, the embodiment of the present disclosure is not limited thereto.

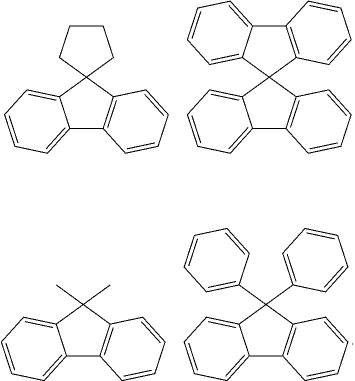

The heterocyclic group herein refers to any suitable functional group or substituent derived from a ring including at least one of B, O, N, P, Si, or S as a heteroatom. The heterocyclic group includes an aliphatic heterocyclic group and/or an aromatic heterocyclic group. The aromatic heterocyclic group may be a heteroaryl group. The aliphatic heterocycle and the aromatic heterocycle may be monocyclic or polycyclic.

In the disclosure, the heterocyclic group may include at least one of B, O, N, P, Si, or S as a heteroatom. When the heterocyclic group includes two or more heteroatoms, the two or more heteroatoms may be the same or different. The heterocyclic group may be a monocyclic heterocyclic group or a polycyclic heterocyclic group and may include a heteroaryl group. The number of ring-forming carbon atoms in the heterocyclic group may be 2 to 30, 2 to 20, or 2 to 10.

In the disclosure, the heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the disclosure, the above description of the aryl group may be applied to an arylene group except that the arylene group is a divalent group. The above description of the heteroaryl group may be applied to a heteroarylene group except that the heteroarylene group is a divalent group.

In the disclosure, the silyl group includes an alkylsilyl group and/or an arylsilyl group. Examples of the silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, an embodiment of the present disclosure is not limited thereto.

In the disclosure, a thio group may include an alkylthio group and/or an arylthio group. The thio group may refer to a sulfur atom that is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but the embodiment of the present disclosure is not limited thereto.

In the disclosure, an oxy group may refer to an oxygen atom that is bonded to the alkyl group or the aryl group as defined above. The oxy group may include an alkoxy group and/or an aryl oxy group. The alkoxy group may be a linear chain, a branched chain, or a ring chain. The number of carbon atoms in the alkoxy group is not limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

The boron group herein may refer to a boron atom that is bonded to the alkyl group or the aryl group as defined above. The boron group includes an alkyl boron group and/or an aryl boron group. Examples of the boron group may include a dimethylboron group, a t-butyldimethylboron group, a diphenylboron group, a phenylboron group, etc., but the embodiment of the present disclosure is not limited thereto.

In the disclosure, the number of carbon atoms in an amine group is not limited, but may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, etc., but the embodiment of the present disclosure is not limited thereto.

In the disclosure, a direct linkage may refer to a single bond. In the disclosure, “—*” refers to a position to be linked.

Hereinafter, embodiments will be described in more detail with reference to the accompanying drawings.

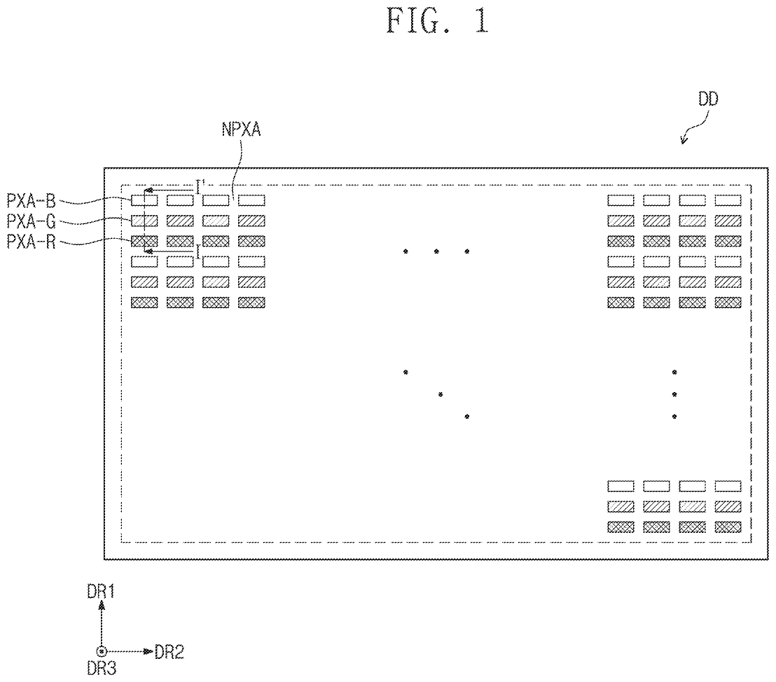

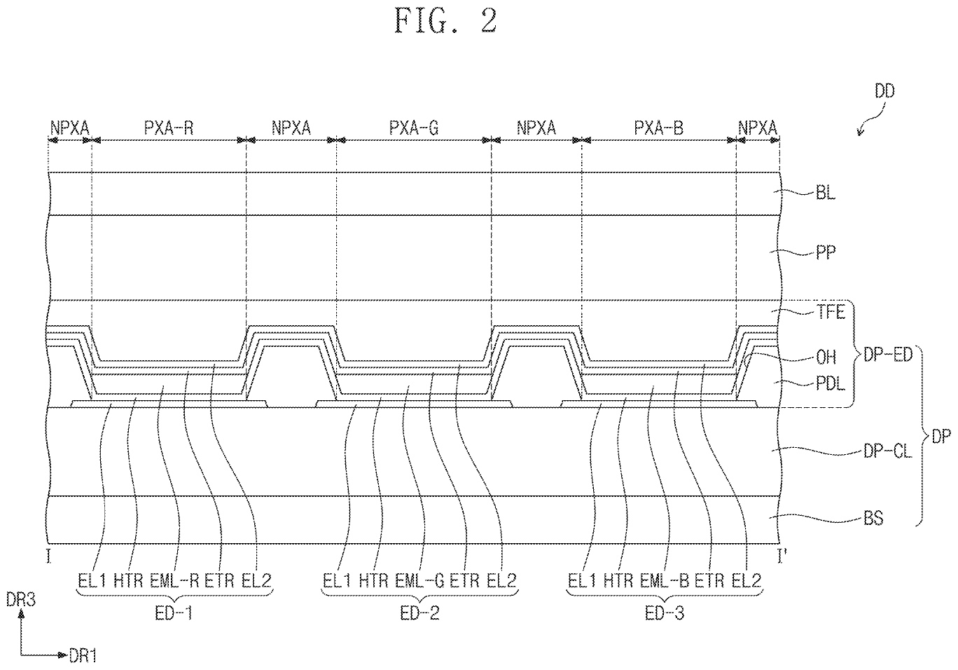

FIG. 1 is a plan view illustrating an embodiment of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP on the display panel DP. The display panel DP may include light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer or a color filter layer. In some embodiments, the optical layer PP may not be provided from the display device DD of an embodiment.

A base substrate BL may be on the optical layer PP. The base substrate BL may be a member which provides a base surface on which the optical layer PP disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

The display device DD according to an embodiment may further include a filling layer. The filling layer may be between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 disposed between portions of the pixel defining film PDL, and an encapsulation layer TFE on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

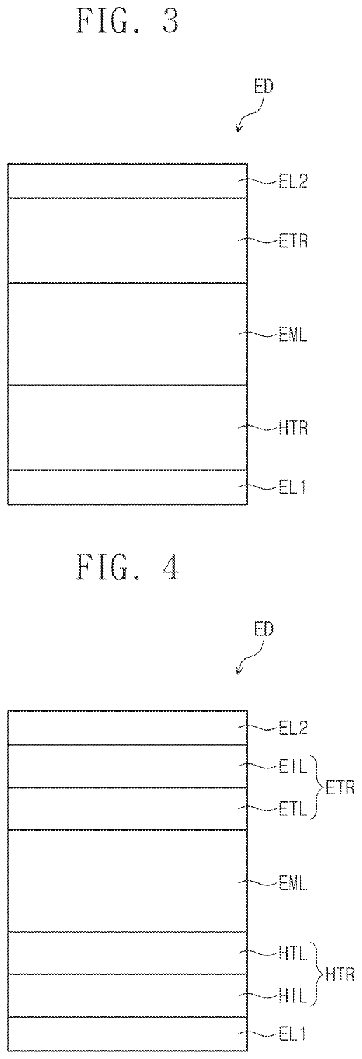

Each of the light emitting elements ED-1, ED-2, and ED-3 may have a structure of a light emitting element ED of an embodiment according to FIGS. 3 to 6, which will be described in more detail. Each of the light emitting elements ED-1, ED-2 and ED-3 may include a first electrode EL1, a hole transport region HTR, emission layers EML-R, EML-G and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-ED from moisture/oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not limited thereto.

The encapsulation layer TFE may be on the second electrode EL2 and may be disposed filling the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2 and ED-3 is emitted. The light emitting regions PXA-R, PXA-G, and PXA-B may be spaced apart from (separated from) each other on a plane (e.g., in a plan view).

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In some embodiments, in the disclosure, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, respectively are illustrated as an example. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2, and ED-3 may emit light beams having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may emit light beams in substantially the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R may be arranged with each other along a second direction axis DR2, the plurality of green light emitting regions PXA-G may be arranged with each other along the second direction axis DR2, and the plurality of blue light emitting regions PXA-B each may be arranged with each other along the second direction axis DR2. In some embodiments, the red light emitting region PXA-R, the green light emitting region PXA-G, and the blue light emitting region PXA-B may be alternately arranged in this order along a first direction axis DR1. (DR3 is a third direction which is normal or perpendicular to the plane defined by the first direction DR1 and the second direction DR2).

FIGS. 1 and 2 illustrate that all the light emitting regions PXA-R, PXA-G, and PXA-B have substantially similar areas, but the embodiment of the present disclosure is not limited thereto. Thus, the light emitting regions PXA-R, PXA-G, and PXA-B may have different areas from each other according to the wavelength range of the emitted light. In this embodiment, the areas of the light emitting regions PXA-R, PXA-G, and PXA-B may refer to areas when viewed on a plane defined by the first direction axis DR1 and the second direction axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a PENTILE© arrangement form (for example, an RGBG matrix, an RGBG structure, or RGBG matrix structure) or a Diamond Pixel™ arrangement form (e.g., a display (e.g., an OLED display) containing red, blue, and green (RGB) light emitting regions arranged in the shape of diamonds. PENTILE® is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIGS. 3 to 6 are cross-sectional views schematically illustrating light emitting elements according to embodiments. Each of the light emitting elements ED according to embodiments may include a first electrode EL1, a hole transport region HTR, an emission layer EML, an electron transport region ETR, and a second electrode EL2 that are sequentially stacked (in the stated order).

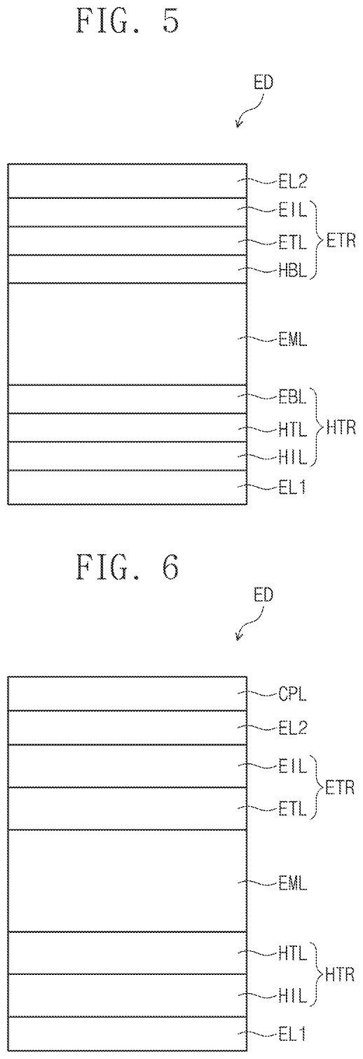

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of an embodiment including a capping layer CPL on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or one or more oxides thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds or mixtures thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. However, the embodiment of the present disclosure is not limited thereto, and the first electrode EL1 may include the above-described one or more of the metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

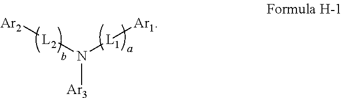

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer from 0 to 10. In some embodiments, when a or b is an integer of 2 or greater, a plurality of L₁s and L₂s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds of Compound Group H. However, the compounds listed in Compound Group H are merely examples, and the compounds represented by Formula H-1 are not limited to those represented by Compound Group H:

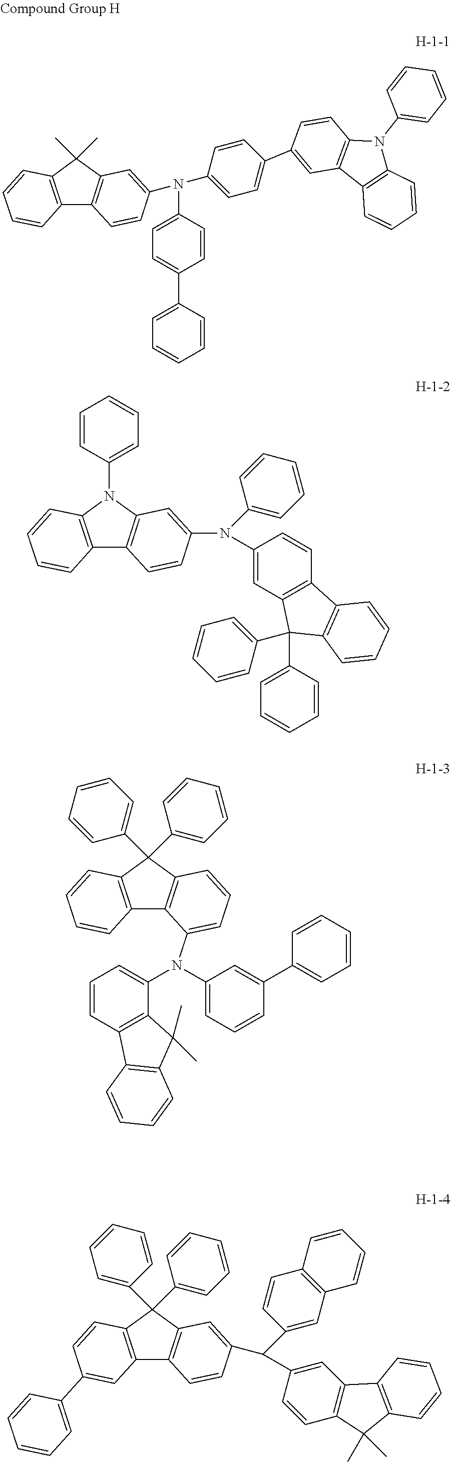

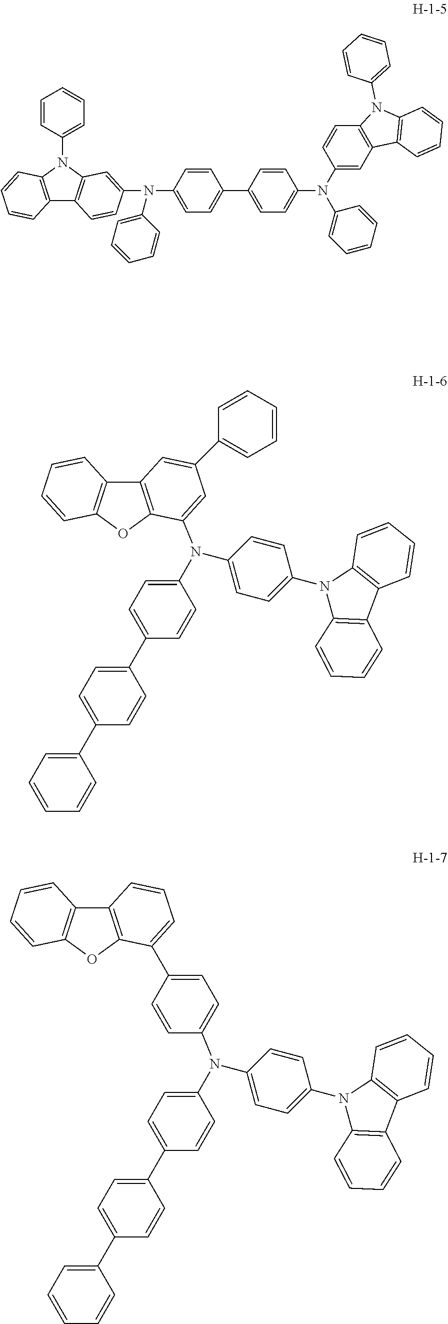 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

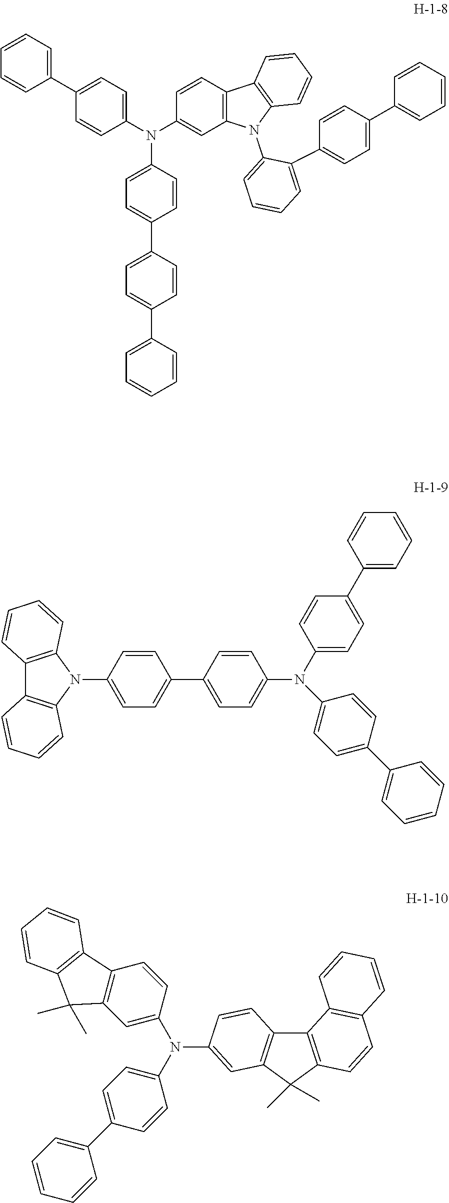 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

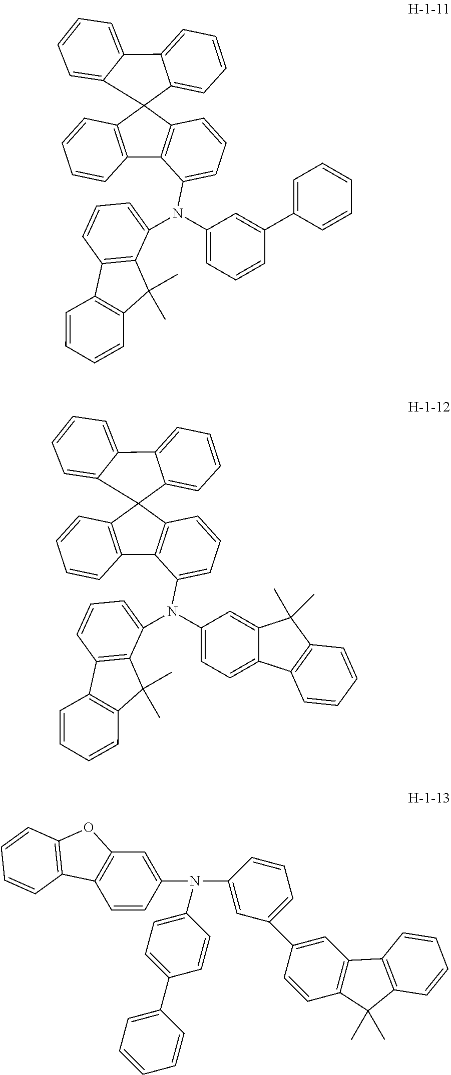 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

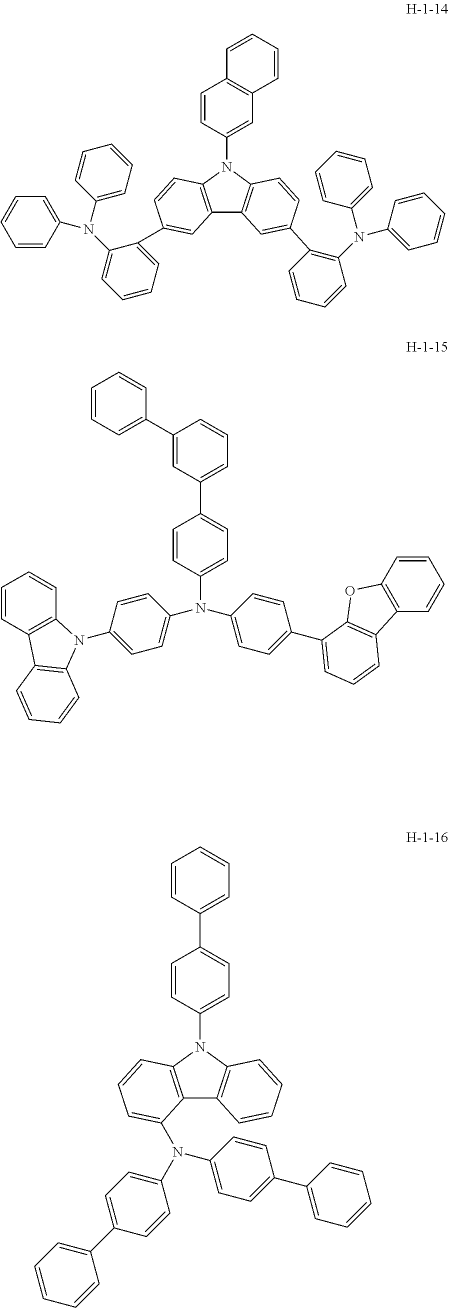 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

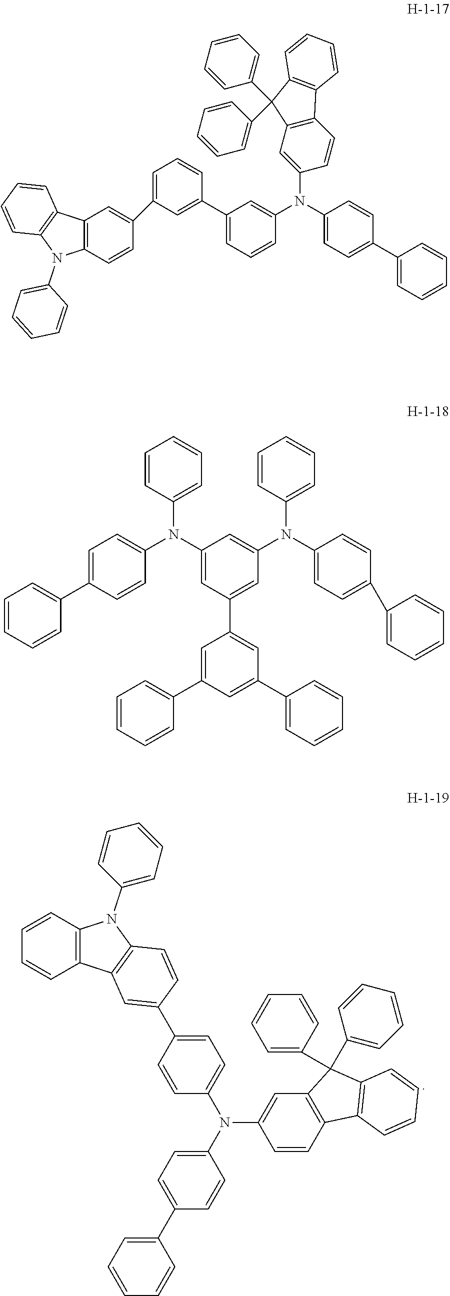 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory (suitable) hole transport properties may be achieved without a substantial increase in driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HAT-CN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may also be utilized as a material to be contained in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML in the light emitting element ED according to an embodiment may include an organometallic compound of an embodiment. In an embodiment, the emission layer EML may include the organometallic compound of an embodiment as a dopant. The organometallic compound of an embodiment may be a dopant material of the emission layer EML.

The organometallic compound of an embodiment may contain a central metal atom, and a ligand bonded to the central metal atom. for example, the organometallic compound may contain a central metal atom, and a first to fourth ligands bonded to the central metal atom. The central metal atom and the first to fourth ligands may be bonded with the coordination bonds. The first to fourth ligands may be a tetradentate ligand linked, via a linking group, to at least one among adjacent ligands. For example, the first to fourth ligands may be one tetradentate ligand optionally linked to each other. For example, the first ligand may be linked to the second ligand via a linking group, and the second ligand may be linked to each of the first ligand and the third ligand via a linking group. In some embodiments, the third ligand may be linked to each of the second ligand and the fourth ligand via a linking group.

The metal atom may be platinum (Pt), palladium (Pd), copper (Cu), argentum (Ag), aurum (Au), rhodium (Rh), iridium (Ir), ruthenium (Ru), osmium (Os), titanium (Ti), zirconium (Zr), hafnium (Hf), europium (Eu), terbium (Tb), or thulium (Tm). For example, the metal atom may be a platinum (Pt) atom.

The first ligand may be a substituted or unsubstituted N-heterocyclic carbene group. For example, the first ligand may be a substituted or unsubstituted benzimidazole group. For example, the first ligand may include a substituted or unsubstituted benzimidazol-2-ylidene group.

The second ligand may be a substituted or unsubstituted aryl group. For example, the second ligand may be a substituted or unsubstituted phenyl group, but the embodiment of the present disclosure is not limited thereto.

The third ligand may be a substituted or unsubstituted fused heterocycle. In an embodiment, the third ligand is a heterocycle in which four 5-membered and/or 6-membered rings are fused, and may include an indole moiety in which a heterocycle containing O or S as a ring-forming atom is fused. For example, the third ligand may include a polycyclic ring in which a 5-membered heterocycle containing O or S as a ring-forming atom is directly linked to a 5-membered pyrrole ring of the indole. For example, a monocyclic or polycyclic hydrocarbon ring or heterocycle may be bonded to the 5-membered heterocycle.

The fourth ligand may be a substituted or unsubstituted heteroaryl group containing at least one N as a ring-forming atom. For example, the fourth ligand may be a substituted or unsubstituted pyridine group. In some embodiments, in the present disclosure, the first ligand may refer to ring A10 in Formula 1 which will be described in more detail, and the second ligand may refer to ring A30. The third ligand may refer to a heterocycle in which a 5-membered heterocycle is directly linked to the 5-membered pyrrole ring of the indole and at least four 5-membered and/or 6-membered rings are fused. The fourth ligand may refer to ring A20.

The light emitting element ED according to the present disclosure is capable of emitting green light having excellent or suitable color purity by applying the organometallic compound of an embodiment, in which the first to fourth ligands are linked to the central metal atom, as a dopant material for the emission layer EML.

The organometallic compound of an embodiment may be represented by Formula 1. The light emitting element ED of an embodiment may include the organometallic compound represented by Formula 1:

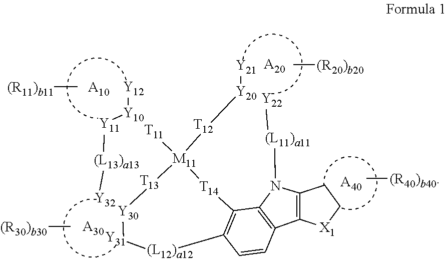

In Formula 1, M₁₁ may be a metal atom bonded to a tetradentate ligand. In an embodiment, M₁₁ may be Pt, Pd, Cu, Ag, Au, Rh, Ir, Ru, Os, Ti, Zr, Hf, Eu, Tb, or Tm. For example, M may be Pt. In Formula 1, X₁ may be O or S.

In Formula 1, Y₁₀, Y₁₁, Y₁₂, Y₂₀, Y₂₁, Y₂₂, Y₃₀, Y₃₁, and Y₃₂ may each independently be N, C, NRₐ, or CR_{b}. In an embodiment, at least one of Y₁₀, Y₁₁, Y₁₂, Y₂₀, Y₂₁, Y₂₂, Y₃₀, Y₃₁, or Y₃₂ is NRₐ, and the rest (i.e., the substituents that are not NRₐ) may be N, C, or CR_{b}. For example, Y₁₂ may be NRₐ, and the rest may be N, C, or CR_{b}. However, the embodiment of the present disclosure is not limited thereto.

In Formula 1, T₁₁ to T₁₄ may each independently be a direct linkage, *—O—*′ or *—S—*′. For example, T₁₁ to T₁₄ may all be a direct linkage. However, the embodiment of the present disclosure is not limited thereto.

In Formula 1, L₁₁ to L₁₃ may each independently be a direct linkage, *—O—*′, *—S—*′, *—C(R₁)(R₂)—*′, *—C(R₁)═*′, *═C(R₁)—*′, *—C(R₁)═C(R₂)—*′, *—C(═O)—*′, *—C(═S)—*′, *—C≡C—*′, *—B(R₁)—*′, *—N(R₁)—*′, *—P(R₁)—*′, *—Si(R₁)(R₂)—*′, or *—Ge(R₁)(R₂)—*′. In an embodiment, at least one selected from among L₁₁ to L₁₃ may be *—O—*′, and the rest may be a direct linkage. For example, L₁₁ and L₁₃ may be a direct linkage, and L₁₂ may be *—O—*′.

In Formula 1, a11 to a13 may each independently be an integer from 0 to 3. In an embodiment, the embodiment in which a11 to a13 is 0 may be the same as the embodiment in which L₁₁ to L₁₃ are a direct linkage. The embodiment in which a11 to a13 are 2 or 3 may refer to linking units L₁₁s to L₁₃s that are provided in plurality, and linking units L₁₁ to L₁₃ allow the adjacent first to fourth ligands to be linked. When a11 to a13 are 2 or 3, each of the plurality of linking units L₁₁s to L₁₃s may be the same as or different from each other.

In Formula 1, rings A₁₀, A₂₀, A₃₀, and A₄₀ may each independently be a substituted or unsubstituted hydrocarbon ring having 5 to 60 ring-forming carbon atoms, or a substituted or unsubstituted heterocycle having 2 to 60 ring-forming carbon atoms. In an embodiment, rings A₁₀, A₂₀, A₃₀, and A₄₀ may each independently be a substituted or unsubstituted aromatic hydrocarbon ring having 5 to 60 ring-forming carbon atoms, or a substituted or unsubstituted aromatic heterocycle having 2 to 60 ring-forming carbon atoms. For example, ring A₁₀ may be a substituted or unsubstituted benzimidazole group, ring A₂₀ may be a substituted or unsubstituted pyridine group, ring A₃₀ may be a substituted or unsubstituted aryl group having 6 to 15 ring-forming carbon atoms, and ring A₄₀ may be a substituted or unsubstituted phenyl group.

In Formula 1, Rₐ, R_{b}, R₁, R₂, R₁₀, R₂₀, R₃₀, and R₄₀ may each independently be a hydrogen atom, a deuterium atom, a halogen atom (—F, —Cl, —Br, and —I), a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂), and/or may be bonded to an adjacent group to form a ring.

In an embodiment, Rₐ and R_{b} may each independently be a hydrogen atom, a deuterium atom, or a substituted or unsubstituted aryl group having 6 to 60 ring-forming carbon atoms. R₁, R₂, R₁₀, R₂₀, R₃₀, and R₄₀ may each independently be a hydrogen atom, a deuterium atom, a substituted or unsubstituted alkyl group having 1 to 60 carbon atoms, a substituted or unsubstituted aryl group having 6 to 60 ring-forming carbon atoms, —Si(Q₁)(Q₂)(Q₃), or —N(Q₁)(Q₂), and/or may be bonded to an adjacent group to form a substituted or unsubstituted hydrocarbon ring having 5 to 60 ring-forming carbon atoms, or a substituted or unsubstituted heterocycle having 2 to 60 ring-forming carbon atoms. For example, R₁, R₂, R₁₀, R₂₀, R₃₀, and R₄₀ may each independently be a hydrogen atom, a deuterium atom, a substituted or unsubstituted alkyl group having 1 to 10 carbon atoms, or a substituted or unsubstituted aryl group having 6 to 30 ring-forming carbon atoms. For example, R₁, R₂, R₁₀, R₂₀, R₃₀, and R₄₀ may each independently be a hydrogen atom, a deuterium atom, a substituted or unsubstituted methyl group, a substituted or unsubstituted i-propyl group, a substituted or unsubstituted t-butyl group, a substituted or unsubstituted phenyl group, a substituted or unsubstituted terphenyl group, a substituted or unsubstituted quaterphenyl group, or a substituted or unsubstituted quinquephenyl group. However, the embodiment of the present disclosure is not limited thereto.

In Formula 1, b10, b20, b30, and b40 may each independently be an integer from 0 to 8. When each of b10, b20, b30, and b40 is 2 or more, a plurality of R₁₀s, R₂₀s, R₃₀s, and R₄₀s may each be the same or at least one may be different from the others.

In Formula 1, Q₁ to Q₃ may each independently be a hydrogen atom, a deuterium atom, a halogen atom, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms. In an embodiment, Q₁ to Q₃ may each independently be a hydrogen atom, a deuterium atom, an alkyl group having 1 to 30 carbon atoms, or a substituted or unsubstituted aryl group having 6 to 30 ring-forming carbon atoms. For example, Q₁ to Q₃ may each independently be a hydrogen atom, a deuterium atom, a substituted or unsubstituted methyl group, or a substituted or unsubstituted phenyl group. In some embodiments, in Formula 1, * and *′ refer to a linkage position.

In an embodiment, the organometallic compound represented by Formula 1 may be represented by Formula 2. The organometallic compound represented by Formula 2 corresponds to the embodiment in which T₁₁ to T₁₄ in Formula 1 are all direct linkages. In Formula 2, the same as described in Formula 1 may be applied to M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, L₁₁ to L₁₃, a11 to a13, R₁₀, R₂₀, R₃₀, R₄₀, b10, b20, b30, and b40.

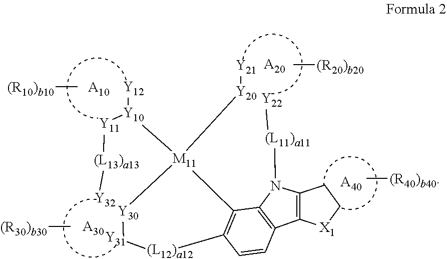

The organometallic compound represented by Formula 1 of an embodiment may be represented by Formula 3. The organometallic compound represented by Formula 3 corresponds to the embodiment in which in Formula 1, T₁₁ to T₁₄, L₁₁, and L₁₃ are direct linkages, and L₁₂ is *—O—*′. In Formula 3, the same as described in Formula 1 may be applied to M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, R₁₀, R₂₀, R₃₀, R₄₀, b10, b20, b30, and b40.

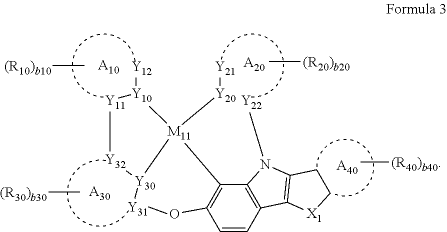

In an embodiment, the central metal atom of the organometallic compound represented by Formula 3 may be platinum (Pt). In this embodiment, Formula 3 may be represented by Formula 3-A. In Formula 3-A, the same as described in Formula 3 may be applied to X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, R₁₀, R₂₀, R₃₀, R₄₀, b10, b20, b30, and b40.

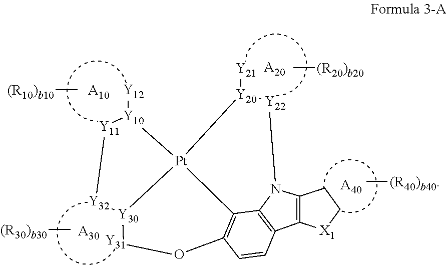

In an embodiment, the organometallic compound represented by Formula 3 may be represented by any one selected from among Formula 3-1 to Formula 3-3. Each of Formula 3-1 to Formula 3-3 corresponds to the embodiment in which ring A₄₀ is specified in Formula 3. In Formula 3-1 to Formula 3-3, M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, R₁₀, R₂₀, R₃₀, b10, b20, and b30 may each independently be the same as defined in Formula 1.

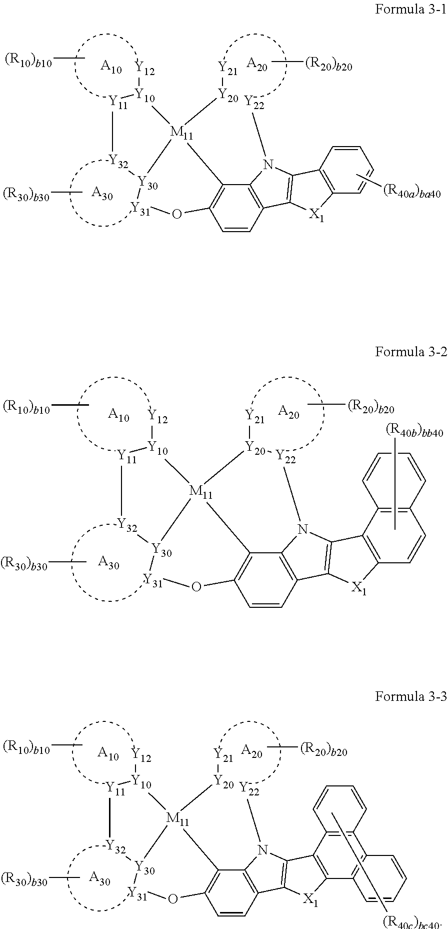

In Formula 3-1 to Formula 3-3, R₄₀ₐ to R_{40c} may each independently be a hydrogen atom or a deuterium atom. ba40 may be an integer from 0 to 4, bb40 may be an integer from 0 to 6, and bc40 may be an integer from 0 to 8. Here, the embodiment in which ba40 is 0 may be the same as the embodiment in which ba40 is 1 and R₄₀ₐ is a hydrogen atom. Such a description may also be equally applied to the embodiment in which bb40 and bc40 are 0. In some embodiments, when each of bb40, bb40 Å, and bc40 is an integer of 2 or more, a plurality of R₄₀ₐs to R_{40c}s may each be the same or different.

In an embodiment, the organometallic compound represented by Formula 1 may be represented by Formula 4. Formula 4 corresponds to the embodiment in which in Formula 1, T₁₁ to T₁₄, L₁₁, L₁₂, L₁₃, and ring A₁₀ are specified. In Formula 4, the same as described in Formula 1 may be applied to M₁₁, X₁, Y₂₀, Y₂₁, Y₂₂, Y₃₀, Y₃₁, Y₃₂, A₂₀, A₃₀, A₄₀, R₂₀, R₃₀, R₄₀, b20, b30, and b40.

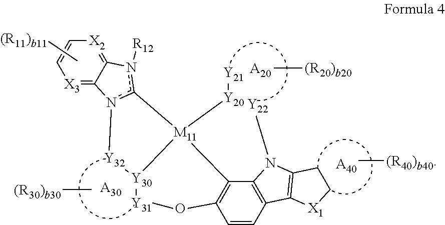

In Formula 4, X₂ and X₃ may each independently be CRₓ or N. Rₓ and R₁₁ may each independently be a hydrogen atom, a deuterium atom, a substituted or unsubstituted alkyl group having 1 to 60 carbon atoms, or a substituted or unsubstituted aryl group having 6 to 60 ring-forming carbon atoms. In an embodiment, Rₓ and R₁₁ may each independently be a hydrogen atom, a deuterium atom, a substituted or unsubstituted alkyl group having 1 to 10 carbon atoms, or a substituted or unsubstituted aryl group having 6 to 10 ring-forming carbon atoms. For example, Rₓ and R₁₁ may each independently be a hydrogen atom, a deuterium atom, a substituted or unsubstituted t-butyl group, or a substituted or unsubstituted phenyl group.

In Formula 4, b11 may be an integer from 0 to 2. In Formula 4, when b11 is 0, the organometallic compound of an embodiment may not be substituted with R₁₁. In Formula 4, the embodiment in which b11 is 2 and R₁₁s are all hydrogen atoms may be the same as the embodiment in which b11 is 0 in Formula 4. When b11 is 2, two of R₁₁s may be the same or different.

In Formula 4, R₁₂ may correspond to Rₐ in Formula 1. R₁₂ may be a substituted or unsubstituted aryl group having 6 to 60 ring-forming carbon atoms, or a substituted or unsubstituted heteroaryl group having 2 to 60 ring-forming carbon atoms. For example, R₁₂ may be a substituted or unsubstituted phenyl group, a substituted or unsubstituted terphenyl group, a substituted or unsubstituted quaterphenyl group, a substituted or unsubstituted pentaphenyl group, a substituted a unsubstituted pyridine group, or a substituted or unsubstituted 1,3-di(pyridin-4-yl)benzene group.

In an embodiment, R₁₂ may be represented by any one selected from among R12-1 to R12-32.

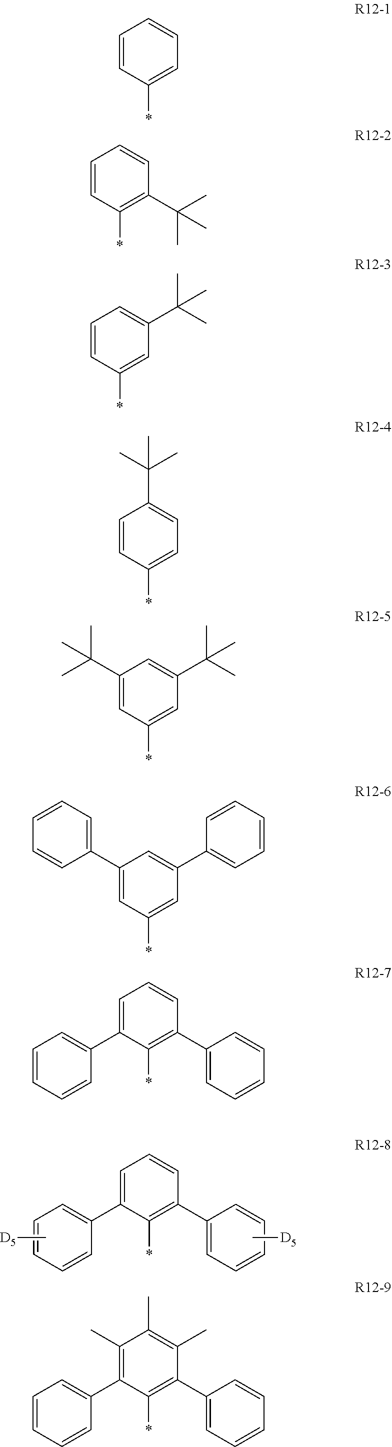

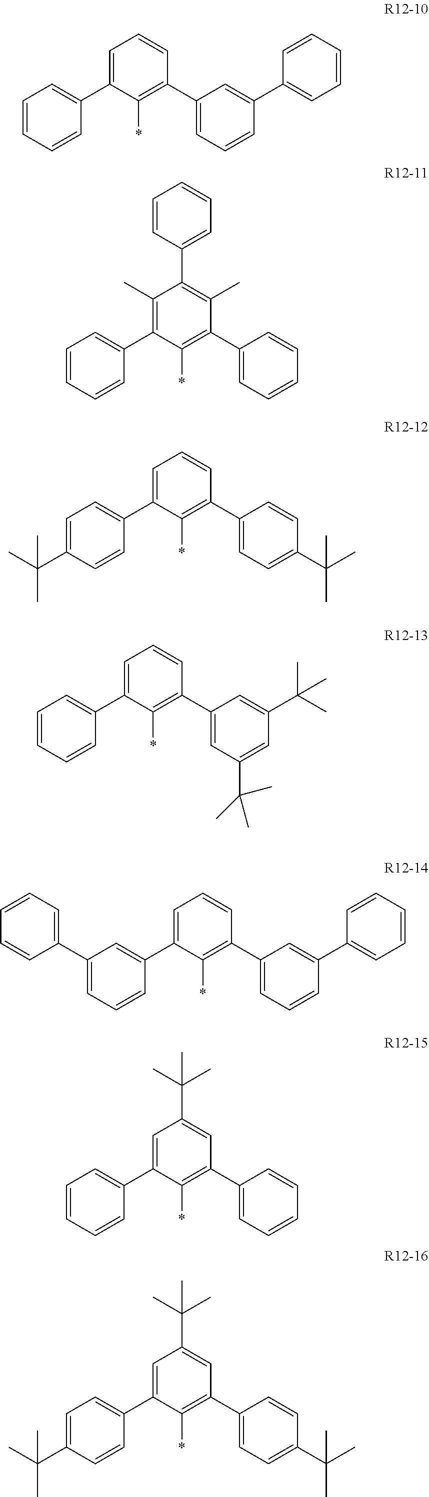

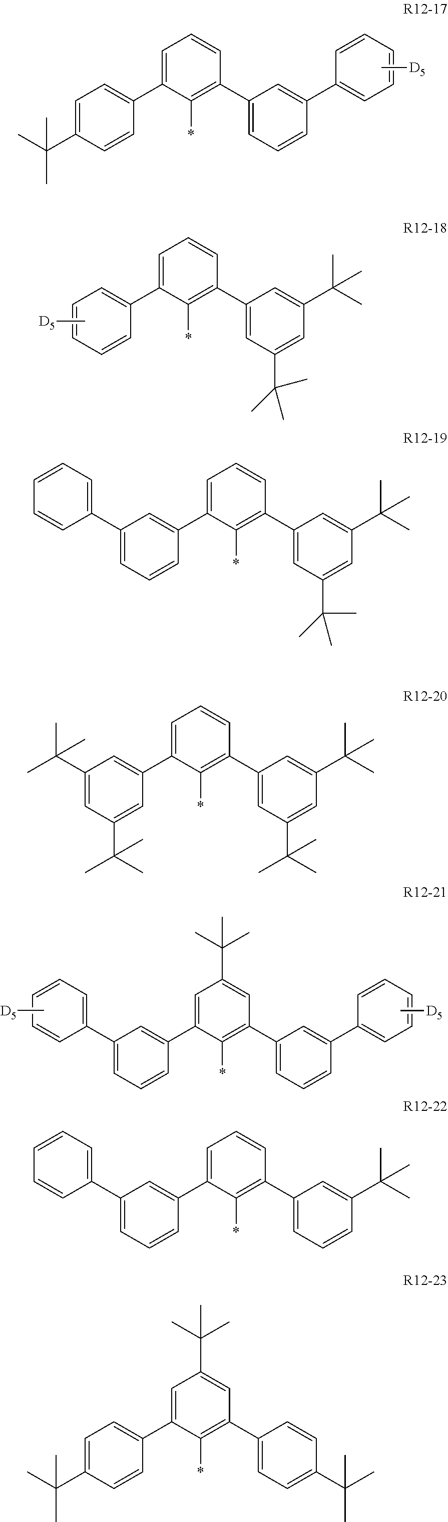

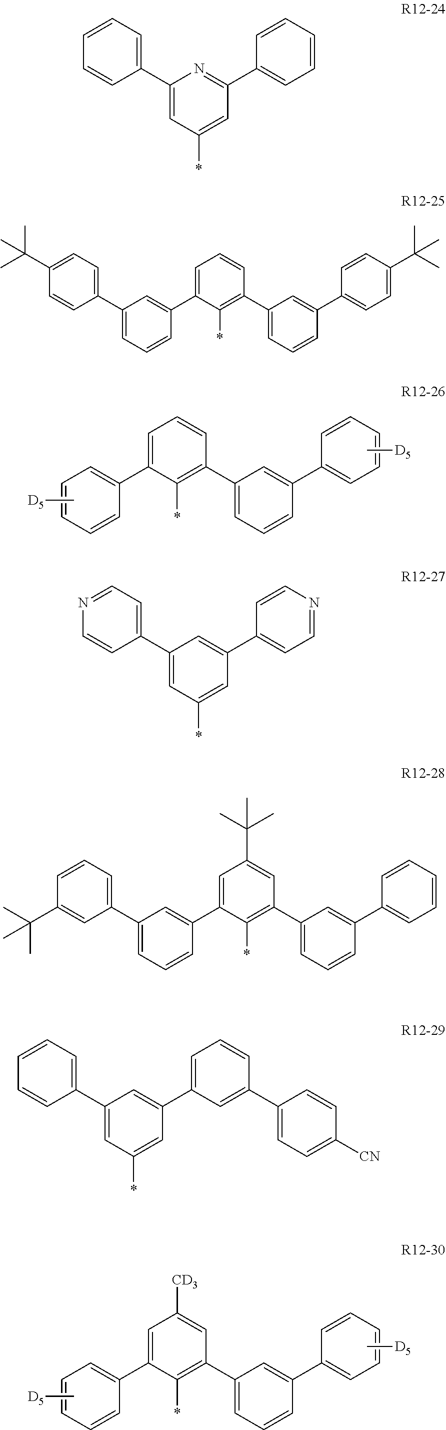

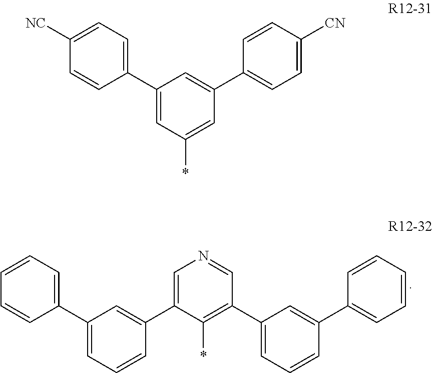 [SMILES: *c1cc(-c2ccc(C#N)cc2)cc(-c2ccc(C#N)cc2)c1 ; *c1c(-c2cccc(-c3ccccc3)c2)cncc1-c1cccc(-c2ccccc2)c1]

In an embodiment, the organometallic compound represented by Formula 4 may be represented by Formula 5. Formula 5 corresponds to the embodiment in which in Formula 4, ring A₂₀, ring A₃₀, R₂₀, R₃₀, and R₄₀ are specified. In some embodiments, Formula 5 may correspond to the embodiment in which in Formula 1, T₁₁ to T₁₄, L₁₁, L₁₂, L₁₃, ring A₁₀, ring A₂₀, ring A₃₀, R₁₀, R₂₀, R₃₀, and R₄₀ are specified.

In Formula 5, the same as described in Formula 1 may be applied to A₄₀, X₁, and M₁₁. In some embodiments, the same as described in Formula 4 may be applied to X₂, X₃, R₁₁, R₁₂, and b11 in Formula 5.

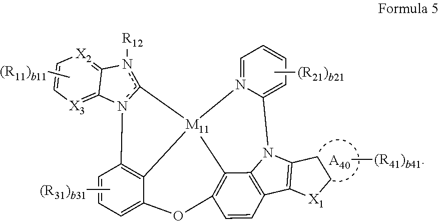

In Formula 5, R₂₁, R₃₁, and R₄₁ may each independently be a hydrogen atom, a deuterium atom, a cyano group, a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), or —N(Q₁)(Q₂). In an embodiment, R₂₁, R₃₁, and R₄₁ may each independently be a hydrogen atom, a deuterium atom, a cyano group, a substituted or unsubstituted alkyl group having 1 to 10 carbon atoms, a substituted or unsubstituted aryl group having 6 to 10 ring-forming carbon atoms, a substituted or unsubstituted heteroaryl group having 2 to 10 ring-forming carbon atoms, —Si(Q₁)(Q₂)(Q₃), or —N(Q₁)(Q₂). For example, R₂₁ may each independently be a hydrogen atom, a deuterium atom, a substituted or unsubstituted methyl group, a substituted or unsubstituted i-propyl group, a substituted or unsubstituted t-butyl group, a substituted or unsubstituted phenyl group, —Si(CH₃)(CH₃)(CH₃), or —N(CH₃)(CH₃). R₃₁ and R₄₁ may each independently be a hydrogen atom, a deuterium atom, a cyano group, a substituted or unsubstituted methyl group, a substituted or unsubstituted i-propyl group, a substituted or unsubstituted t-butyl group, a substituted or unsubstituted pyridine group, a substituted or unsubstituted phenyl group, —Si(Ph)₃, —Si(CH₃)(CH₃)(CH₃), or —N(CH₃)(CH₃). For example, Ph may be a phenyl group. However, the embodiment of the present disclosure is not limited thereto.

In Formula 5, the same as described in Formula 1 may be applied to Q₁ to Q₃. In an embodiment, Q₁ to Q₃ may each independently be a substituted or unsubstituted alkyl group having 1 to 10 carbon atoms, or a substituted or unsubstituted aryl group having 6 to 10 ring-forming carbon atoms. For example, Q₁ to Q₃ may each independently be a substituted or unsubstituted methyl group, or a substituted or unsubstituted phenyl group.

In Formula 5, b21 may be an integer from 0 to 4, b31 may be an integer from 0 to 3, and b41 may be an integer from 0 to 8. In Formula 5, when b21 is 0, the organometallic compound of an embodiment may not be substituted with R₂₁. In Formula 5, the embodiment in which b21 is 4 and R₂₁s are all hydrogen atoms may be the same as the embodiment in which b21 is 0 in Formula 5. Such a description may also be equally applied to the embodiment in which b31 and b41 are 0. In some embodiments, when b21 is an integer of 2 or more, a plurality of R₂₁s may all be the same, or at least one of the plurality of R₂₁s may be different from the others. Such a description may also be equally applied to the embodiment in which b31 and b41 each are an integer of 2 or more.

In an embodiment, the organometallic compound represented by Formula 5 may be represented by any one selected from among Formula 5-1 to Formula 5-3. Each of Formula 5-1 to Formula 5-3 corresponds to the embodiment in which ring A₄₀ is specified in Formula 5.

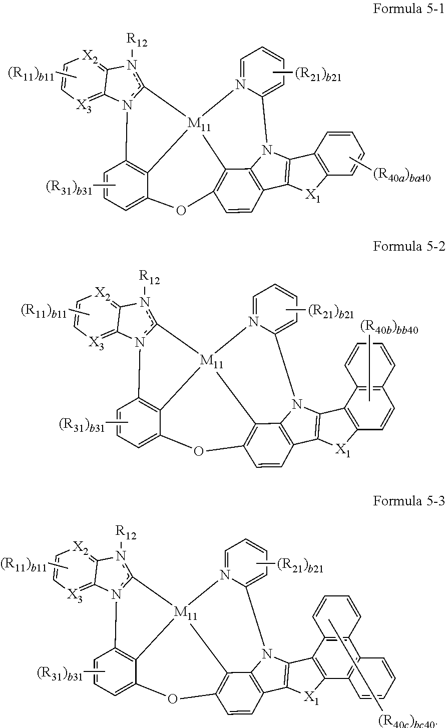

In Formula 5-1 to Formula 5-3, the same as described in Formula 5 may be applied to M₁₁, X₁, X₂, X₃, R₁₁, R₁₂, R₂₁, R₃₁, b11, b21, and b31. In some embodiments, the same as described in Formula 3-1 to Formula 3-3 may be applied to R₄₀ₐ to R_{40c}, ba40, bb40, and bc40.

The organometallic compound represented by Formula 1 of an embodiment may be represented by any one selected from among the compounds represented by Compound Group 1. The light emitting element ED of an embodiment may include at least one organometallic compound selected from among the compounds represented by Compound Group 1 in the emission layer EML.

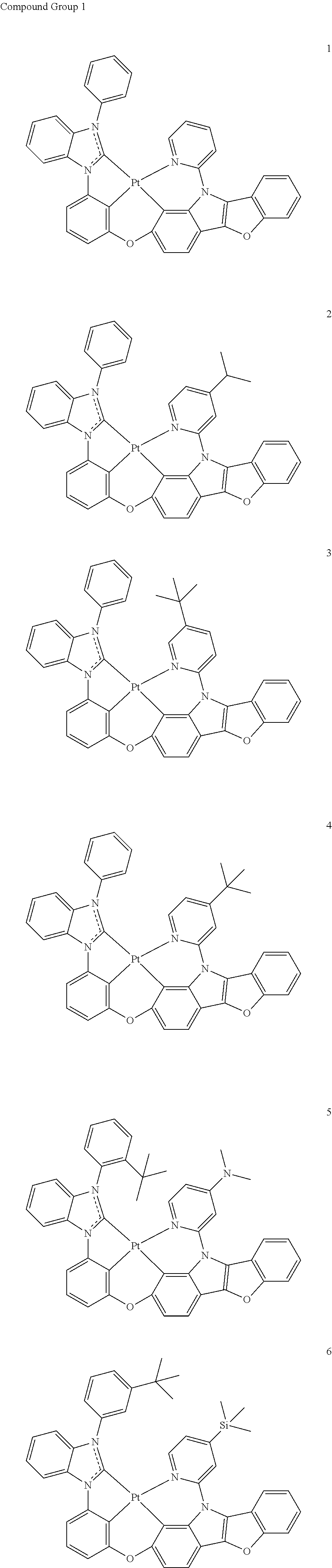

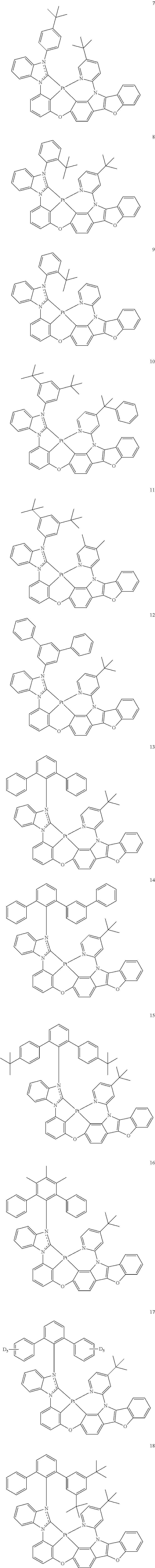

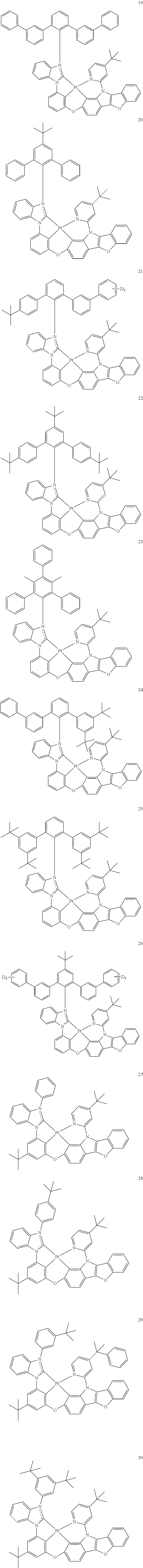

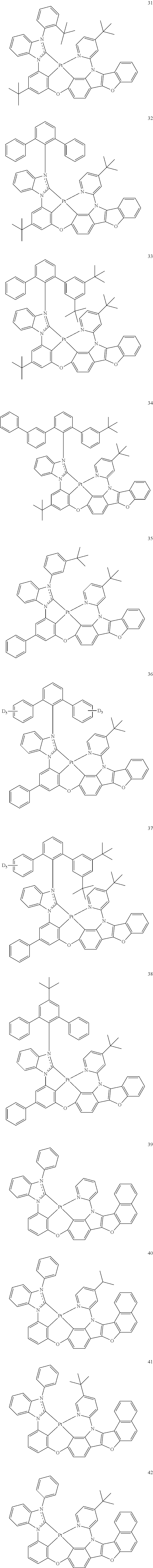

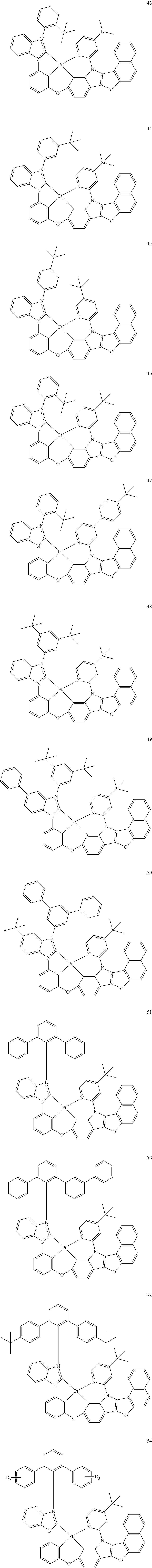

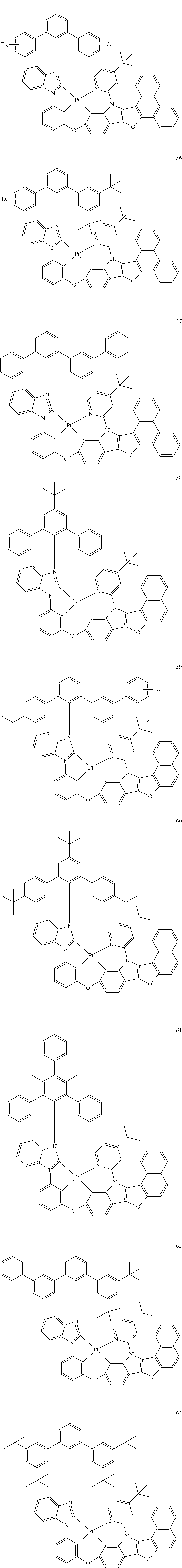

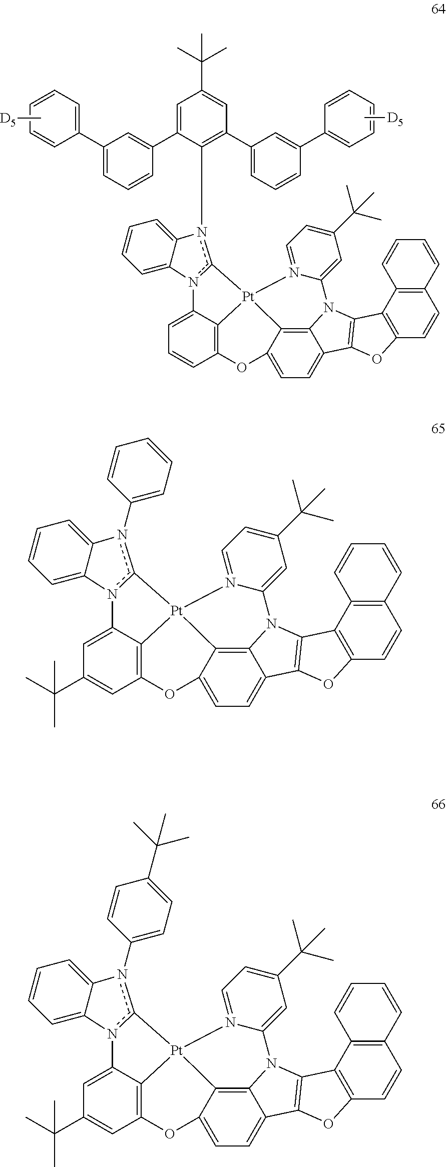

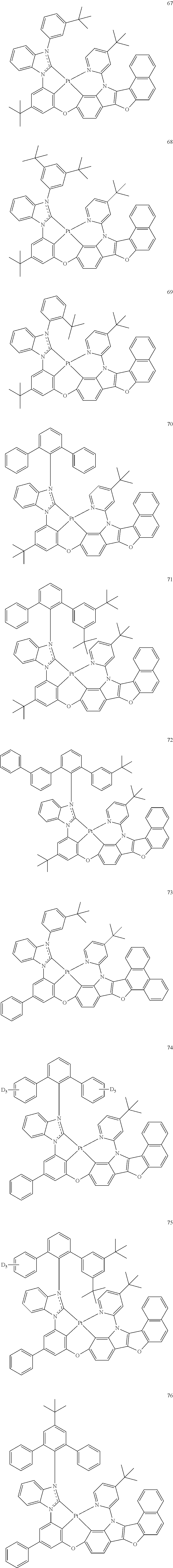

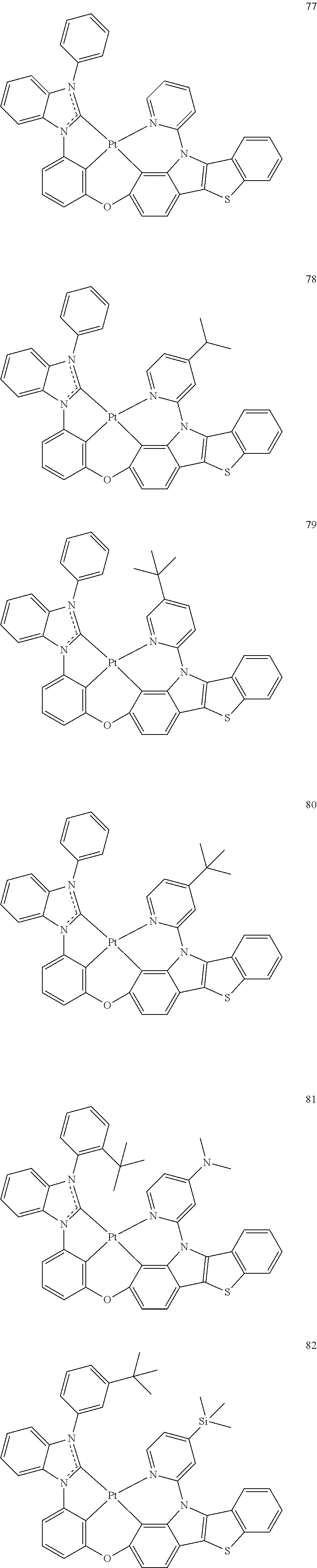

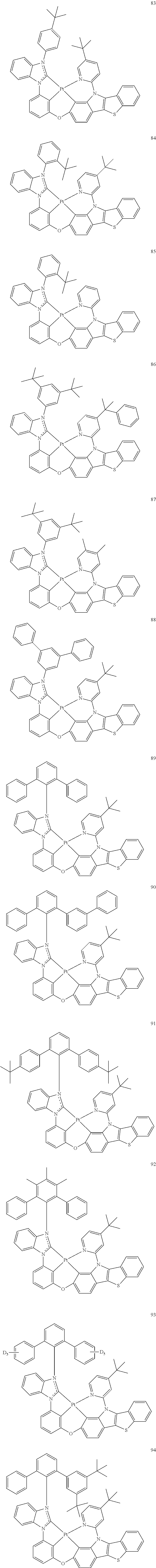

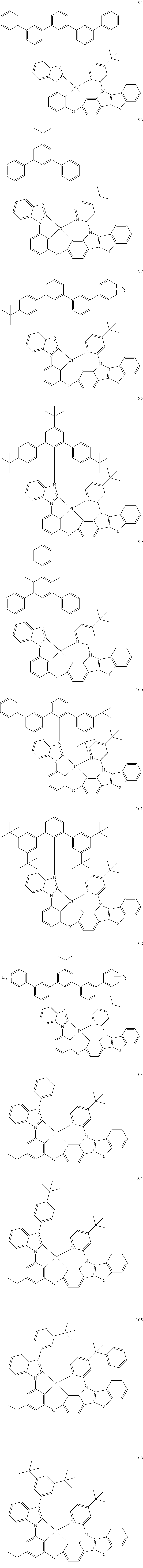

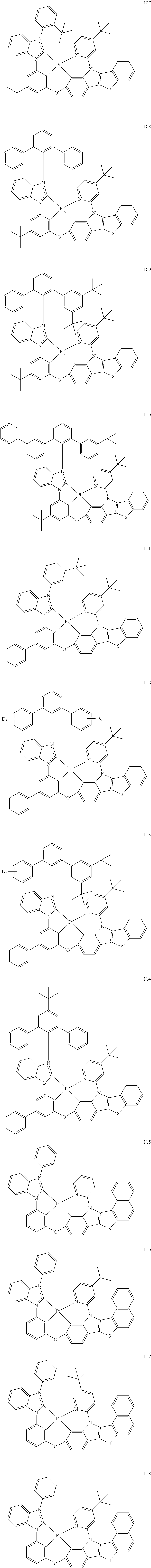

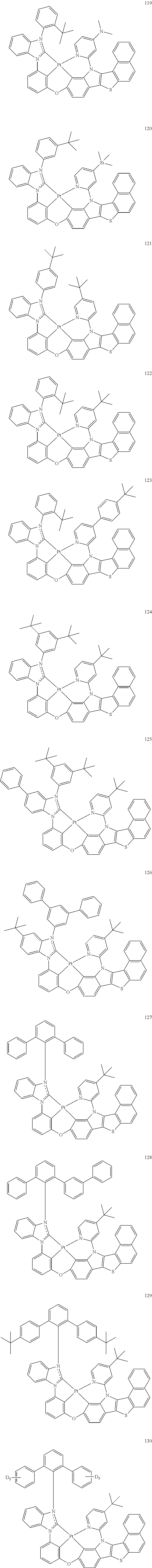

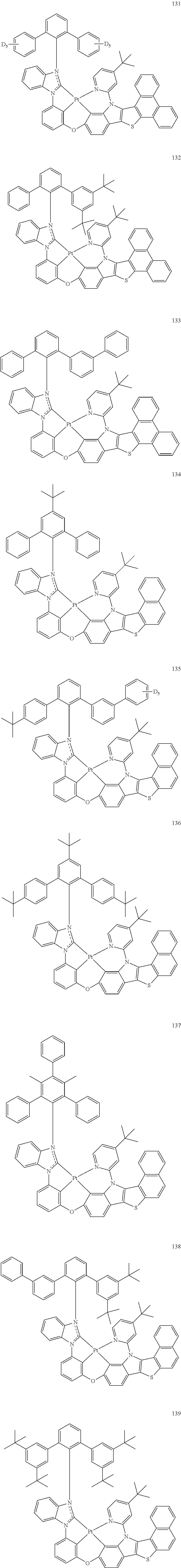

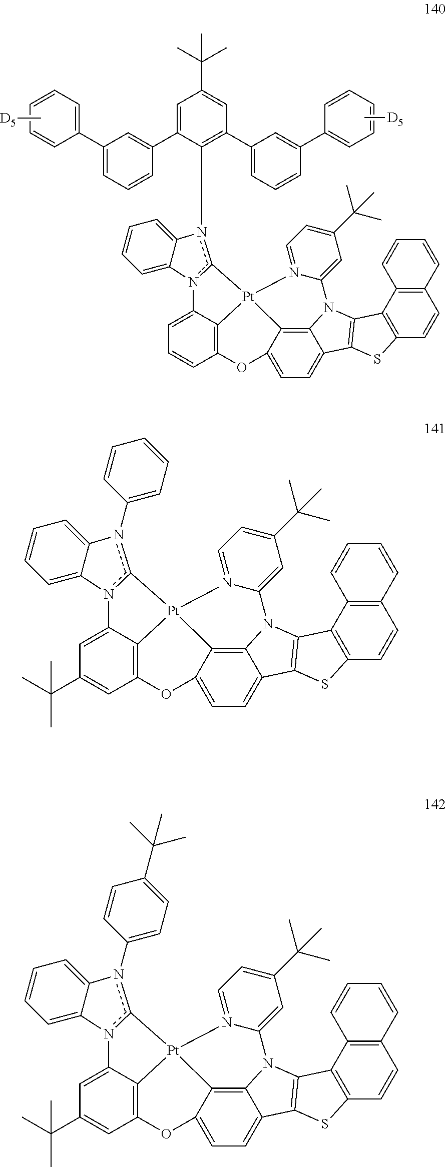

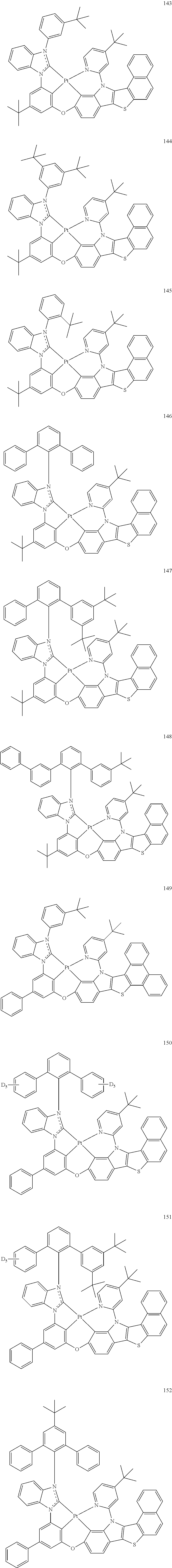

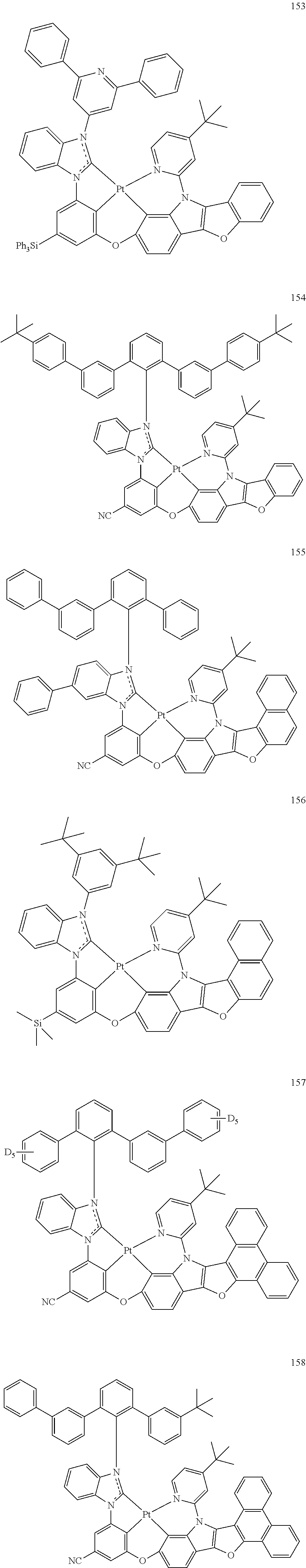

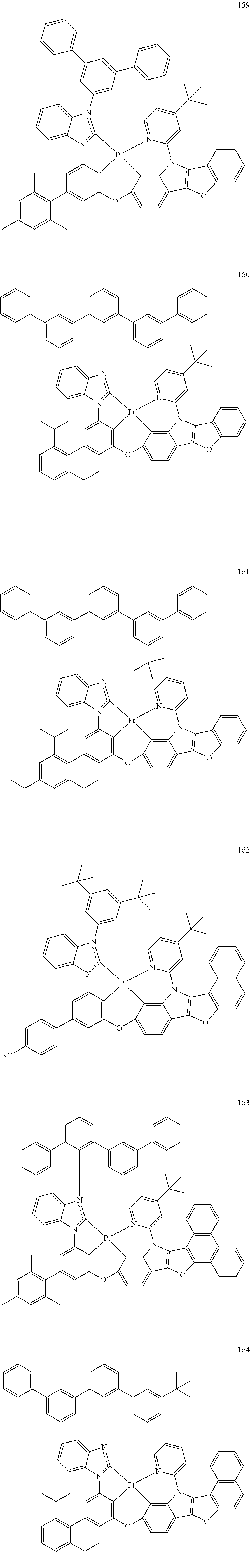

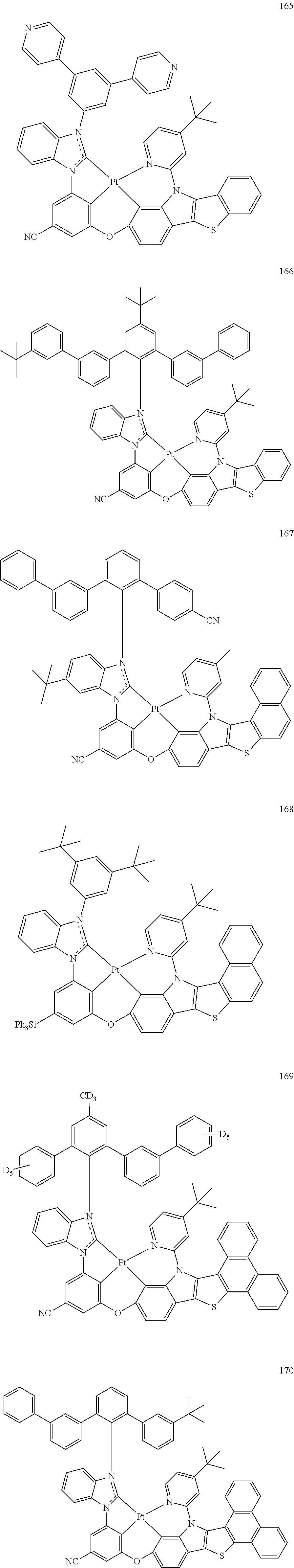

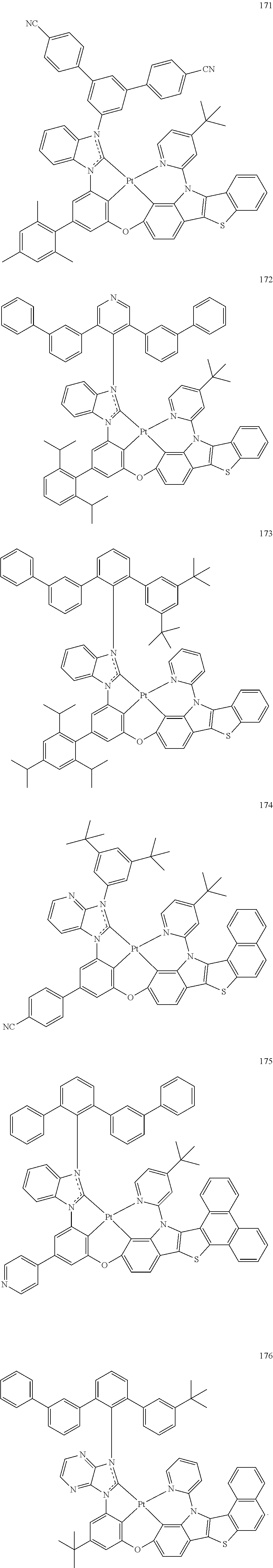

In the embodiment of compounds presented in Compound Group 1, “D” corresponds to a deuterium atom, and “Ph” corresponds to a phenyl group.

The organometallic compound represented by Formula 1 includes tetradentate ligands in which the first to fourth ligands are selectively linked to the central metal atom such as Pt, and thus may exhibit excellent or suitable material stability. Accordingly, the light emitting element ED including the organometallic compound of an embodiment may exhibit a low driving voltage, high brightness, high efficiency, and long service life characteristics.

For example, the organometallic compound of an embodiment includes, as a third ligand, a fused ring in which a 5-membered heterocycle is directly linked to an indole moiety, and thus may provide a green emission color having high color purity.

In an embodiment, the emission layer EML includes a host and a dopant, and may include the above-described organometallic compound of an embodiment as a dopant. The organometallic compound represented by Formula 1 of an embodiment may be a dopant material for the emission layer.

In an embodiment, the emission layer EML may emit phosphorescence. For example, the organometallic compound represented by Formula 1 according to an embodiment may be a phosphorescence dopant.

In another embodiment, the emission layer EML may include a host, a dopant, and a sensitizer, and the emission layer EML may also include the organometallic compound represented by Formula 1 as a sensitizer material. The organometallic compound included in the emission layer EML may serve as a sensitizer to deliver energy from the host to the light emitting dopant. For example, the organometallic compound serving as an auxiliary dopant accelerates energy delivery to the first compound that is a light emitting dopant, thereby increasing the emission ratio of the first compound. Therefore, the emission layer EML of an embodiment may improve luminous efficiency. In some embodiments, when the energy delivery to the light emitting dopant through the sensitizer is increased, an exciton formed in the emission layer EML is not accumulated inside the emission layer EML and emits light rapidly, and thus deterioration of the element may be reduced. Therefore, the service life of the light emitting element ED of an embodiment may increase.

In some embodiments, the emission layer EML may further include a host material in addition to the organometallic compound of an embodiment as described above. The emission layer EML in the light emitting element ED of an embodiment may include general materials, which are generally utilized/generally available in the art, as a host material. In the light emitting element ED of an embodiment, the emission layer EML may include an anthracene derivative, a pyrene derivative, a fluoranthene derivative, a chrysene derivative, a dehydrobenzanthracene derivative, or a triphenylene derivative. For example, the emission layer EML may include the anthracene derivative or the pyrene derivative.

In an embodiment, the emission layer EML may include a compound represented by Formula E-1. The compound represented by Formula E-1 may be utilized as a fluorescent host material.

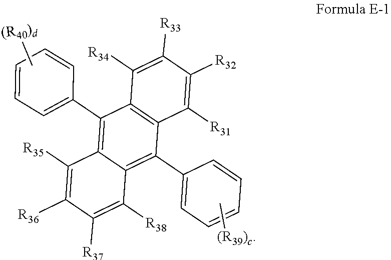

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, d and c may each independently be an integer from 0 to 5. In some embodiments, when d is 2 or more, a plurality of R₄₀s may each independently be the same as or different from each other, and when c is 2 or more, a plurality of R₃₉s may each independently be the same as or different from each other.

Formula E-1 may be represented by any one selected from among Compound E1 to Compound E19:

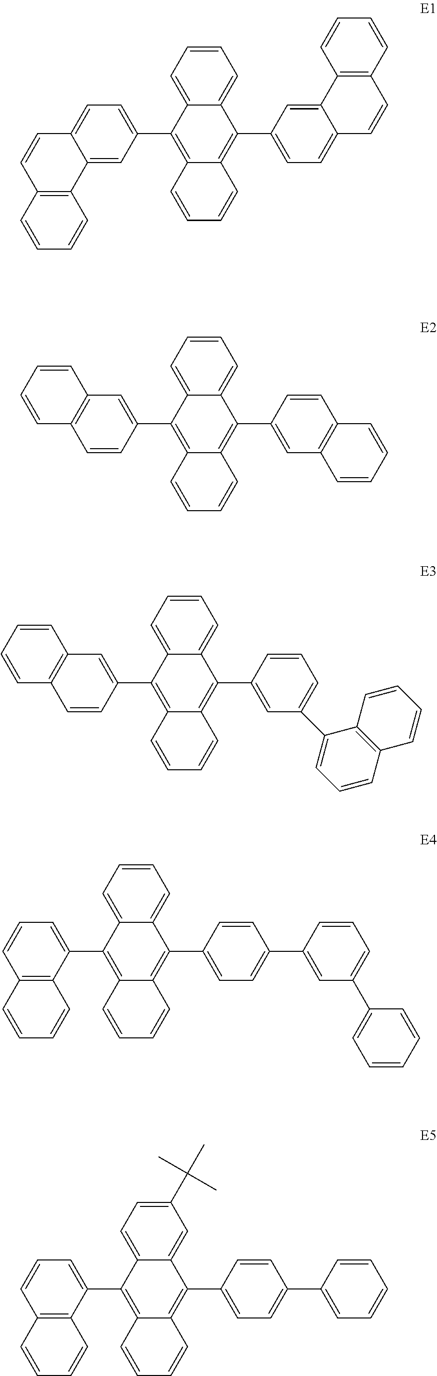

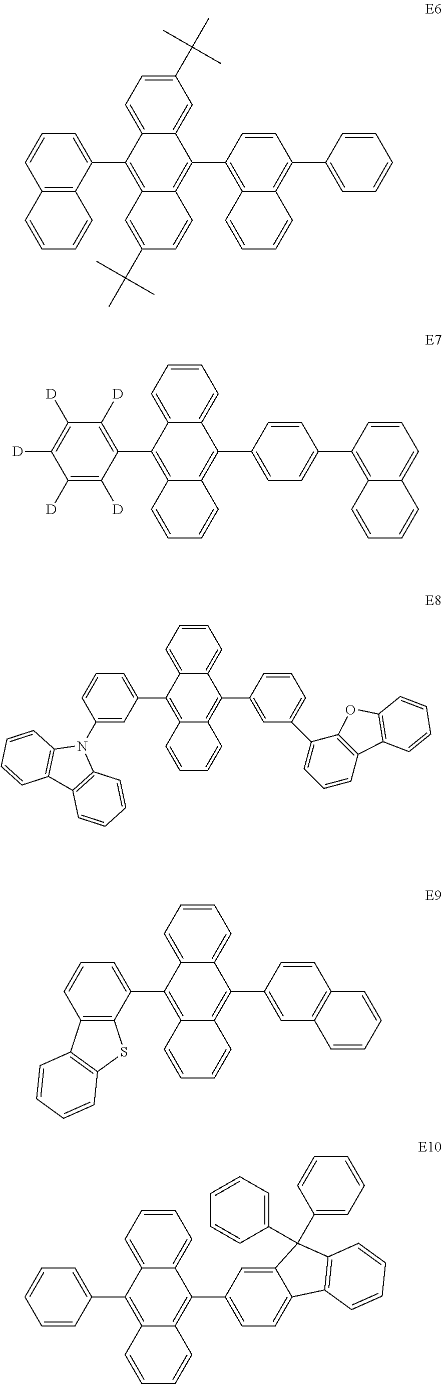

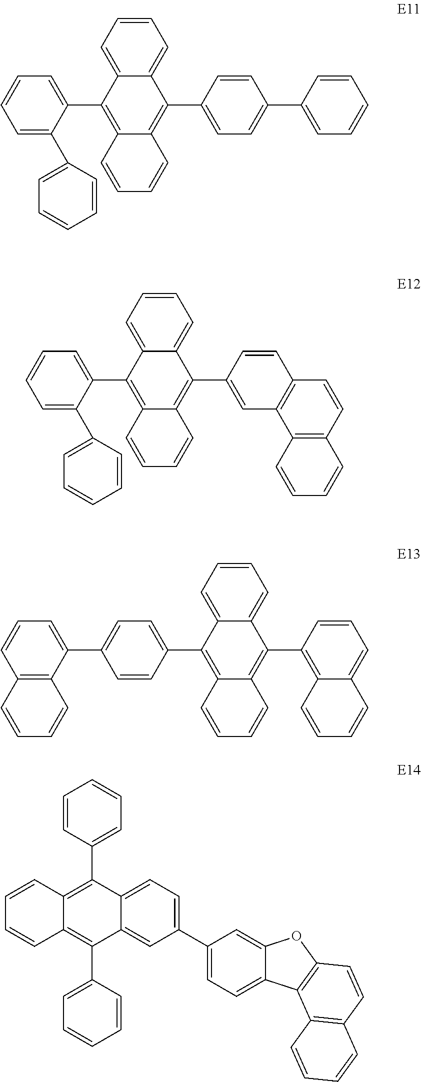

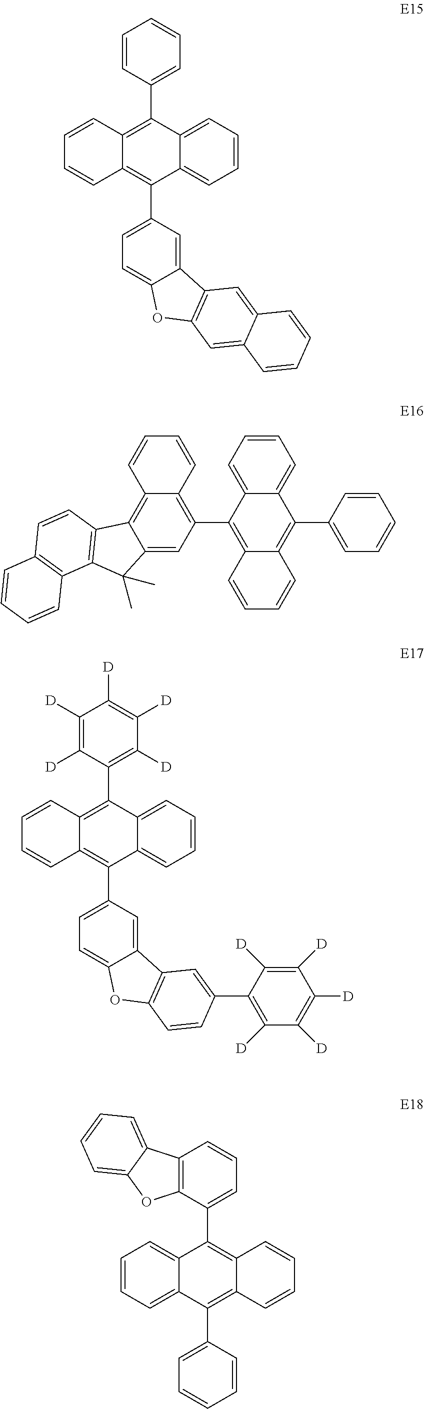

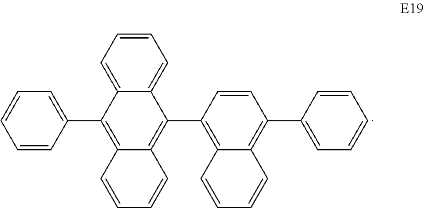 [SMILES: c1ccc(-c2ccc(-c3c4ccccc4c(-c4ccccc4)c4ccccc34)c3ccccc23)cc1]

In an embodiment, the emission layer EML may include a compound represented by Formula E-2a or Formula E-2b. The compound represented by Formula E-2a or Formula E-2b may be utilized as a phosphorescent host material.

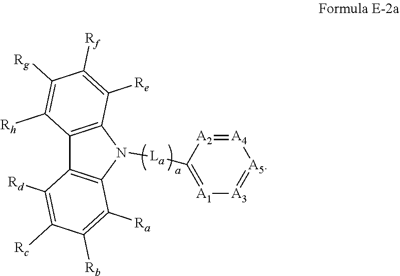

In Formula E-2a, and a may be an integer from 0 to 10, La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of Las may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the rest (i.e., the substituents that are not N) may be CRᵢ.

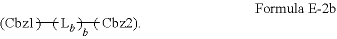

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer from 0 to 10, and when b is an integer of 2 or more, a plurality of L_{b}s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are merely examples, and the compound represented by Formula E-2a or Formula E-2b is not limited to those represented in Compound Group E-2.

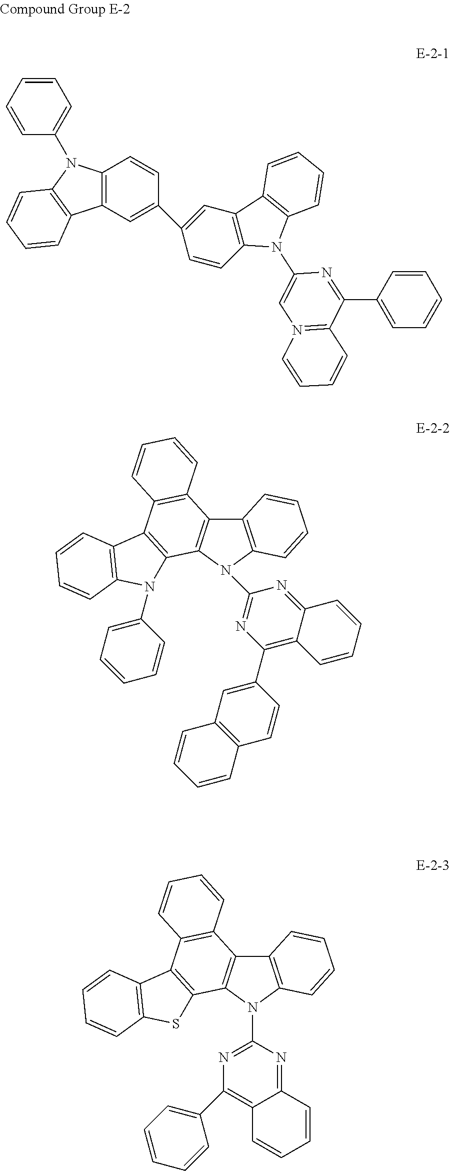

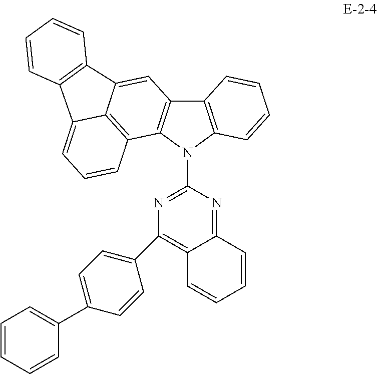 [SMILES: c1ccc(-c2ccc(-c3nc(-n4c5ccccc5c5cc6c7c(cccc7c54)-c4ccccc4-6)nc4ccccc34)cc2)cc1]

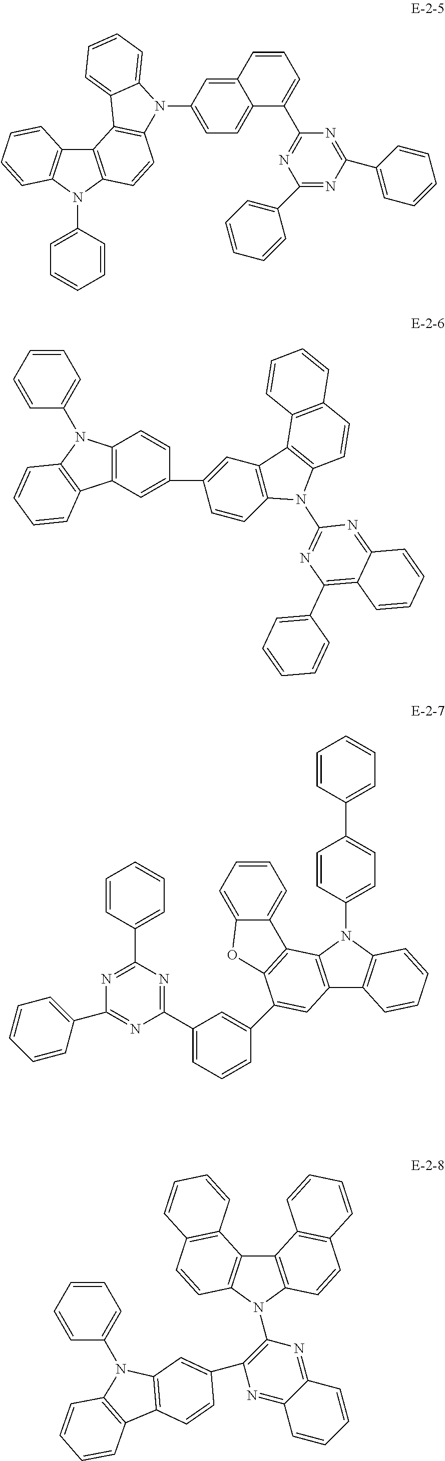 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

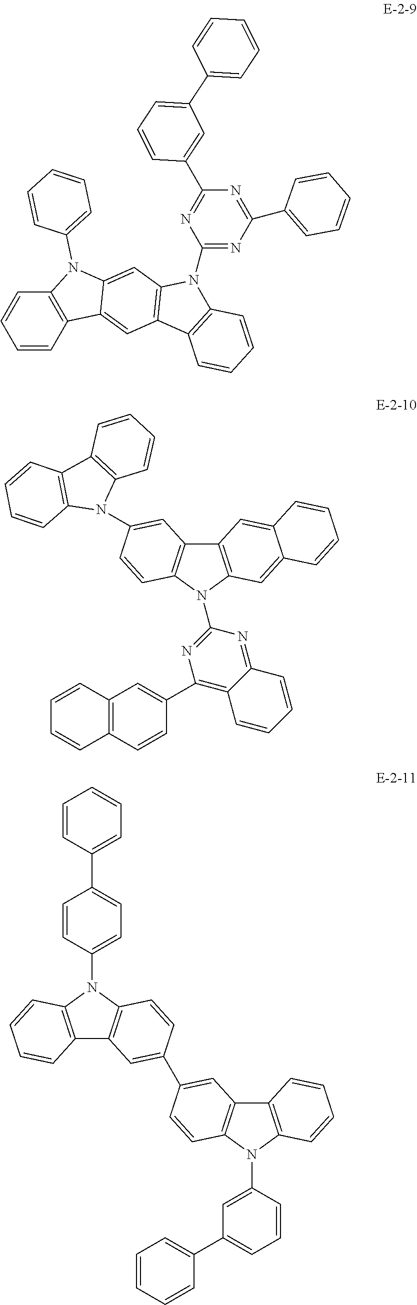

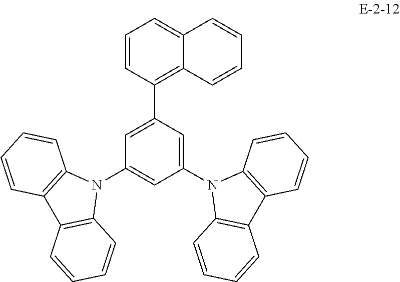 [SMILES: c1ccc2c(-c3cc(-n4c5ccccc5c5ccccc54)cc(-n4c5ccccc5c5ccccc54)c3)cccc2c1]

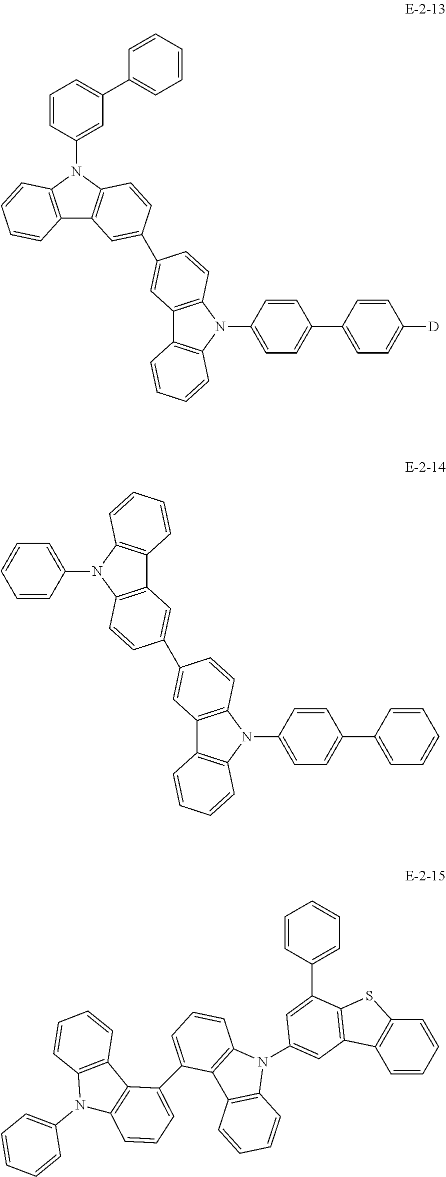 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

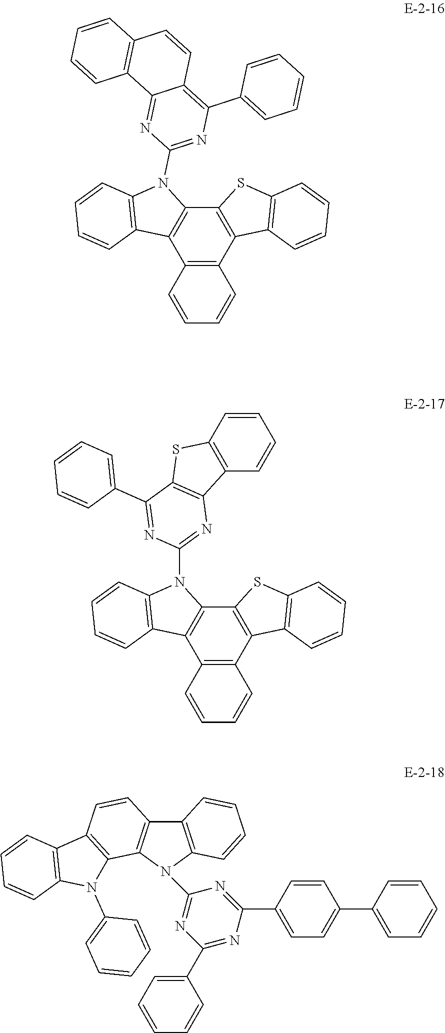 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

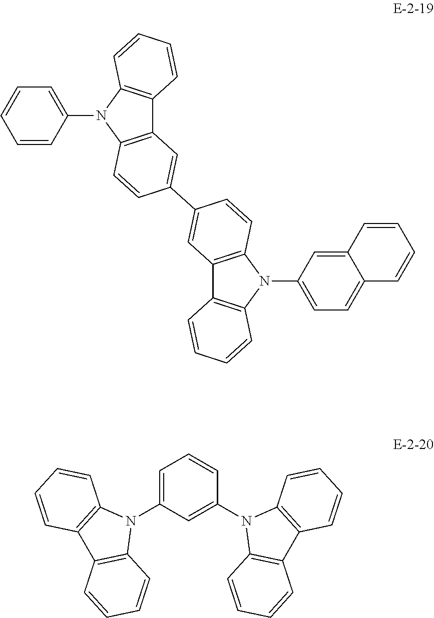 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

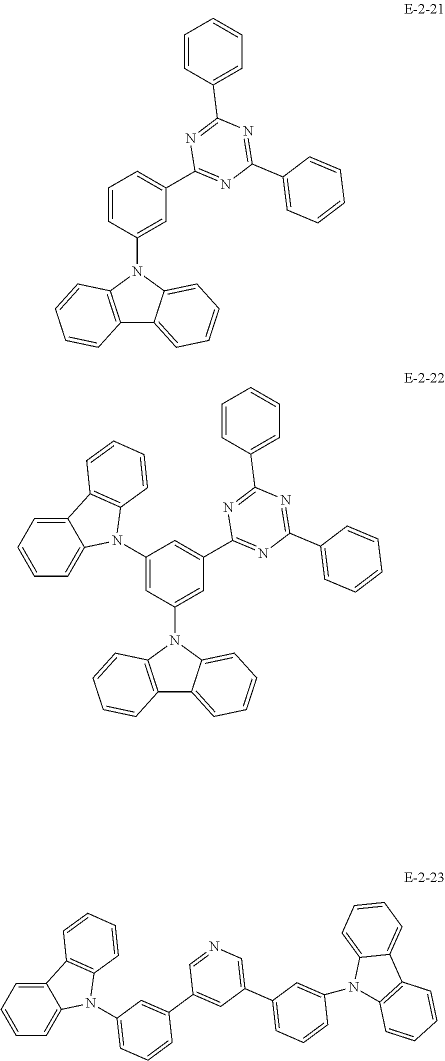 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

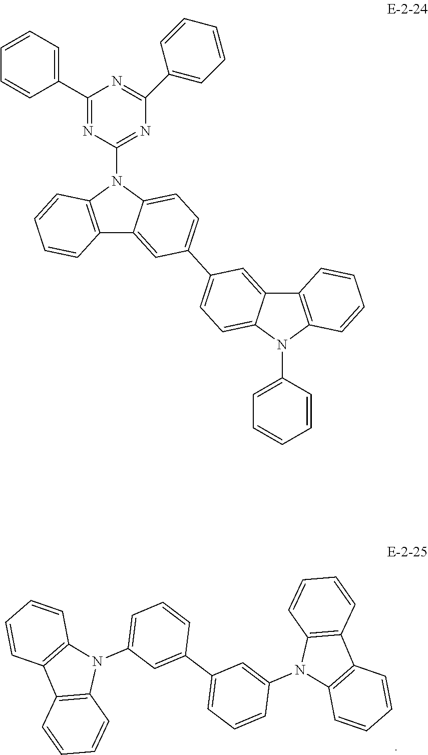 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1cc(-c2cccc(-n3c4ccccc4c4ccccc43)c2)cc(-n2c3ccccc3c3ccccc32)c1]

The emission layer EML may further include a general material generally utilized/generally available in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(N-carbazolyl)benzene (mCP), 2,8-bis(diphenylphosphoryl)dibenzo[b,d]furan (PPF), 4,4′,4″-tris(N-carbazolyl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

The emission layer EML may include a compound represented by Formula M-a or Formula M-b. The compound represented by Formula M-a or Formula M-b may be utilized as a phosphorescent dopant material. In the light emitting element ED of an embodiment, when the compound represented by Formula M-a or Formula M-b is utilized as a green phosphorescent dopant material in the emission layer EML, the compound represented by Formula M-a or Formula M-b may be further included as an auxiliary dopant material, in addition to the above-described organometallic compound.

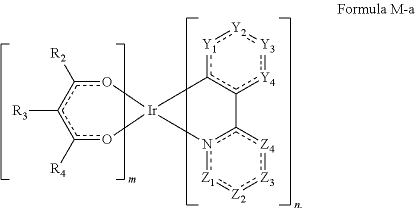

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are merely examples, and the compound represented by Formula M-a is not limited to those represented by Compounds M-a1 to M-a25.

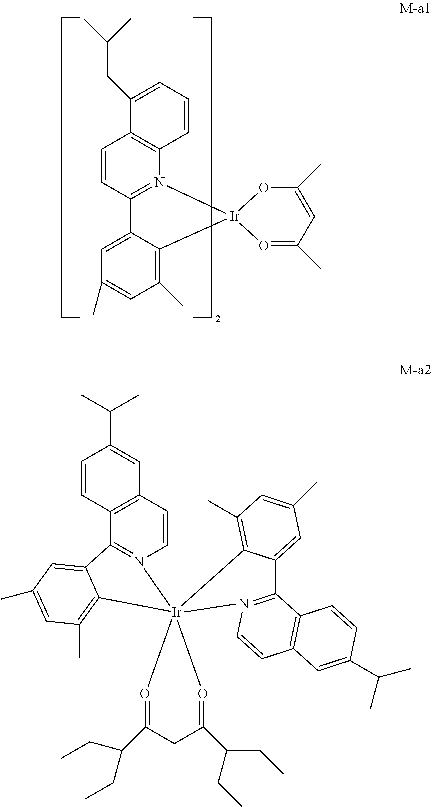

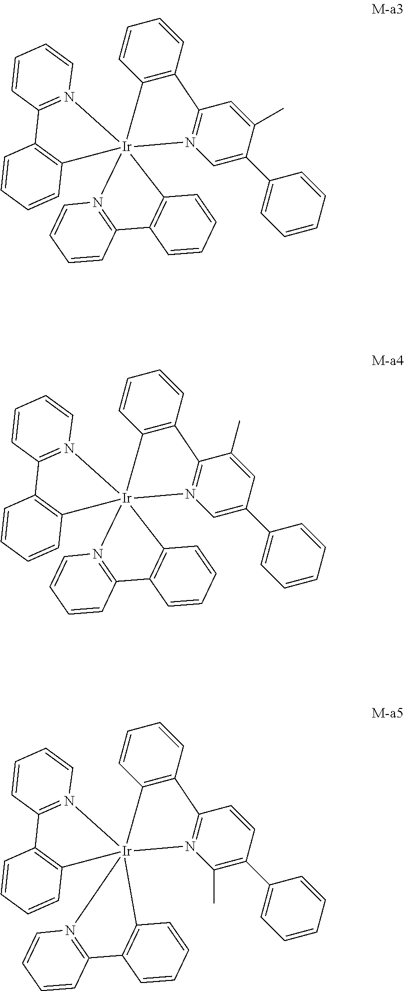

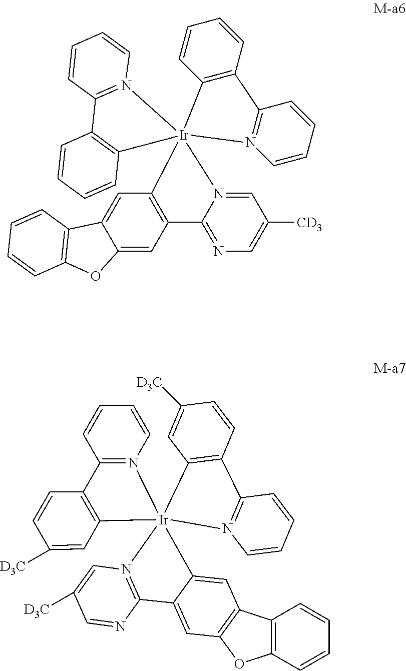

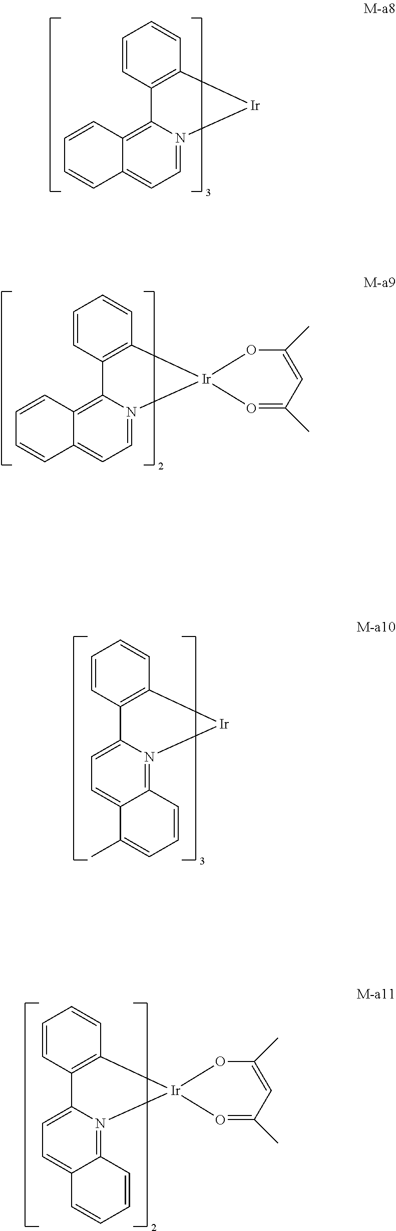

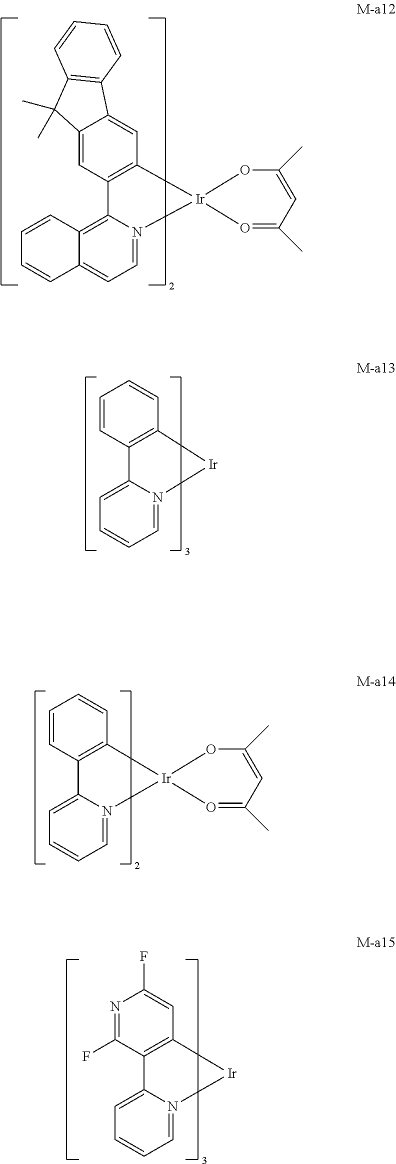

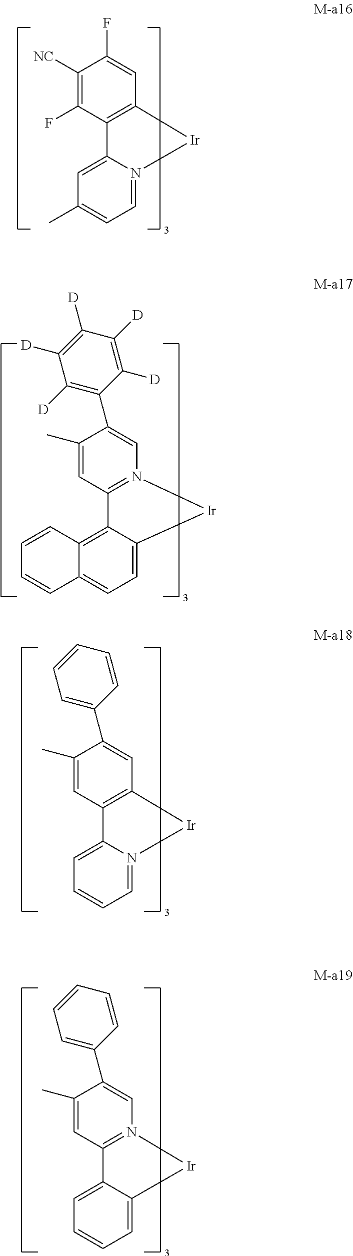

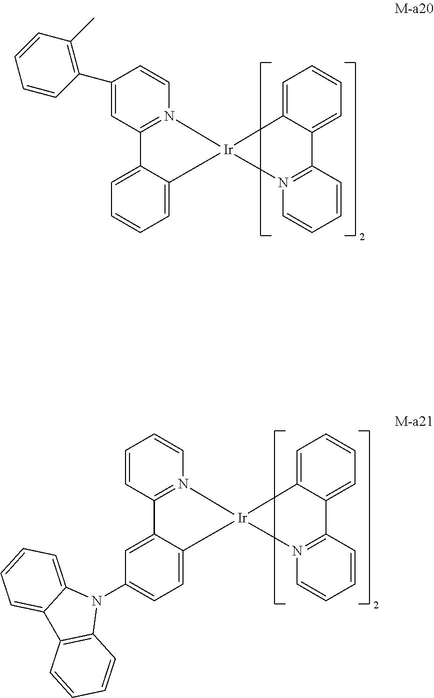

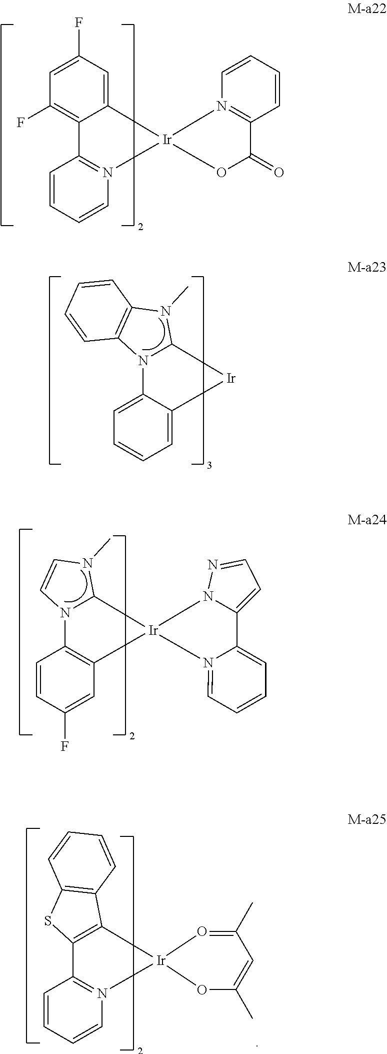

Compound M-a1 and Compound M-a2 may be utilized as a red dopant material, and Compound M-a3 to Compound M-a7 may be utilized as a green dopant material.

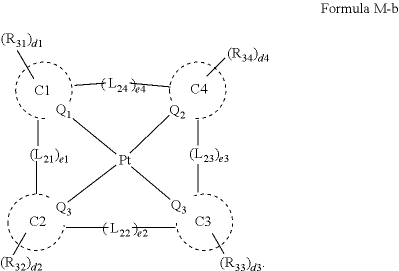

In Formula M-b, Q₁ to Q₄ may each independently be C or N, and C1 to C4 may each independently be a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ may each independently be a direct linkage,

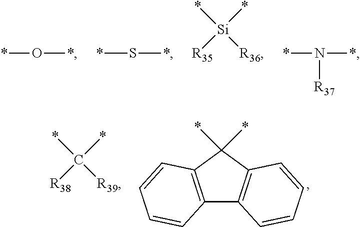

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and e1 to e4 may each independently be 0 or 1. R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and d1 to d4 may each independently be an integer from 0 to 4.

The compound represented by Formula M-b may be utilized as a blue phosphorescent dopant or a green phosphorescent dopant.

The compound represented by Formula M-b may be represented by any one selected from among the compounds below. However, the compounds below are merely examples, and the compound represented by Formula M-b is not limited to those represented by the compounds below.

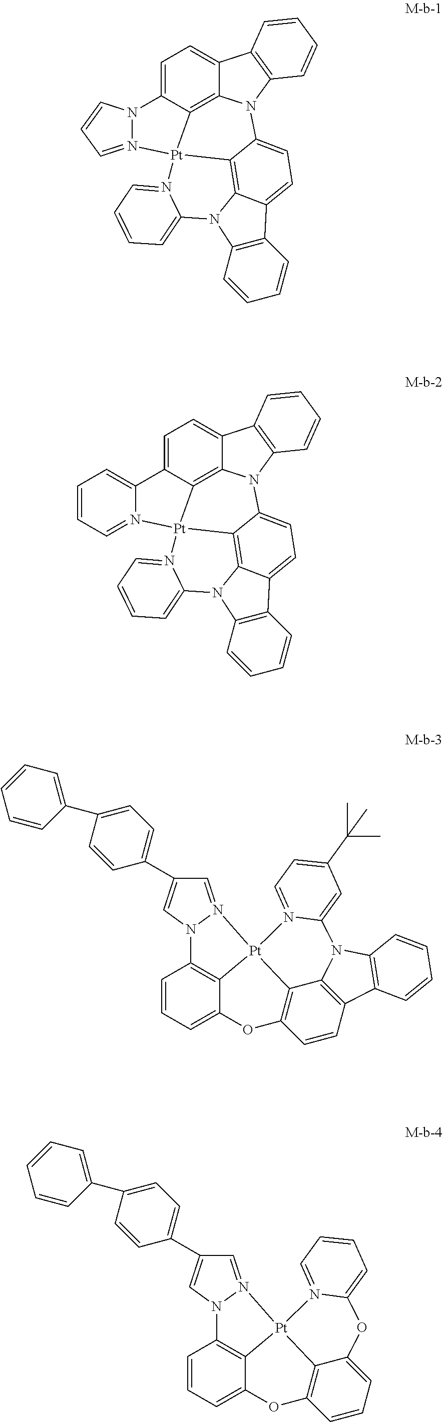

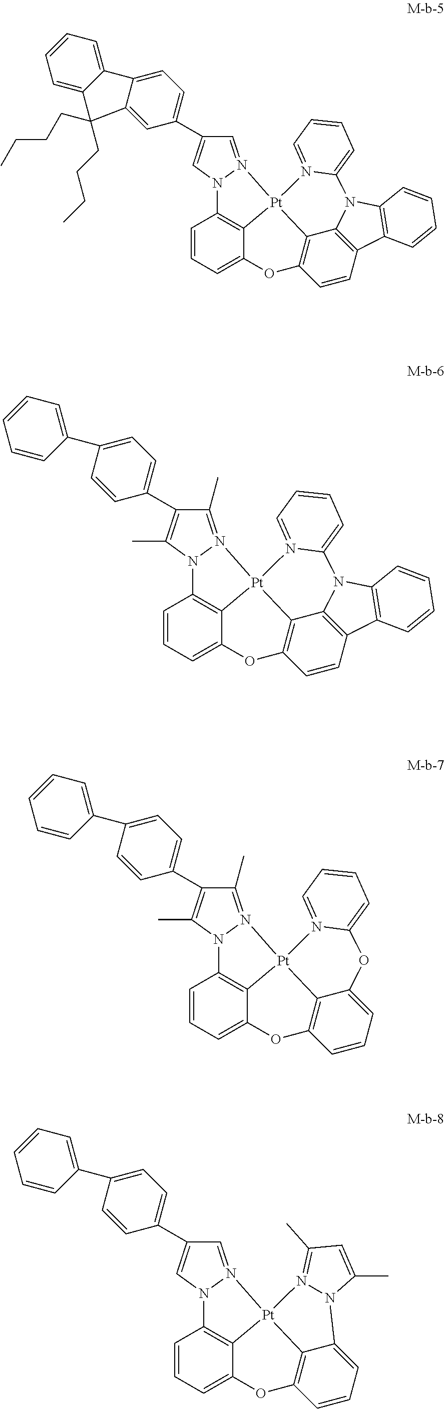

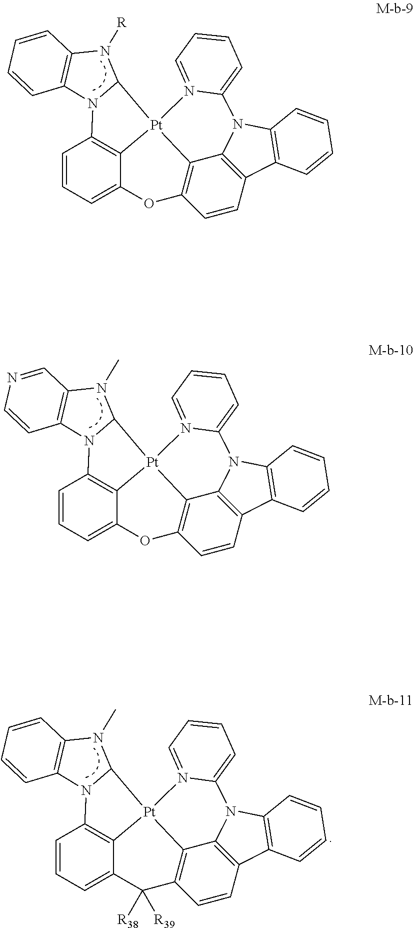

In the compounds, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one selected from among Formula F-a to Formula F-c. The compound represented by Formula F-a to Formula F-c may be utilized as a fluorescence dopant material.

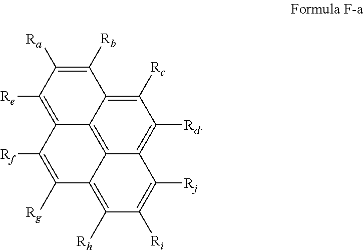

In Formula F-a, two selected from among Rₐ to Rⱼ may each independently be substituted with *—NAr₁Ar₂. The others, which are not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

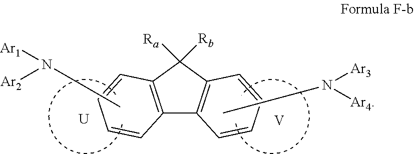

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

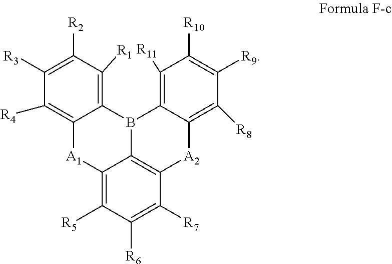

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a condensed ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may include, as a generally utilized/generally available dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layer EML may include a generally utilized/generally available phosphorescent dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from among a Group II-VI compound, a Group III-VI compound, a Group I-III-VI compound, a Group III-V compound, a Group III-II-V compound, a Group IV-VI compound, a Group IV element, a Group IV compound, and one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof, and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, and one or more compounds or mixtures thereof.

The Group III-VI compound may include a binary compound such as In₂S₃ or In₂Se₃, a ternary compound such as InGaS₃ or InGaSe₃, or one or more combinations thereof.

The Group I-III-VI compound may be selected from a ternary compound selected from the group including (e.g., consisting of) AgInS, AgInS₂, CuInS, CuInS₂, AgGaS₂, CuGaS₂ CuGaO₂, AgGaO₂, AgAlO₂, and one or more compounds or mixtures thereof, or a quaternary compound such as AgInGaS₂ or CuInGaS₂.

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. In some embodiments, the Group III-V compound may further include a Group II metal. For example, InZnP, etc. may be selected as a Group III-II-V compound.

The Group IV-VI compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and a quaternary compound selected from the group including (e.g., consisting of) SnPbSSe, SnPbSeTe, SnPbSTe, and one or more compounds or mixtures thereof. The Group IV element may be selected from the group including (e.g., consisting of) Si, Ge, and a mixture thereof. The Group IV compound may be a binary compound selected from the group including (e.g., consisting of) SiC, SiGe, and a mixture thereof.

In this embodiment, a binary compound, a ternary compound, or a quaternary compound may be present in a particle form with a substantially uniform concentration distribution, or may be present in substantially the same particle form with a partially different concentration distribution. In some embodiments, a core/shell structure in which one quantum dot surrounds another quantum dot may also be possible. The core/shell structure may have a concentration gradient in which the concentration of elements present in the shell decreases toward the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dot may have a full width of half maximum (FWHM) of a light emitting wavelength spectrum of about 45 nm or less, about 40 nm or less, or about 30 nm or less, and color purity or color reproducibility may be improved in the above range. In some embodiments, light emitted through such a quantum dot is emitted in all directions, and thus a wide viewing angle may be improved (increased).

In some embodiments, although the form of the quantum dot is not limited as long as it is a form commonly utilized in the art, for example, the quantum dot in the form of a substantially spherical, pyramidal, multi-arm, or cubic nanoparticles, nanotubes, nanowires, nanofibers, nanoplate particles, etc. may be utilized.

A quantum dot may control the color of emitted light according to the particle size thereof and thus the quantum dot may have one or more suitable light emission colors such as blue, green, red, etc.

In each light emitting element ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

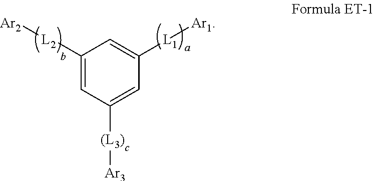

In Formula ET-1, at least one selected from among X₁ to X₃ is N, and the rest (i.e., the substituents that are not N) are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq3), diphenyl(4-(triphenylsilyl)phenyl)phosphine oxide (TSPO1), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl)anthracene (ADN), 1,3-bis[3,5-di(pyridin-3-yl)phenyl]benzene (BmPyPhB), or one or more compounds or mixtures thereof.

The electron transport region ETR may include at least one selected from among Compound ET1 to Compound ET36:

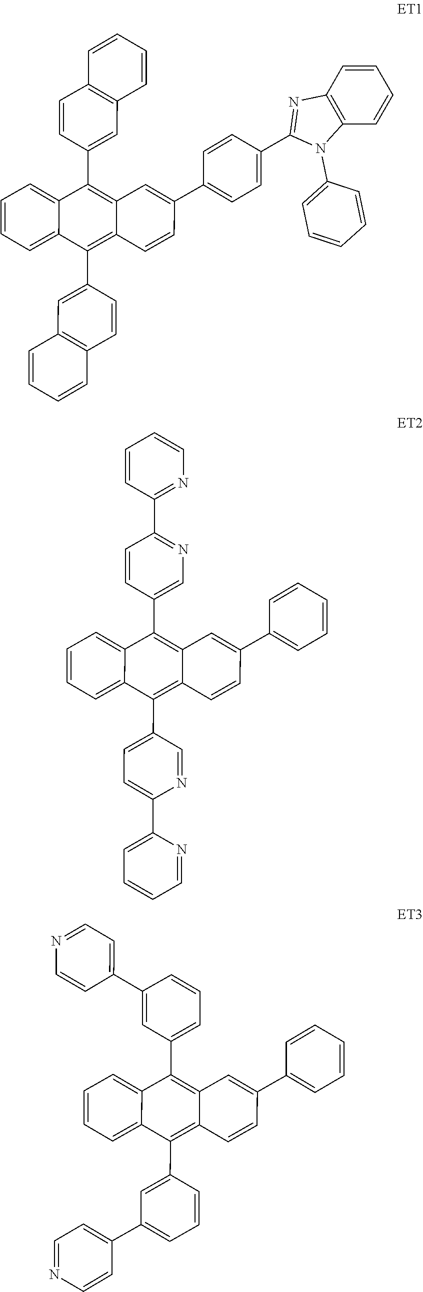 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

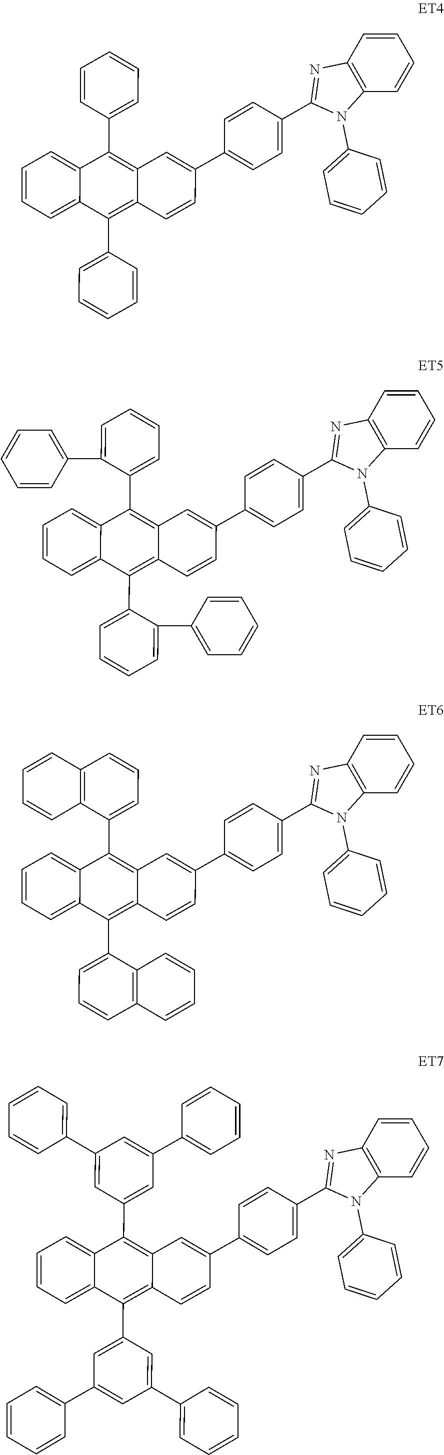 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

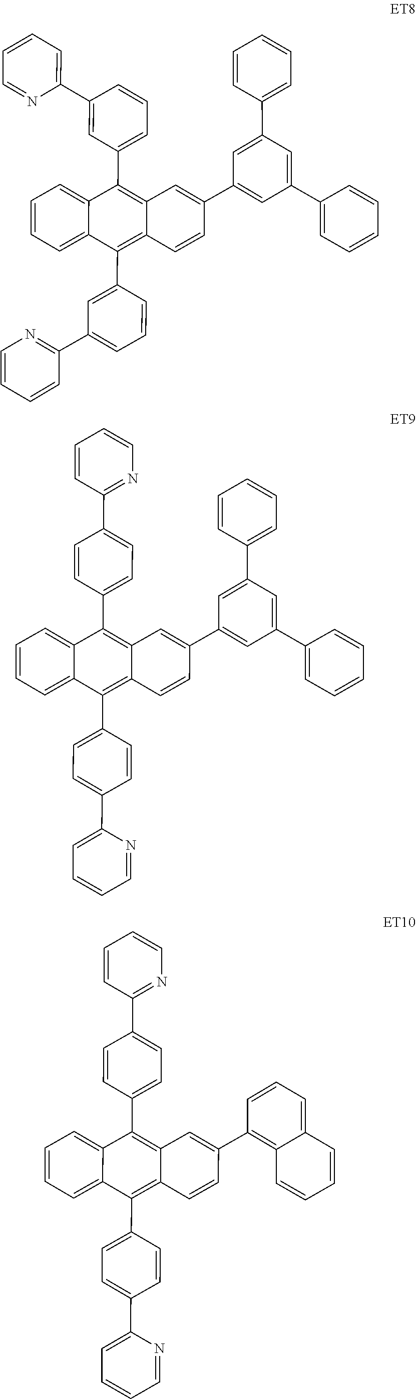 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

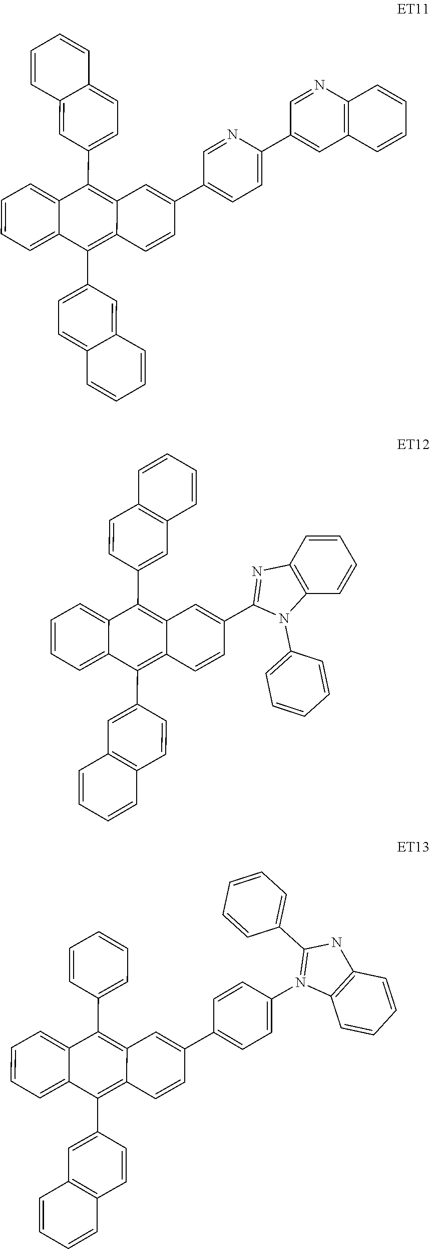

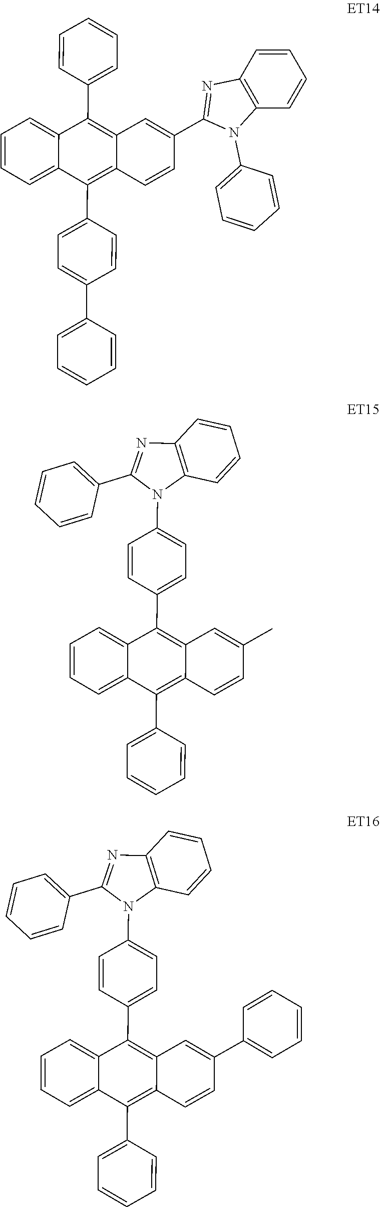

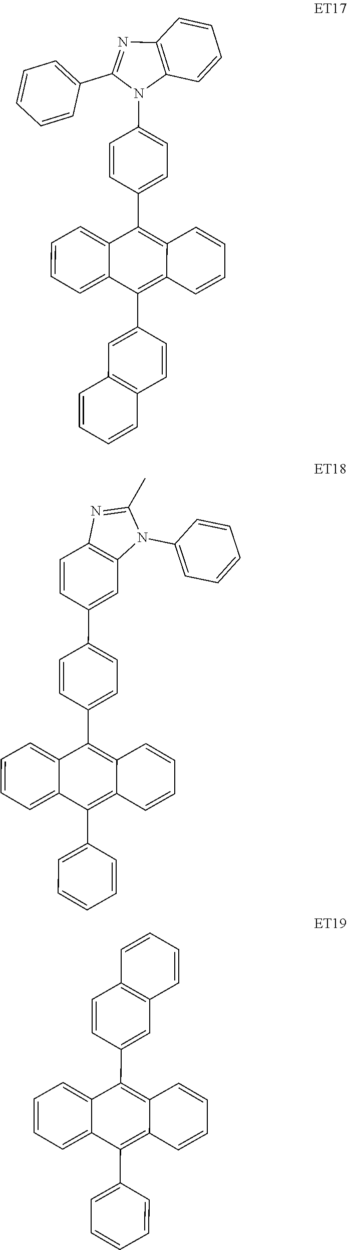

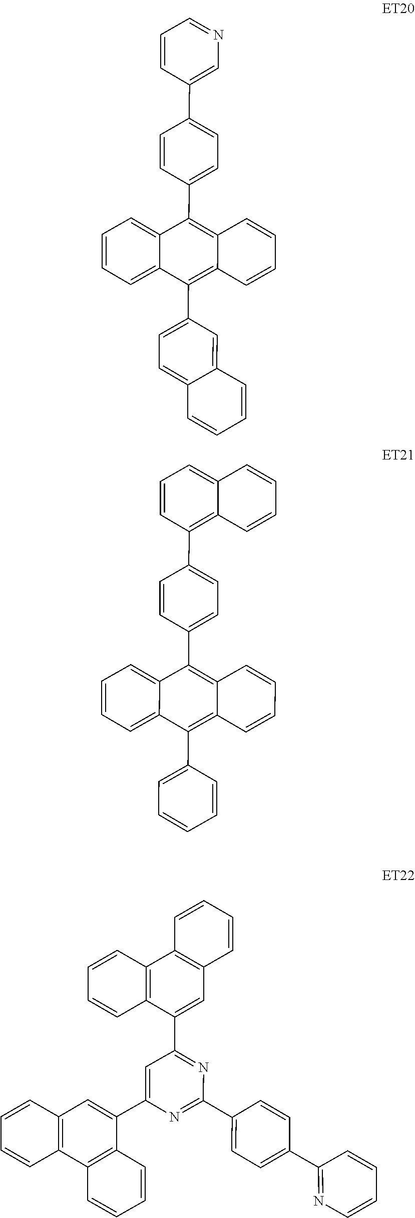

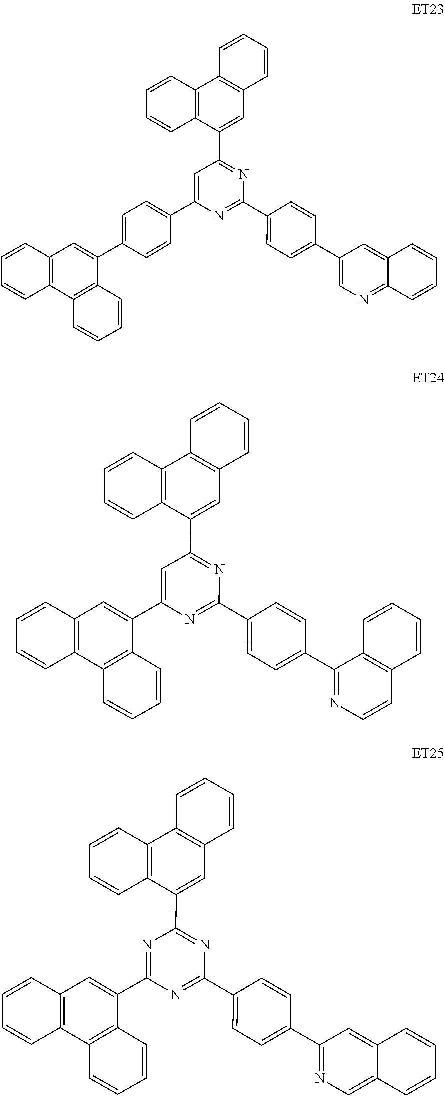 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)nc(-c5cc6ccccc6c6ccccc56)n4)cc3)ncc2c1]

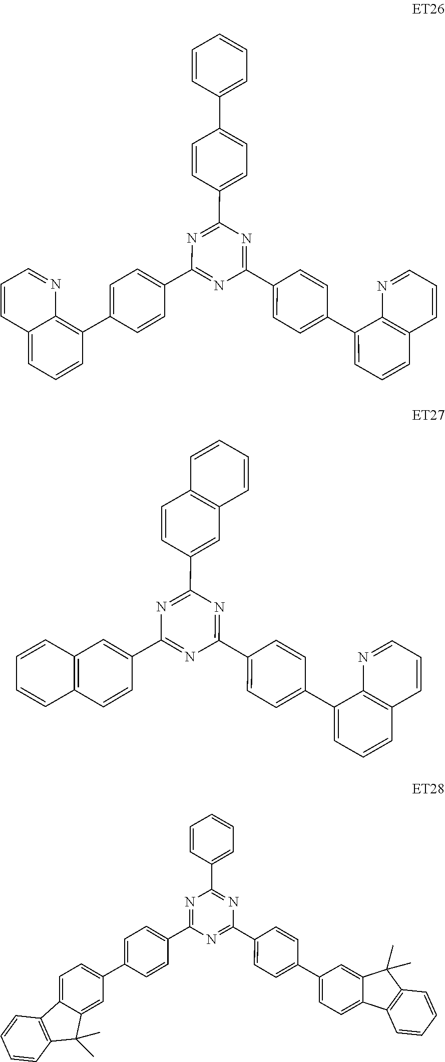 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

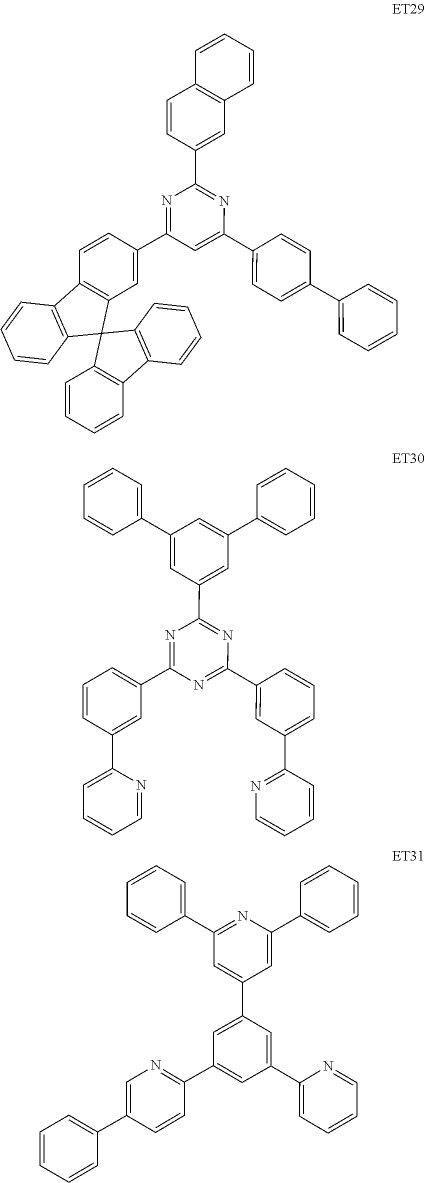

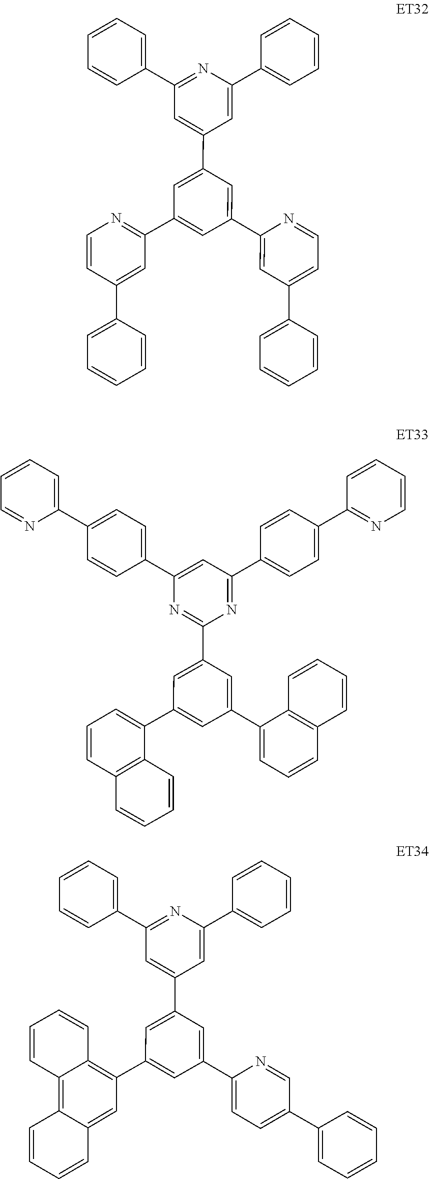 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

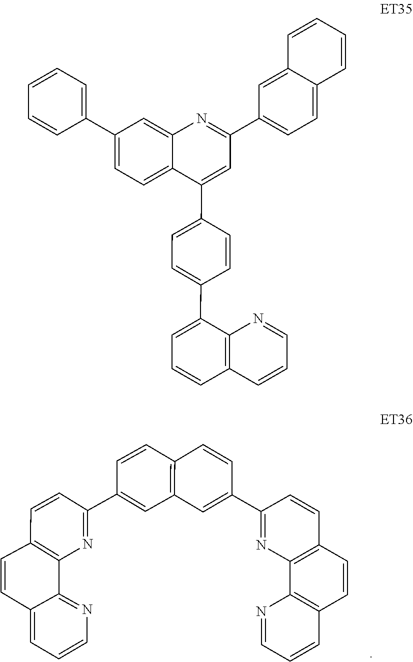 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport regions ETR may include a metal halide such as LiF, NaCl, CsF, RbCl, RbI, CuI, or KI, a lanthanide metal such as Yb, and a co-deposited material of the metal halide and the lanthanide metal. For example, the electron transport region ETR may include KI:Yb, RbI:Yb, etc. as a co-deposited material. In some embodiments, the electron transport region ETR may be formed utilizing a metal oxide such as Li₂O and/or BaO, and/or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), or 4,7-diphenyl-1,10-phenanthroline (Bphen) in addition to the above-described materials, but the embodiment of the present disclosure is not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory (suitable) electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described range, satisfactory (suitable) electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or one or more compounds or mixtures thereof (e.g., AgMg, AgYb, or MgYb). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

The second electrode EL2 may be connected to an auxiliary electrode. When the second electrode EL2 is connected to the auxiliary electrode, the resistance of the second electrode EL2 may decrease.

In some embodiments, a capping layer CPL may further be disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiO_{y}, etc.

For example, when the capping layer CPL contains an organic material, the organic material may include α-NPD, NPB, TPD, m-MTDATA, Alq3, CuPc, N4,N4,N4′,N4′-tetra(biphenyl-4-yl)biphenyl-4,4′-diamine (TPD15), 4,4′,4″-tris(N-carbazolyl)triphenylamine (TCTA), etc., or may include an epoxy resin, or an acrylate such as a methacrylate. However, the embodiment of the present disclosure is not limited thereto, and the capping layer CPL may include at least one selected from among Compounds P1 to P5:

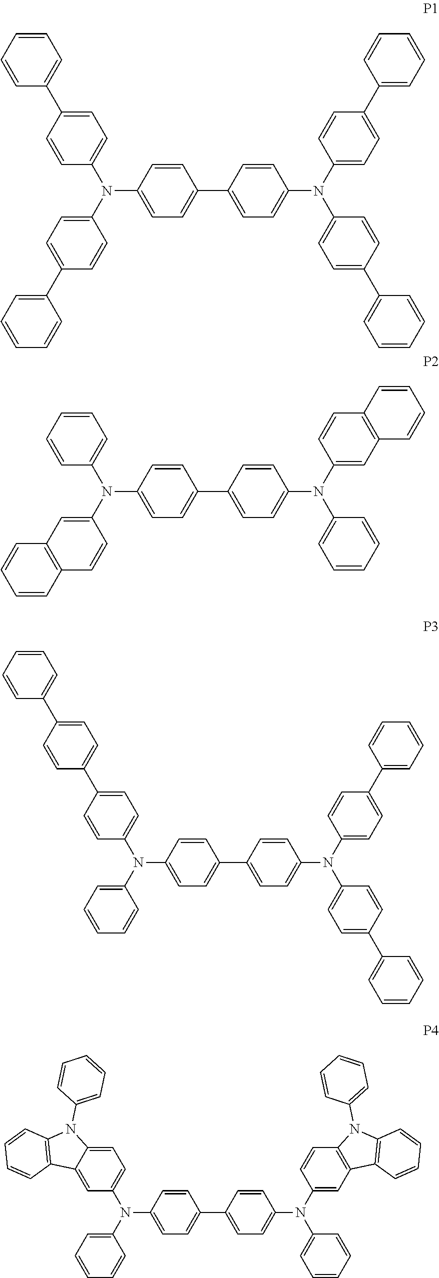 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

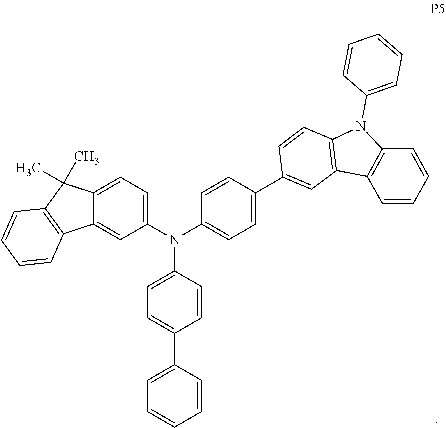 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

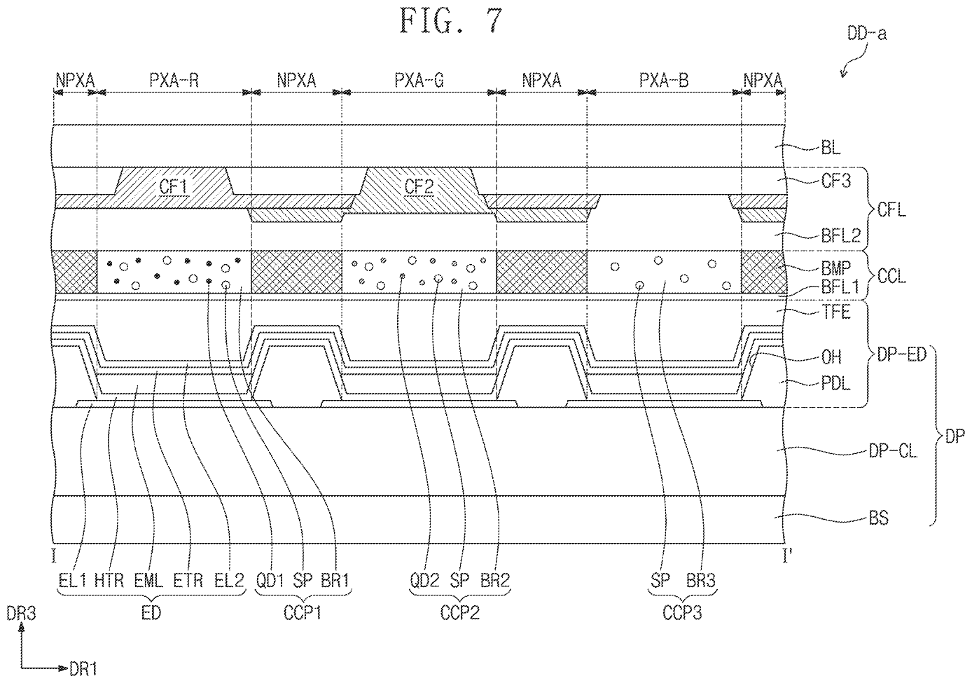

FIGS. 7 to 10 each are a cross-sectional view of a display device according to an embodiment. Hereinafter, in describing the display devices of embodiments with reference to FIGS. 7 to 10, the duplicated features which have been described in FIGS. 1 to 6 may not be described again, but their differences will primarily be described.

Referring to FIG. 7, the display device DD-a according to an embodiment may include a display panel DP including a display element layer DP-ED, a light control layer CCL on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In some embodiments, the structures of the light emitting elements ED of FIGS. 3 to 6 as described above may be equally applied to the structure of the light emitting element ED illustrated in FIG. 7.

The emission layer EML of the light emitting element ED included in the display device DD-a according to an embodiment may include the above-described organometallic compound of an embodiment.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may emit light in substantially the same wavelength range. In the display device DD-a of an embodiment, the emission layer EML may emit blue light. In some embodiments, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. For example, the light control layer CCL may be a layer containing the quantum dot or a layer containing the phosphor.

The light control layer CCL may include a plurality of light control parts CCP1, CCP2, and CCP3. The light control parts CCP1, CCP2, and CCP3 may be spaced apart from (separated from) each other.

Referring to FIG. 7, divided patterns BMP may be disposed between the light control parts CCP1, CCP2, and CCP3 which are spaced apart from (separated from) each other, but the embodiment of the present disclosure is not limited thereto. FIG. 7 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. Substantially the same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but may still include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be disposed on the light control parts CCP1, CCP2, and CCP3 to block or reduce the light control parts CCP1, CCP2, and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be on the light control layer CCL. For example, the color filter layer CFL may be directly on the light control layer CCL. In this embodiment, the barrier layer BFL2 may not be provided.

The color filter layer CFL may include a light shielding part and filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. However, the embodiment of the present disclosure is not limited thereto, and the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated from each other, but may be provided as one filter.

The light shielding part may be a black matrix. The light shielding part may include an organic light shielding material or an inorganic light shielding material containing a black pigment and/or dye. The light shielding part may prevent or reduce light leakage, and may separate boundaries between the adjacent filters CF1, CF2, and CF3. In some embodiments, the light shielding part may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

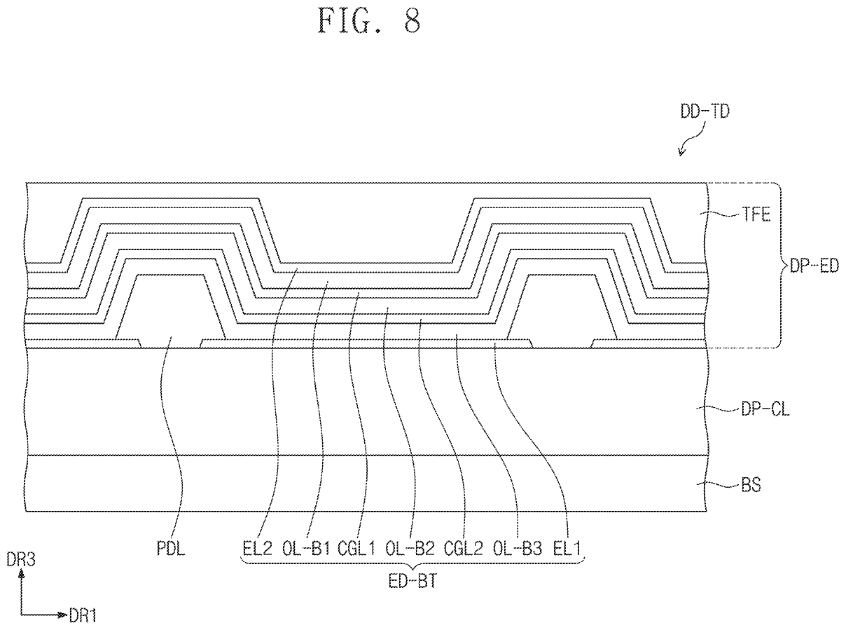

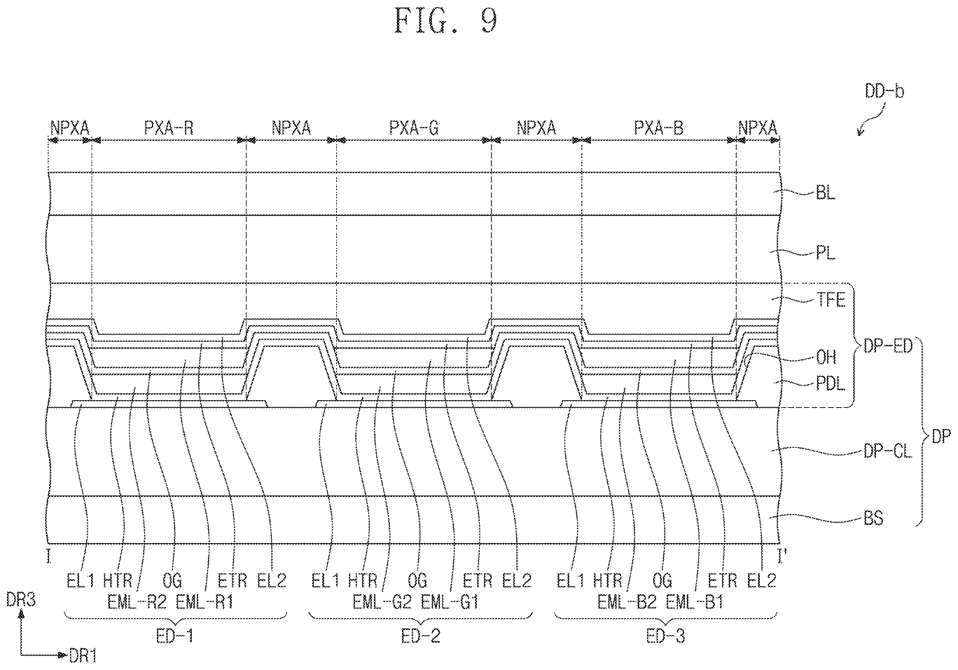

FIG. 8 is a cross-sectional view illustrating a portion of a display device according to an embodiment of the present disclosure. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) therebetween.

For example, the light emitting element ED-BT included in the display device DD-TD of an embodiment may be a light emitting element having a tandem structure and including a plurality of emission layers.

In an embodiment illustrated in FIG. 8, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light (e.g., a combined white light).

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer (e.g., P-charge generation layer) and/or an n-type or kind charge generation layer (e.g., N-charge generation layer).

At least one selected from among the light emitting structures OL-B1, OL-B2, and OL-B3 included in the display device DD-TD of an embodiment may include the above-described organometallic compound of an embodiment. For example, at least one selected from among the plurality of emission layers included in the light emitting element ED-BT may include the organometallic compound of an embodiment.

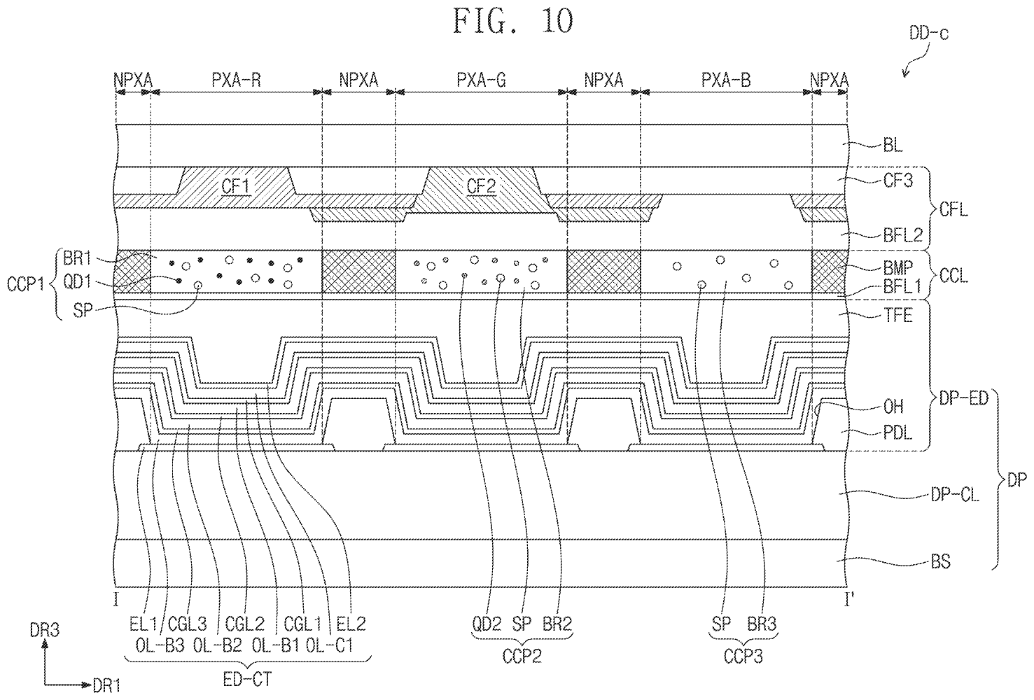

FIG. 9 is a cross-sectional view illustrating a display device according to an embodiment of the present disclosure; and FIG. 10 is a cross-sectional view illustrating a display device according to an embodiment of the present disclosure.

Referring to FIG. 9, the display device DD-b according to an embodiment may include light emitting elements ED-1, ED-2, and ED-3 in which two emission layers are stacked. Compared with the display device DD of an embodiment illustrated in FIG. 2, an embodiment illustrated in FIG. 9 has a difference in that the first to third light emitting elements ED-1, ED-2, and ED-3 each include two emission layers stacked in the thickness direction. In each of the first to third light emitting elements ED-1, ED-2, and ED-3, the two emission layers may emit (may each) light in substantially the same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R₁, the first green emission layer EML-G1, and the first blue emission layer EML-B1 may be between the electron transport region ETR and the emission auxiliary part OG. The second red emission layer EML-R₂, the second green emission layer EML-G2, and the second blue emission layer EML-B2 may be between the emission auxiliary part OG and the hole transport region HTR.

For example, the first light emitting element ED-1 may include the first electrode EL1, the hole transport region HTR, the second red emission layer EML-R₂, the emission auxiliary part OG, the first red emission layer EML-R₁, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be on the display element layer DP-ED. The optical auxiliary layer PL may include a polarizing layer. The optical auxiliary layer PL may be on the display panel DP and control reflected light in the display panel DP due to external light. The optical auxiliary layer PL in the display device according to an embodiment may not be provided.

At least one emission layer included in the display device DD-b of an embodiment illustrated in FIG. 9 may include the above-described organometallic compound of an embodiment. For example, in an embodiment, at least one of the first blue emission layer EML-B1 or the second blue emission layer EML-B2 may include the organometallic compound of an embodiment.

Unlike FIGS. 8 and 9, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, the embodiment of the present disclosure is not limited thereto, and the first to fourth light emitting structures OL-B1, OL-B2, OL-B3, and OL-C1 may emit light beams in different wavelength regions.

The charge generation layers CGL1, CGL2, and CGL3 disposed between adjacent light emitting structures OL-B1, OL-B2, OL-B3, and OL-C1 may include a p-type or kind charge generation layer (e.g., P-charge generation layer) and/or an n-type or kind charge generation layer (e.g., N-charge generation layer).

At least one selected from among the light emitting structures OL-B1, OL-B2, OL-B3, and OL-C1 included in the display device DD-c of an embodiment may include the above-described organometallic compound of an embodiment. For example, in an embodiment, at least one selected from among the first to third light emitting structures OL-B1, OL-B2, and OL-B3 may include the described-above organometallic compound of an embodiment.

Hereinafter, with reference to Examples and Comparative Examples, an organometallic compound according to an embodiment of the present disclosure and a light emitting element of an embodiment of the present disclosure will be described in more detail. Examples described below are merely examples to assist the understanding of the inventive concept, and the scope of the inventive concept is not limited thereto.

### EXAMPLES

### 1. Synthesis of Organometallic Compound of Examples

First, a synthetic method of an organometallic compound according to the present embodiment will be described by illustrating synthetic methods of Compounds 4, 36, 54, 63, 95, 148, 162, and 175. In some embodiments, in the following descriptions, the synthetic method of the organometallic compound is provided as an example, but the synthetic method of the compound according to an embodiment of the present disclosure is not limited to Examples.

### Examples

### (1) Synthetic Example 1: Synthesis of Compound 4

Compound 4 according to an example may be synthesized by, for example, the steps (e.g., acts or tasks) shown in Reaction Scheme 1:

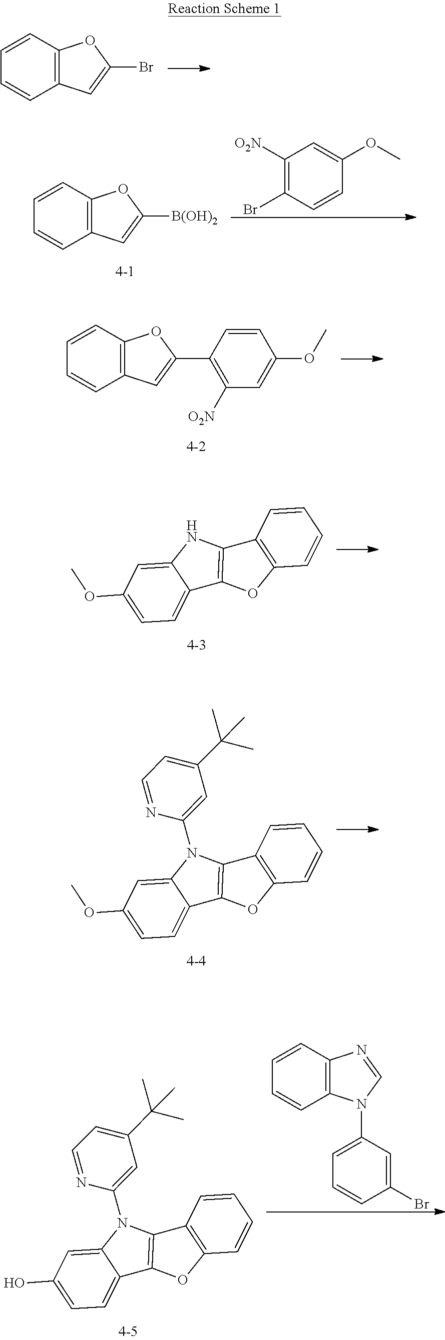

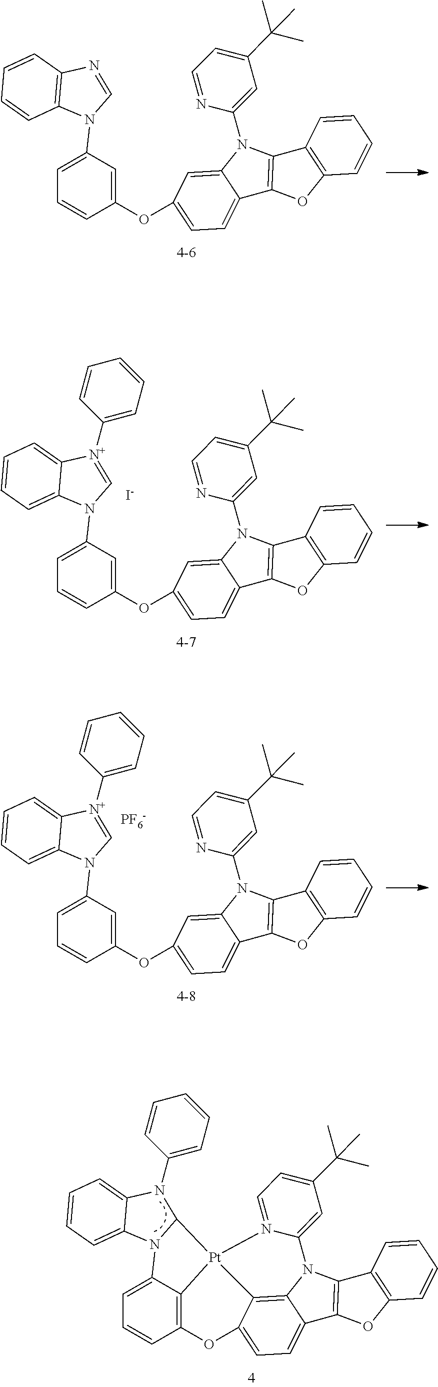

### 1) Synthesis of Intermediate Compound 4-1

2-bromobenzofuran (3.94 g, 20 mmol) was dissolved in 50 mL of THF, and then n-butyllithium (8 mL, 2.5 M in hexane) was added thereto at about −78° C. After one hour, triisopropyl borate (15 mmol) was added thereto at substantially the same temperature. The resulting mixture was stirred at room temperature for about 10 hours, water was then added thereto, and the resultant mixture was washed three times with diethyl ether (40 mL). The washed diethyl ether layer was dried over MgSO₄, then dried under reduced pressure to obtain a product. Then, the obtained product was separated and purified by silica gel column chromatography to obtain Intermediate Compound 4-1 (2.8 g, 17 mmol).

### 2) Synthesis of Intermediate Compound 4-2

Intermediate Compound 4-1 (2.8 g, 17 mmol), 1-bromo-4-methoxy-2-nitrobenzene (4.1 g, 17.7 mmol), Pd(PPh₃)₄ (0.59 g, 0.51 mmol), and NaOH (2.0 g, 51 mmol) were added to a reaction vessel and suspended in 80 mL of THF. The reaction mixture was heated and stirred at about 80° C. for about 10 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 4-2 (4.0 g, 15 mmol).

### 3) Synthesis of Intermediate Compound 4-3

Intermediate Compound 4-2 (4.0 g, 15 mmol) and triphenyl phosphine (9.8 g, 37.5 mmol) were added to a reaction vessel and suspended in 80 mL of o-dichlorobenzene. The reaction mixture was heated and stirred at about 180° C. for about 20 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 4-3 (2.8 g, 12 mmol).

### 4) Synthesis of Intermediate Compound 4-4

Intermediate Compound 4-3 (2.8 g, 12 mmol), 2-bromo-4(tert-butyl)pyridine (3.9 g, 18 mmol), potassium triphosphate (5.5 g, 24 mmol), CuI (0.44 g, 2.4 mmol), and picolinic acid (0.27 g, 2.4 mmol) were added to a reaction vessel and suspended in 50 mL of dimethylsulfoxide. The reaction mixture was heated and stirred at about 160° C. for about 24 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 4-4 (3.7 g, 10 mmol).

### 5) Synthesis of Intermediate Compound 4-5

Intermediate Compound 4-4 (3.7 g, 10 mmol) was suspended in an excess of bromic acid solution. The reaction mixture was heated and stirred at about 110° C. for about 24 hours. After the reaction was completed, the reaction solution was cooled to room temperature, and neutralized by adding an appropriate or suitable amount of sodium bicarbonate. Distilled water (100 mL) was added thereto and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 4-5 (3.2 g, 9.0 mmol).

### 6) Synthesis of Intermediate Compound 4-6

Intermediate Compound 4-5 (3.2 g, 9 mmol), 1-(3-bromophenyl)-1H-benzimidazole (3.0 g, 13.5 mmol), potassium triphosphate (4.2 g, 18 mmol), CuI (0.33 g, 0.18 mmol), and picolinic acid (0.02 g, 0.18 mmol) were added to a reaction vessel and suspended in 40 mL of dimethylsulfoxide. The reaction mixture was heated and stirred at about 160° C. for about 20 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 4-6 (3.6 g, 6.5 mmol).

### 7) Synthesis of Intermediate Compound 4-7

Intermediate Compound 4-6 (3.6 g, 6.5 mmol) and diphenyliodanium (13 mmol) were suspended in toluene. The reaction mixture was heated and stirred at about 110° C. for about 24 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 4-7 (3.8 g, 5.1 mmol).

### 8) Synthesis of Intermediate Compound 4-8

Intermediate Compound 4-7 (3.8 g, 5.1 mmol) and ammonium hexafluorophosphate (3.3 g, 20 mmol) were added to a reaction vessel and suspended in a mixed solution of methyl alcohol (100 mL) and water (25 mL). The reaction mixture was stirred at room temperature for about 24 hours. After the reaction was completed, the resulting solid was filtered and washed with ether. The washed solid was dried to obtain Intermediate Compound 4-8 (3.8 g, 4.9 mmol).

### 9) Synthesis of Compound 4

Intermediate Compound 4-8 (3.8 g, 4.9 mmol) and dichloro(1,5-cyclooctadiene)platinum (1.9 g, 5.39 mmol), and sodium acetate (0.8 g, 9.8 mmol) were suspended in 90 mL of dioxane. The reaction mixture was heated and stirred at about 110° C. for about 72 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Compound 4 (1.6 g, 2.0 mmol).

### (2) Synthetic Example 2: Synthesis of Compound 36

Compound 36 according to an example may be synthesized by, for example, the steps shown in Reaction Scheme 2:

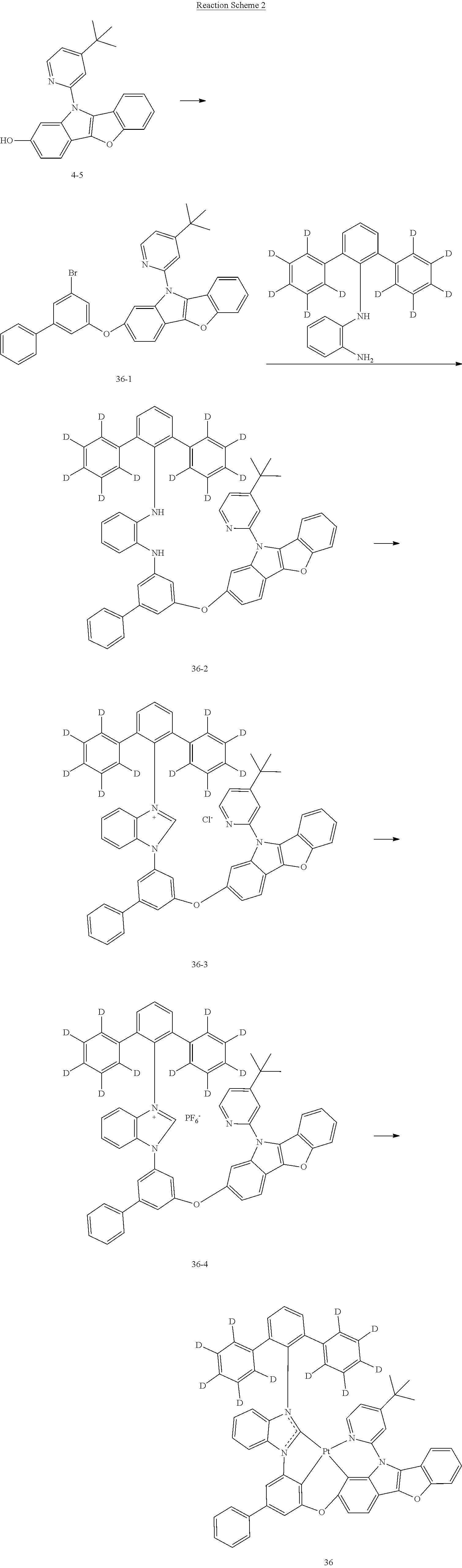

### 1) Synthesis of Intermediate Compound 36-1

Intermediate Compound 4-5 (3.2 g, 9 mmol), 3,5-dibromo-1,1′-biphenyl (4.2 g, 13.5 mmol), potassium triphosphate (4.2 g, 18 mmol), CuI (0.33 g, 0.18 mmol), and picolinic acid (0.02 g, 0.18 mmol) were added to a reaction vessel and suspended in 40 mL of dimethylsulfoxide. The reaction mixture was heated and stirred at about 160° C. for about 20 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 36-1 (4.0 g, 6.8 mmol).

### 2) Synthesis of Intermediate Compound 36-2

Intermediate Compound 36-1 (4.0 g, 6.8 mmol), N1-([1,1′:3′,1″-terphenyl]-2′-yl-2,2″,3,3″,4,4″,5,5″,6,6″-d₁₀)benzene-1,2-diamine (2.4 g, 6.8 mmol), SPhos (0.51 mmol), Pd₂(dba)₃ (0.34 mmol), and sodium t-butoxide (13.6 mmol) were suspended in 100 mL of a toluene solvent, and the resulting solution was heated to about 100° C. and stirred for about 4 hours. After the reaction was completed, the solvent was removed under reduced pressure, and an organic layer was extracted with methylene chloride and distilled water. The extracted organic layer was washed with a saturated sodium chloride aqueous solution and dried over sodium sulfate. Residues with a solvent removed were separated by column chromatography to obtain Intermediate Compound 36-2 (5.0 g, 5.9 mmol).

### 3) Synthesis of Intermediate Compound 36-3

Intermediate Compound 36-2 (5.0 g, 5.9 mmol) was dissolved in triethyl orthoformate (300 mmol), and then HCl (7.1 mmol) was added dropwise thereto. The resulting mixture was heated to about 80° C. and stirred for about 20 hours. After the reaction was completed, the solvent was removed under reduced pressure, and an organic layer was extracted with methylene chloride and distilled water. The extracted organic layer was washed with a saturated sodium chloride aqueous solution and dried over sodium sulfate. Residues with a solvent removed were separated by column chromatography to obtain Intermediate Compound 36-3 (4.3 g, 4.8 mmol).

### 4) Synthesis of Intermediate Compound 36-4

Intermediate Compound 36-3 (4.3 g, 4.8 mmol) and ammonium hexafluorophosphate (2.4 g, 14.4 mmol) were added to a reaction vessel and suspended in a mixed solution of methyl alcohol (120 mL) and water (30 mL). The reaction mixture was stirred at room temperature for about 24 hours. After the reaction was completed, the resulting solid was filtered and washed with ether. The washed solid was dried to obtain Intermediate Compound 36-4 (4.7 g, 4.7 mmol).

### 5) Synthesis of Compound 36

Compound 36 (3.3 g, 3.1 mmol) was obtained by utilizing substantially the same manner as in Synthesis of Compound 4 of Synthetic Example 1 above except for utilizing Intermediate Compound [36-4] instead of Intermediate Compound 4-8.

### (3) Synthetic Example 3: Synthesis of Compound 54

Compound 54 according to an example may be synthesized by, for example, the steps shown in Reaction Scheme 3:

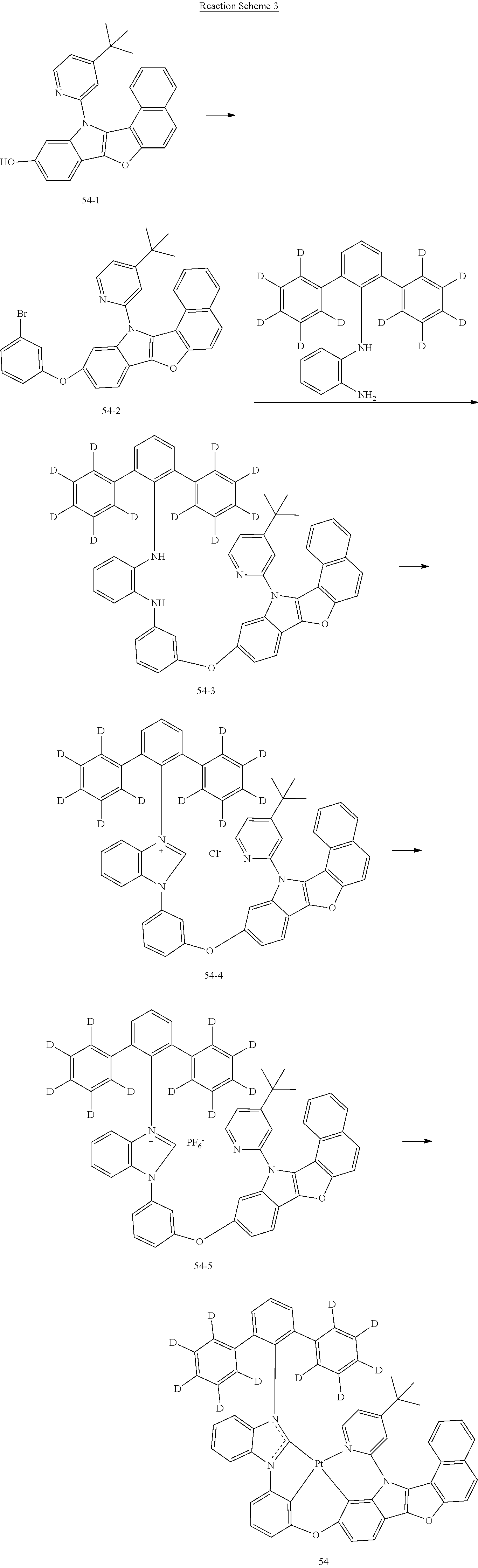

### 1) Synthesis of Intermediate Compound 54-1

Intermediate Compound 54-1 was obtained utilizing 2-bromonaphtho[2,1-b]furan instead of 2-bromobenzofuran as a starting material and utilizing substantially the same condition and manner as in Synthesis of Intermediate Compound 4-1 to Intermediate Compound 4-5 of Synthetic Example 1 above.

### 2) Synthesis of Intermediate Compound 54-2

Intermediate Compound 54-1 (4.1 g, 10 mmol), 1-bromo-3-fluorobenzene (2.6 g, 15 mmol), and potassium triphosphate (4.6 g, 20 mmol) were added to a reaction vessel and suspended in 50 mL of dimethylsulfoxide. The reaction mixture was heated and stirred at about 160° C. for about 12 hours. After the reaction was completed, the reaction solution was cooled to room temperature, 100 mL of distilled water was added thereto, and an organic layer was extracted with ethyl acetate. The extracted organic layer was washed with a saturated sodium chloride aqueous solution and dried over sodium sulfate. Residues with a solvent removed were separated by column chromatography to obtain Intermediate Compound 54-2 (4.3 g, 7.6 mmol).

### 3) Synthesis of Intermediate Compound 54-3

Intermediate Compound 54-3 was obtained by utilizing substantially the same manner as in Synthesis of Intermediate Compound 36-2 of Synthetic Example 2 except for utilizing Intermediate Compound 54-2 instead of Intermediate Compound 36-1.

### 4) Synthesis of Intermediate Compound 54-4

Intermediate Compound 54-4 was obtained by utilizing substantially the same manner as in Synthesis of Intermediate Compound 36-3 of Synthetic Example 2 except for utilizing Intermediate Compound 54-3 instead of Intermediate Compound 36-2.

### 5) Synthesis of Intermediate Compound 54-5

Intermediate Compound 54-5 was obtained by utilizing substantially the same manner as in Synthesis of Intermediate Compound 36-4 of Synthetic Example 2 except for utilizing Intermediate Compound 54-4 instead of Intermediate Compound 36-3.

### 6) Synthesis of Compound 54

Compound 54 (1.9 g, 1.8 mmol) was obtained by utilizing substantially the same manner as in Synthesis of Compound 4 of Synthetic Example 1 except for utilizing Intermediate Compound 54-5 instead of Intermediate Compound 4-8.

### (4) Synthetic Example 4: Synthesis of Compound 63

Compound 63 according to an example may be synthesized by, for example, the steps shown in Reaction Scheme 4:

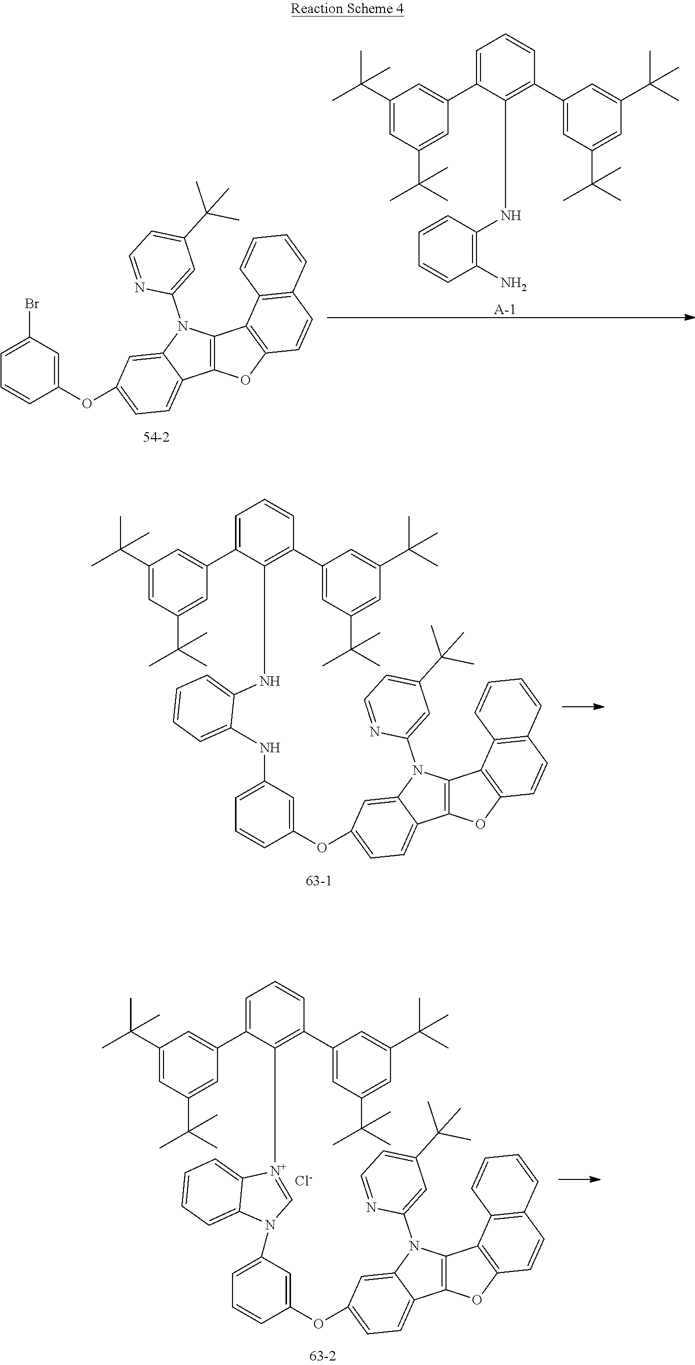

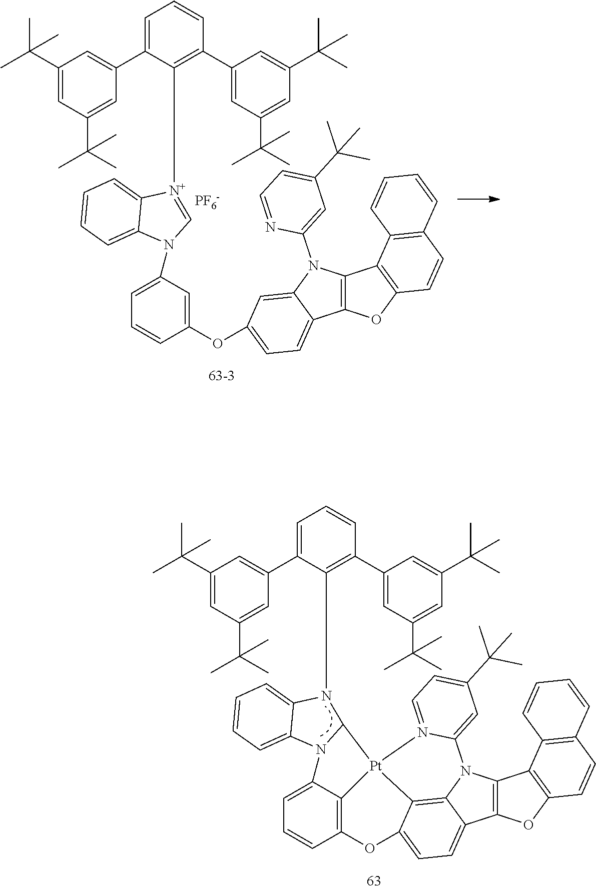

### 1) Synthesis of Intermediate Compound 63-1

Intermediate Compound 63-1 was obtained by utilizing substantially the same manner as in Synthesis of Intermediate Compound 36-2 of Synthetic Example 2 except for utilizing Intermediate Compound 54-2 instead of Intermediate Compound 36-1 and utilizing Intermediate Compound A-1 instead of N1-([1,1′:3′,1″-terphenyl]-2′-yl-2,2″,3,3″,4,4″,5,5″,6,6″-d₁₀)benzene-d₄-1,2-diamine.

### 2) Synthesis of Intermediate Compound 63-2

Intermediate Compound 63-2 was obtained by utilizing substantially the same manner as in Synthesis of Intermediate Compound 36-3 of Synthetic Example 2 except for utilizing Intermediate Compound 63-1 instead of Intermediate Compound 36-2.

### 3) Synthesis of Intermediate Compound 63-3

Intermediate Compound 63-3 was obtained by utilizing substantially the same manner as in Synthesis of Intermediate Compound 36-4 of Synthetic Example 2 except for utilizing Intermediate Compound 63-2 instead of Intermediate Compound 36-3.

### 4) Synthesis of Compound 63

Compound 63 (2.0 g, 1.6 mmol) was obtained by utilizing substantially the same manner as in Synthesis of Compound 4 of Synthetic Example 1 except for utilizing Intermediate Compound [63-3 instead of Intermediate Compound [4-8.

### (5) Synthetic Example 5: Synthesis of Compound 95

Compound 95 according to an example may be synthesized by, for example, the steps shown in Reaction Scheme 5:

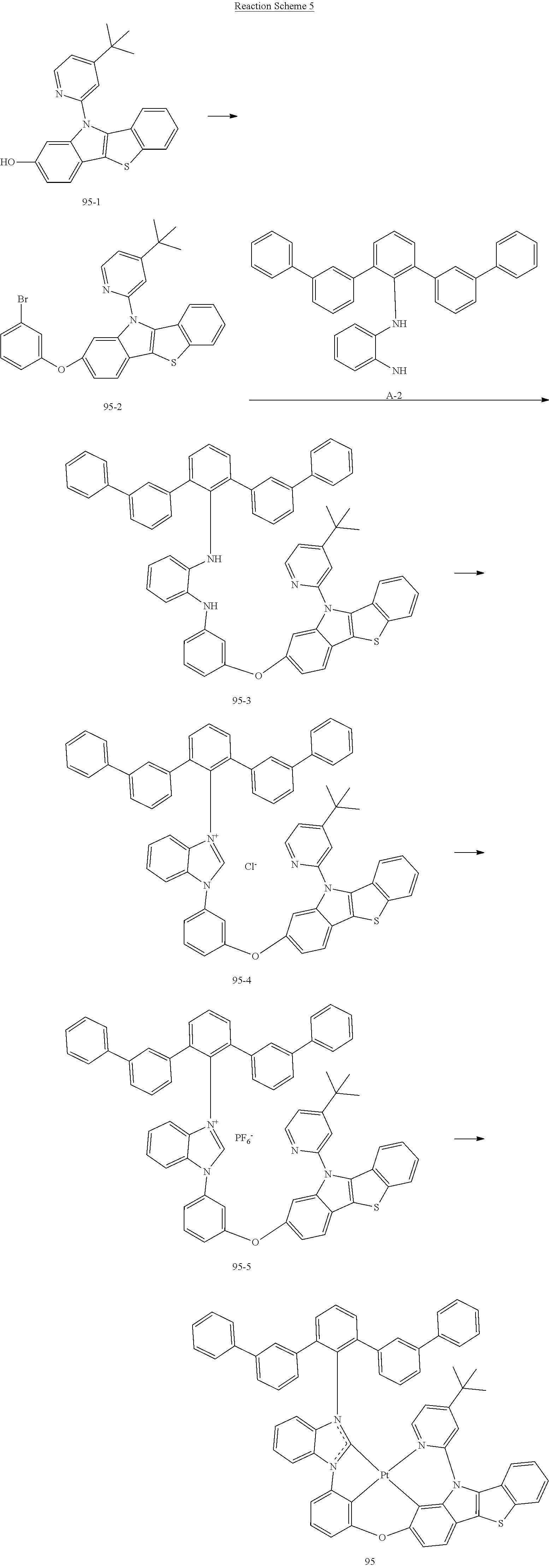

### 1) Synthesis of Intermediate Compound 95-1

Intermediate Compound 95-1 was obtained utilizing 2-bromobenzo[b]thiophene instead of 2-bromobenzofuran as a starting material and utilizing substantially the same condition and manner as in Synthesis of Intermediate Compound 4-1 to Intermediate Compound 4-5 of Synthetic Example 1.

### 2) Synthesis of Intermediate Compound 95-2

Intermediate Compound 95-2 was obtained by utilizing substantially the same manner as in Synthesis of Intermediate Compound 54-2 of Synthetic Example 3 except for utilizing Intermediate Compound 95-1 instead of Intermediate Compound 54-1.

### 3) Synthesis of Intermediate Compound 95-3

Intermediate Compound 95-3 was obtained by utilizing substantially the same manner as in Synthesis of Intermediate Compound 36-2 of Synthetic Example 2 except for utilizing Intermediate Compound 95-2 instead of Intermediate Compound 36-1 and utilizing Intermediate Compound A-2 instead of N1-([1,1′:3′,1″-terphenyl]-2′-yl-2,2″,3,3″,4,4″,5,5″,6,6″-d₁₀)benzene-d₄-1,2-diamine.

### 4) Synthesis of Intermediate Compound 95-4

Intermediate Compound 95-4 was obtained by utilizing substantially the same manner as in Synthesis of Intermediate Compound 36-3 of Synthetic Example 2 except for utilizing Intermediate Compound 95-3 instead of Intermediate Compound 36-2.

### 5) Synthesis of Intermediate Compound 95-5

Intermediate Compound 95-5 was obtained by utilizing substantially the same manner as in Synthesis of Intermediate Compound 36-4 of Synthetic Example 2 except for utilizing Intermediate Compound 95-4 instead of Intermediate Compound 36-3.

### 6) Synthesis of Compound 95

Compound 95 (1.5 g, 1.3 mmol) was obtained by utilizing substantially the same manner as in Synthesis of Compound 4 of Synthetic Example 1 except for utilizing Intermediate Compound 95-5 instead of Intermediate Compound 4-8.

### (6) Synthetic Example 6: Synthesis of Compound 148

Compound 148 according to an example may be synthesized by, for example, the steps shown in Reaction Scheme 6:

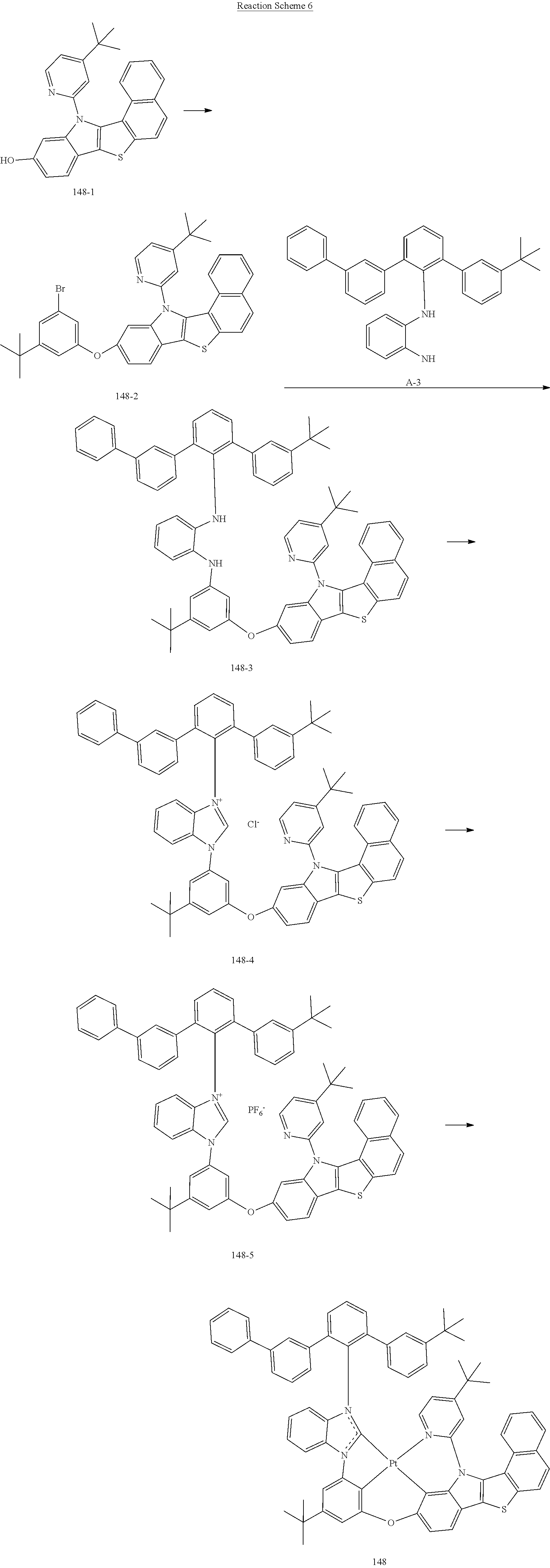

### 1) Synthesis of Intermediate Compound 148-1

Intermediate Compound 148-1 was obtained utilizing 2-bromonaphtho[2,1-b]thiophene instead of 2-bromobenzofuran as a starting material and utilizing substantially the same condition and manner as in Synthesis of Intermediate Compound 4-1 to Intermediate Compound 4-5 of Synthetic Example 1.

### 2) Synthesis of Intermediate Compound 148-2

Intermediate Compound 148-2 was obtained by utilizing substantially the same manner as in Synthesis of Intermediate Compound 36-1 of Synthetic Example 2 except for utilizing Intermediate Compound 148-1 instead of Intermediate Compound 4-5 and utilizing 1,3-dibromo-5-(t-butyl)benzene instead of 3,5-dibromo-1,1′-biphenyl.

### 3) Synthesis of Intermediate Compound 148-3

Intermediate Compound 148-3 was obtained by utilizing substantially the same manner as in Synthesis of Intermediate Compound 36-2 of Synthetic Example 2 except for utilizing Intermediate Compound 148-2 instead of Intermediate Compound 36-1 and utilizing Intermediate Compound A-3 instead of N1-([1,1′:3′,1″-terphenyl]-2′-yl-2,2″,3,3″,4,4″,5,5″,6,6″-d₁₀)benzene-d₄-1,2-diamine.

### 4) Synthesis of Intermediate Compound 148-4

Intermediate Compound 148-4 was obtained by utilizing substantially the same manner as in Synthesis of Intermediate Compound 36-3 of Synthetic Example 2 except for utilizing Intermediate Compound 148-3 instead of Intermediate Compound 36-2.

### 5) Synthesis of Intermediate Compound 148-5

Intermediate Compound 148-5 was obtained by utilizing substantially the same manner as in Synthesis of Intermediate Compound 36-4 of Synthetic Example 2 except for utilizing Intermediate Compound 148-4 instead of Intermediate Compound 36-3.

### 6) Synthesis of Compound 148

Compound 148 (3.4 g, 2.8 mmol) was obtained by utilizing substantially the same manner as in Synthesis of Compound 4 of Synthetic Example 1 except for utilizing Intermediate Compound 148-5 instead of Intermediate Compound 4-8.

### (7) Synthetic Example 7: Synthesis of Compound 162

Compound 162 according to an example may be synthesized by, for example, the steps shown in Reaction Scheme 7:

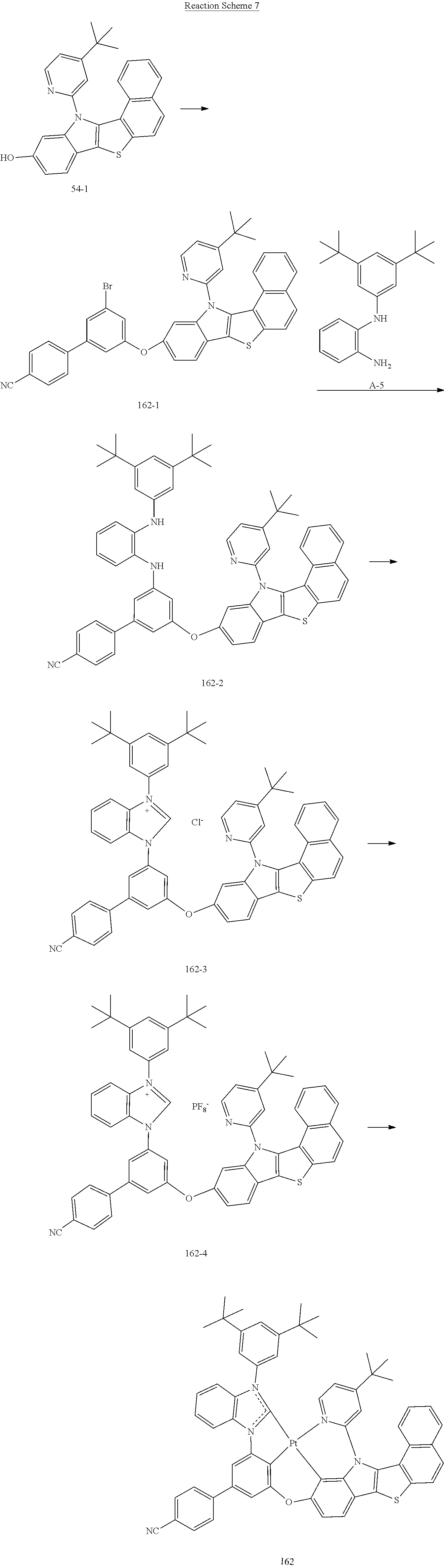

### 1) Synthesis of Intermediate Compound 162-1

Intermediate Compound 162-1 was obtained by utilizing substantially the same manner as in Synthesis of Intermediate Compound 36-1 of Synthetic Example 2 except for utilizing Intermediate Compound 54-1 instead of Intermediate Compound 4-5 and utilizing Intermediate Compound [A-4 instead of 3,5-dibromo-1,1′-biphenyl.

### 2) Synthesis of Intermediate Compound 162-2

Intermediate Compound 162-2 was obtained by utilizing substantially the same manner as in Synthesis of Intermediate Compound 36-2 of Synthetic Example 2 except for utilizing Intermediate Compound 162-1 instead of Intermediate Compound 36-1 and utilizing Intermediate Compound A-5 instead of N1-([1,1′:3′,1″-terphenyl]-2′-yl-2,2″,3,3″,4,4″,5,5″,6,6″-d₁₀)benzene-d₄-1,2-diamine.

### 3) Synthesis of Intermediate Compound 162-3

Intermediate Compound 162-3 was obtained by utilizing substantially the same manner as in Synthesis of Intermediate Compound 36-3 of Synthetic Example 2 except for utilizing Intermediate Compound 162-2 instead of Intermediate Compound 36-2.

### 4) Synthesis of Intermediate Compound 162-4

Intermediate Compound 162-4 was obtained by utilizing substantially the same manner as in Synthesis of Intermediate Compound 36-4 of Synthetic Example 2 except for utilizing Intermediate Compound 162-3 instead of Intermediate Compound 36-3.

### 5) Synthesis of Compound 162

Compound 162 (2.6 g, 2.4 mmol) was obtained by utilizing substantially the same manner as in Synthesis of Compound 4 of Synthetic Example 1 except for utilizing Intermediate Compound 162-4 instead of Intermediate Compound 4-8.

### (8) Synthetic Example 8: Synthesis of Compound 175

Compound 175 according to an example may be synthesized by, for example, the steps shown in Reaction Scheme 8:

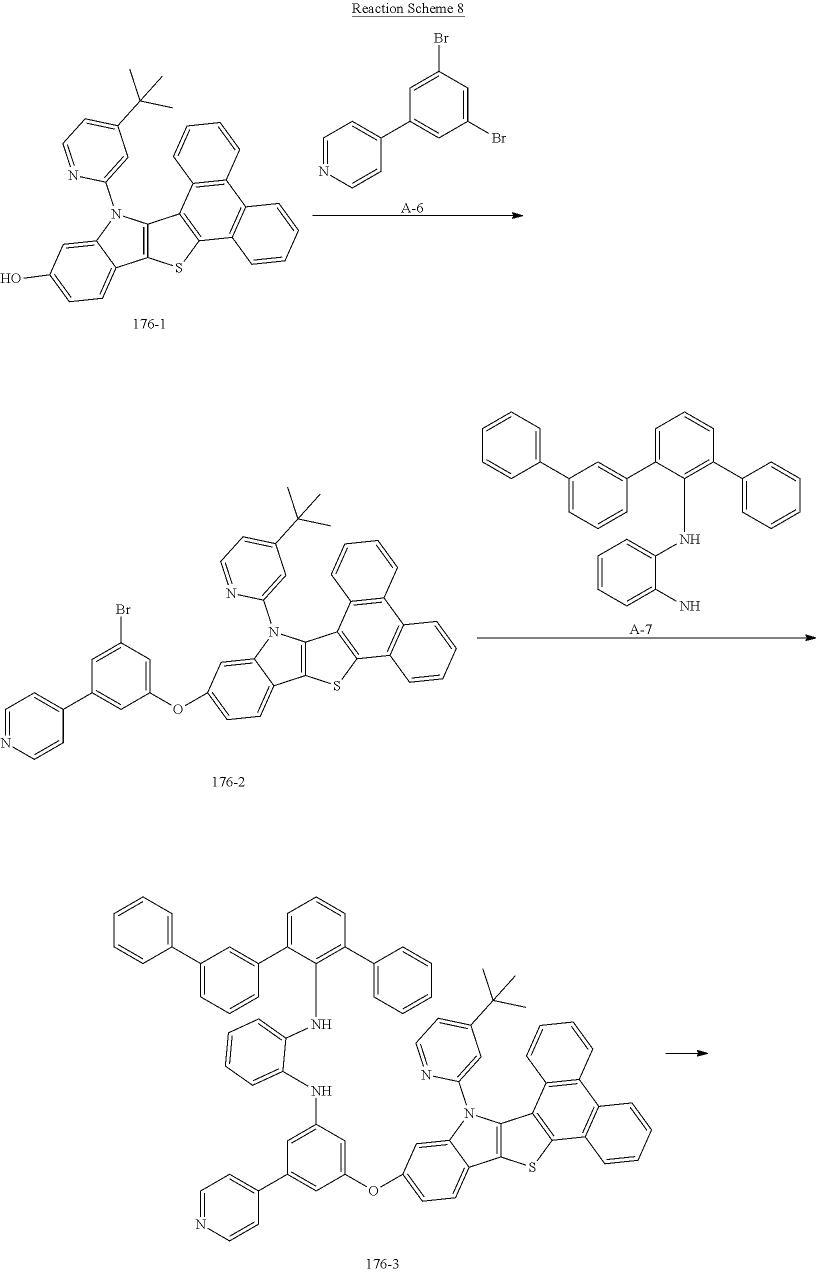

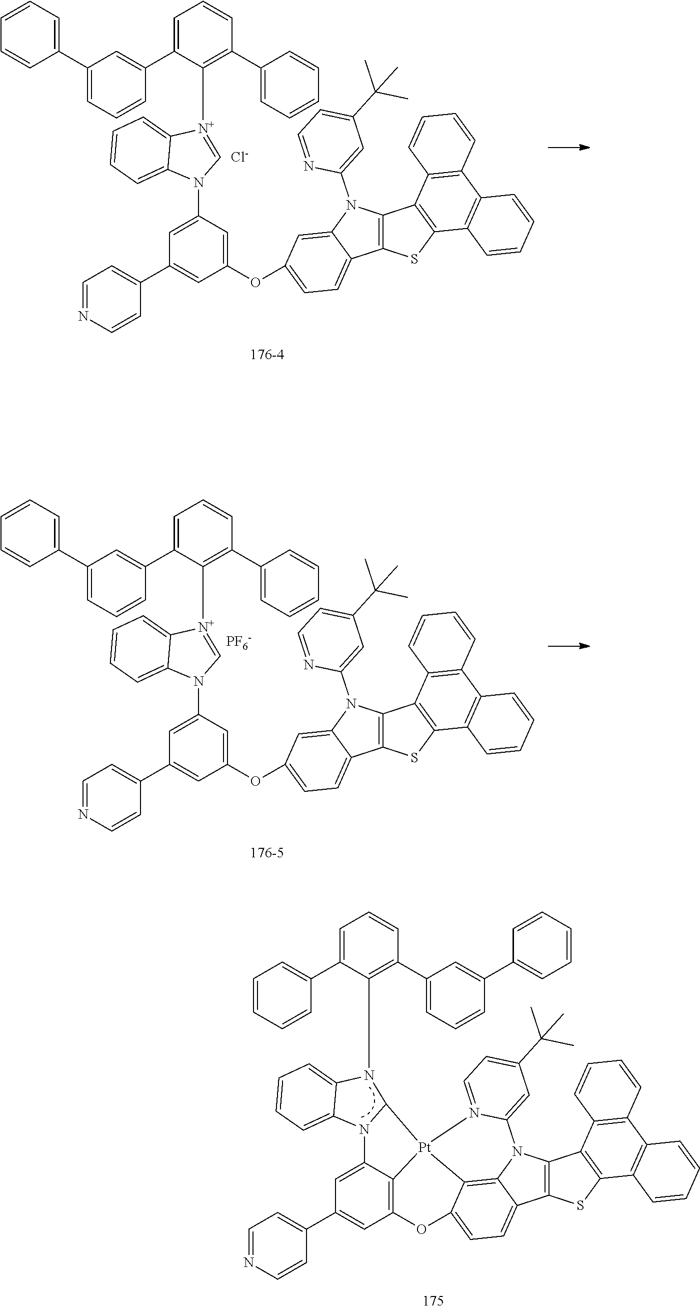

### 1) Synthesis of Intermediate Compound 175-1PG-3C

Intermediate Compound 175-1 was obtained utilizing 2-bromophenanthro[9,10-b]thiophene instead of 2-bromobenzofuran as a starting material and utilizing substantially the same condition and manner as in Synthesis of Intermediate Compound 4-1 to Intermediate Compound 4-5 of Synthetic Example 1

### 2) Synthesis of Intermediate Compound 175-2

Intermediate Compound 175-2 was obtained by utilizing substantially the same manner as in Synthesis of Intermediate Compound 36-1 of Synthetic Example 2 except for utilizing Intermediate Compound 175-1 instead of Intermediate Compound 4-5 and utilizing Intermediate Compound A-6 instead of 3,5-dibromo-1,1′-biphenyl.

### 3) Synthesis of Intermediate Compound 175-3

Intermediate Compound 175-3 was obtained by utilizing substantially the same manner as in Synthesis of Intermediate Compound 36-2 of Synthetic Example 2 except for utilizing Intermediate Compound 175-2 instead of Intermediate Compound 36-1 and utilizing Intermediate Compound A-7 instead of N1-([1,1′:3′,1″-terphenyl]-2′-yl-2,2″,3,3″,4,4″,5,5″,6,6″-d₁₀)benzene-d₄-1,2-diamine.

### 4) Synthesis of Intermediate Compound 175-4

Intermediate Compound 175-4 was obtained by utilizing substantially the same manner as in Synthesis of Intermediate Compound 36-3 of Synthetic Example 2 except for utilizing Intermediate Compound 175-3 instead of Intermediate Compound 36-2.

### 5) Synthesis of Intermediate Compound 175-5

Intermediate Compound 175-5 was obtained by utilizing substantially the same manner as in Synthesis of Intermediate Compound 36-4 of Synthetic Example 2 except for utilizing Intermediate Compound 175-4 instead of Intermediate Compound 36-3.

### 6) Synthesis of Compound 175

Compound 175 (1.9 g, 1.5 mmol) was obtained by utilizing substantially the same manner as in Synthesis of Compound 4 of Synthetic Example 1 except for utilizing Intermediate Compound 175-5 instead of Intermediate Compound 4-8.

¹H NMR and MS/FAB in the synthesized compounds in Synthetic Examples above are shown in Table 1.

The synthetic methods of other compounds in addition to the compounds shown in Table 1 may be recognized by those skilled in the art with reference to the above synthetic path and raw materials.

TABLE 1

| Compound | | MS/FAB | |
|---|---|---|---|
| No. | ¹H NMR (CDCl₃, 400 MHz) | found | calc. |
| 4 | δ 8.71(d, 1H), 8.37(d, 1H), 7.70-7.65(m, 2H), | 817.2019 | 817.2017 |
| | 7.41-7.36(m, 6H), 7.21-7.15(m, 4H), 7.00- | | |
| | 6.96(m, 5H), 6.68-6.66(m, 2H), 1.32(s, 9H) | | |
| 36 | δ 8.72(d, 1H), 8.38(d, 1H), 8.20(d, 2H), 7.75- | 1055.3582 | 1055.3583 |
| | 7.70(m, 4H), 7.49-7.40(m, 7H), 7.20-7.15(m, | | |
| | 3H), 6.99-6.95(m, 4H), 6.69(d, 1H), 1.32(s, 9H) | | |
| 54 | δ 8.73(d, 1H), 8.54(d, 1H), 8.39(d, 1H), | 1029.3428 | 1029.3427 |
| | 8.20(d, 2H), 7.99(d, 1H), 7.61-7.55(m, 4H), | | |
| | 7.41-7.39(m, 3H), 7.17-7.15(m, 3H), 6.99- | | |
| | 6.95(m, 3H), 6.69-6.67(m, 2H), 1.33(s, 9H) | | |
| 63 | δ 8.73(d, 1H), 8.54(d, 1H), 8.39(d, 1H), | 1243.5305 | 1243.5303 |
| | 8.20(d, 2H), 7.99(d, 1H), 7.73-7.71(m, 4H), | | |
| | 7.60-7.55(m, 6H), 7.41-7.39(m, 3H), 7.17- | | |
| | 7.15(m, 3H), 6.99-6.95(m, 3H), 6.69-6.67(m, | | |
| | 2H), 1.40(s, 36H), 1.33(s, 9H) | | |
| 95 | δ 8.74(d, 1H), 8.38(d, 1H), 8.20(d, 2H), | 1137.3039 | 1137.3040 |
| | 8.05(d, 1H), 7.95-7.93(m, 3H), 7.75-7.72(m, | | |
| | 6H), 7.62-7.61(m, 4H), 7.49-7.41(m, 11H), | | |
| | 7.16-7.13(m, 3H), 6.99-6.95(m, 3H), 6.69- | | |
| | 6.66(m, 2H), 1.32(s, 9H) | | |
| 148 | δ 8.73(d, 1H), 8.53(d, 1H), 8.38(d, 1H), | 1223.4138 | 1223.4136 |
| | 8.20(d, 2H), 7.99-7.95(m, 3H), 7.80-7.75(m, | | |
| | 5H), 7.61-7.40(m, 12H), 7.31(d, 1H), 7.14- | | |
| | 7.12(m, 3H), 6.96-6.95(m, 2H), 6.70-6.69(m, | | |
| | 2H), 1.43(s, 9H), 1.35(s, 9H), 1.31(s, 9H) | | |
| 162 | δ 8.74(d, 1H), 8.54(d, 1H), 8.38(d, 1H), | 1080.3692 | 1080.3690 |
| | 7.99(d, 1H), 7.85-7.83(m, 4H), 7.60-7.55(m, | | |
| | 4H), 7.43-7.41(m, 2H), 7.12(s, 1H), 7.20- | | |
| | 7.13(m, 4H), 6.99-6.95(m, 4H), 6.68(d, 1H), | | |
| | 1.42(s, 18H), 1.32(s, 9H) | | |
| 175 | δ 9.01(d, 1H), 8.97(d, 1H), 8.74-8.72(m, 3H), | 1238.3308 | 1238.3306 |
| | 8.38(d, 1H), 8.20-8.11(m, 4H), 8.00(d, 2H), | | |
| | 7.95(s, 1H), 7.75-7.61(m, 9H), 7.61-7.41(m, | | |
| | 9H), 7.14-7.10(m, 4H), 6.98-6.95(m, 4H), | | |
| | 6.69(d, 1H), 1.32(s, 9H) | | |

### 2. DFT (Density Functional Theory) Calculation of Example Compound and Comparative Example Compound

The structures of Example Compound 54 and Comparative Example Compounds 1 to 3 were enhanced or optimized by DFT calculation. The DFT calculation was performed by utilizing program Gaussian09. Geometric shapes were enhanced or optimized by utilizing B3LYP/6-311g(d,p)/LANL2DZ. The excited state energy was calculated by energy differences between the optimized singlet ground state geometric shape and the triplet ground state geometric shape, and the results are shown in Table 2. The calculation obtained by the confirmed DFT function set and basic set is theoretical. The calculation protocol such as Gaussian09 having B3LYP/6-311g(d,p)/LANL2DZ protocol utilized herein is dependent on the assumption that electron effects are additional, and thus a bigger basic set may be utilized to assume a complete basic set limit.

Changes in the highest occupied molecular orbital (HOMO) energy level, the lowest unoccupied molecular orbital (LUMO), energy level, Emission wavelength, and/or the like with respect to the structurally related compounds are expected to be similar. Therefore, the absolute errors caused by the utilization of B3LYP may be more significant than other calculation methods, but relative differences between HOMO, LUMO, and T1 values calculated by the B3LYP protocol are expected to be experimentally reproduced.

TABLE 2

| | | | | Calculated |
|---|---|---|---|---|
| | | Calculated | Calculated | Emission |
| | | HOMO | LUMO | wavelength |
| Division | Structure | (eV) | (eV) | (nm) |
| Example Compound 54 | 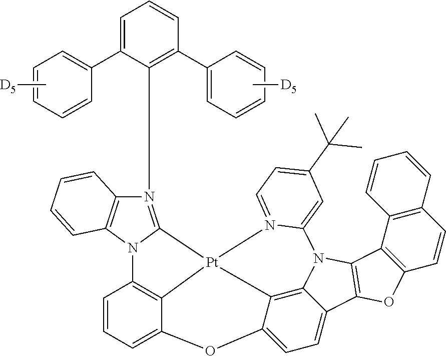 | −4.77 | −1.54 | 511 |
| Comparative Example Compound 1 | 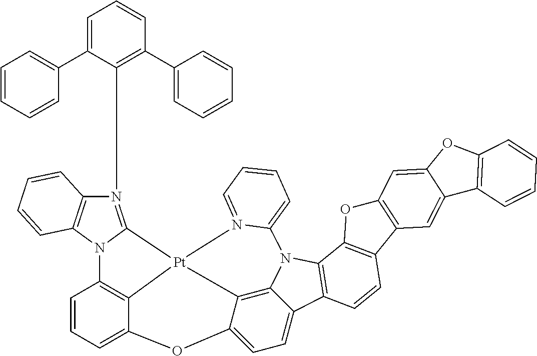 | −4.93 | −1.58 | 470 |
| Comparative Example Compound 2 | 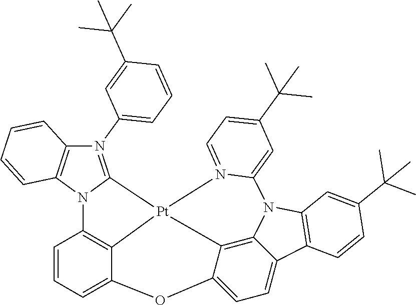 | −4.85 | −1.45 | 459 |
| Comparative Example Compound 3 | 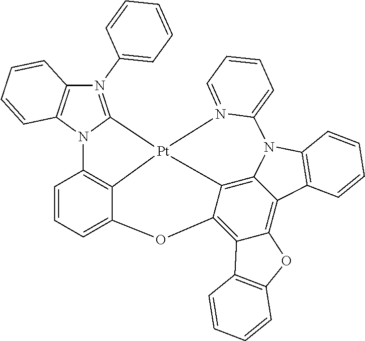 | −4.98 | −1.66 | 462 |

Referring to Table 2, it may be seen that Example Compound 54 and Comparative Example Compounds 1, 2, and 3 have similar skeleton structures, but light emitting regions are clearly different judging from the DFT (Density Functional Theory) calculation results. It may be seen that Example Compound 54 emits green phosphorescence, and Comparative Example Compounds 1, 2, and 3 emit blue light.

### 3. Manufacture and Evaluation of Light Emitting Elements

### (1) Manufacture of Light Emitting Elements

Light emitting elements including the organometallic compound of an example or Comparative Example Compound in the emission layer were manufactured as follows. Compounds 4, 36, 54, 63, 95, 148, 162, and 175 which are the organometallic compounds of examples were utilized as a dopant material for the emission layer to manufacture the light emitting elements of Examples 1 to 8, respectively. The light emitting element of Comparative Example 1 was manufactured by utilizing Comparative Example Compound, Ir(PPy)₃ as a dopant material for the emission layer.

### 1) Example 1

For a positive electrode, an ITO glass substrate of about 15 Ω/cm² (about 1,200 Å) made by Corning Co. was cut to a size of about 50 mm×50 mm×0.7 mm, cleansed by ultrasonic waves utilizing isopropyl alcohol for about five minutes and pure water for about five minutes, and then irradiated with ultraviolet rays for about 30 minutes and exposed to ozone and cleansed. The ITO glass substrate was installed on a vacuum deposition apparatus. On the upper portion of the ITO glass substrate, the compound, 2-TNATA, was first deposited in vacuum to form a 600 Å-thick hole injection layer, and then N,N′-di(naphthalen-1-yl)-N,N′-diphenyl-benzidine (hereinafter, NPB) as a hole transporting compound was deposited in vacuum to form a 300 Å-thick hole transport layer. On the upper portion of the hole transport layer, Compound 4 of the present disclosure as 10% dopant proportion and 3,3-di(9H-carbazol-9-yl)biphenyl (mCBP) as host were co-deposited to form a 300 Å-thick emission layer in a green phosphorescence emission layer. Then, TSPO1 (diphenyl(4-(triphenylsilyl)phenyl)-phosphine oxide) was deposited in vacuum to form a 50 Å-thick hole blocking layer. Then, on the upper portion of the hole blocking layer, Alq3 was deposited to form a 300 Å-thick electron transport layer, LiF that is an alkaline metal halide was deposited on the upper portion of the electron transport layer to form a 10 Å-thick electron injection layer, and Al was deposited in vacuum to form a 3,000 Å-thick LiF/Al electrode (negative electrode), thereby manufacturing a light emitting element.

### 2) Example 2

A light emitting element was manufactured in substantially the same manner as in Example 1 except for utilizing Compound 36 instead of Compound 4 when the green emission layer was formed.

### 3) Example 3

A light emitting element was manufactured in substantially the same manner as in Example 1 except for utilizing Compound 54 instead of Compound 4 when the green emission layer was formed.

### 4) Example 4

A light emitting element was manufactured in substantially the same manner as in Example 1 except for utilizing Compound 63 instead of Compound 4 when the green emission layer was formed.

### 5) Example 5

A light emitting element was manufactured in substantially the same manner as in Example 1 except for utilizing Compound 95 instead of Compound 4 when the green emission layer was formed.

### 6) Example 6

A light emitting element was manufactured in substantially the same manner as in Example 1 except for utilizing Compound 148 instead of Compound 4 when the green emission layer was formed.

### 7) Example 7

A light emitting element was manufactured in substantially the same manner as in Example 1 except for utilizing Compound 162 instead of Compound 4 when the green emission layer was formed.

### 8) Example 8

A light emitting element was manufactured in substantially the same manner as in Example 1 except for utilizing Compound 175 instead of Compound 4 when the green emission layer was formed.

### 9) Comparative Example 1

A light emitting element was manufactured in substantially the same manner as in Example 1 except for utilizing Ir(PPy)₃ that is a generally utilized/generally available green phosphorescence dopant, instead of Compound 4, when the green emission layer was formed.

### Example Compounds

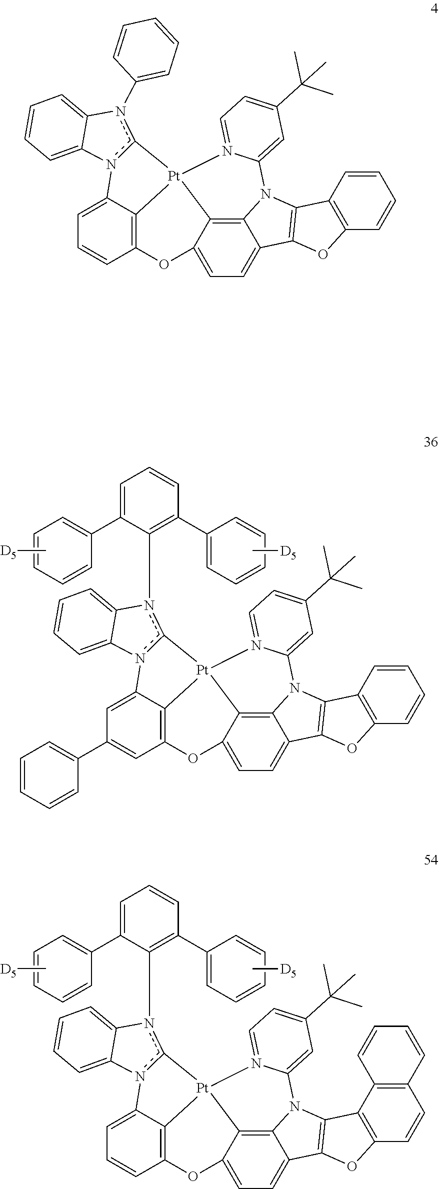

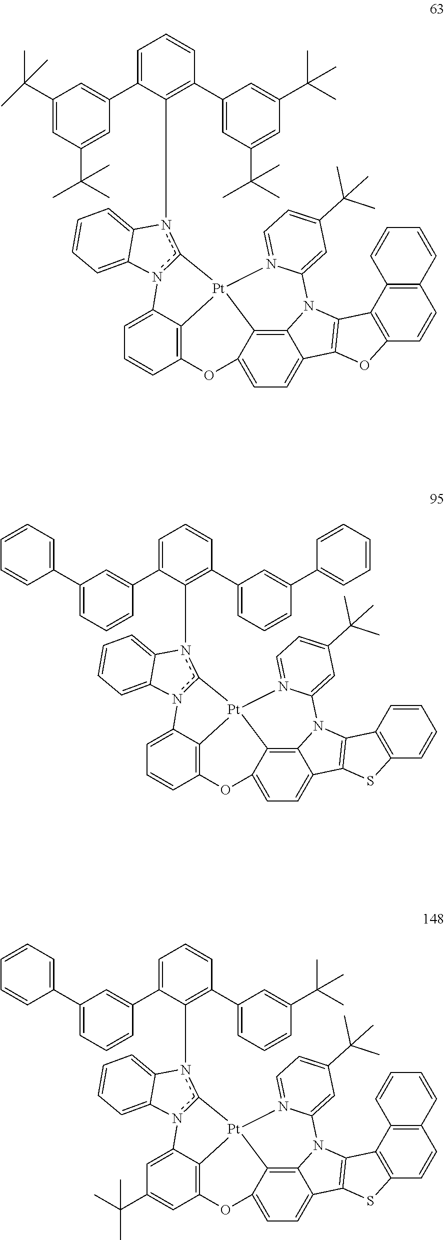

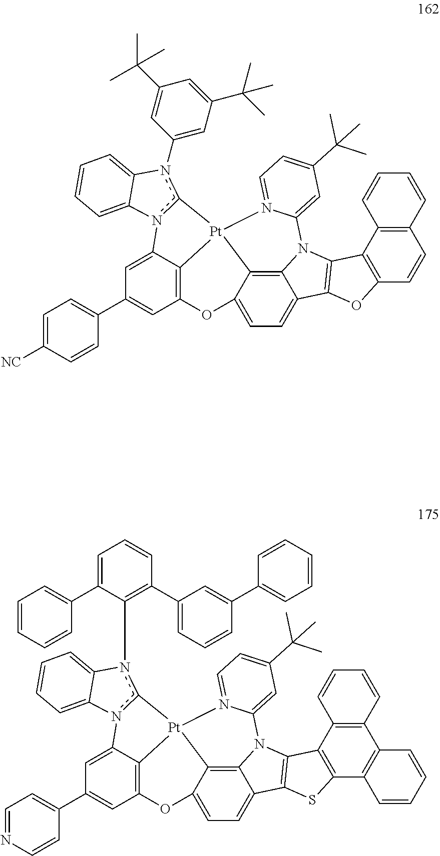

### Comparative Example Compounds

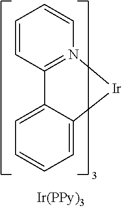

### Materials Used to Manufacture Light Emitting Elements

Compounds utilized for manufacturing the light emitting elements of Examples and Comparative Examples are disclosed below. The compounds below are generally utilized/generally available materials, and commercial products were subjected to sublimation purification and utilized to manufacture the light emitting elements.

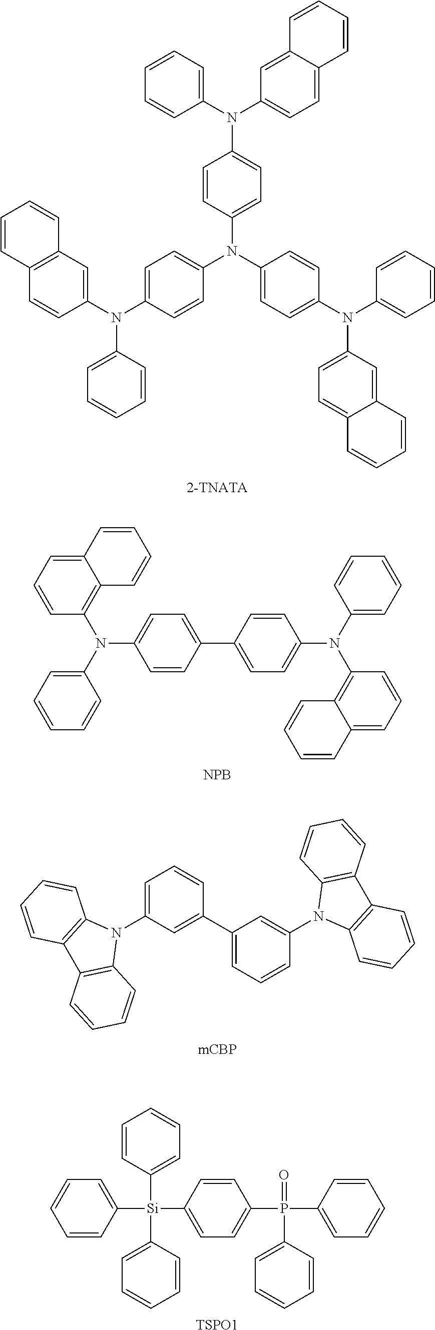

### (2) Evaluation of Light Emitting Element Characteristics

Characteristics of the light emitting elements manufactured with Example Compounds 4, 36, 54, 63, 95, 148, 162, and 175, and Comparative Example Compound, Ir(PPy)₃, as described above were evaluated. Characteristics of the manufactured light emitting elements were evaluated utilizing a brightness distribution characteristics measurement device. To evaluate the characteristics of the light emitting elements according to Examples and Comparative Examples, the driving voltage, brightness, luminous efficiency, luminous color, light emission wavelength, and service life (T₈₀) were measured. With respect to the manufactured light emitting elements, driving voltage (V), luminous efficiency (cd/A) at a current density of 50 mA/cm², and brightness (cd/n²) are shown in Table 3. In some embodiments, a service life (T₈₀) that is a time taken to reduce the brightness to 80% level with respect to a brightness of 1,000 nit is shown in Table 3. The service life (T₈₀) was measured by substantially continuous driving at a current density (J) of 40 mA/cm². In some embodiments, a brightness spectrum in Examples and Comparative Examples was measured with a spectroradiometer. An emission peak, i.e., the maximum emission wavelength was measured from the measured brightness spectrum.

TABLE 3

| | | | | | | | Service |
|---|---|---|---|---|---|---|---|
| | | | | | | | life |
| | | | | | | | (T₈₀@ |
| | | Driving | | Luminous | | Emission | J = 40 |
| | Emission | voltage | Brightness | Efficiency | Luminous | wavelength | mA/cm²) |
| | layer | (V) | (cd/m²) | (cd/A) | color | (nm) | (hr) |
| Example 1 | 4 | 5.15 | 4030 | 8.05 | Green | 504 | 320 |
| Example 2 | 36 | 5.21 | 4265 | 8.50 | Green | 523 | 460 |
| Example 3 | 54 | 5.26 | 4210 | 8.40 | Green | 518 | 420 |
| Example 4 | 63 | 5.10 | 4285 | 8.55 | Green | 519 | 389 |
| Example 5 | 95 | 5.05 | 4195 | 8.36 | Green | 515 | 355 |
| Example 6 | 148 | 5.20 | 4120 | 8.21 | Green | 527 | 411 |
| Example 7 | 162 | 5.01 | 4140 | 8.25 | Green | 530 | 390 |
| Example 8 | 175 | 5.18 | 4180 | 8.33 | Green | 535 | 370 |
| Comparative | Ir(PPy)₃ | 6.74 | 3870 | 7.74 | Green | 516 | 278 |
| Example 1 | | | | | | | |

Referring to Table 3, it may be confirmed that Examples of the light emitting elements in which the organometallic compounds according to examples of the present disclosure are utilized as a green phosphorescence dopant material have improved luminous efficiencies and element service lives compared with Comparative Example 1. In some embodiments, it may be confirmed that Examples have excellent or suitable brightness and exhibit low driving voltage characteristics compared with Comparative Example 1.

The organometallic compound of an example includes tetradentate ligands bonded to the central metal atom such as Pt, and one ligand among the tetradentate ligands includes an indole moiety in which a heterocycle is fused. For example, in the organometallic compound of an example, a 5-membered heterocycle containing O or S as a ring-forming atom is directly linked to the 5-membered pyrrole ring of the indole and a fused ring composed of at least four 5-membered and 6-membered rings is included, and thus green light with high purity may be exhibited. In some embodiments, the light emitting element according to an embodiment of the present disclosure may exhibit low driving voltage, excellent or suitable luminous efficiency, and improved service life characteristics by applying the organometallic compound of an example to the emission layer.

The light emitting element of an embodiment includes the organometallic compound of an embodiment, and thus may exhibit an excellent or suitable color purity, and also low driving voltage, long service life, and high luminous efficiency characteristics.

The organometallic compound of an embodiment may contribute to the exhibition of low driving voltage characteristics by the light emitting element and the improvement in luminous efficiency and service life characteristics.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting element comprising:
a first electrode;
a second electrode on the first electrode; and
an emission layer which is between the first electrode and the second electrode and comprises an organometallic compound represented by Formula 1, 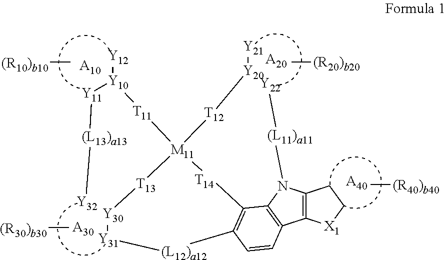
wherein, in Formula 1,
M₁₁ is Pt, Pd, Cu, Ag, Au, Rh, Ir, Ru, Os, Ti, Zr, Hf, Eu, Tb, or Tm,
X₁ is O or S,
Y₁₀, Y₁₁, Y₁₂, Y₂₀, Y₂₁, Y₂₂, Y₃₀, Y₃₁, and Y₃₂ are each independently N, C, NRₐ, or CR_{b},
T₁₁ to T₁₄ are each independently a direct linkage, *—O—*′, or *—S—*′,
L₁₁ to L₁₃ are each independently a direct linkage, *—O—*′, *—S—*′, *—C(R₁)(R₂)—*′, *—C(R₁)═*′, *═C(R₁)—*′, *—C(R₁)═C(R₂)—*′, *—C(═O)—*′, *—C(═S)—*′, *—C≡C—*′, *—B(R₁)—*′, *—N(R₁)—*′, *—P(R₁)—*′, *—Si(R₁)(R₂)—*′, or *—Ge(R₁)(R₂)—*′,
a11 to a13 are each independently an integer from 0 to 3,
rings A₁₀, A₂₀, A₃₀, and A₄₀ are each independently a substituted or unsubstituted hydrocarbon ring having 5 to 60 ring-forming carbon atoms, or a substituted or unsubstituted heterocycle having 2 to 60 ring-forming carbon atoms,
Rₐ, R_{b}, R₁, R₂, R₁₀, R₂₀, R₃₀, and R₄₀ are each independently a hydrogen atom, a deuterium atom, —F, —Cl, —Br, —I, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂), and/or bonded to an adjacent group to form a ring,
b10, b20, b30, and b40 are each independently an integer from 0 to 8,
Q₁ to Q₃ are each independently a hydrogen atom, a deuterium atom, a halogen atom, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms, and
and *′ are linkage positions.

2. The light emitting element of claim 1, wherein the emission layer is configured to emit green phosphorescence.

3. The light emitting element of claim 1, wherein the emission layer comprises a host and a dopant, and
the dopant comprises the organometallic compound represented by Formula 1.

4. The light emitting element of claim 1, wherein the organometallic compound represented by Formula 1 is represented by Formula 2: 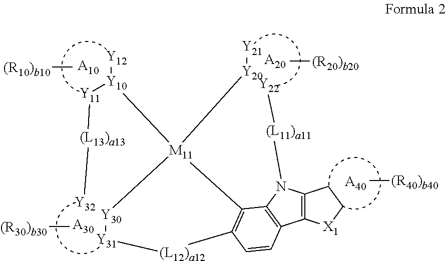
wherein, in Formula 2,
M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, L₁₁ to L₁₃, a11 to a13, R₁₀, R₂₀, R₃₀, R₄₀, b10, b20, b30, and b40 are the same as defined in Formula 1.

5. The light emitting element of claim 1, wherein the organometallic compound represented by Formula 1 is represented by Formula 3: 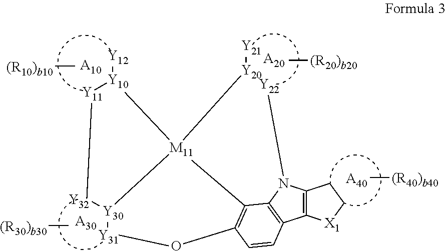
wherein, in Formula 3, M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, R₁₀, R₂₀, R₃₀, R₄₀, b10, b20, b30, and b40 are the same as defined in Formula 1.

6. The light emitting element of claim 5, wherein the organometallic compound represented by Formula 3 is represented by any one selected from among Formula 3-1 to Formula 3-3: 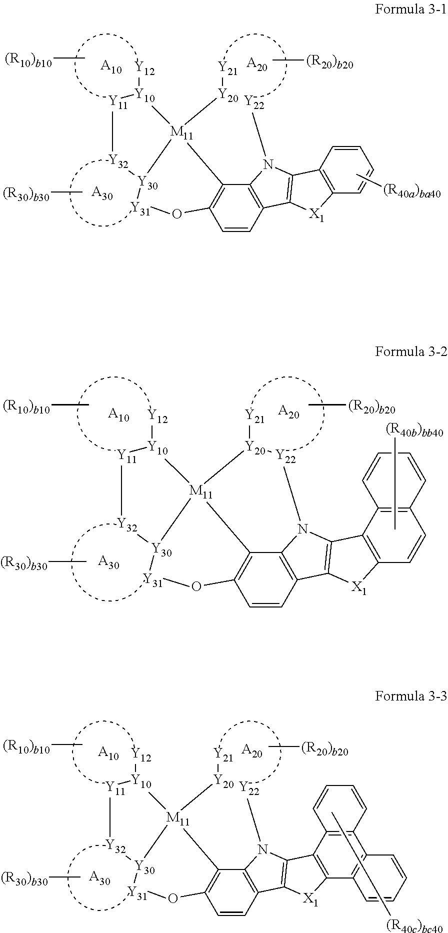
wherein, in Formula 3-1 to Formula 3-3,
R₄₀ₐ to R_{40c} are each independently a hydrogen atom or a deuterium atom,
ba40 is an integer from 0 to 4, bb40 is an integer from 0 to 6, and bc40 is an integer from 0 to 8, and
M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, R₁₀, R₂₀, R₃₀, b10, b20, and b30 are the same as defined in Formula 1.

7. The light emitting element of claim 1, wherein the organometallic compound represented by Formula 1 is represented by Formula 4: 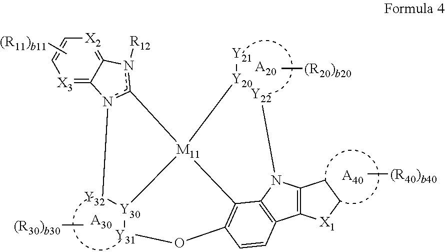
wherein, in Formula 4,
X₂ and X₃ are each independently CRₓ or N,
Rₓ and R₁₁ are each independently a hydrogen atom, a deuterium atom, a substituted or unsubstituted alkyl group having 1 to 60 carbon atoms, or a substituted or unsubstituted aryl group having 6 to 60 ring-forming carbon atoms,
b11 is an integer from 0 to 2,
R₁₂ is a substituted or unsubstituted aryl group having 6 to 60 ring-forming carbon atoms, or a substituted or unsubstituted heteroaryl group having 2 to 60 ring-forming carbon atoms, and
M₁₁, X₁, Y₂₀, Y₂₁, Y₂₂, Y₃₀, Y₃₁, Y₃₂, A₂₀, A₃₀, A₄₀, R₂₀, R₃₀, R₄₀, b20, b30, and b40 are the same as defined in Formula 1.

8. The light emitting element of claim 7, wherein the organometallic compound represented by Formula 4 is represented by Formula 5: 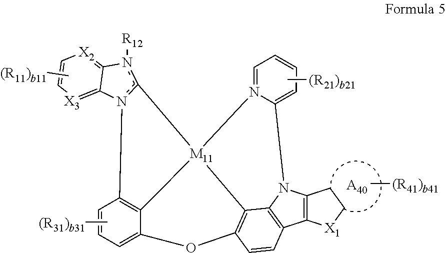
wherein, in Formula 5,
R₂₁, R₃₁, and R₄₁ are each independently a hydrogen atom, a deuterium atom, a cyano group, a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, Si(Q₁)(Q₂)(Q₃), or —N(Q₁)(Q₂),
b21 is an integer from 0 to 4, b31 is an integer from 0 to 3, and b41 is an integer from 0 to 8, and
A₄₀, X₁, M₁₁, and Q₁ to Q₃ are the same as defined in Formula 1, and X₂, X₃, R₁₁, R₁₂, and b11 are the same as defined in Formula 4.

9. The light emitting element of claim 8, wherein the organometallic compound represented by Formula 5 is represented by any one selected from among Formula 5-1 to Formula 5-3: 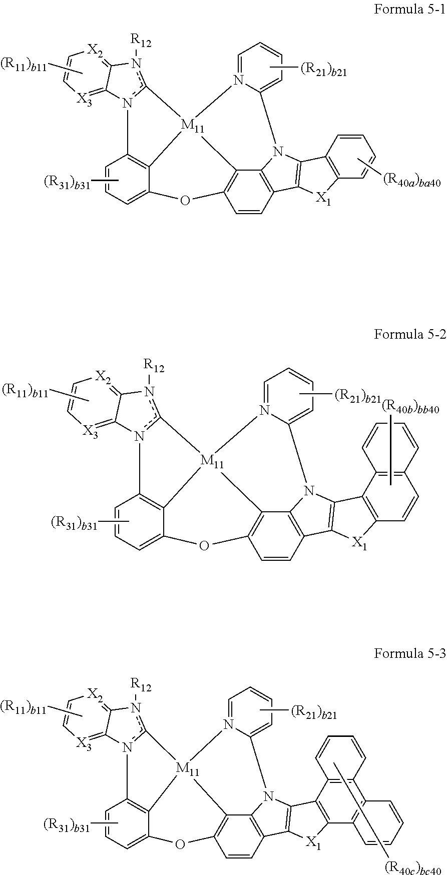
wherein, in Formula 5-1 to Formula 5-3,
R₄₀ₐ to R_{40c} are each independently a hydrogen atom or a deuterium atom,
ba40 is an integer from 0 to 4, bb40 is an integer from 0 to 6, and bc40 is an integer from 0 to 8, and
M₁₁, X₁, X₂, X₃, R₁₁, R₁₂, R₂₁, R₃₁, b11, b21, and b31 are the same as defined in Formula 5.

10. The light emitting element of claim 7, wherein R₁₂ is represented by any one selected from among R12-1 to R12-32:

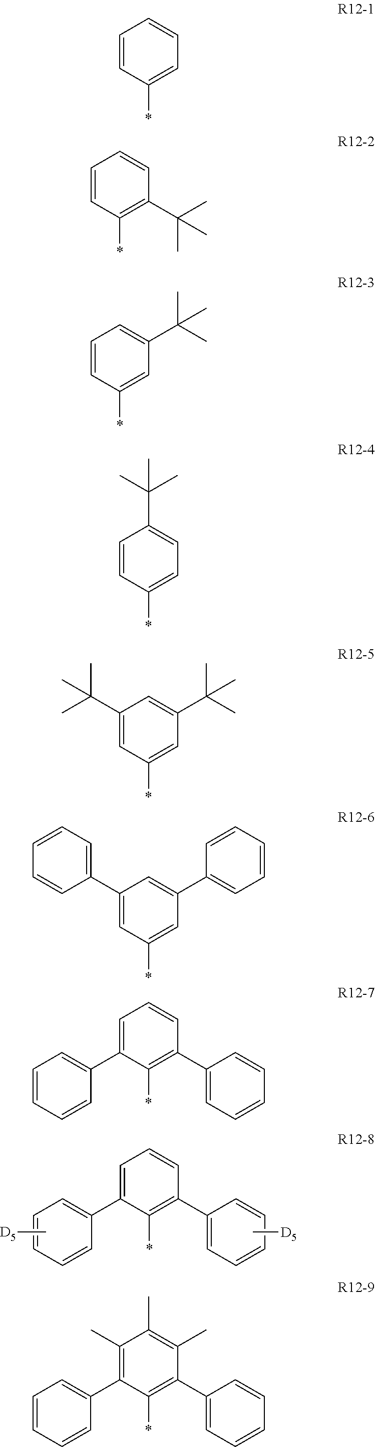

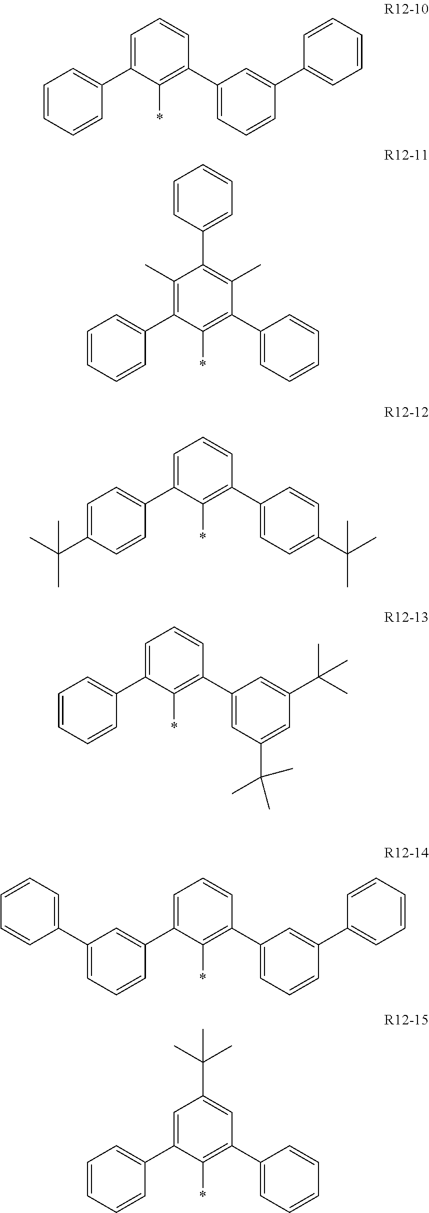 [SMILES: *c1c(-c2ccccc2)cccc1-c1cccc(-c2ccccc2)c1 ; *c1c(-c2ccccc2)c(C)c(-c2ccccc2)c(C)c1-c1ccccc1 ; *c1c(-c2ccc(C(C)(C)C)cc2)cccc1-c1ccc(C(C)(C)C)cc1 ; *c1c(-c2ccccc2)cccc1-c1cc(C(C)(C)C)cc(C(C)(C)C)c1 ; *c1c(-c2cccc(-c3ccccc3)c2)cccc1-c1cccc(-c2ccccc2)c1 ; *c1c(-c2ccccc2)cc(C(C)(C)C)cc1-c1ccccc1]

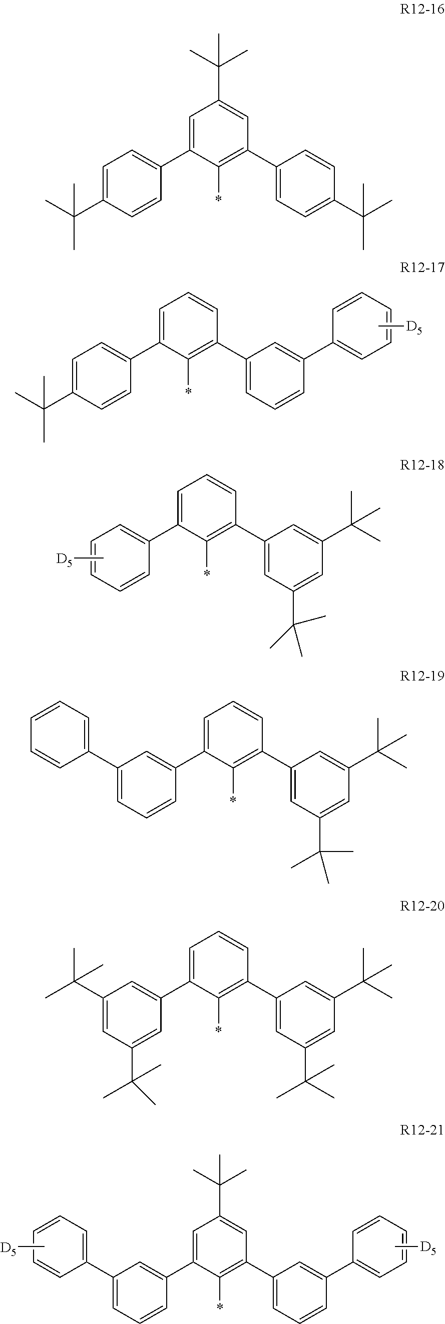

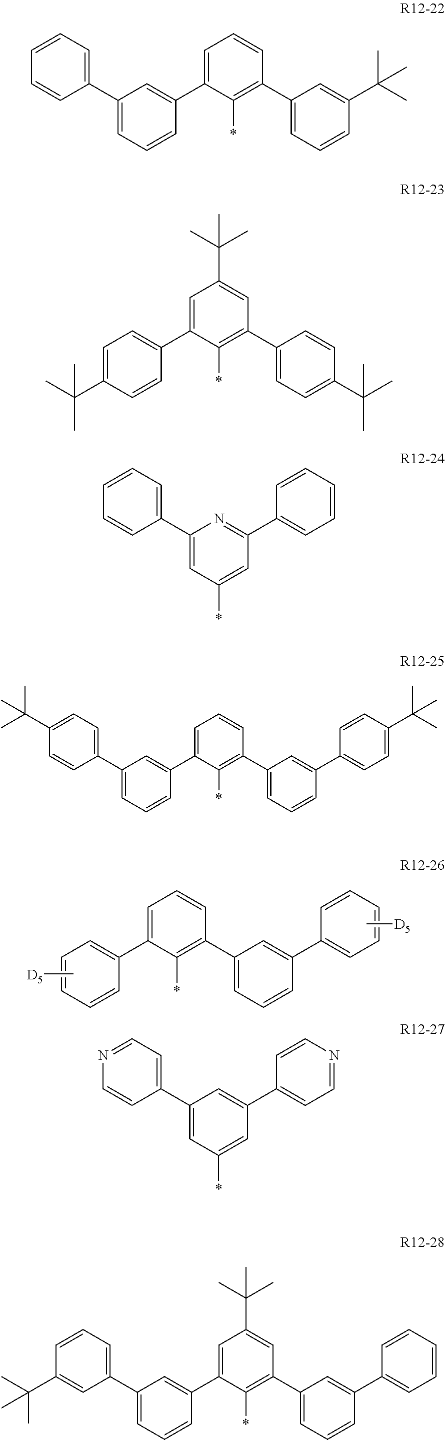

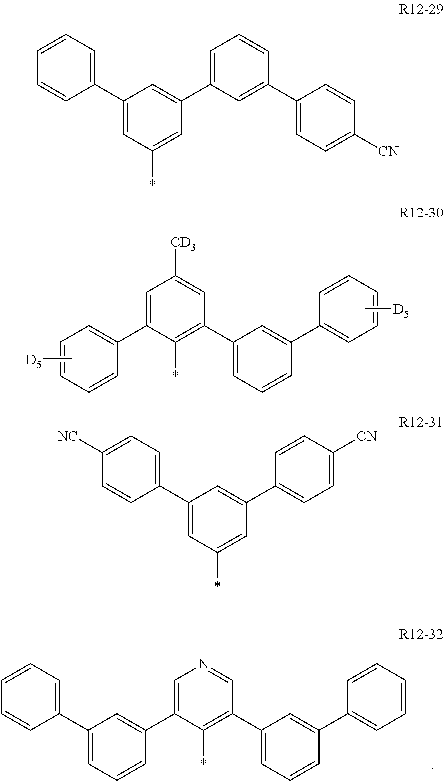

11. The light emitting element of claim 8, wherein R₁₁, R₂₁, R₃₁, and R₄₁ are each independently a hydrogen atom, a deuterium atom, a substituted or unsubstituted methyl group, a substituted or unsubstituted i-propyl group, a substituted or unsubstituted t-butyl group, a substituted or unsubstituted phenyl group, a substituted or unsubstituted pyridine group, —Si(Ph)₃, —Si(CH₃)(CH₃)(CH₃), or —N(CH₃)(CH₃).

12. The light emitting element of claim 1, wherein R₁₀, R₂₀, R₃₀, and R₄₀ are each independently a hydrogen atom, a deuterium atom, a cyano group, a substituted or unsubstituted alkyl group having 1 to 30 carbon atoms, a substituted or unsubstituted aryl group having 6 to 30 ring-forming carbon atoms, a substituted or unsubstituted heteroaryl group having 2 to 30 ring-forming carbon atoms, —Si(Q₁)(Q₂)(Q₃), or —N(Q₁)(Q₂), and
Q₁ to Q₃ are each independently a substituted or unsubstituted alkyl group having 1 to 30 carbon atoms, or a substituted or unsubstituted aryl group having 6 to 30 ring-forming carbon atoms.

13. The light emitting element of claim 1, wherein the organometallic compound represented by Formula 1 comprises at least one selected from among compounds in Compound Group 1:

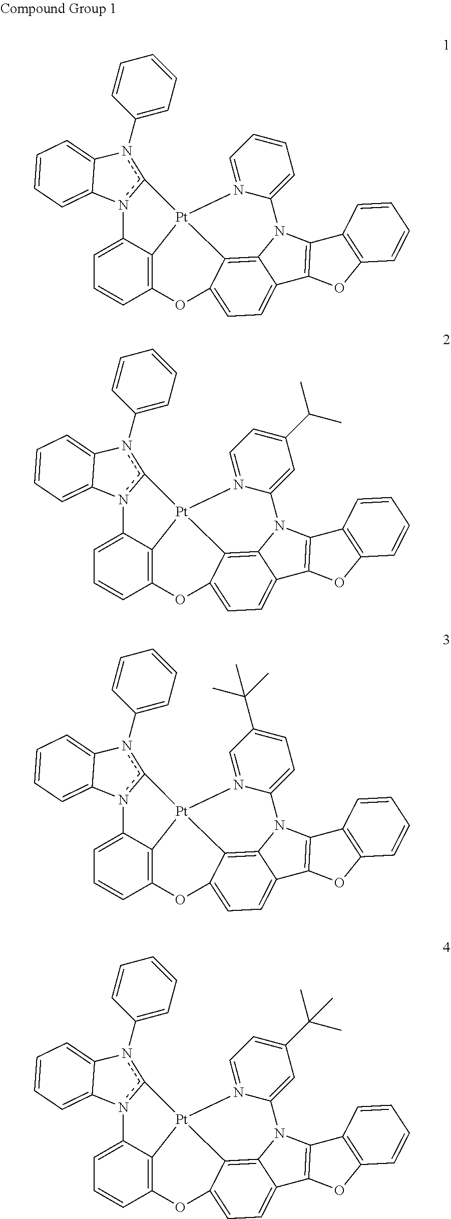

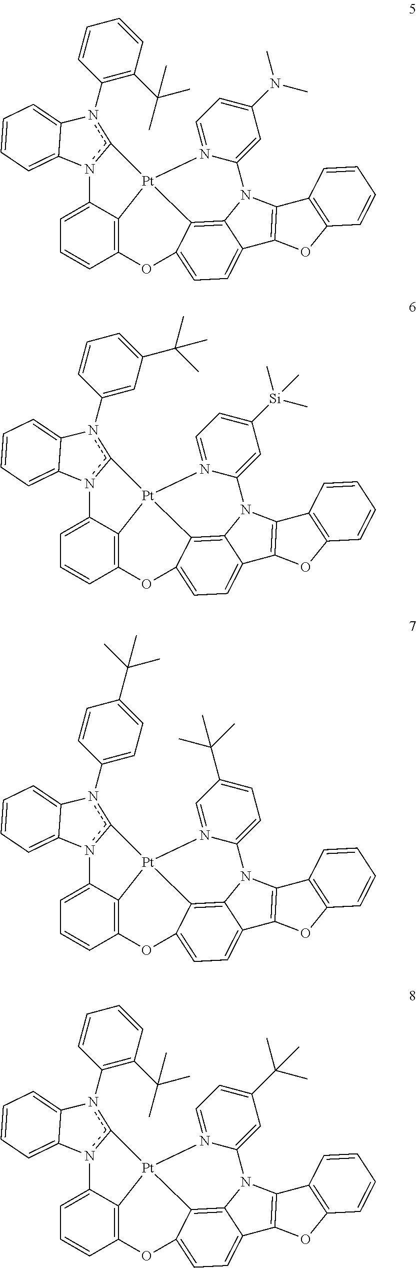

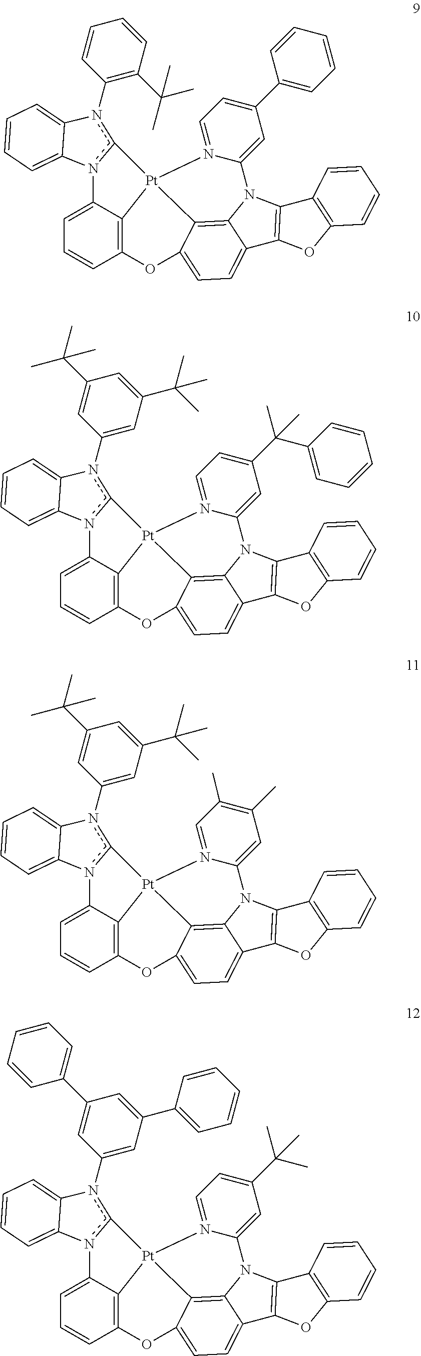

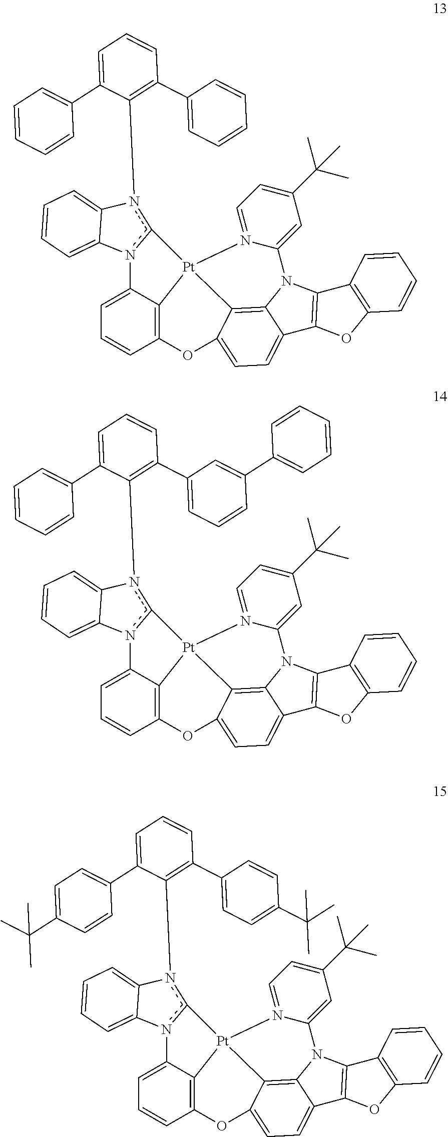

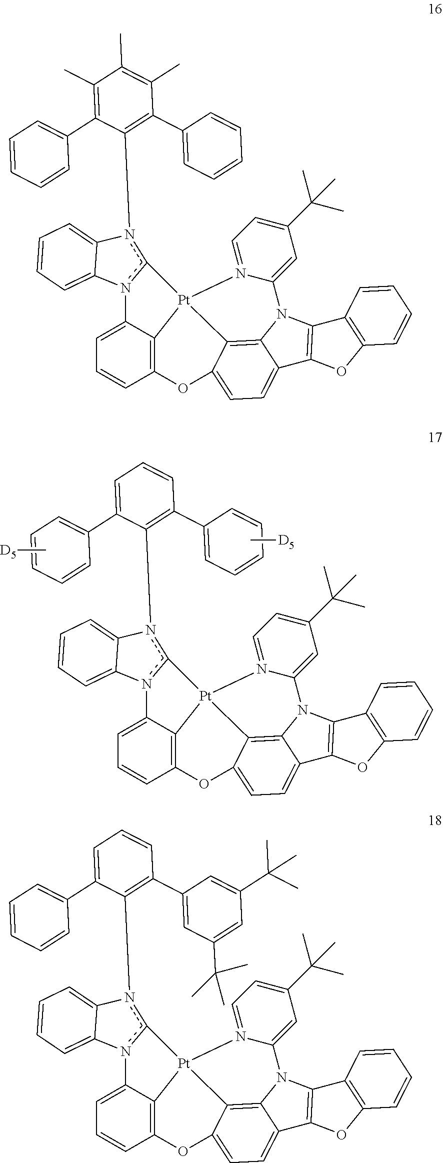

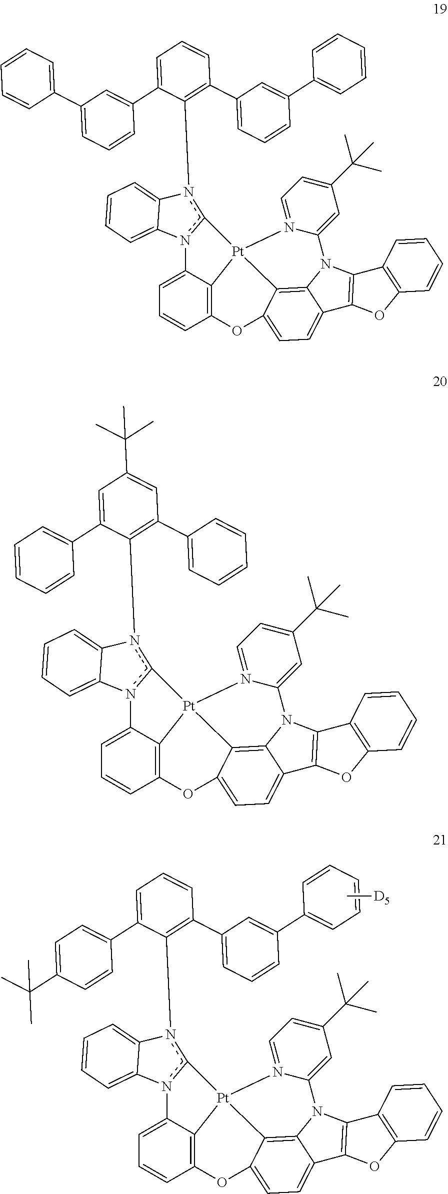

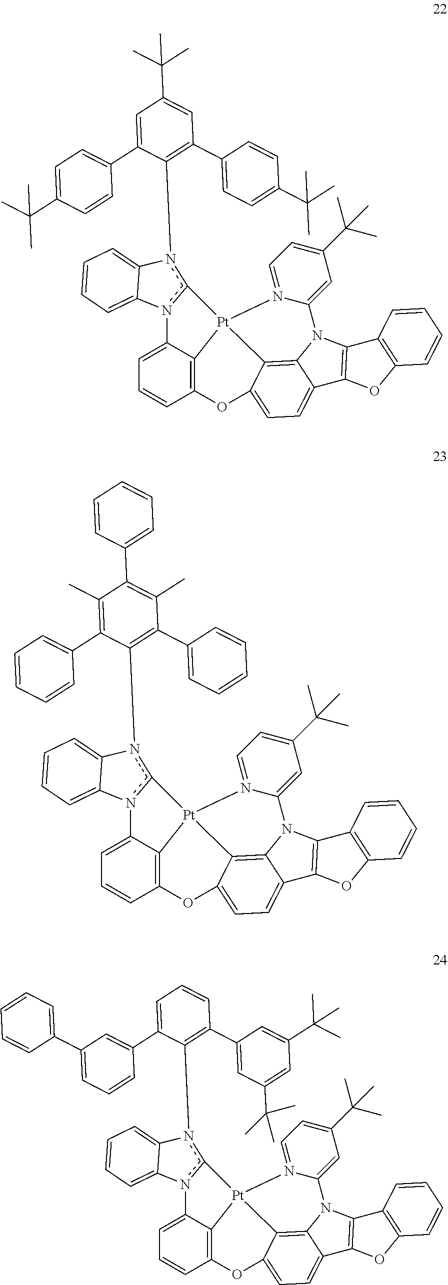

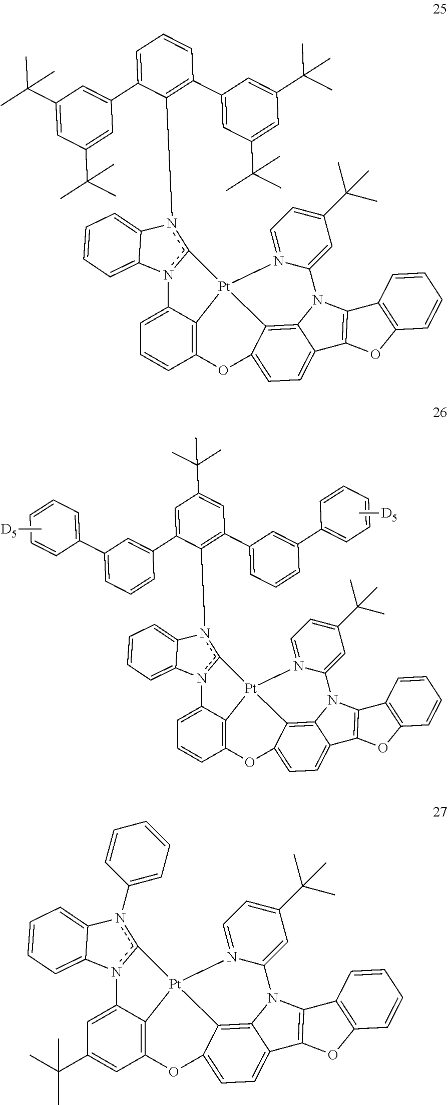

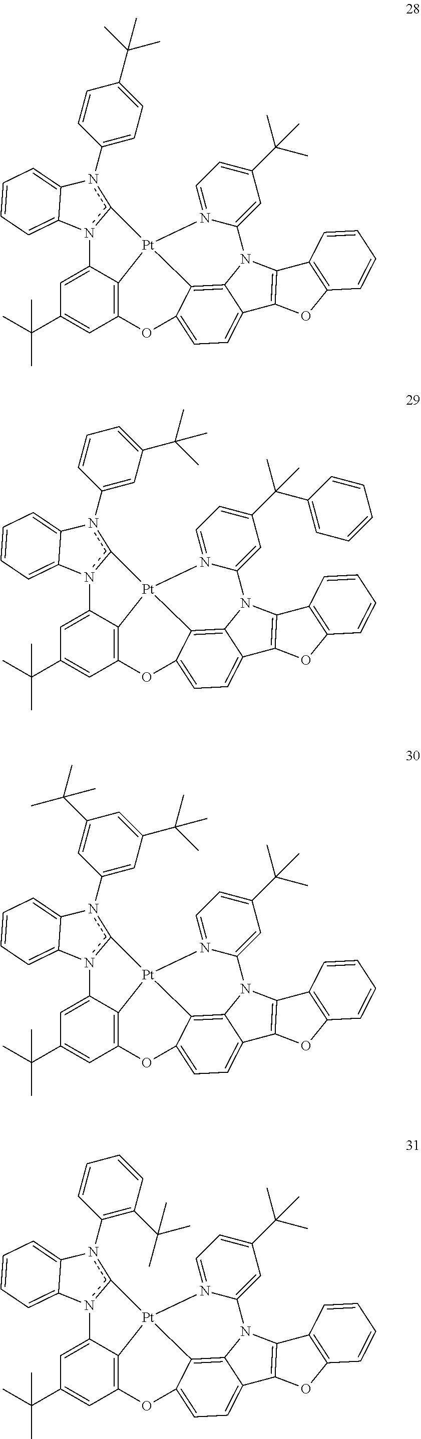

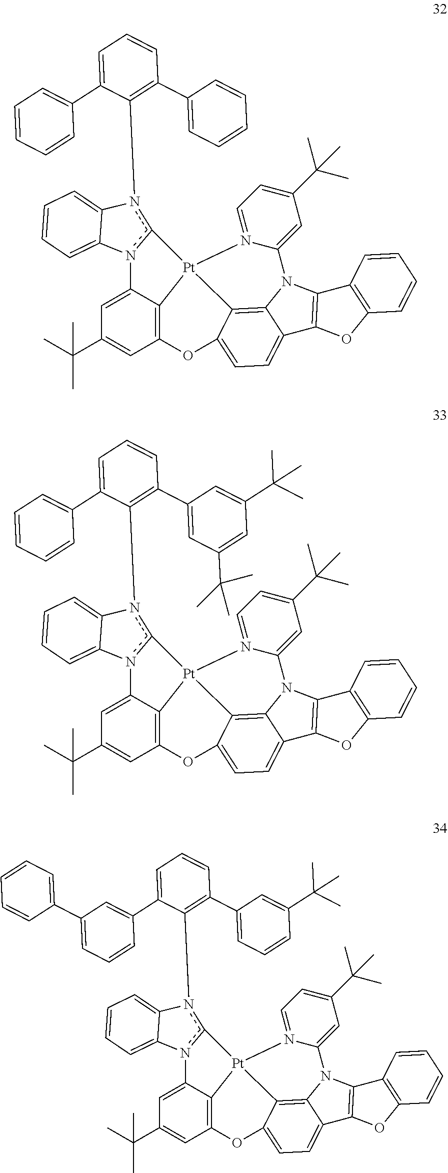

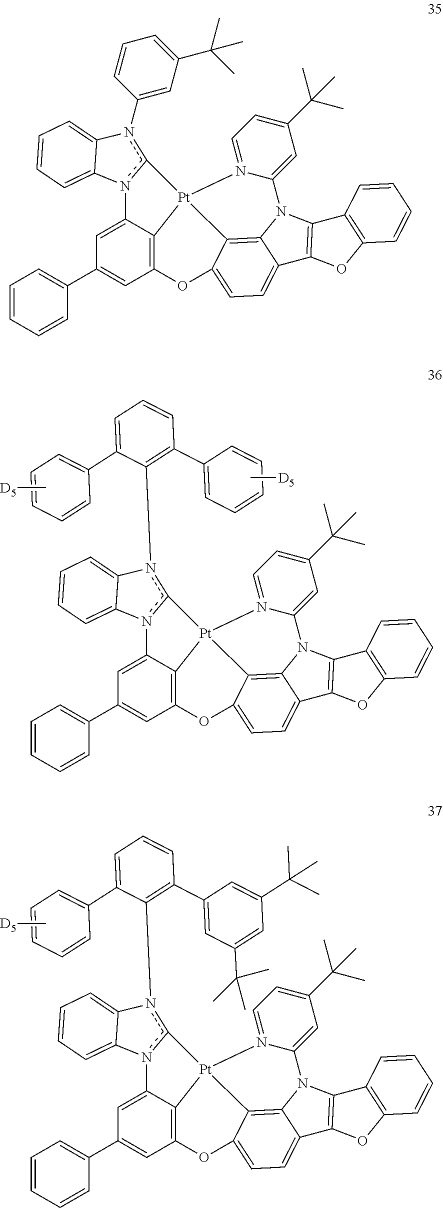

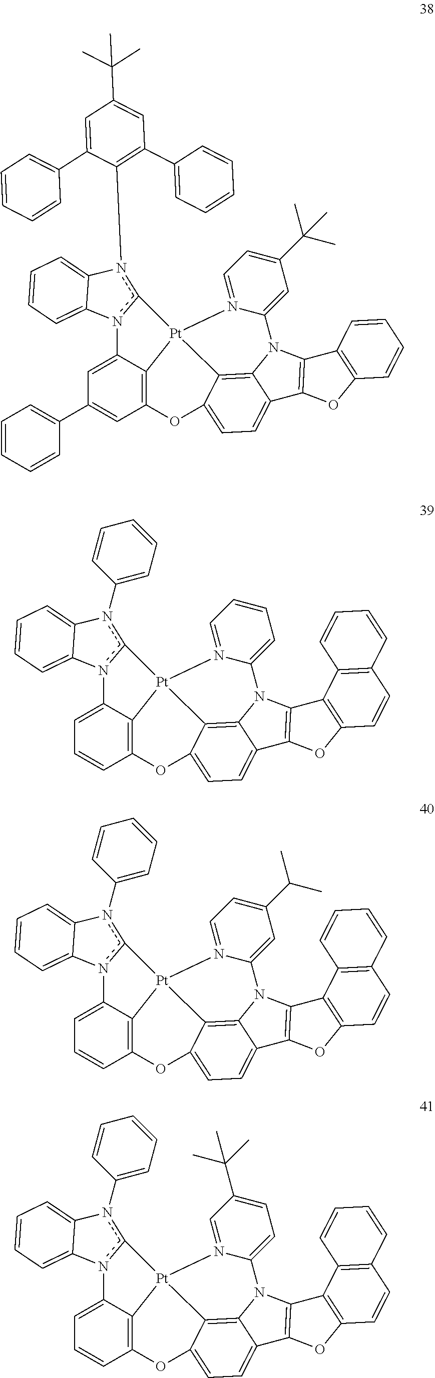

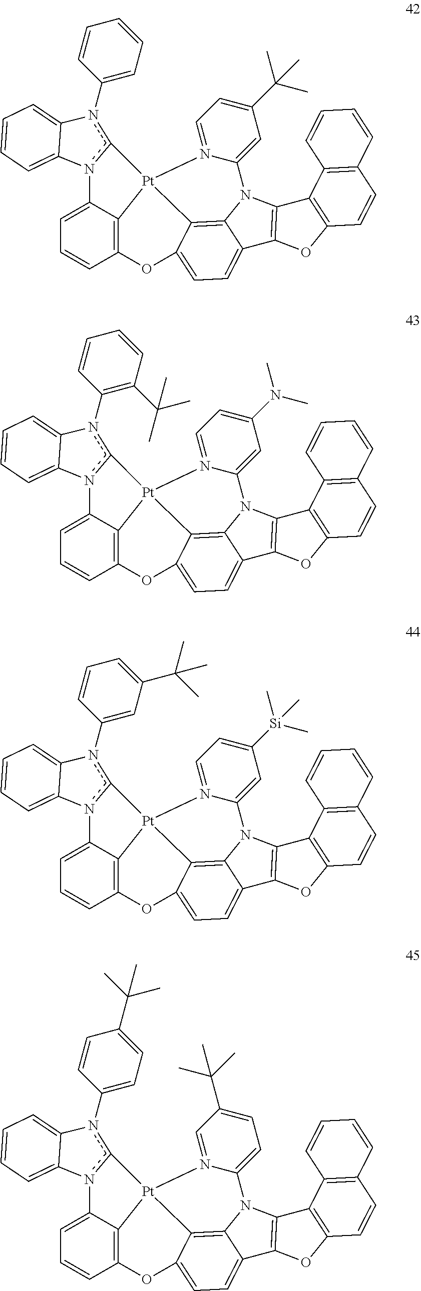

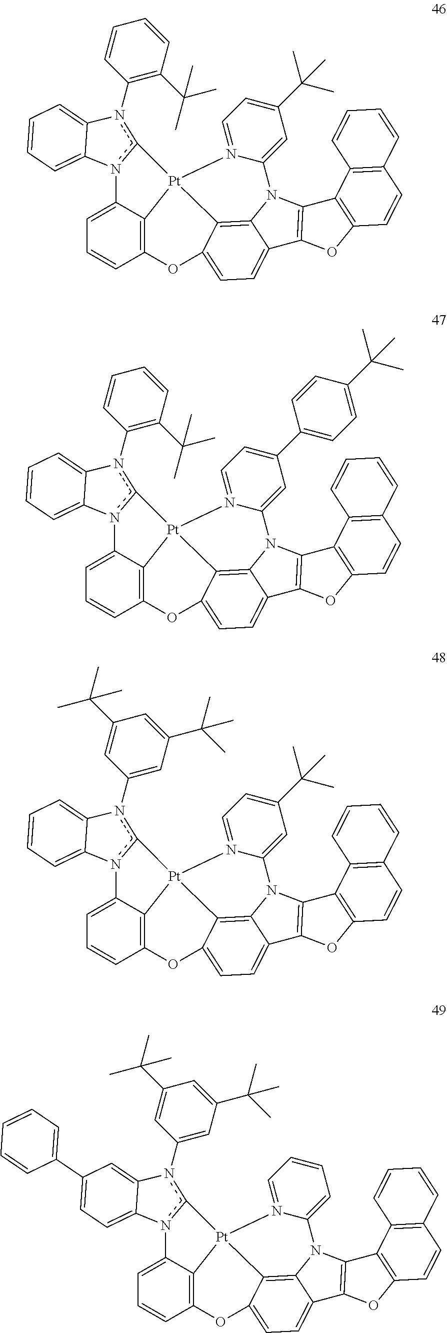

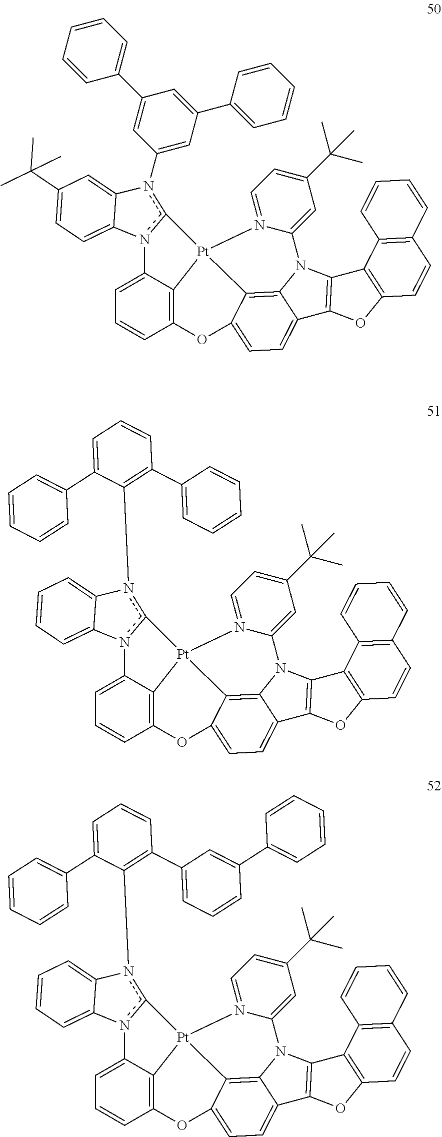

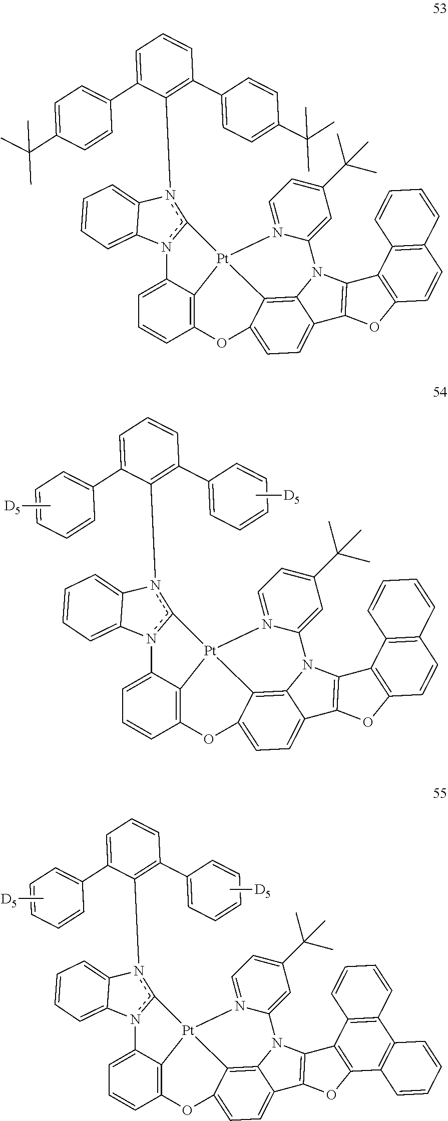

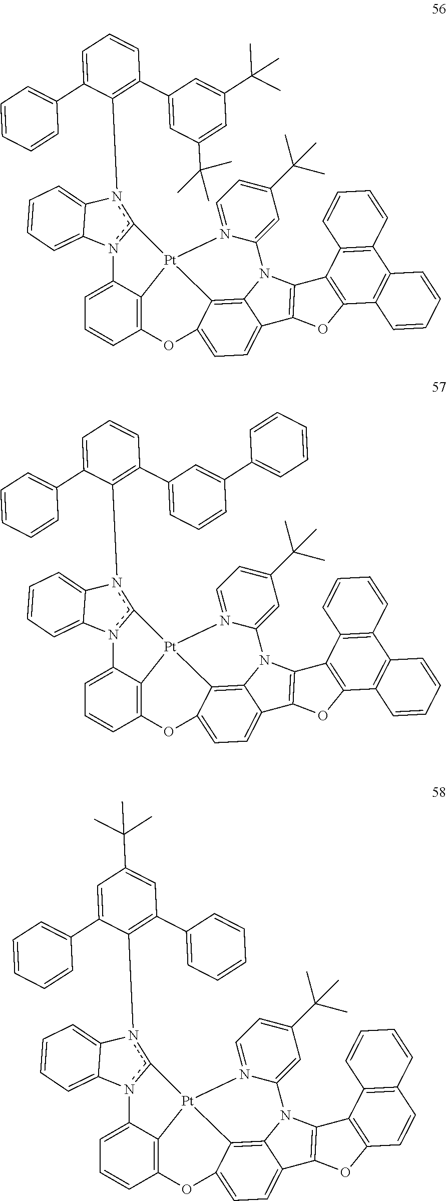

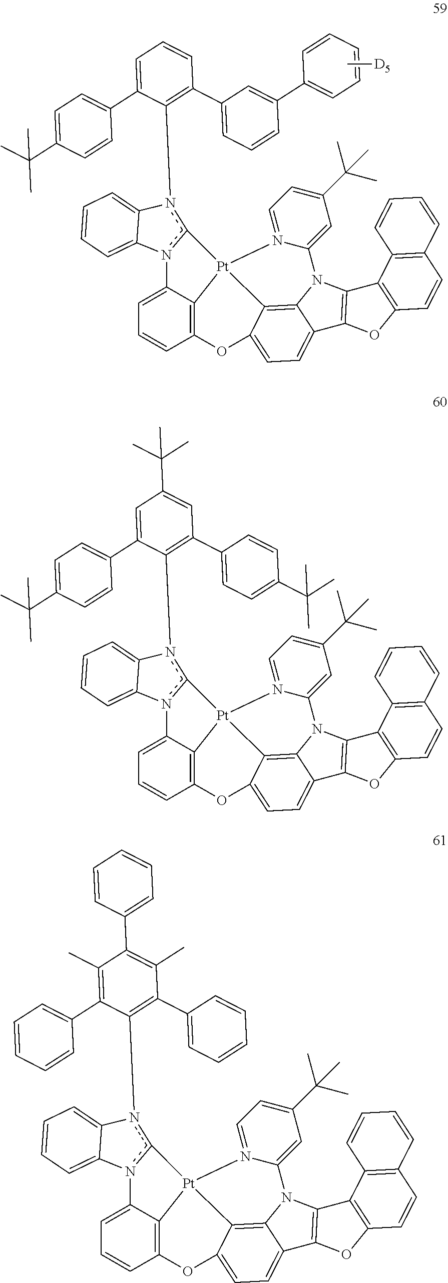

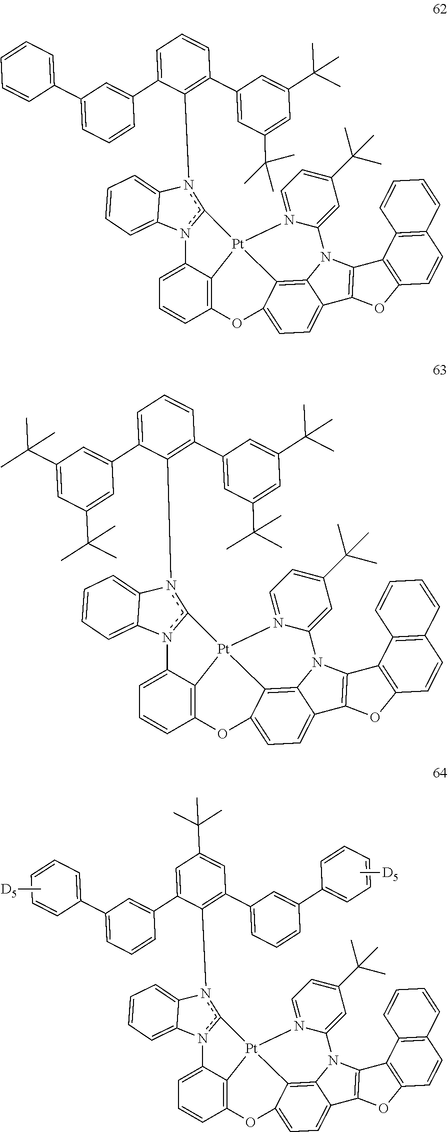

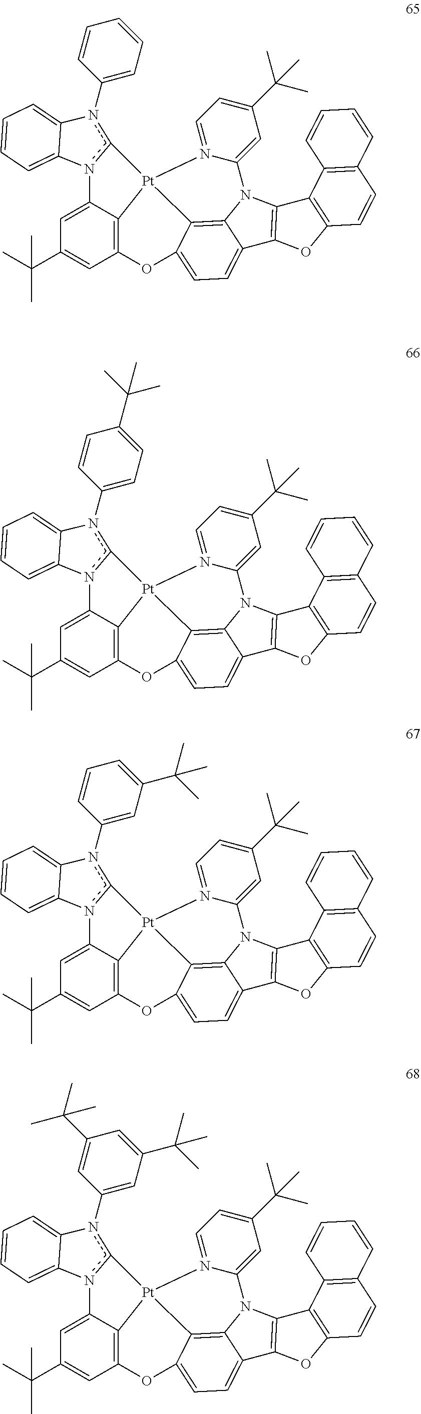

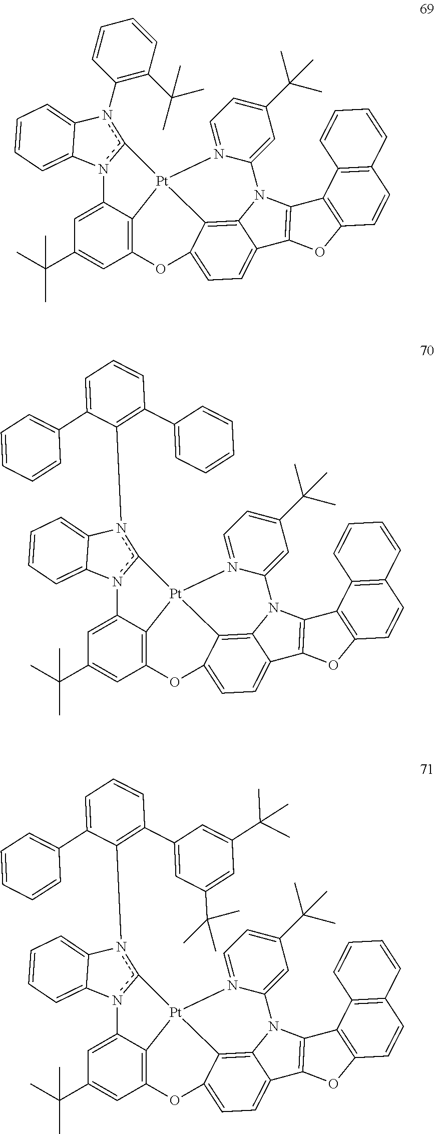

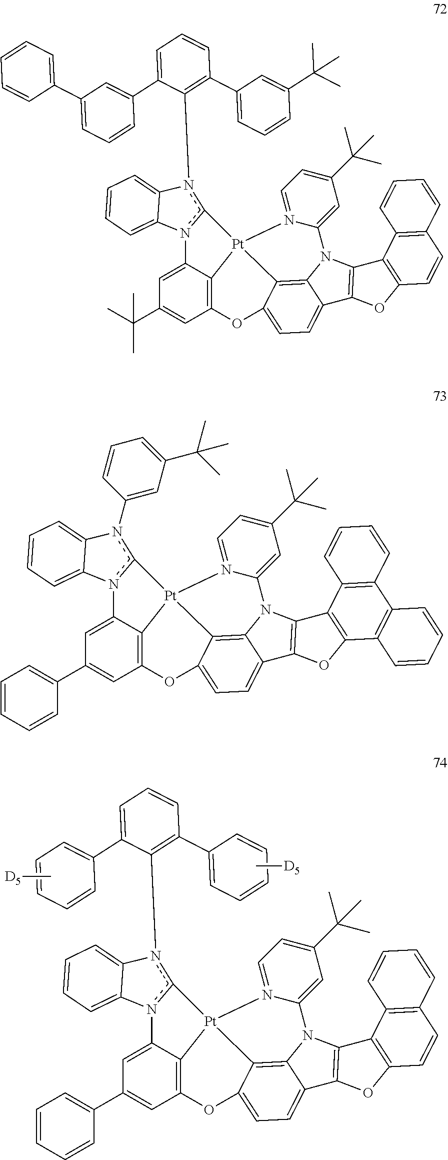

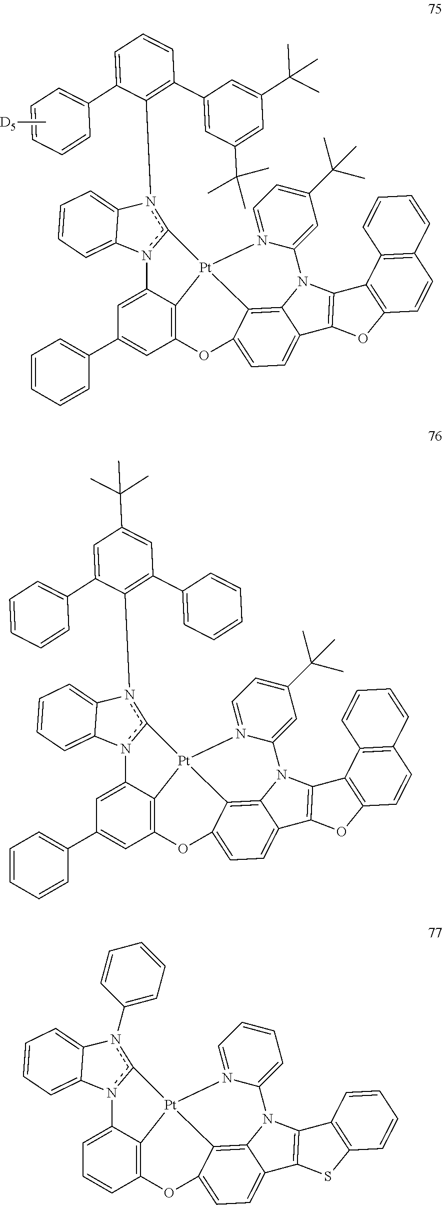

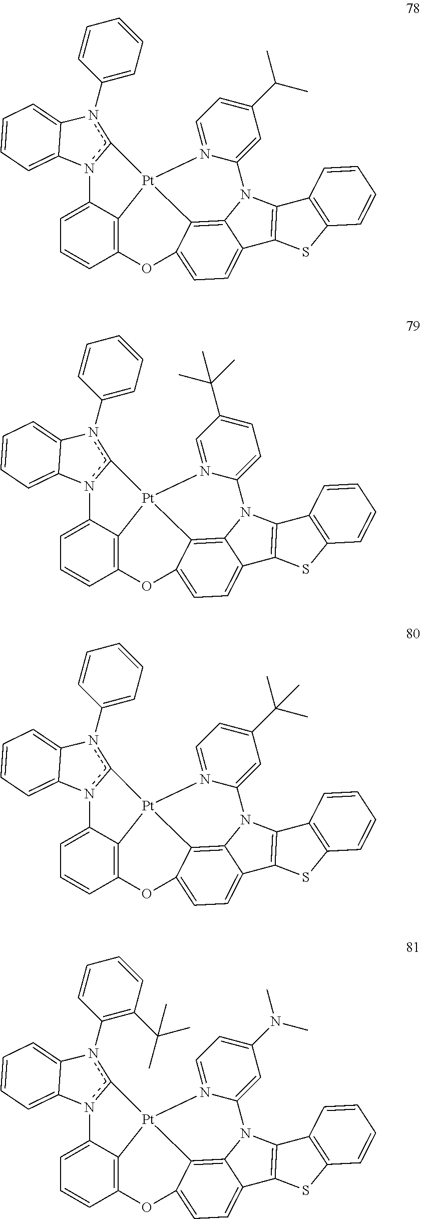

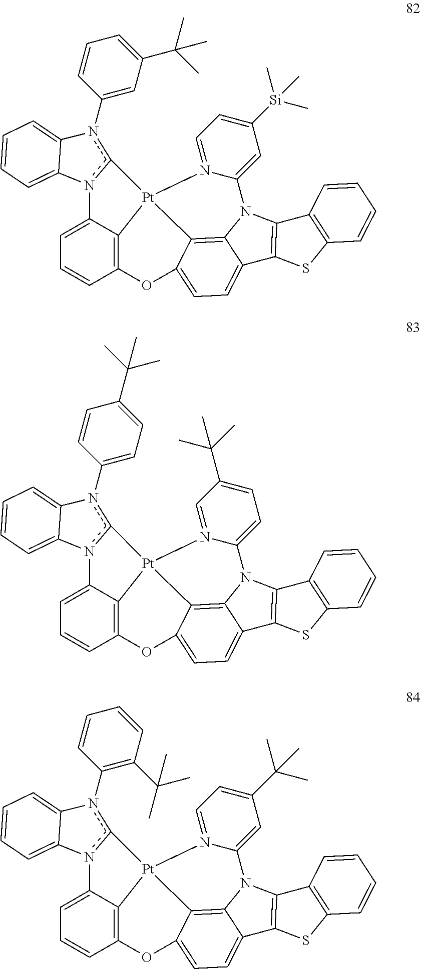

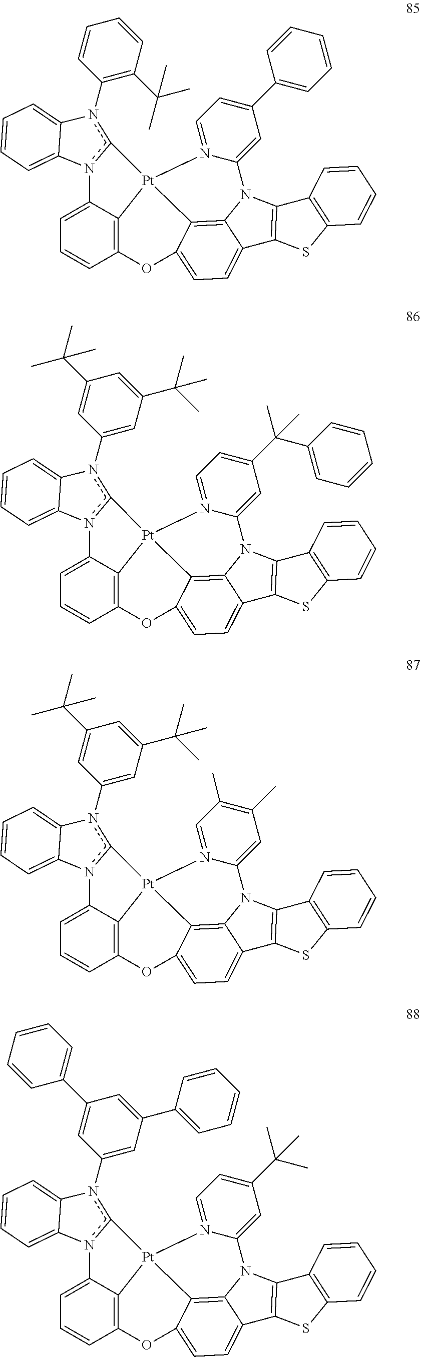

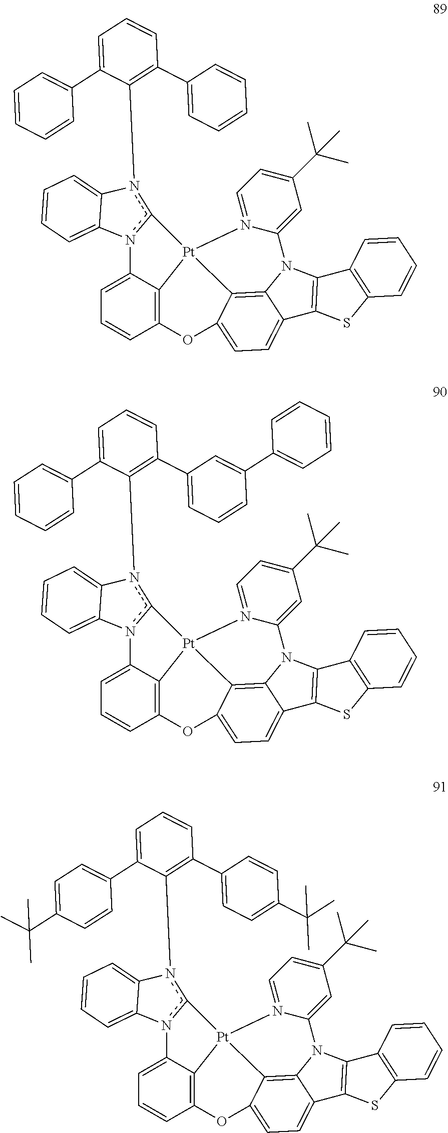

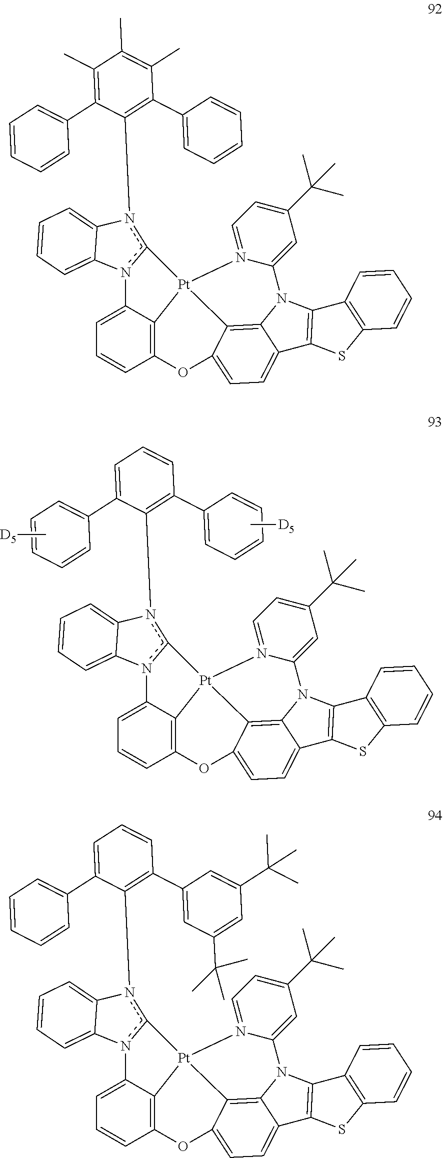

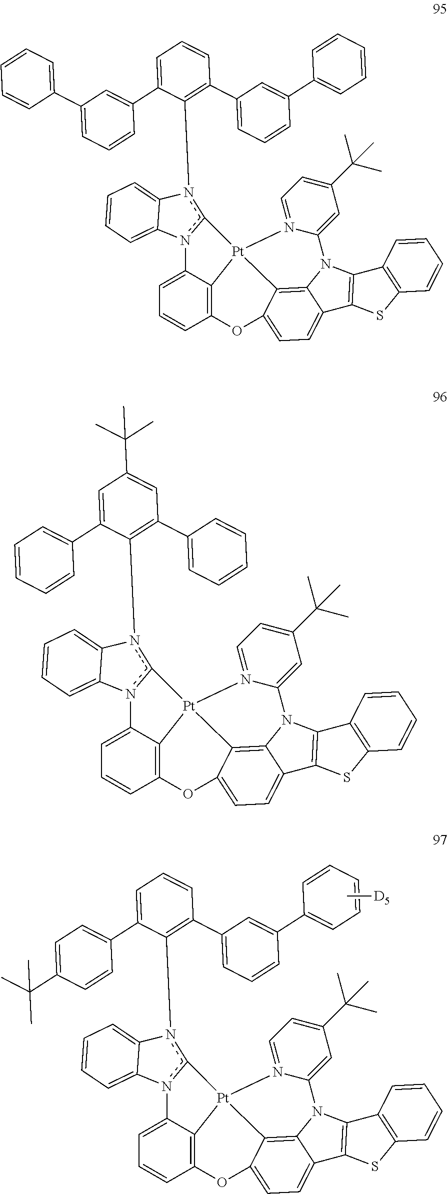

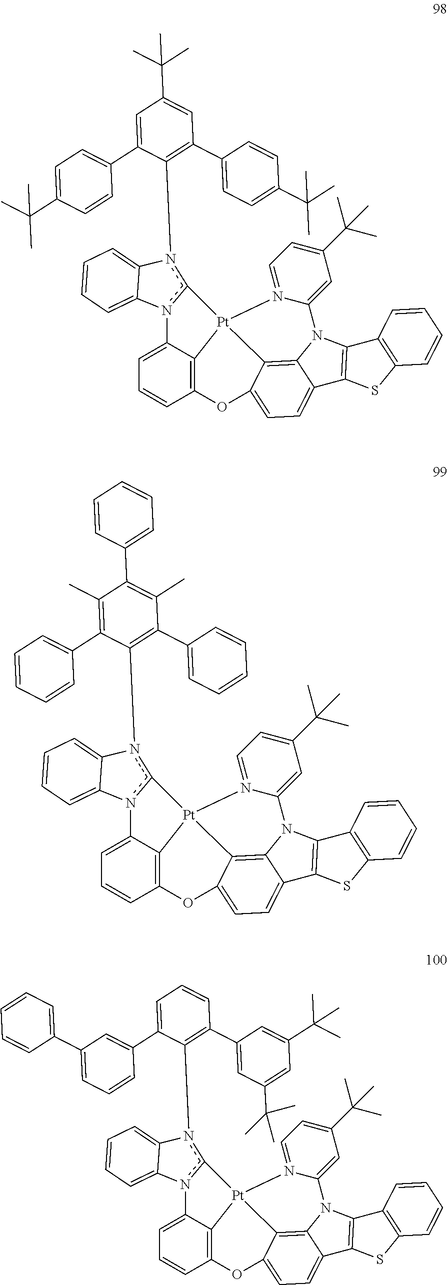

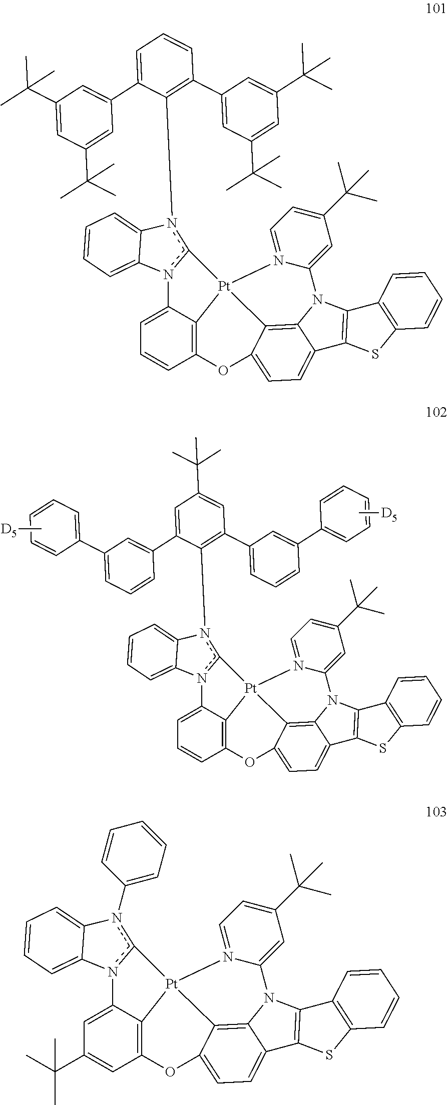

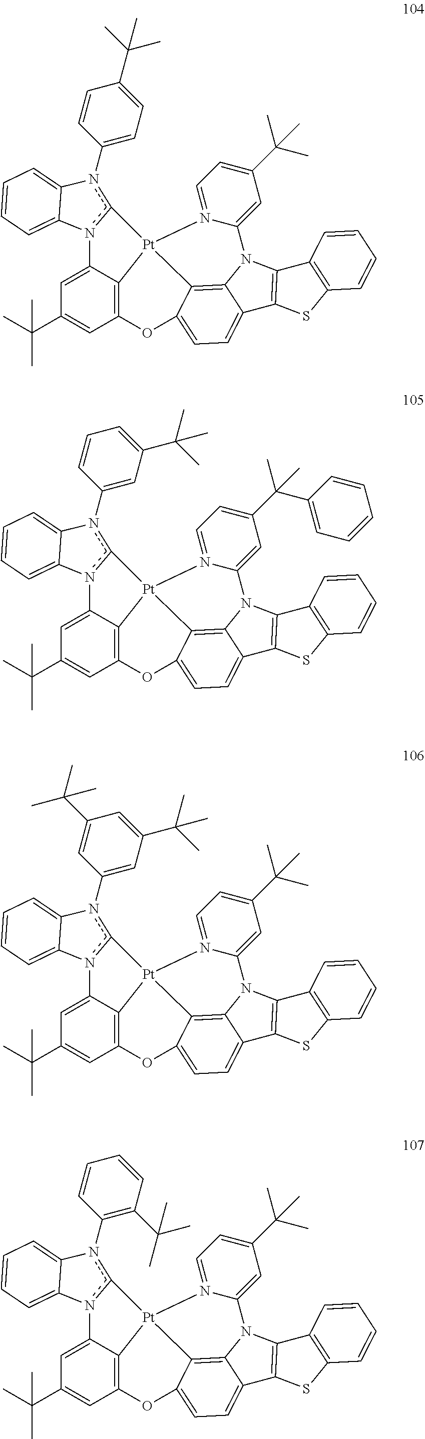

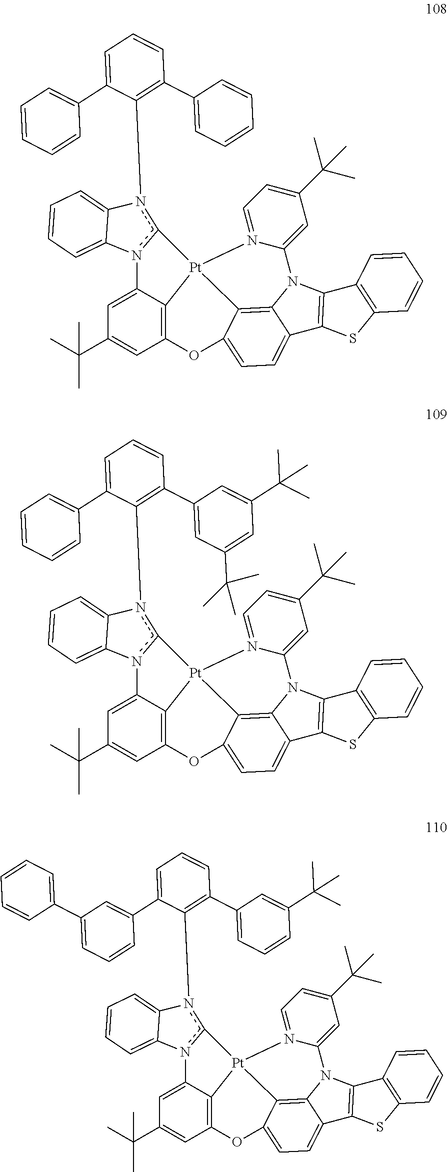

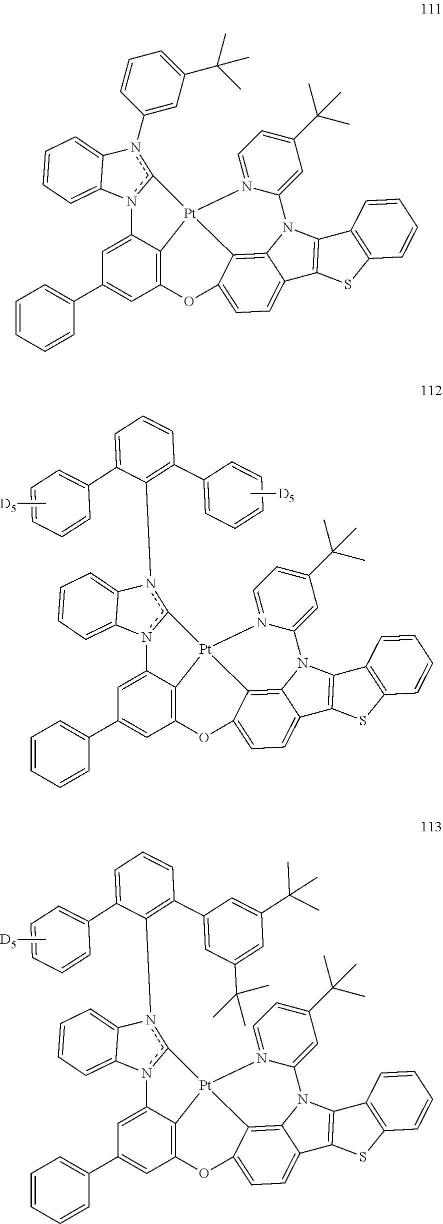

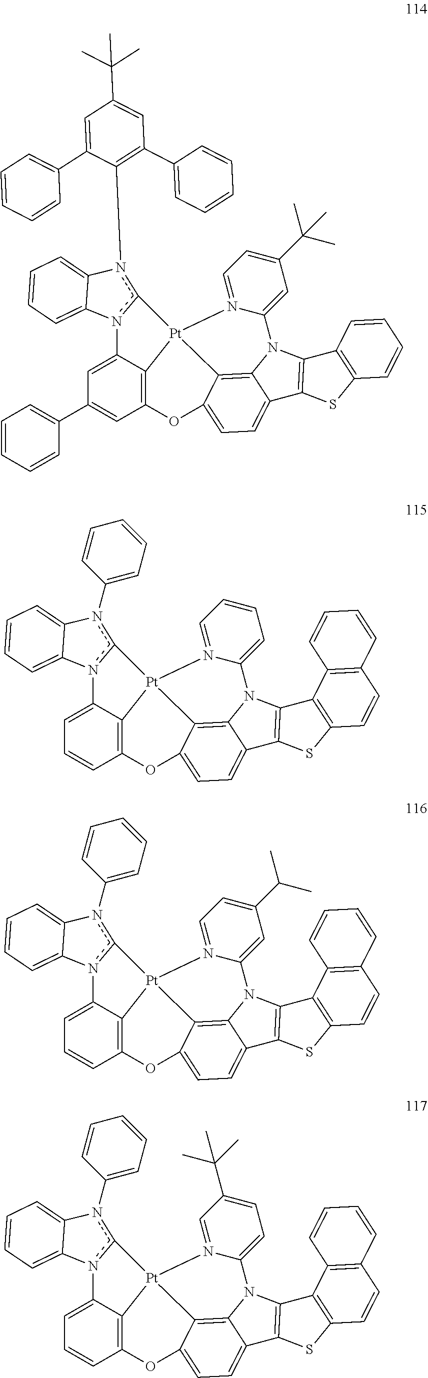

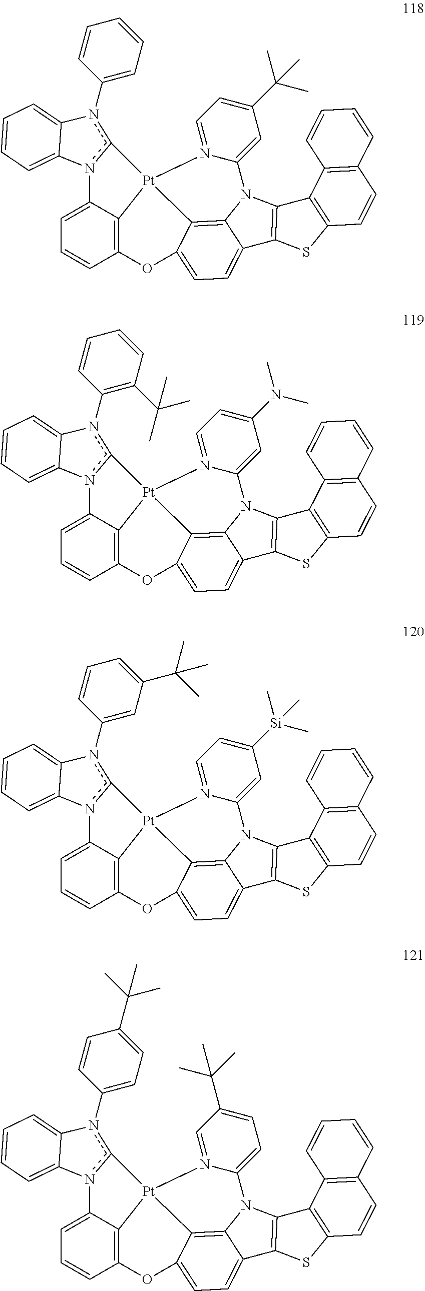

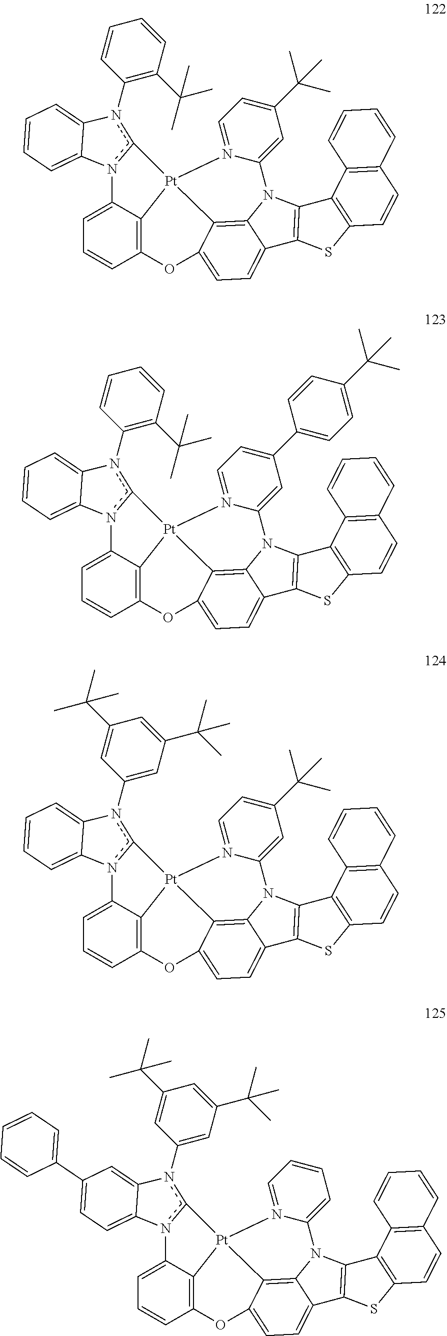

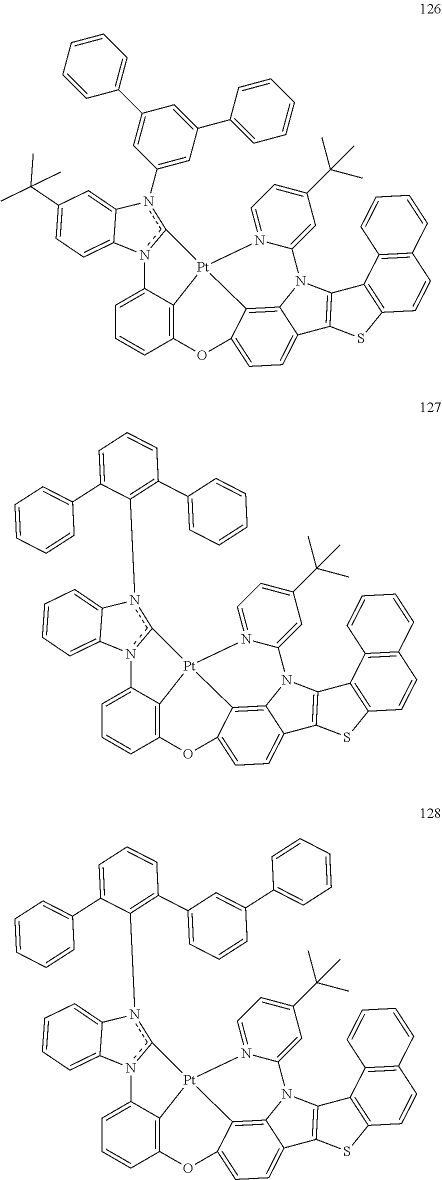

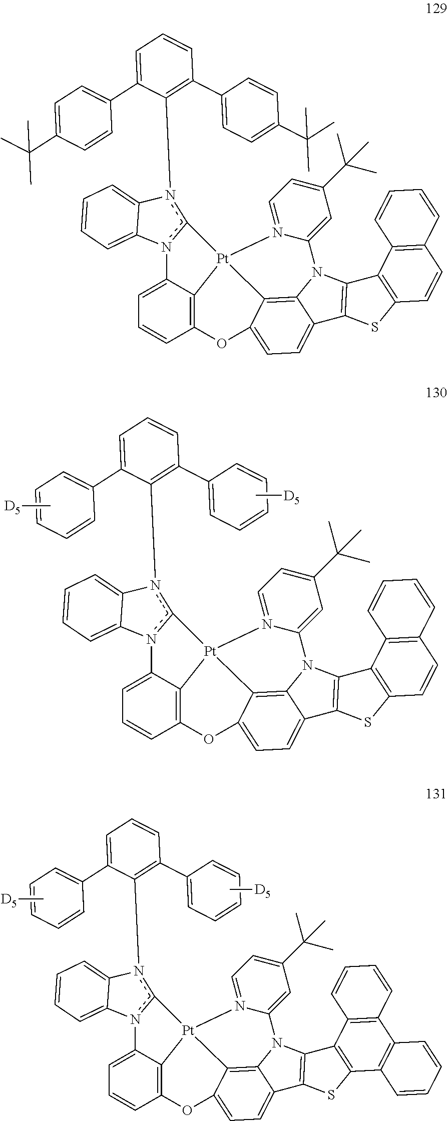

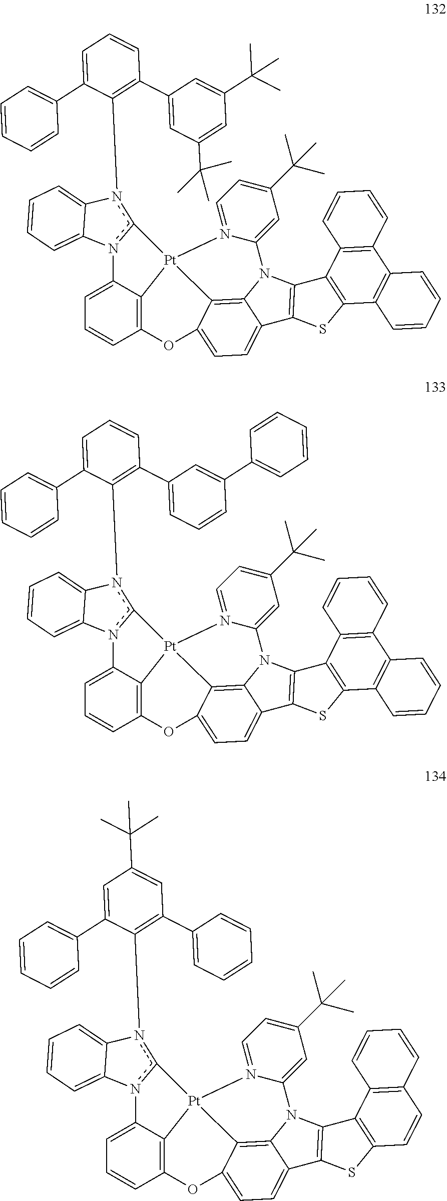

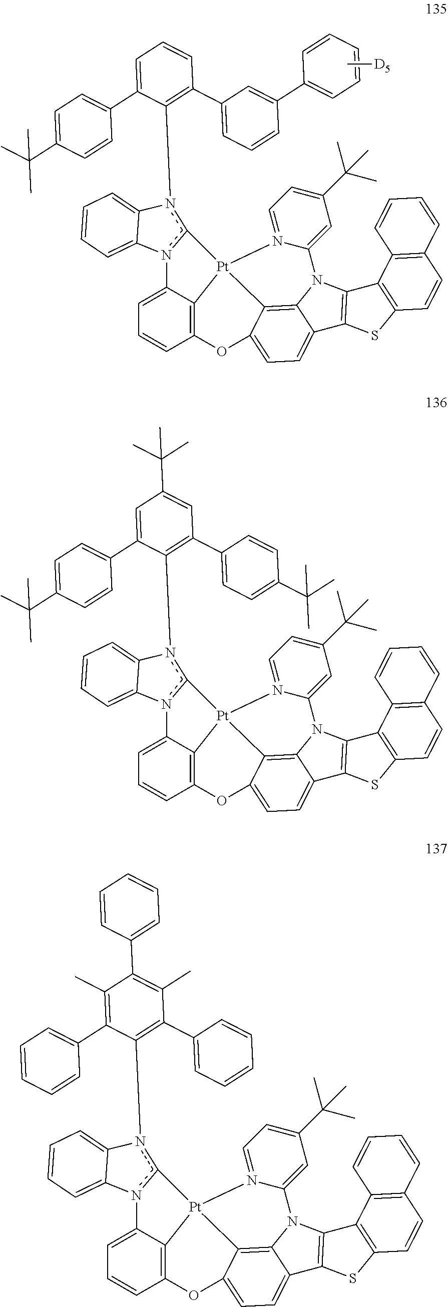

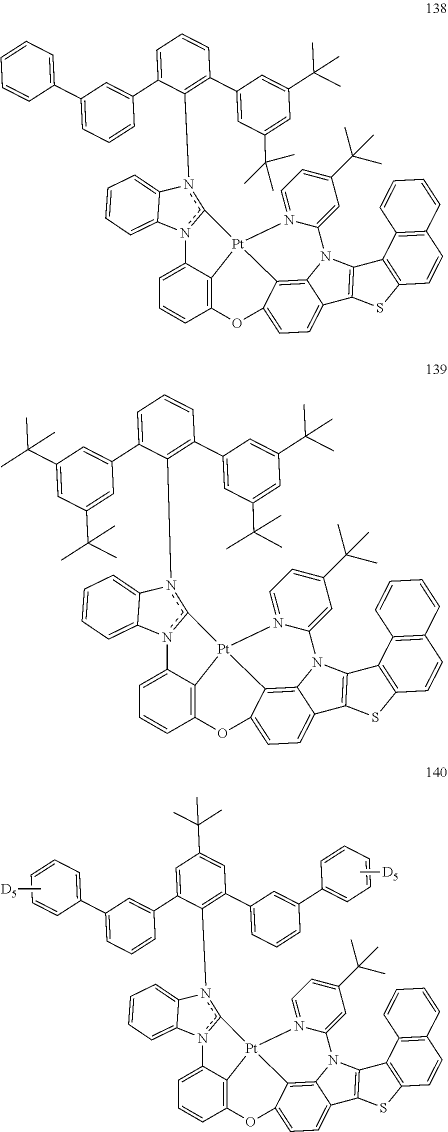

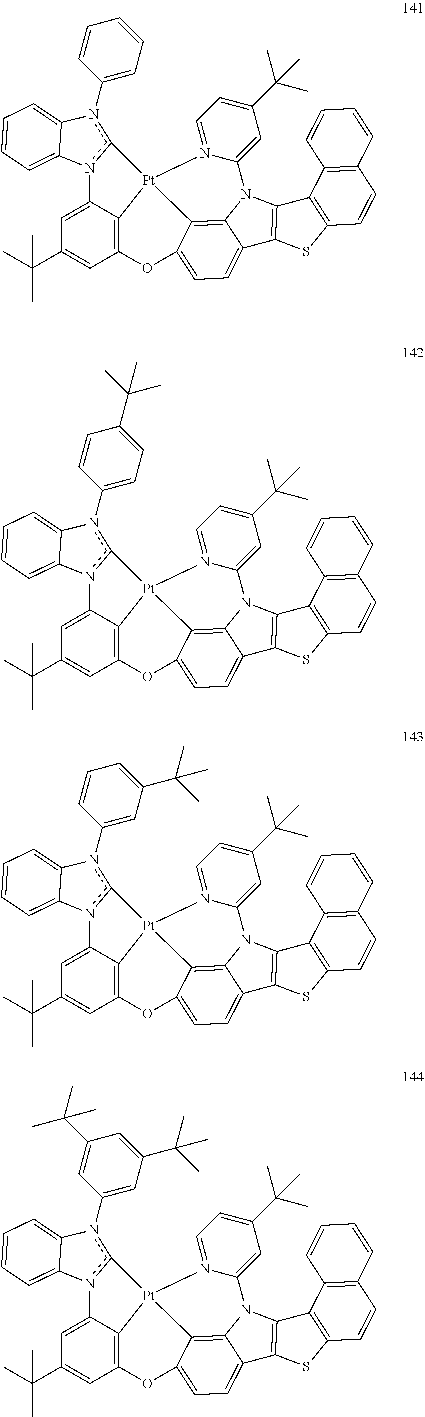

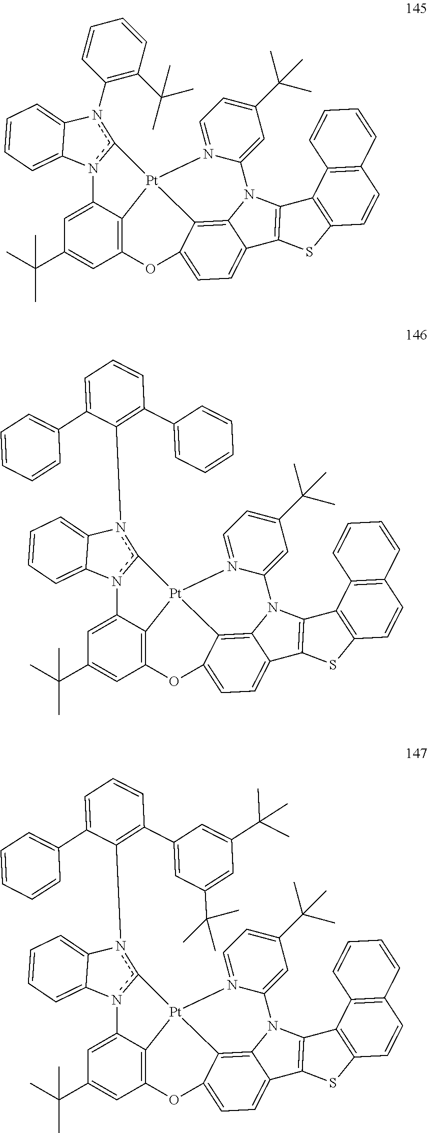

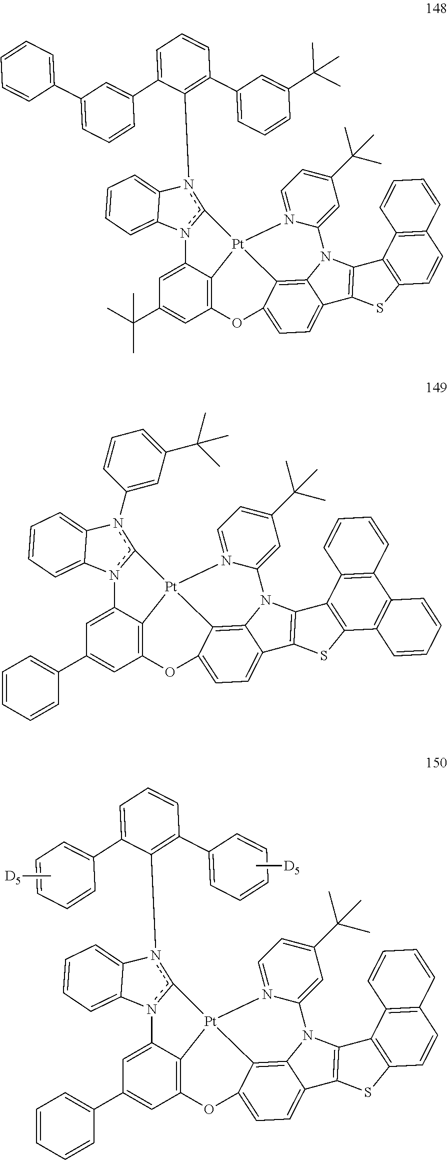

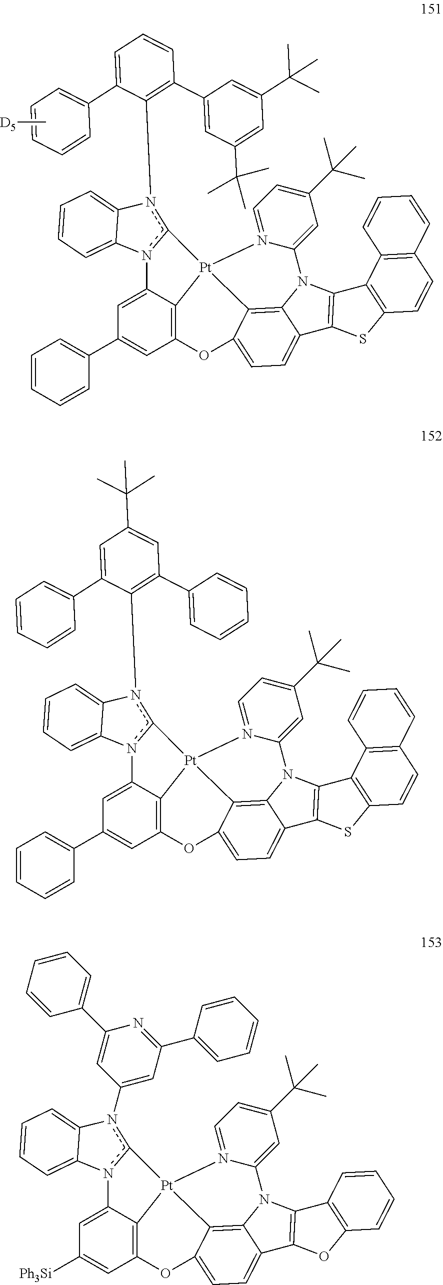

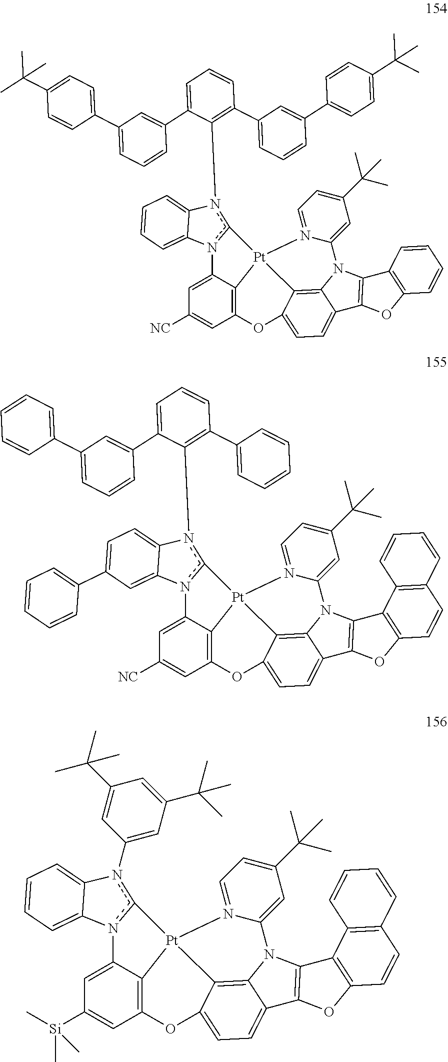

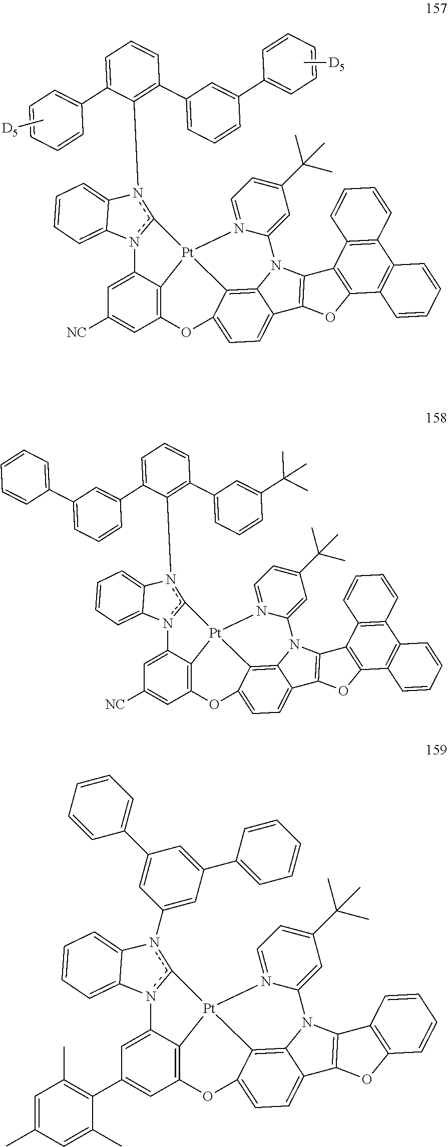

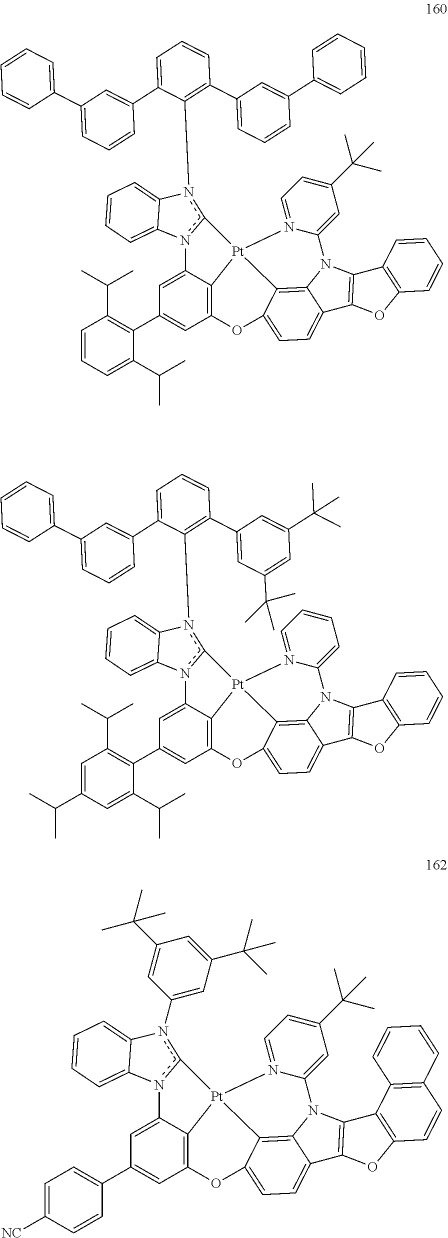

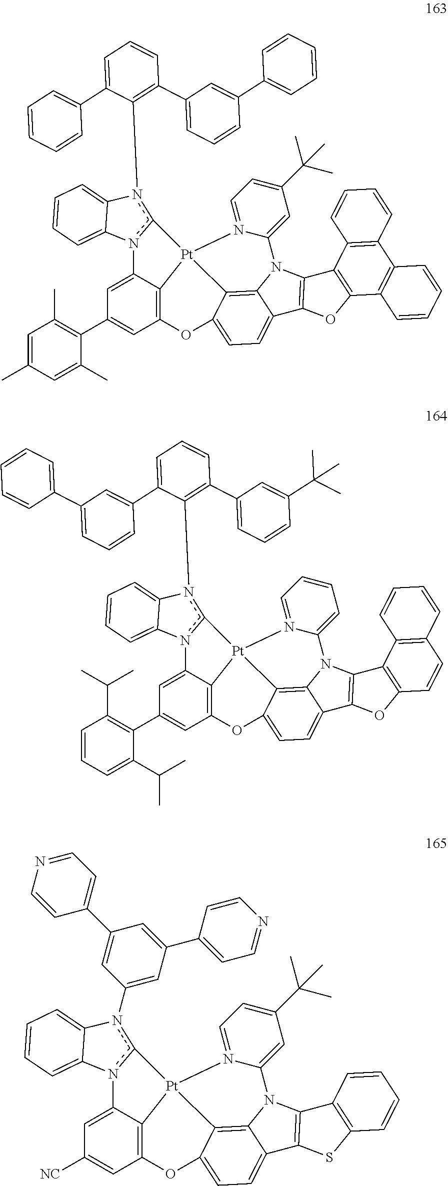

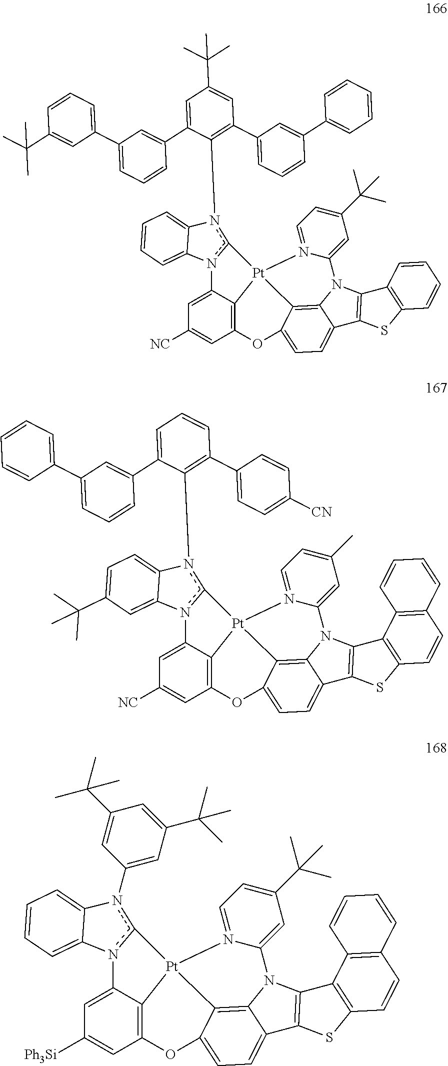

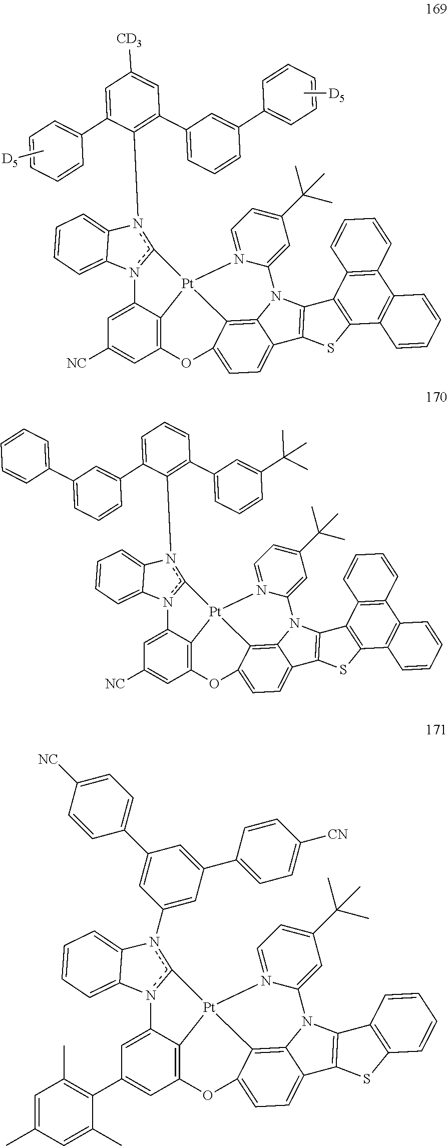

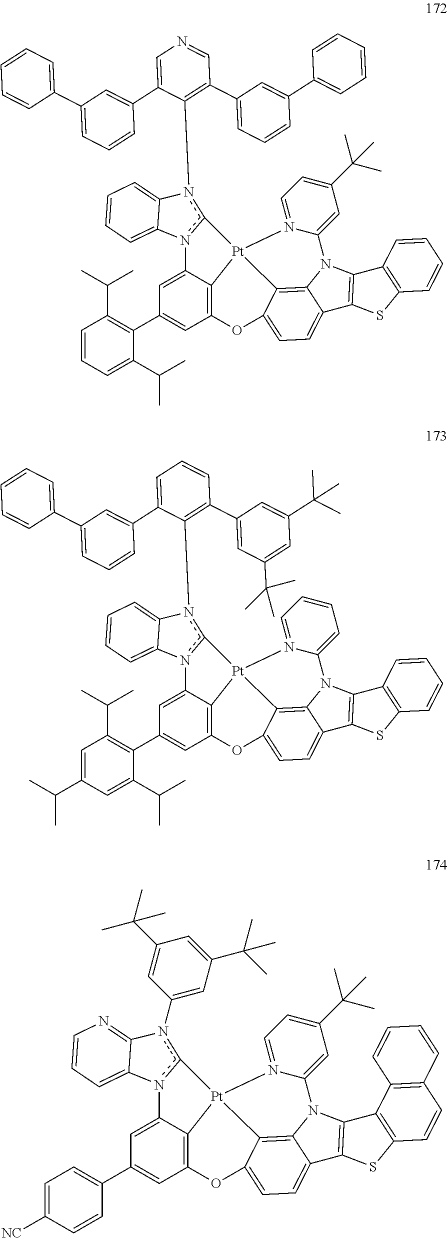

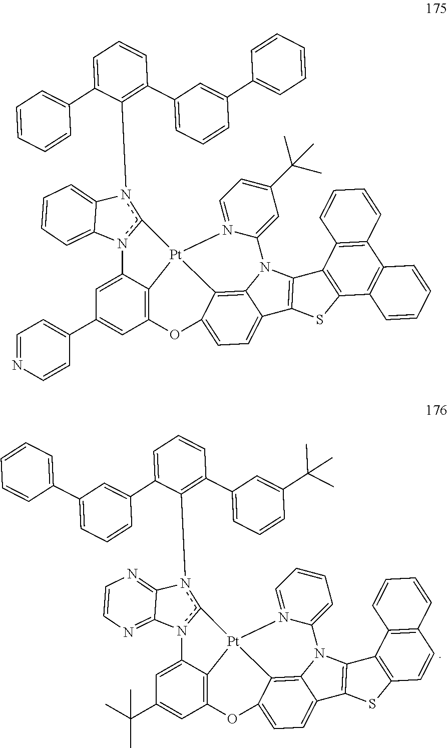

14. An organometallic compound represented by Formula 1: 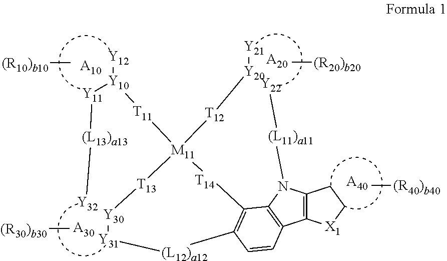
wherein, in Formula 1,
M₁₁ is Pt, Pd, Cu, Ag, Au, Rh, Ir, Ru, Os, Ti, Zr, Hf, Eu, Tb, or Tm,
X₁ is O or S,
Y₁₀, Y₁₁, Y₁₂, Y₂₀, Y₂₁, Y₂₂, Y₃₀, Y₃₁, and Y₃₂ are each independently N, C, NRₐ, or CR_{b},
T₁₁ to T₁₄ are each independently a direct linkage, *—O—*′, or *—S—*′,
L₁₁ to L₁₃ are each independently a direct linkage, *—O—*′, *—S—*′, *—C(R₁)(R₂)—*′, *—C(R₁)═*′, *═C(R₁)—*′, *—C(R₁)═C(R₂)—*′, *—C(═O)—*′, *—C(═S)—*′, *—C≡C—*′, *—B(R₁)—*′, *—N(R₁)—*′, *—P(R₁)—*′, *—Si(R₁)(R₂)—*′, or *—Ge(R₁)(R₂)—*′,
a11 to a13 are each independently an integer from 0 to 3,
rings A₁₀, A₂₀, A₃₀, and A₄₀ are each independently a substituted or unsubstituted hydrocarbon ring having 5 to 60 ring-forming carbon atoms, or a substituted or unsubstituted heterocycle having 2 to 60 ring-forming carbon atoms,
Rₐ, R_{b}, R₁, R₂, R₁₀, R₂₀, R₃₀, and R₄₀ are each independently a hydrogen atom, a deuterium atom, —F, —Cl, —Br, —I, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂), and/or bonded to an adjacent group to form a ring,
b10, b20, b30, and b40 are each independently an integer from 0 to 8,
Q₁ to Q₃ are each independently a hydrogen atom, a deuterium atom, a halogen atom, a hydroxyl group, a cyano group, a nitro group, an amidino group, a hydrazino group, a hydrazono group, a substituted or unsubstituted thio group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted alkynyl group having 2 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted cycloalkenyl group having 3 to 10 ring-forming carbon atoms, a substituted or unsubstituted heterocycloalkenyl group having 2 to 10 ring-forming carbon atoms, a substituted or unsubstituted aryl group having 6 to 60 ring-forming carbon atoms, or a substituted or unsubstituted heteroaryl group having 2 to 60 ring-forming carbon atoms, and
* and *′ are linkage positions.

15. The organometallic compound of claim 14, wherein Formula 1 is represented by Formula 2: 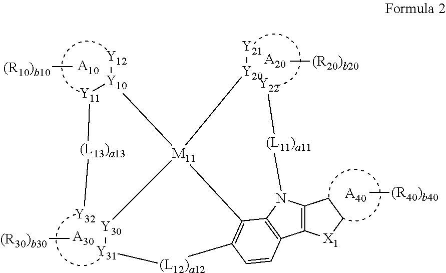
wherein, in Formula 2,
M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, L₁₁ to L₁₃, a11 to a13, R₁₀, R₂₀, R₃₀, R₄₀, b10, b20, b30, and b40 are the same as defined in Formula 1.

16. The organometallic compound of claim 14, wherein Formula 1 is represented by Formula 3: 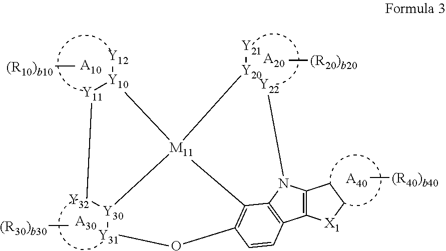
wherein, in Formula 3, M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, A₄₀, R₁₀, R₂₀, R₃₀, R₄₀, b10, b20, b30, and b40 are the same as defined in Formula 1.

17. The organometallic compound of claim 16, wherein Formula 3 is represented by any one selected from among Formula 3-1 to Formula 3-3: 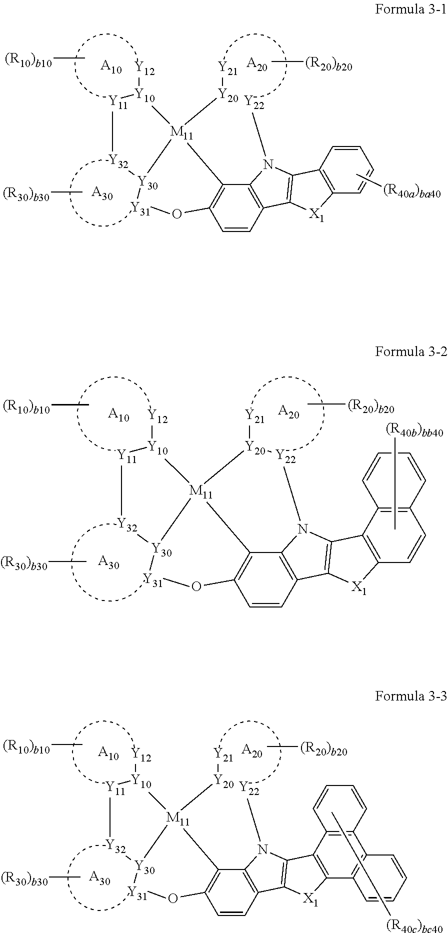
wherein, in Formula 3-1 to Formula 3-3,
R₄₀ₐ to R_{40c} are each independently a hydrogen atom or a deuterium atom,
ba40 is an integer from 0 to 4, bb40 is an integer from 0 to 6, and bc40 is an integer from 0 to 8, and
M₁₁, X₁, Y₁₀, Y₁₁, Y₁₂, Y₂₀, Y₂₁, Y₂₂, Y₃₀, Y₃₁, Y₃₂, A₁₀, A₂₀, A₃₀, R₁₀, R₂₀, R₃₀, b10, b20, and b30 are the same as defined in Formula 1.

18. The organometallic compound of claim 14, wherein Formula 1 is represented by Formula 4: 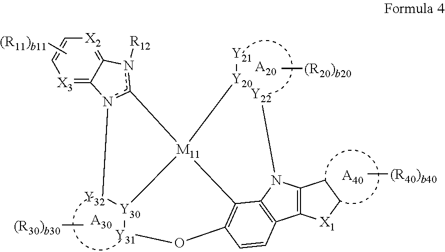
wherein, in Formula 4,
X₂ and X₃ are each independently CRₓ or N,
Rₓ and R₁₁ are each independently a hydrogen atom, a deuterium atom, a substituted or unsubstituted alkyl group having 1 to 60 carbon atoms, or a substituted or unsubstituted aryl group having 6 to 60 ring-forming carbon atoms,
b11 is an integer from 0 to 2,
R₁₂ is a substituted or unsubstituted aryl group having 6 to 60 ring-forming carbon atoms, or a substituted or unsubstituted heteroaryl group having 2 to 60 ring-forming carbon atoms, and
M₁₁, X₁, Y₂₀, Y₂₁, Y₂₂, Y₃₀, Y₃₁, Y₃₂, A₂₀, A₃₀, A₄₀, R₂₀, R₃₀, R₄₀, b20, b30, and b40 are the same as defined in Formula 1.

19. The organometallic compound of claim 18, wherein Formula 4 is the same as represented by Formula 5: 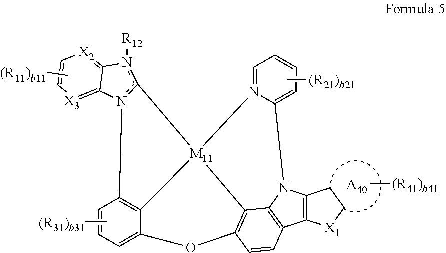
wherein, in Formula 5,
R₂₁, R₃₁, and R₄₁ are each independently a hydrogen atom, a deuterium atom, a cyano group, a substituted or unsubstituted alkyl group having 1 to 60 carbon atoms, a substituted or unsubstituted aryl group having 6 to 60 ring-forming carbon atoms, a substituted or unsubstituted heteroaryl group having 2 to 60 ring-forming carbon atoms, —Si(Q₁)(Q₂)(Q₃), or —N(Q₁)(Q₂),
b21 is an integer of are each independently a 0 to 4, b31 is an integer from 0 to 3, and b41 is an integer from 0 to 8, and
A₄₀, X₁, M₁₁, and Q₁ to Q₃ are the same as defined in Formula 1, and X₂, X₃, R₁₁, R₁₂, and b11 are the same as defined in Formula 4.

20. The organometallic compound of claim 14, wherein Formula 1 is represented by any one selected from among compounds in Compound Group 1: 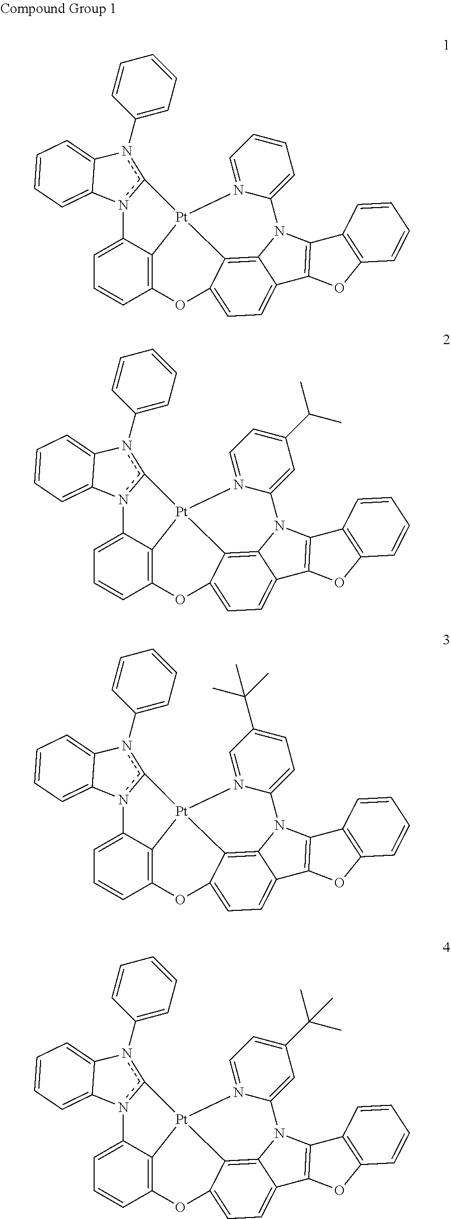 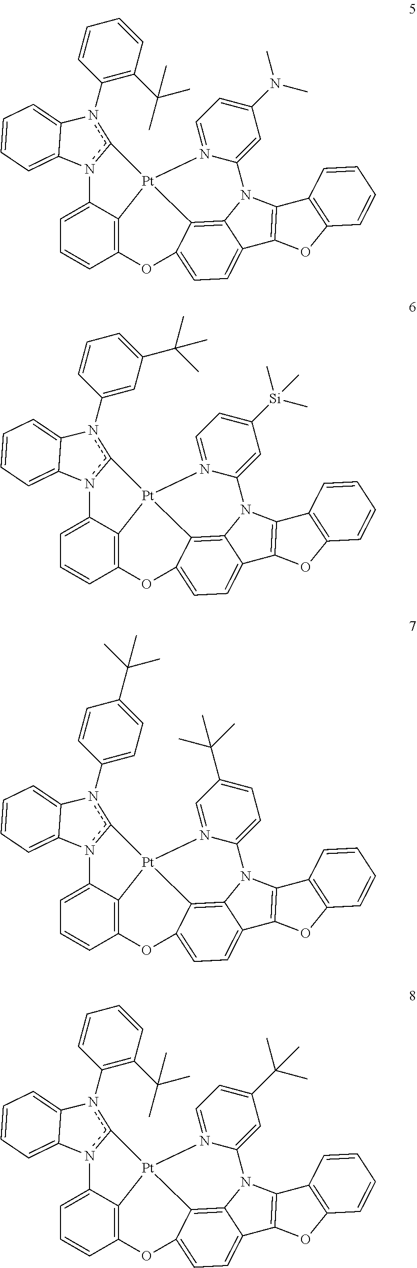 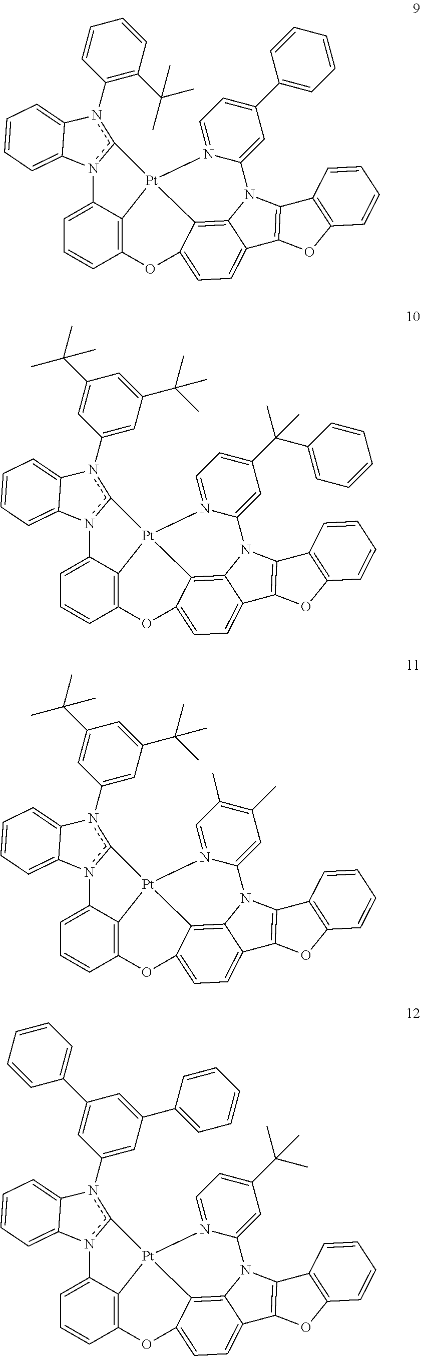 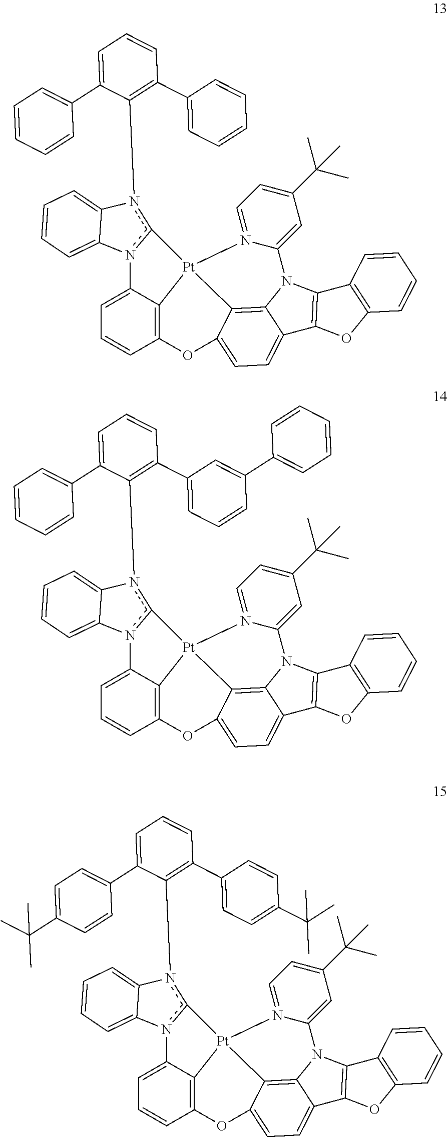 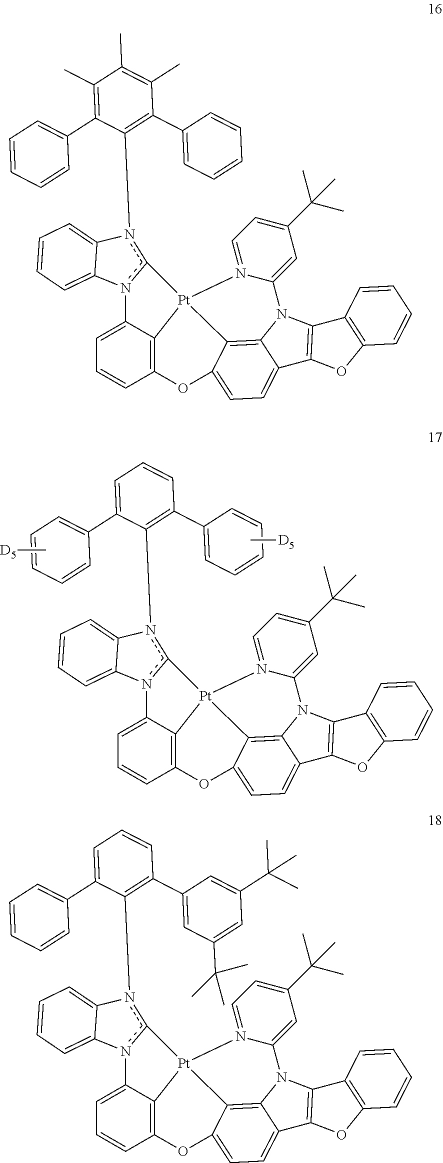 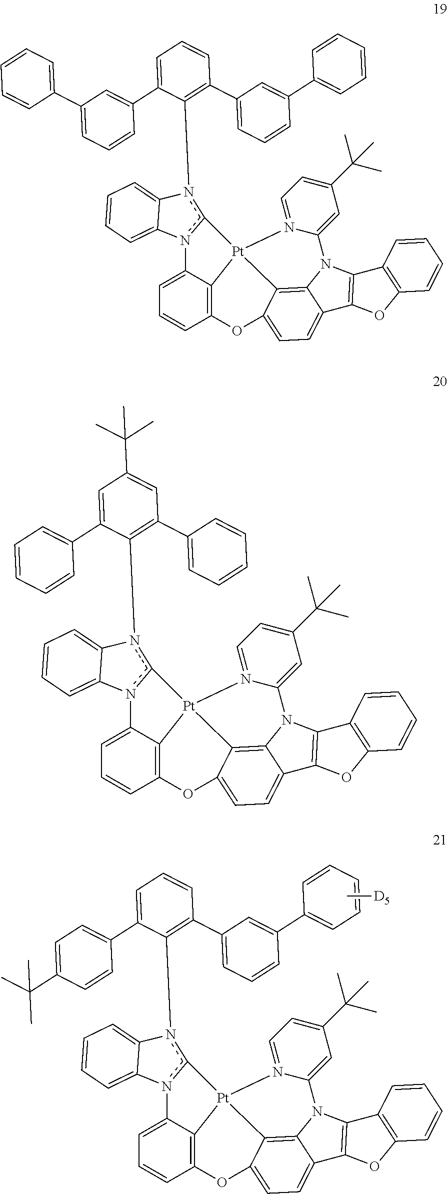 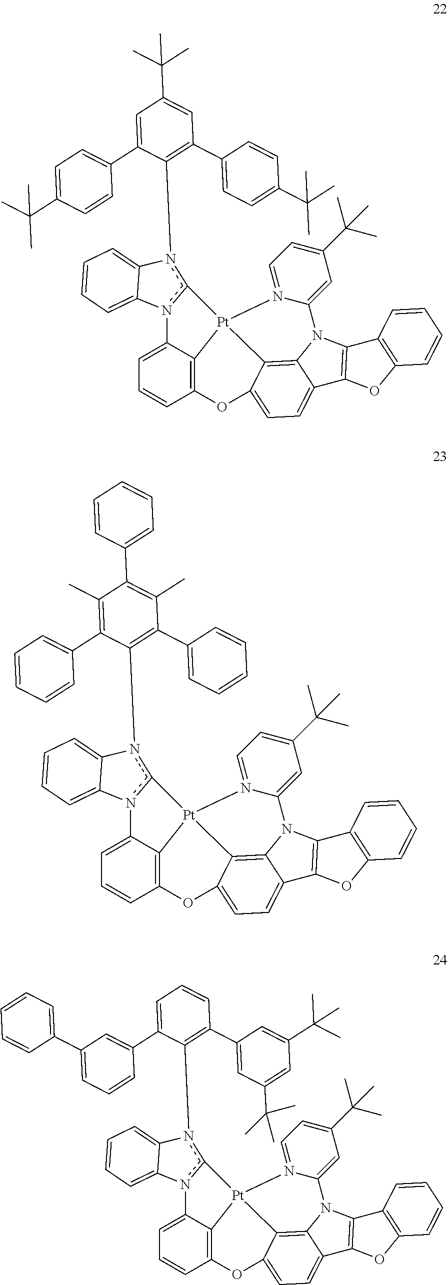 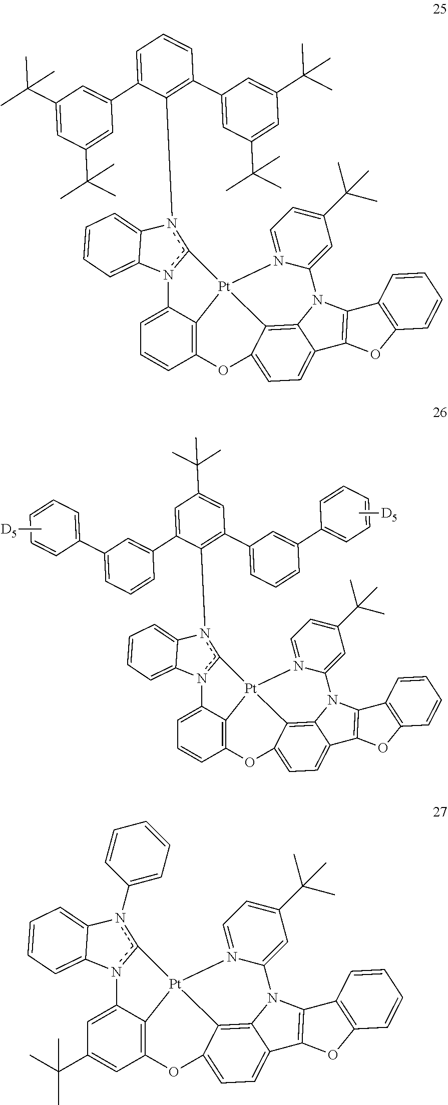 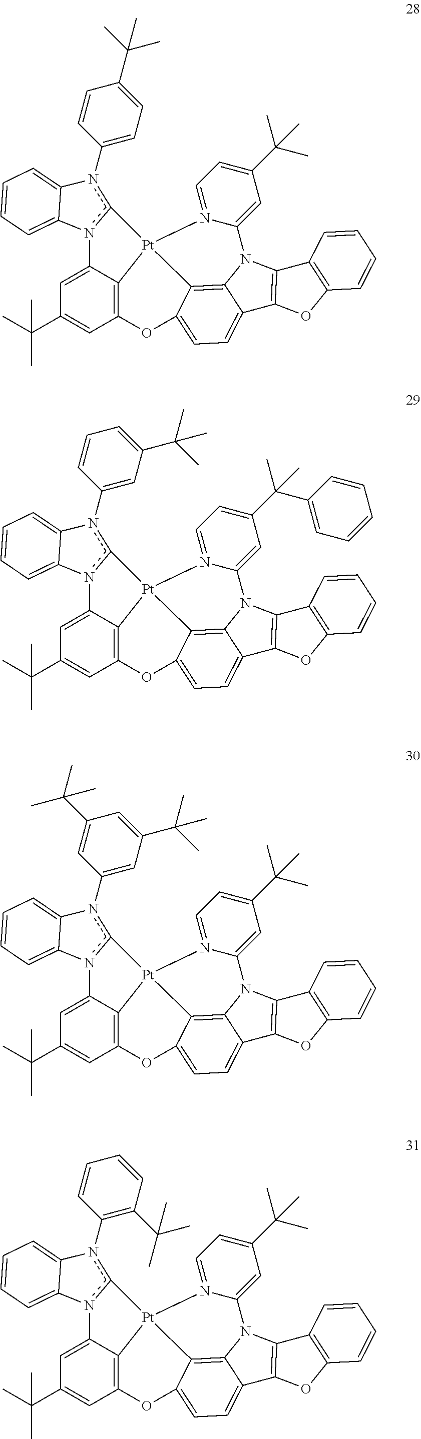 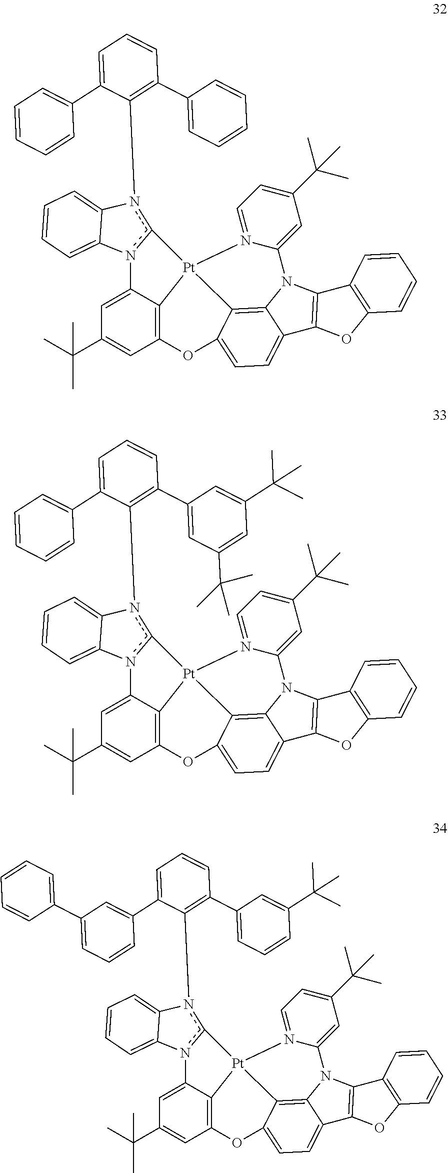 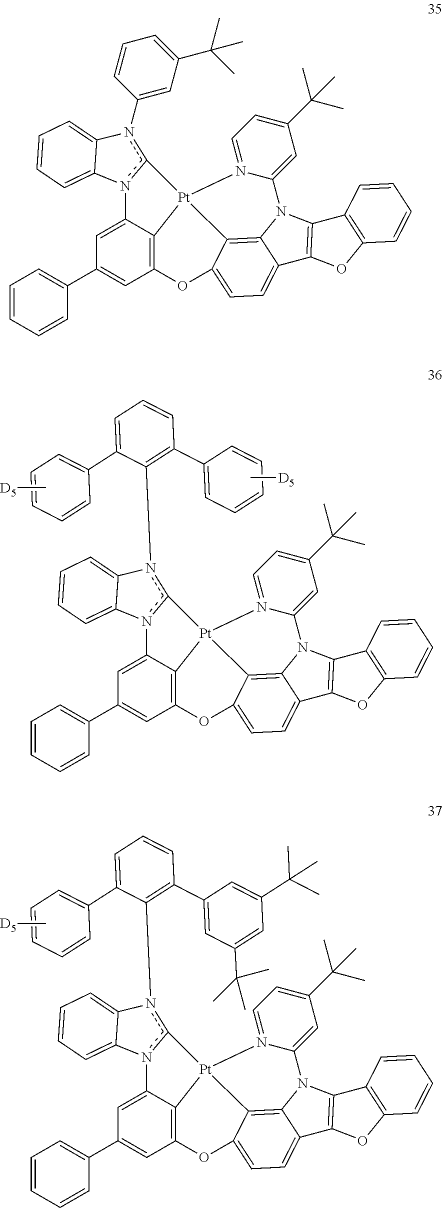 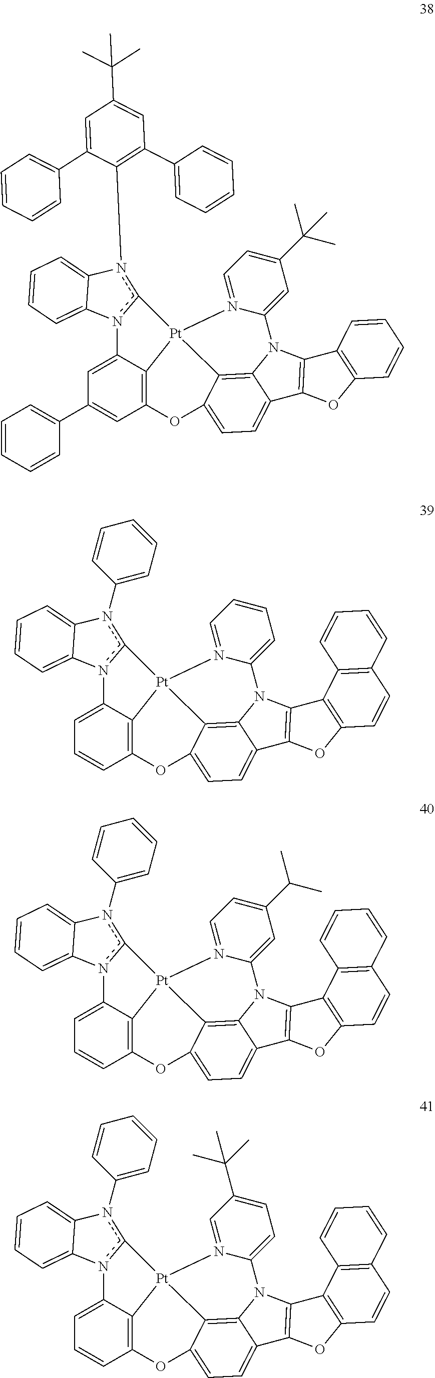 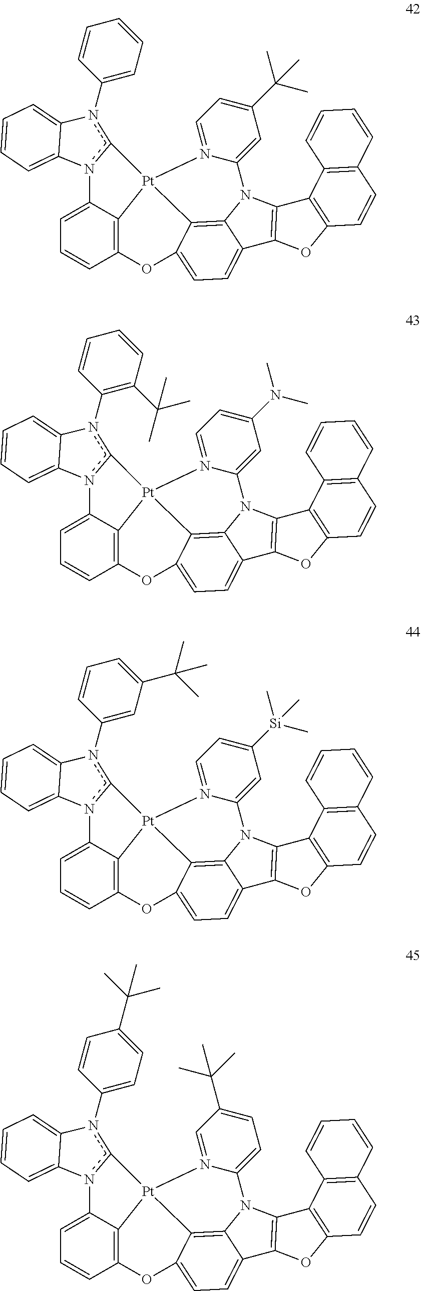 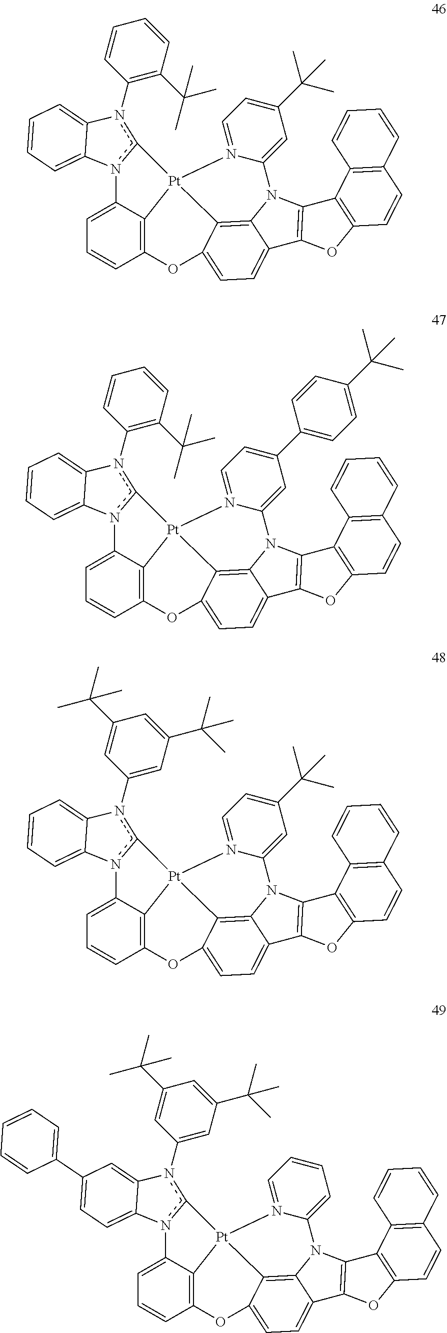 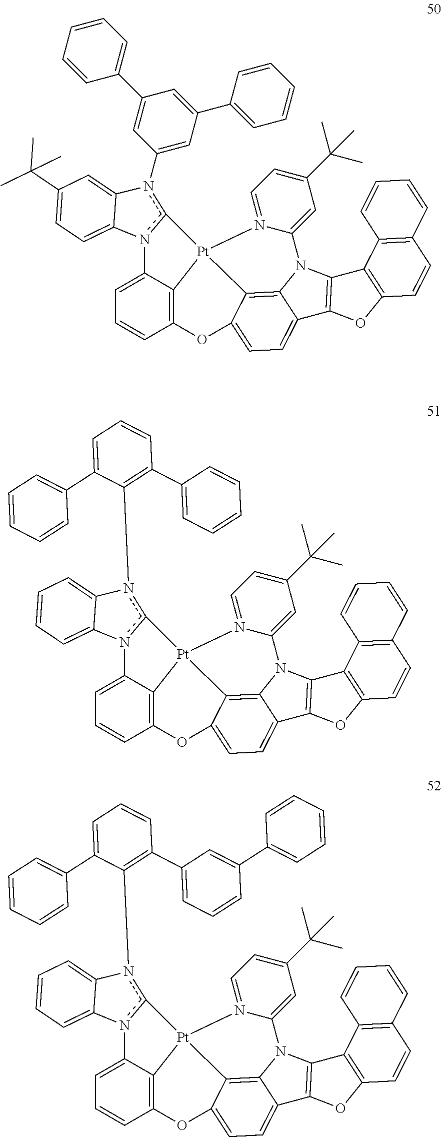 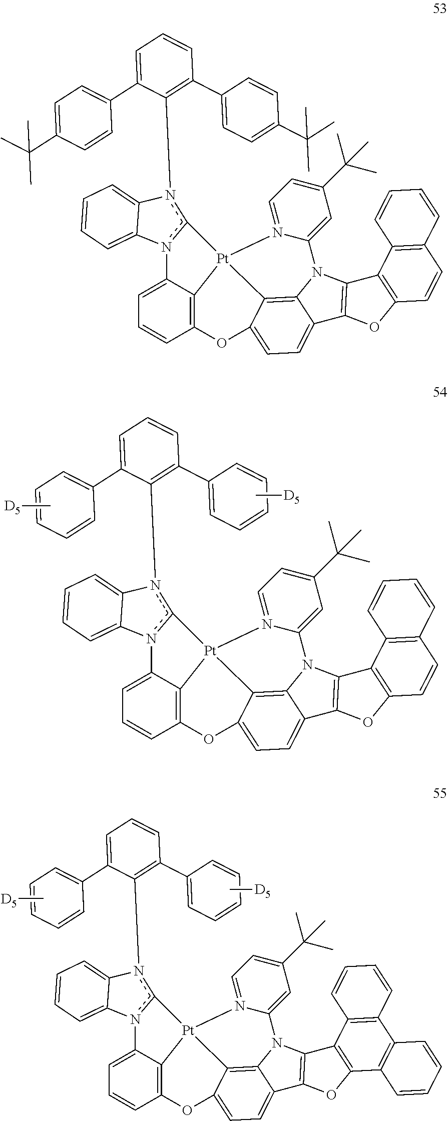 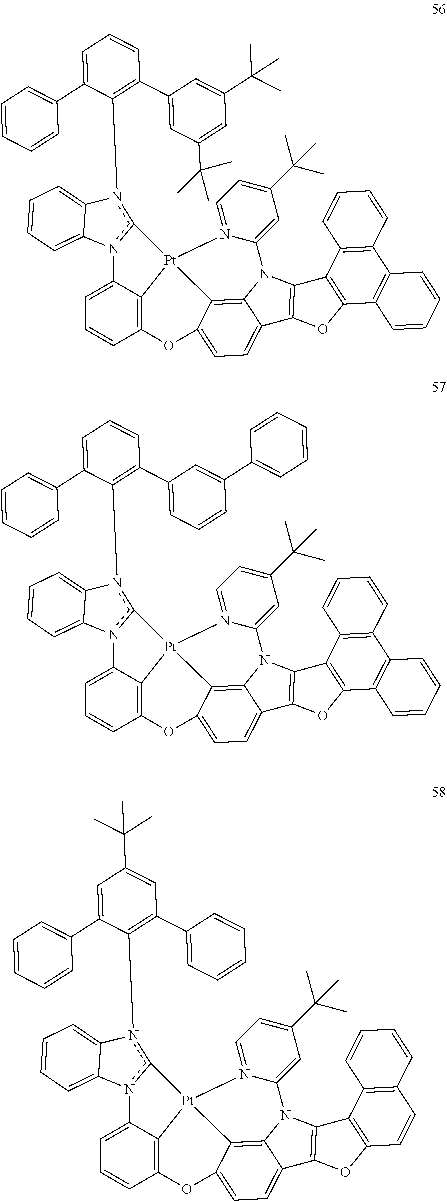 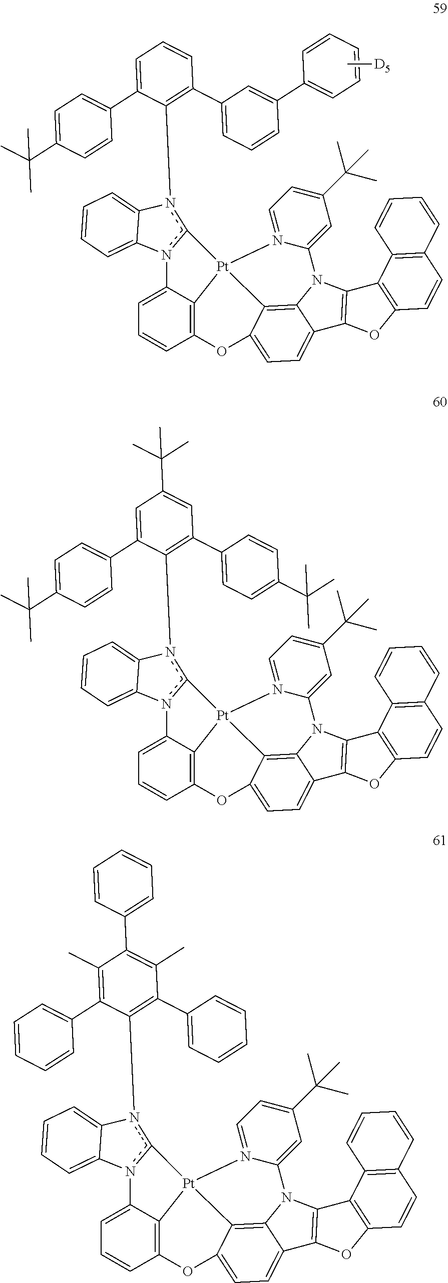 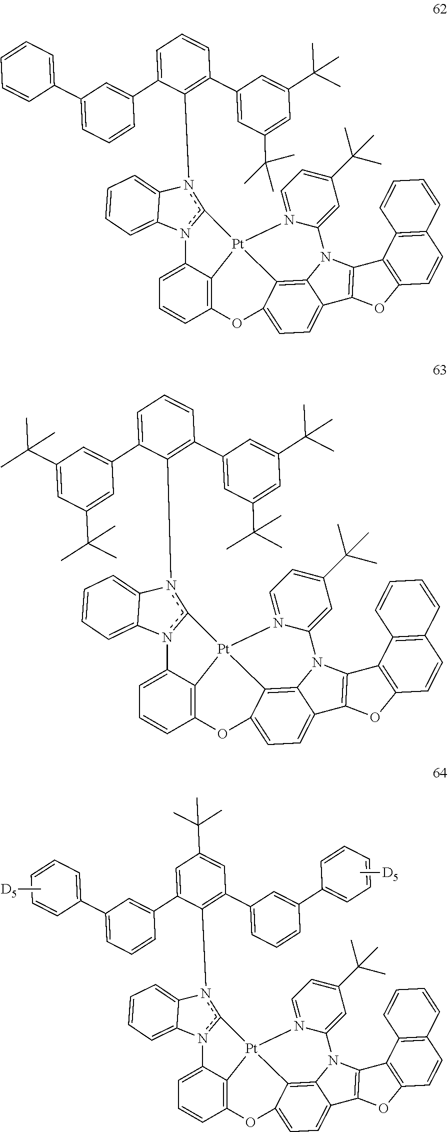 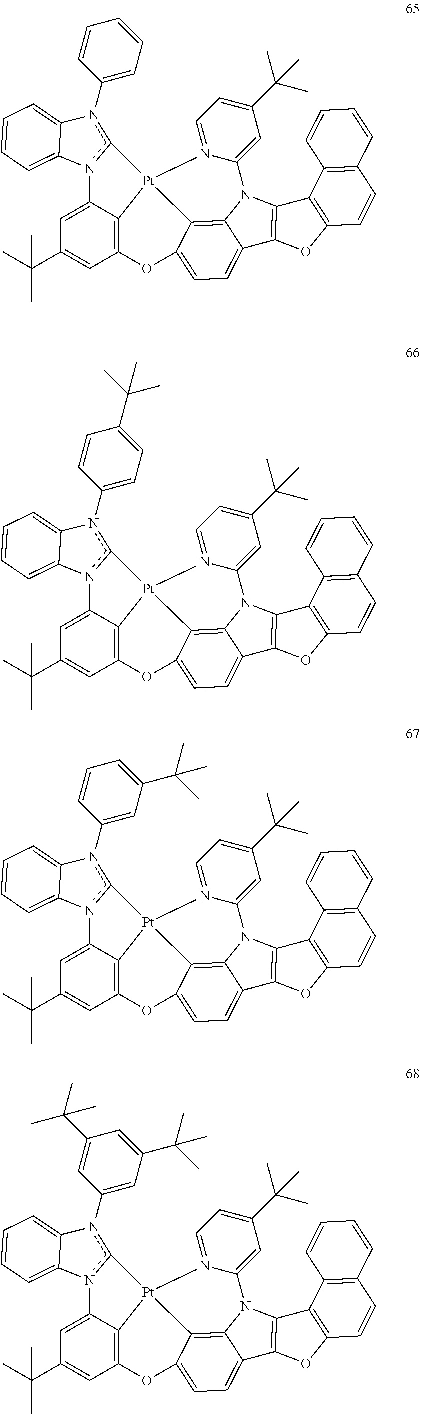 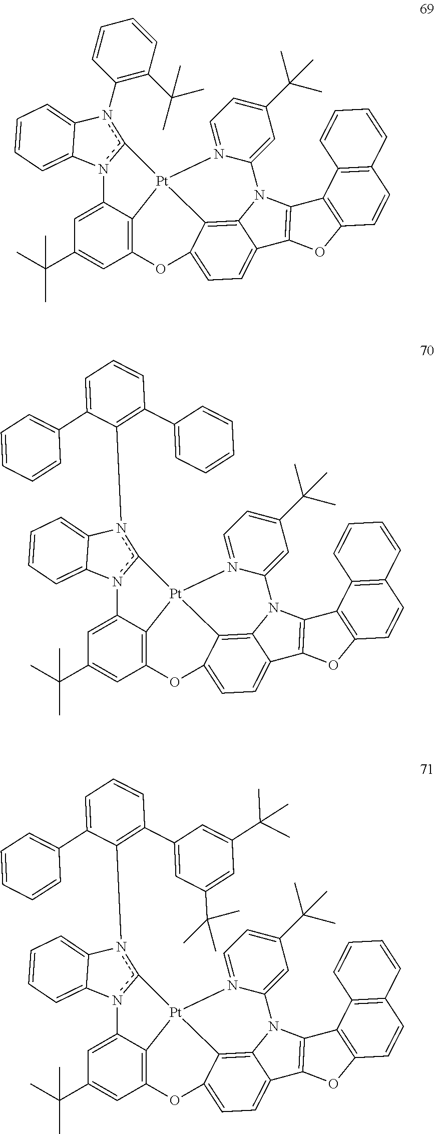 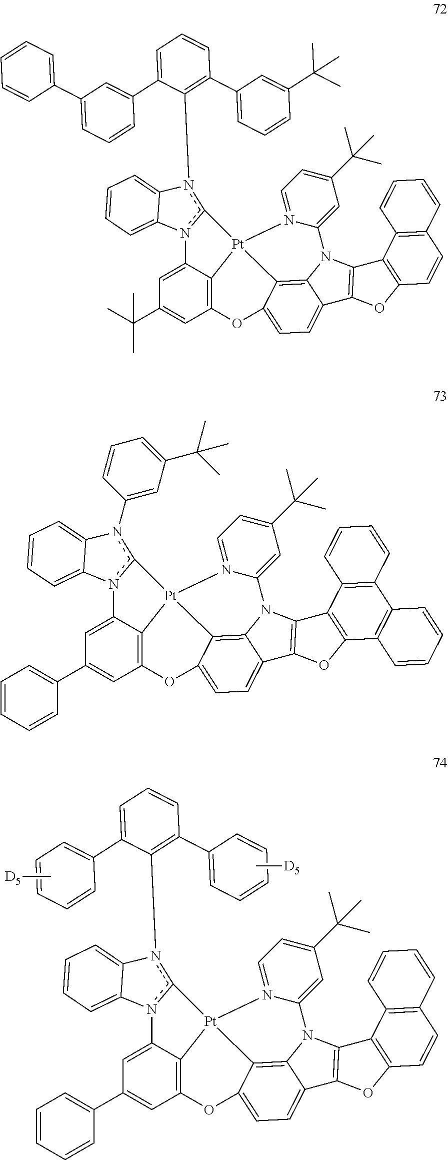 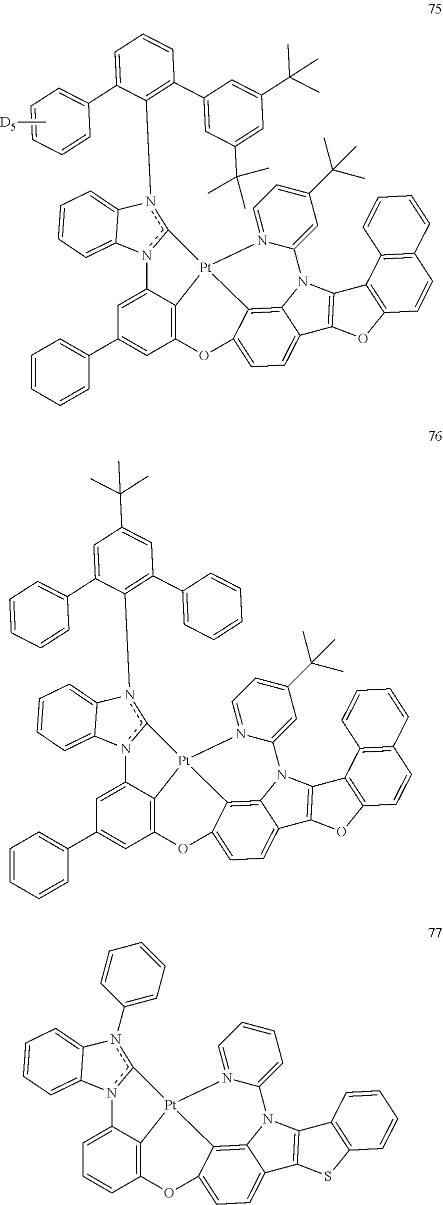 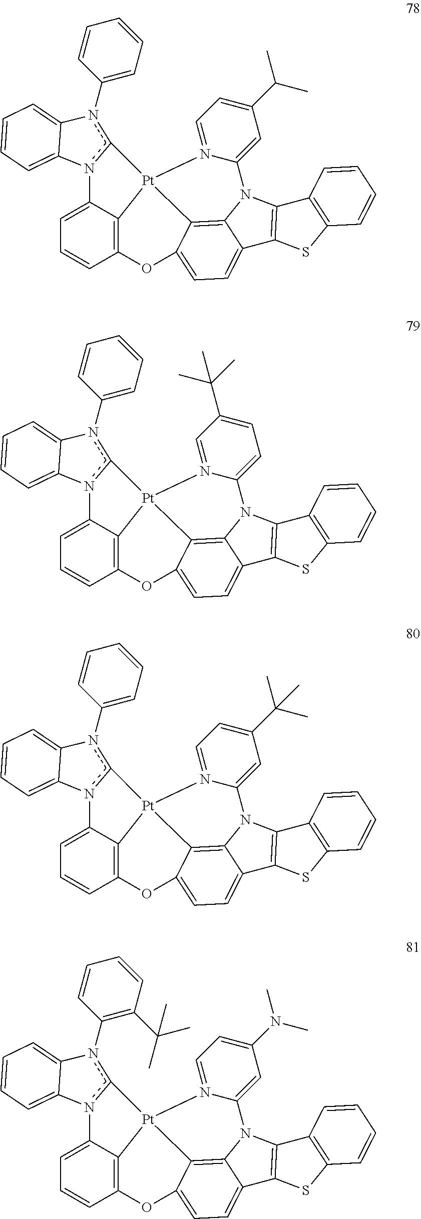 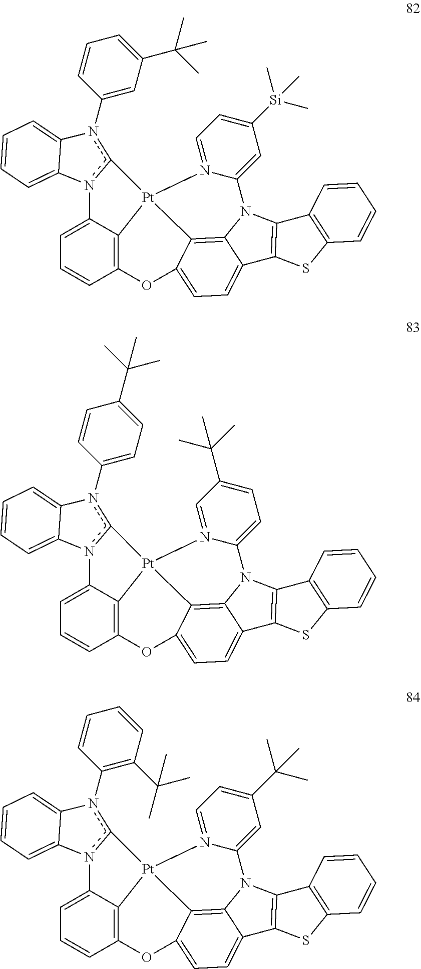 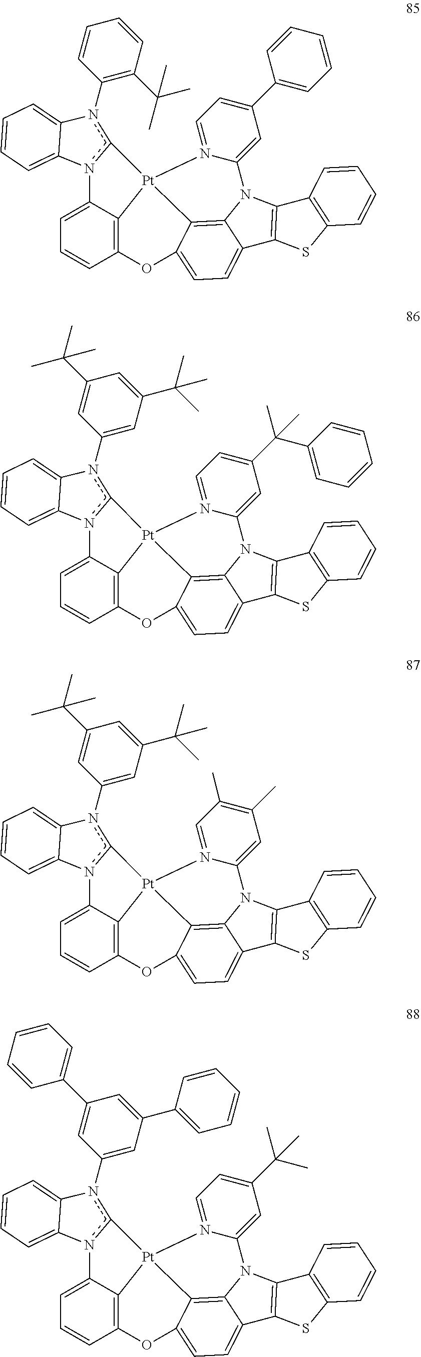 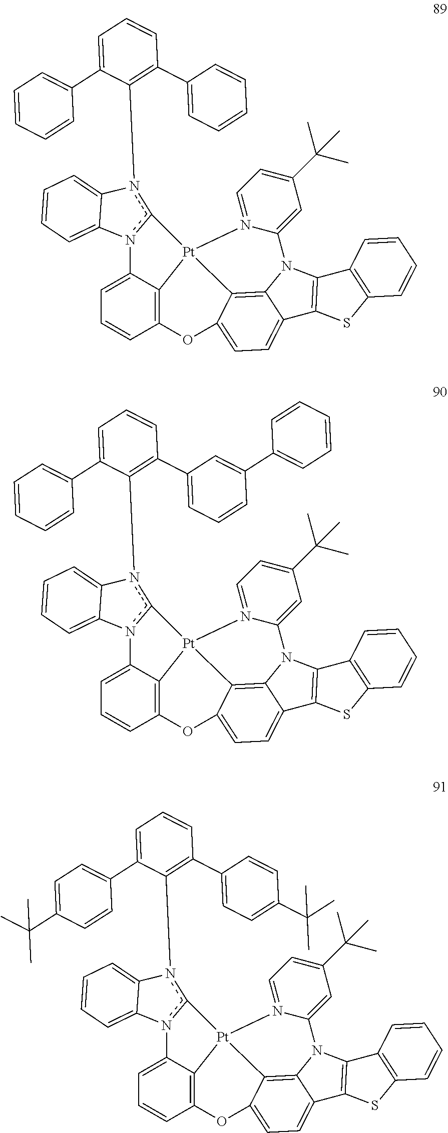 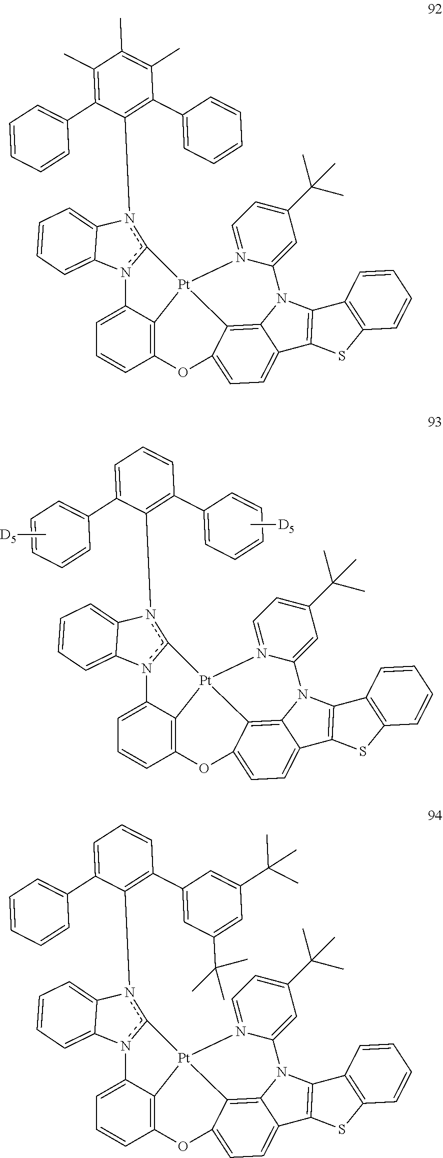 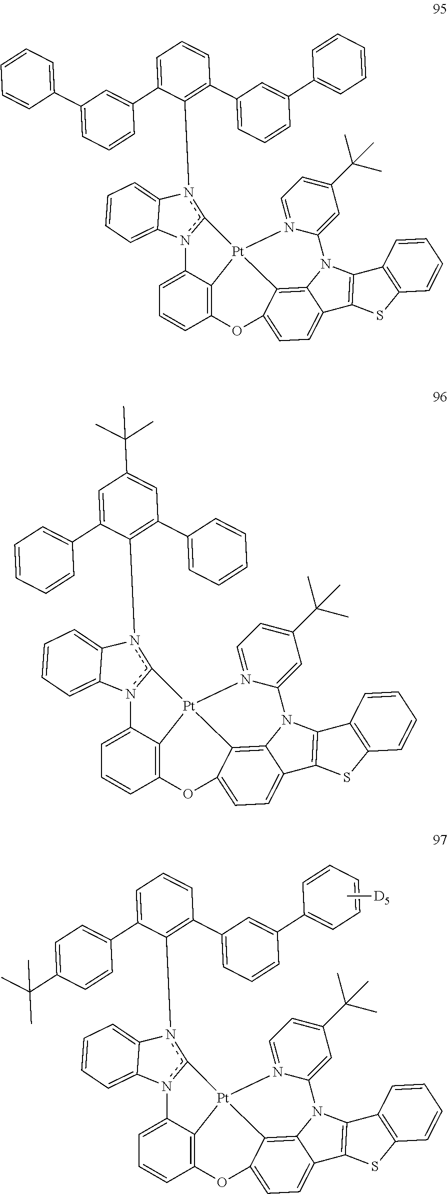 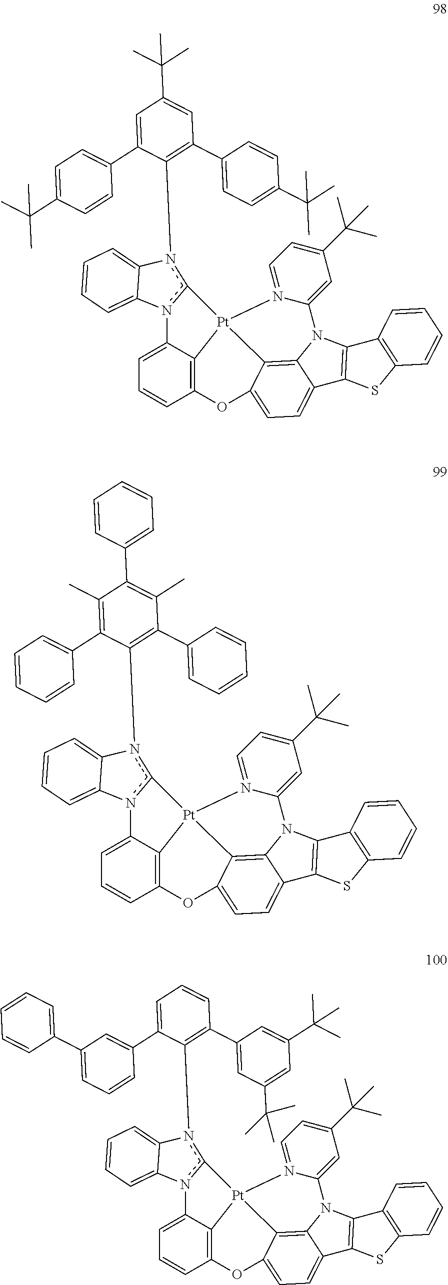 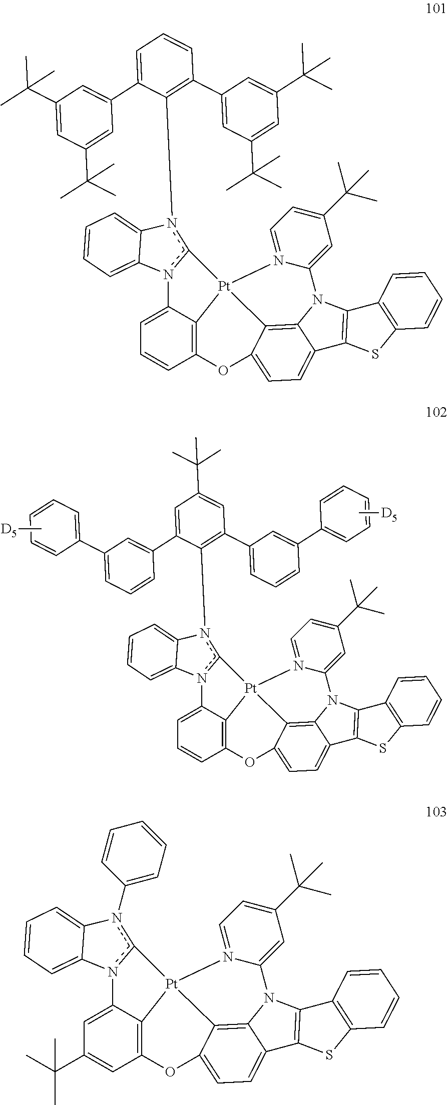 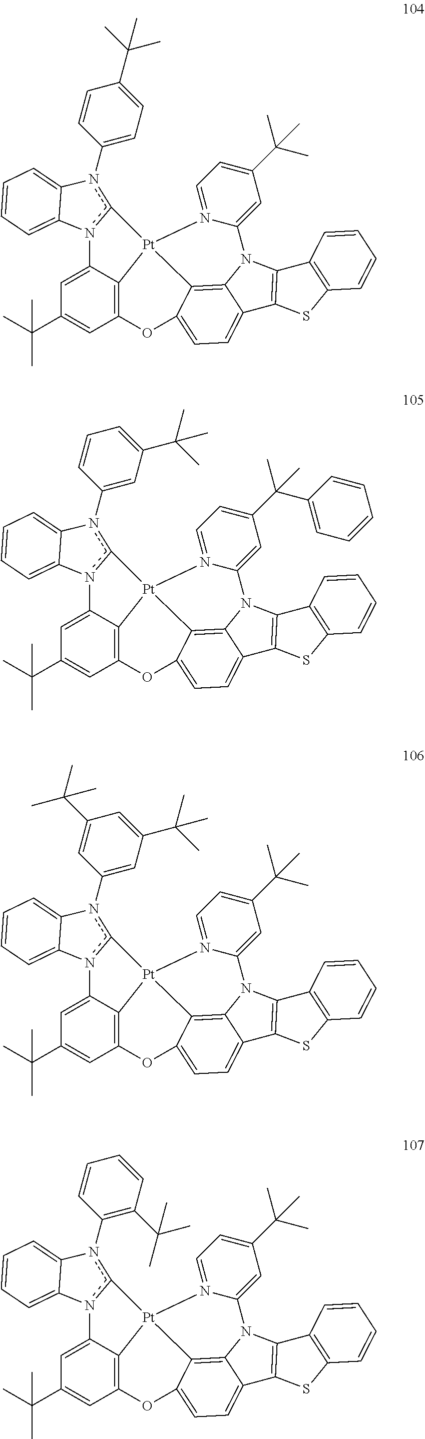 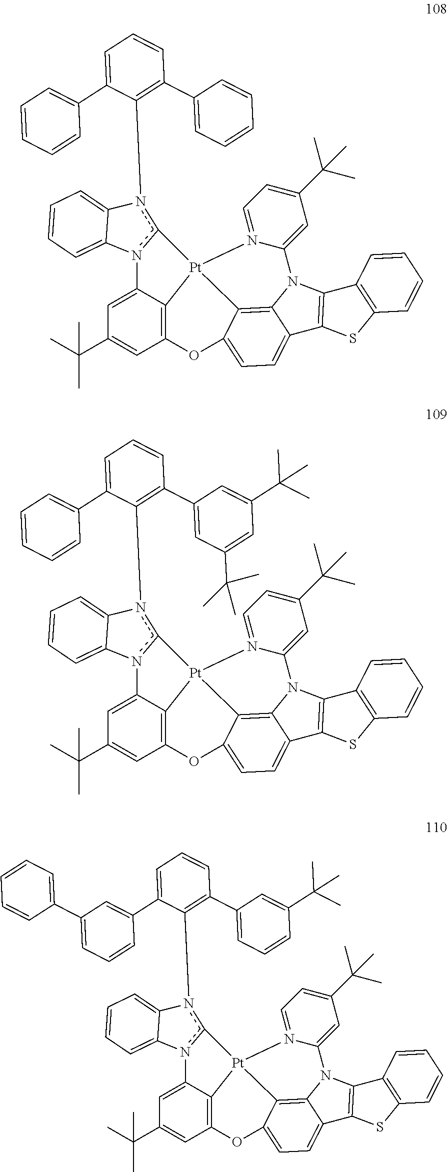 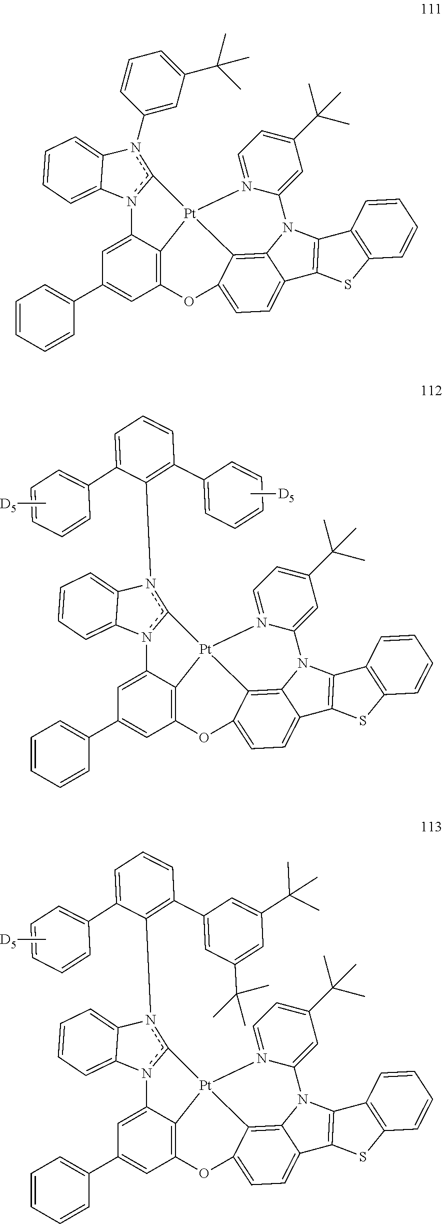 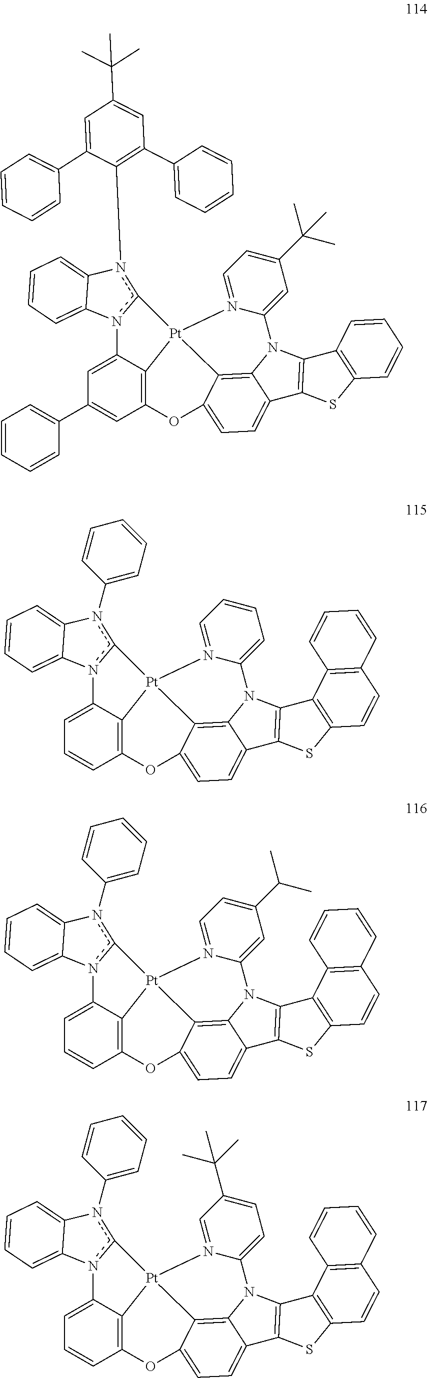 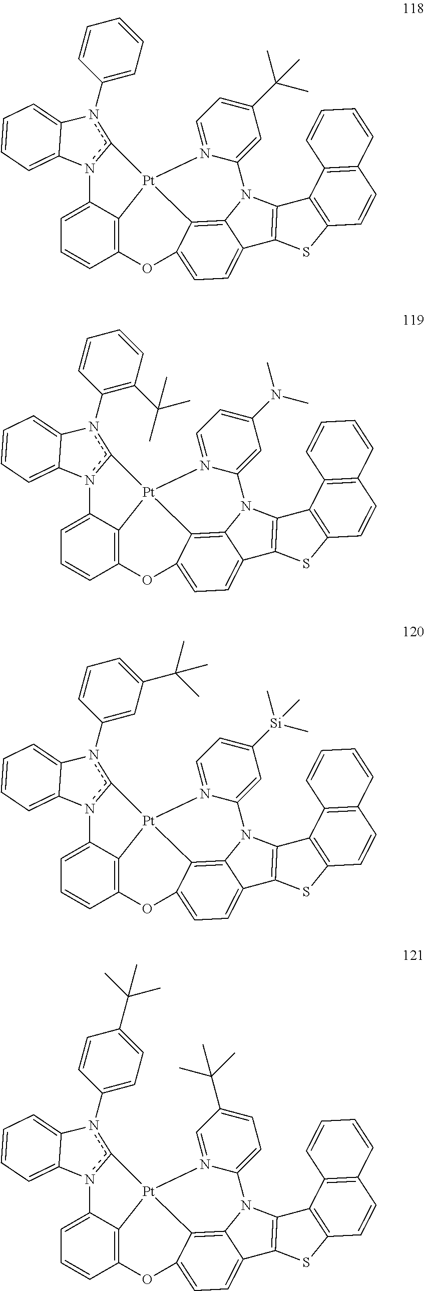 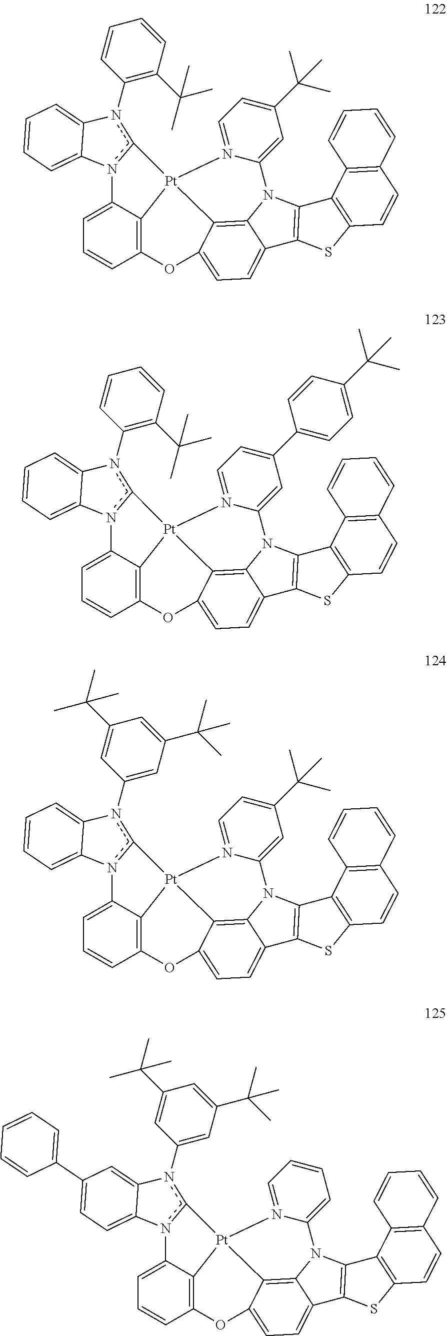 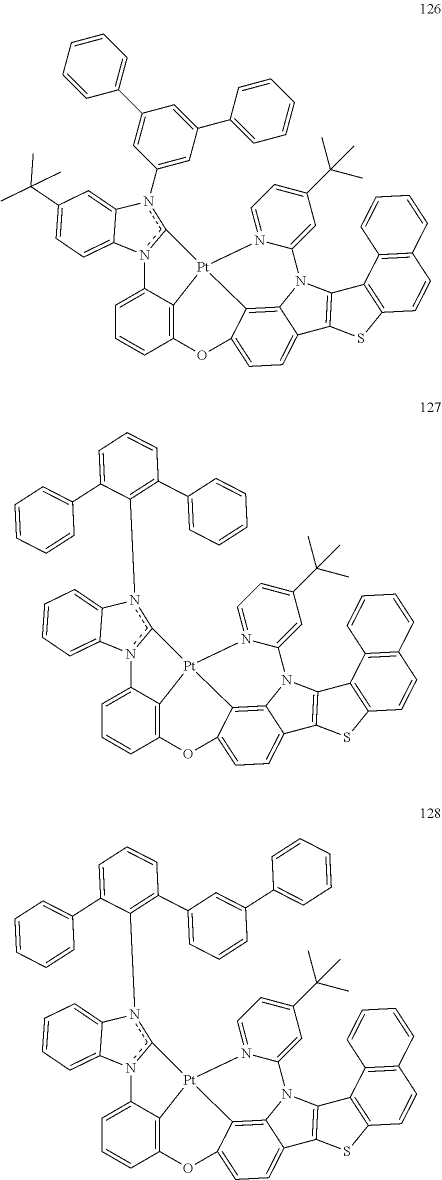 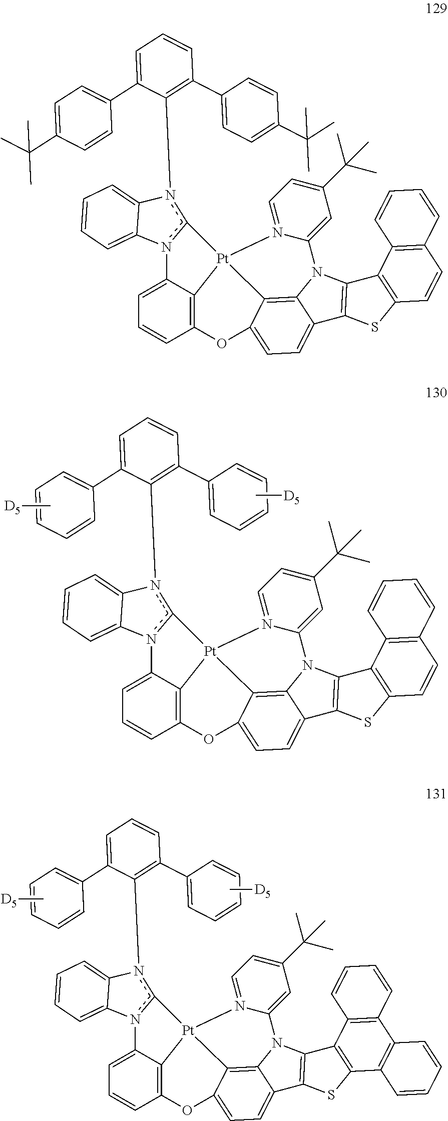 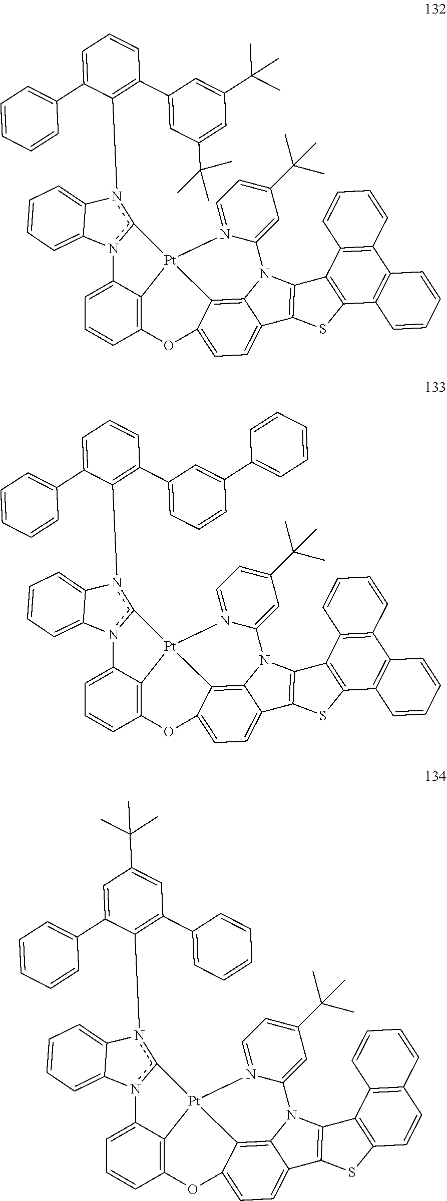 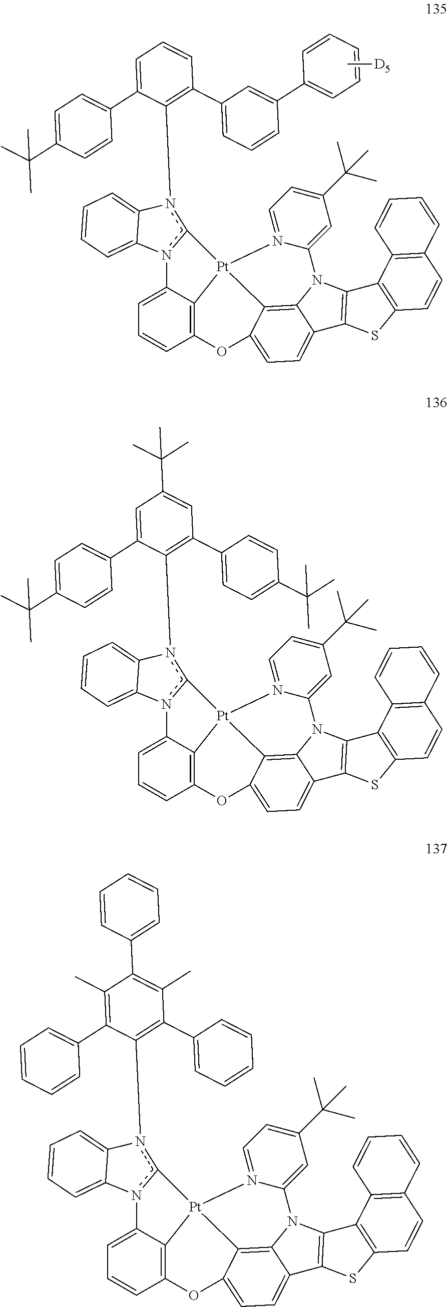 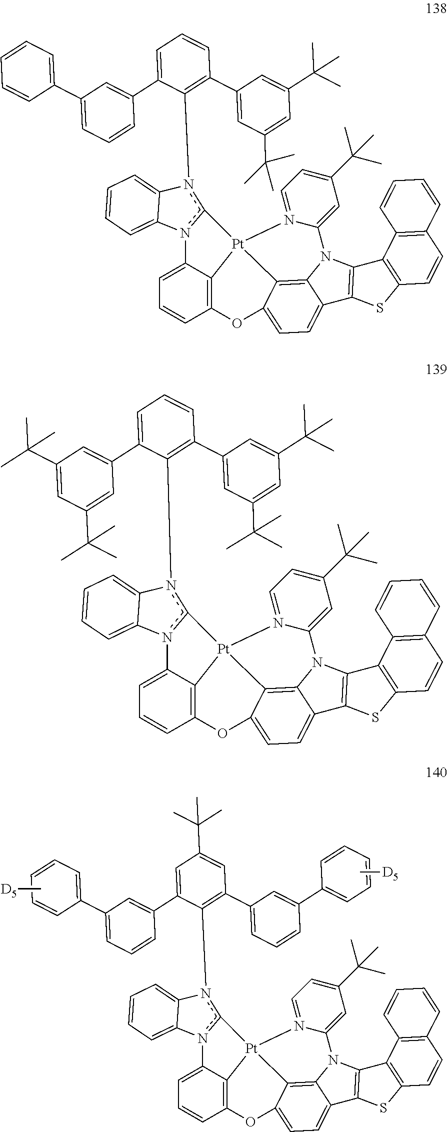 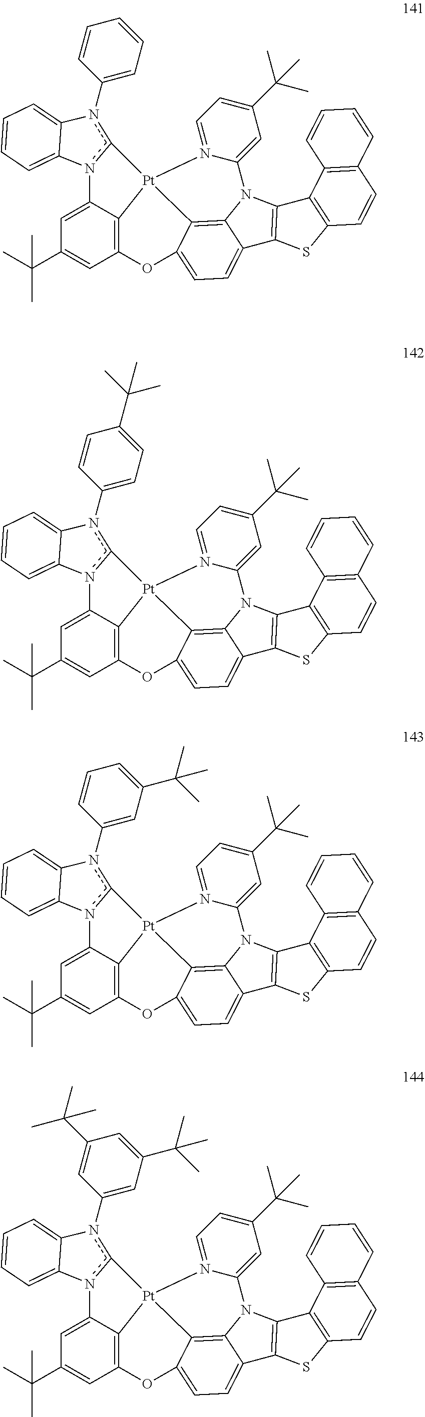 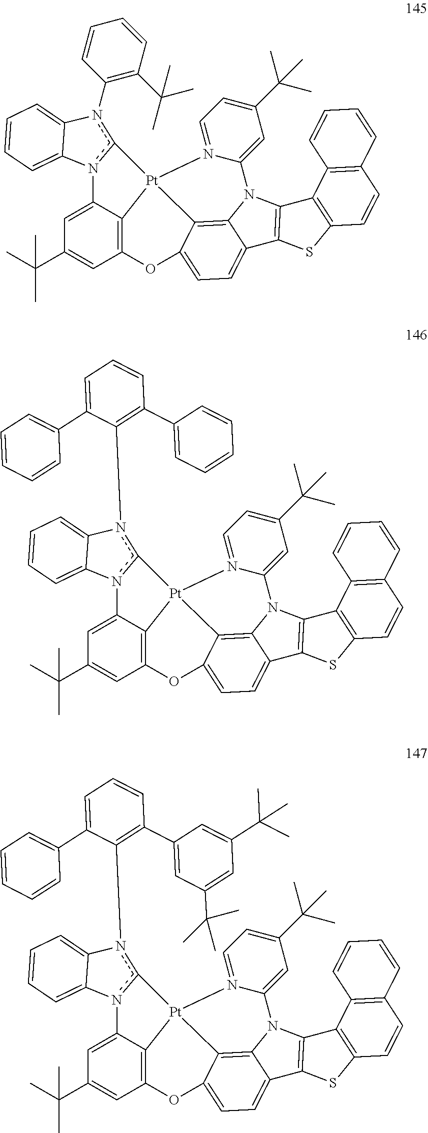 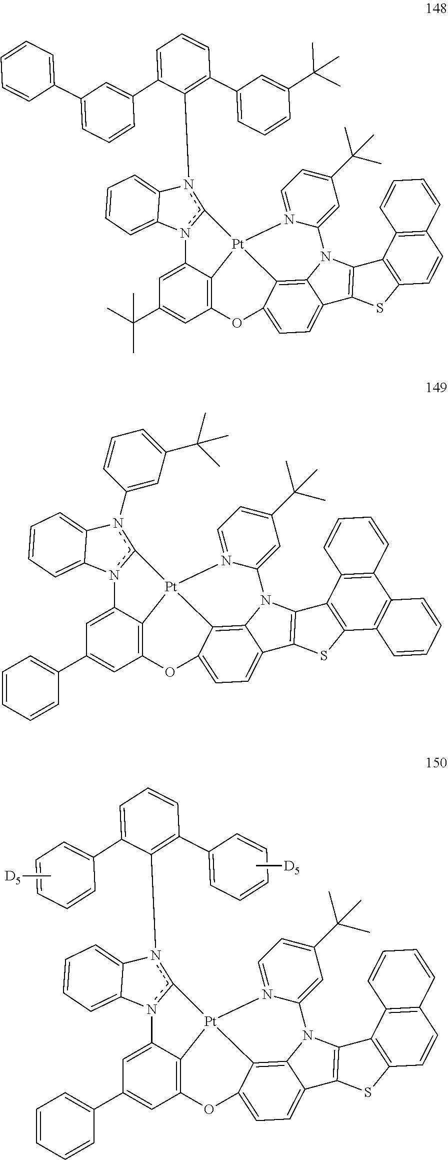 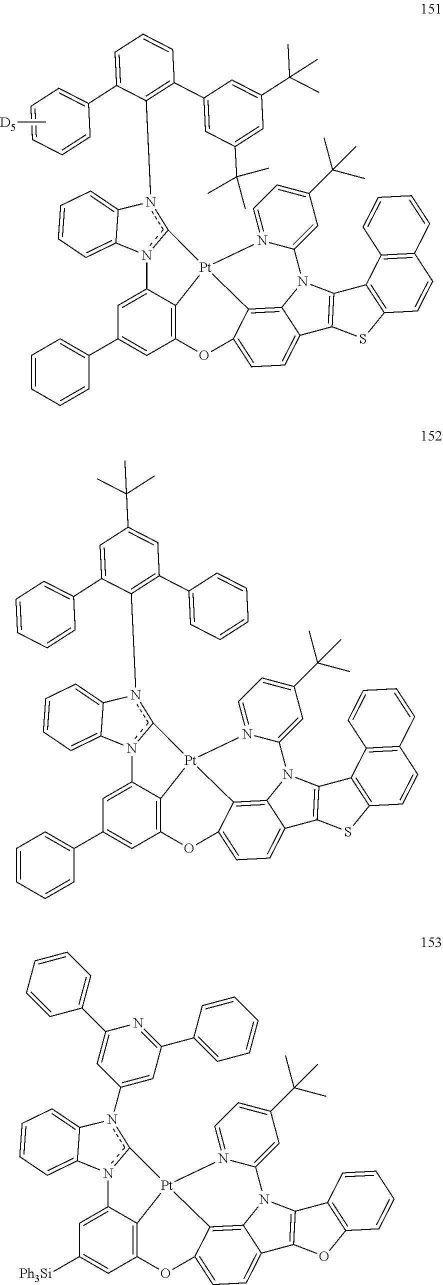 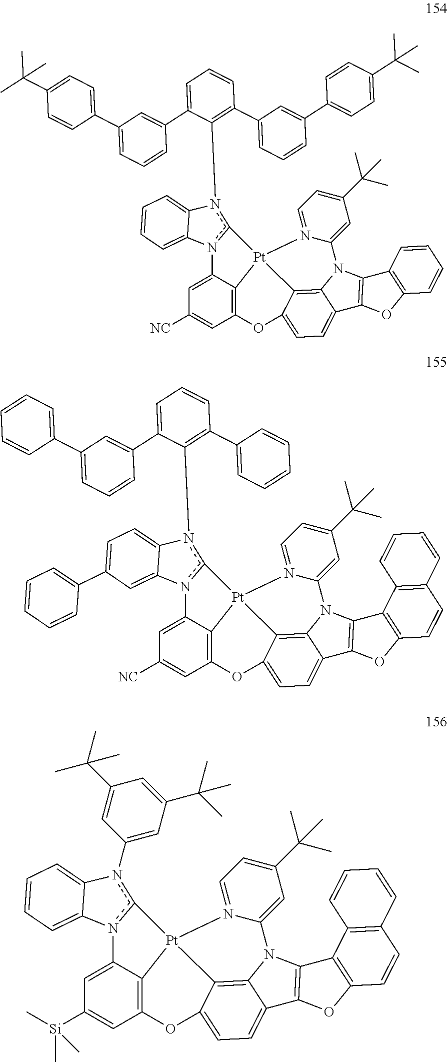 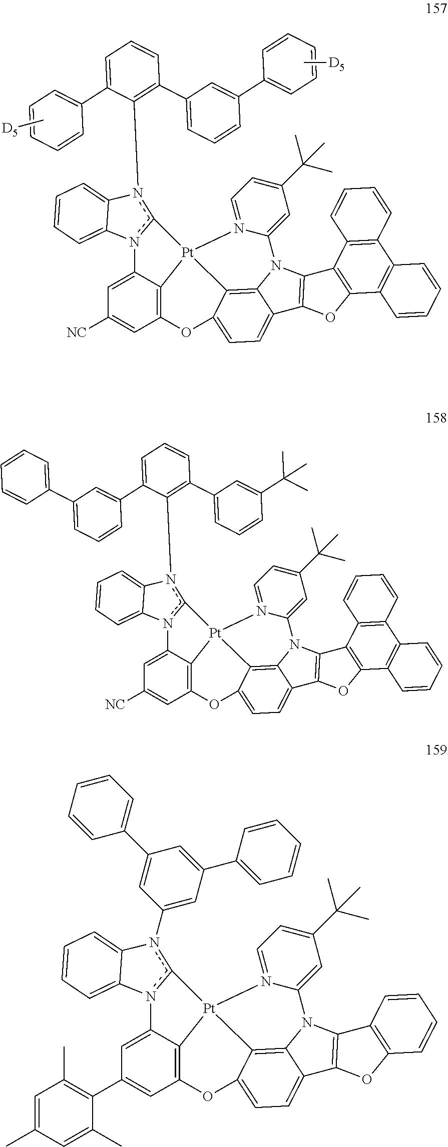 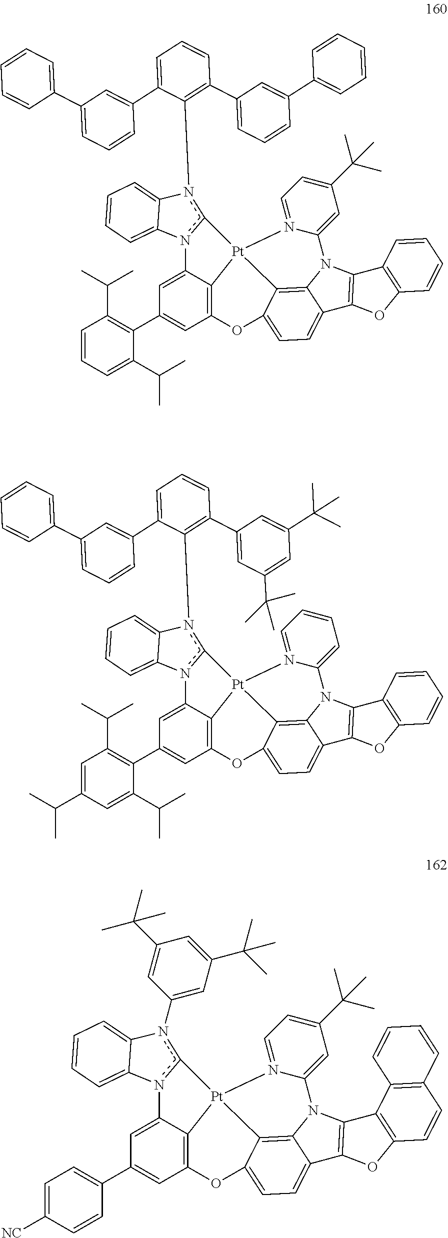 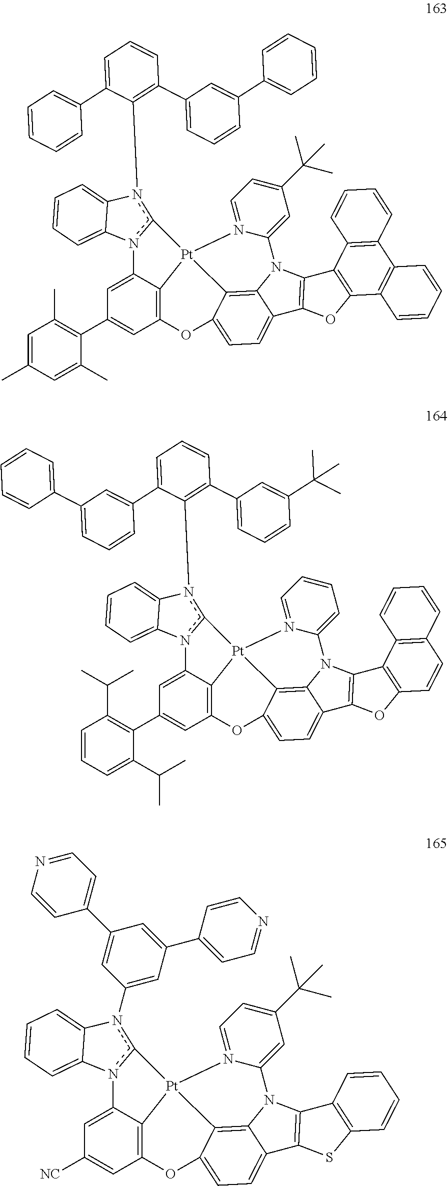 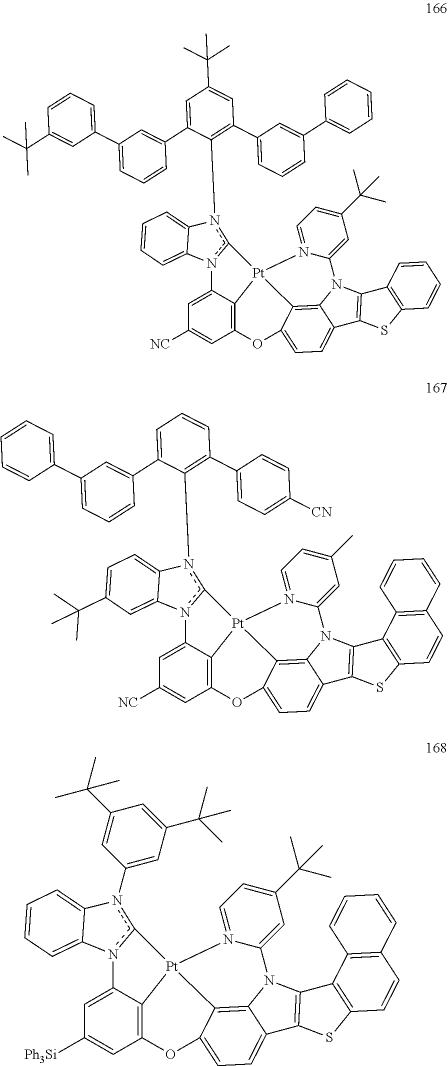 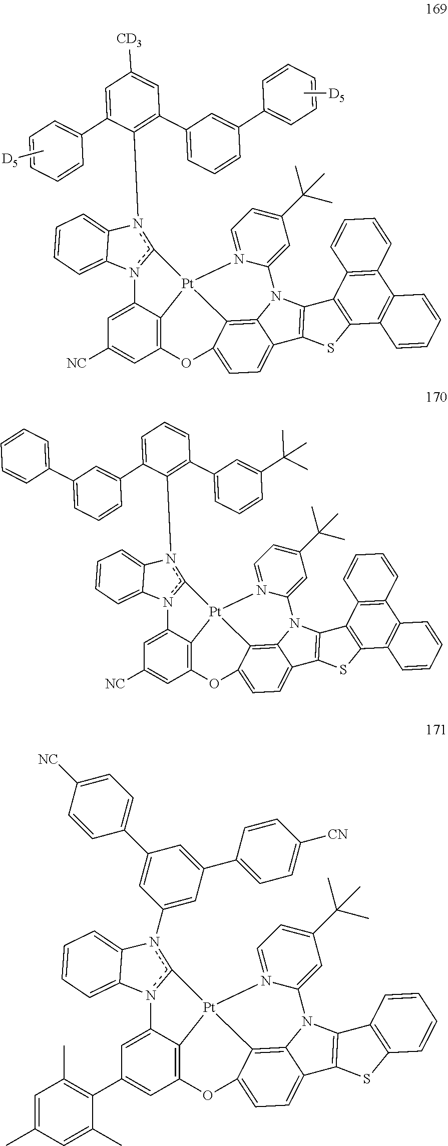 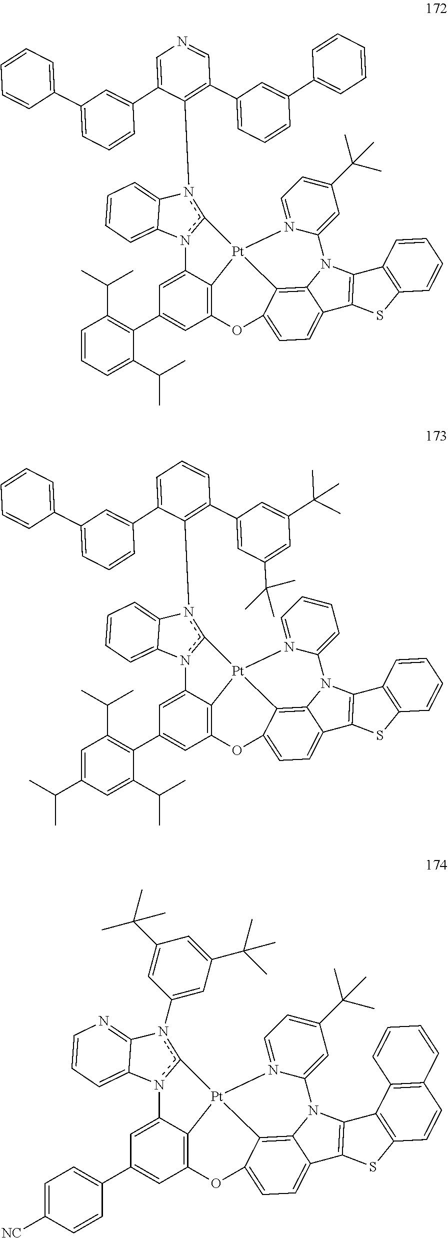 [chemical structure]
